(19) United States
(12) Patent Application Publication
(10) Pub. No.: US 2026/0310019 A1
(43) Pub. Date: Oct. 8, 2026

(54) SEMICONDUCTOR DEVICE, DISPLAY APPARATUS, AND ELECTRONIC DEVICE

(71) Applicant: SEMICONDUCTOR ENERGY LABORATORY CO., LTD., Atsugi-shi, Kanagawa-ken (JP)

(72) Inventors: Hajime KIMURA, Atsugi, Kanagawa (JP); Tatsunori INOUE, Yamato, Kanagawa (JP)

(21) Appl. No.: 19/108,277

(22) PCT Filed: Sep. 1, 2023
(86) PCT No.: PCT/IB2023/058642

§ 371 Date: Mar. 3, 2025

(30) Foreign Application Priority Data
Sep. 8, 2022 (JP) 2022-143013

(51) Int. Cl. G02F 1/133; H10K 59/121

(52) U.S. Cl. CPC G02F 1/13306; H10K 59/1213; H10K 59/1216

(57) ABSTRACT

A semiconductor device with stable operation is provided. The semiconductor device includes a first transistor, a second transistor, a third transistor, and a first capacitor. One of a source and a drain of the third transistor is electrically connected to one of a source and a drain of the second transistor. The other of the source and the drain of the third transistor is electrically connected to a gate of the first transistor and a first terminal of the first capacitor. One of a source and a drain of the first transistor is electrically connected to a gate of the second transistor and a second terminal of the first capacitor. Note that the semiconductor device can be provided in a driver circuit having a function of transmitting a signal for displaying an image to a display device.

### TECHNICAL FIELD

One embodiment of the present invention relates to a semiconductor device, a display apparatus, and an electronic device.

Note that one embodiment of the present invention is not limited to the above technical field. The technical field of the invention disclosed in this specification and the like relates to an object, an operation method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus, a liquid crystal display apparatus, a light-emitting apparatus, a power storage device, an imaging device, a memory device, a signal processing device, a sensor, a processor, an electronic device, a system, a driving method thereof, a manufacturing method thereof, and a testing method thereof.

### BACKGROUND ART

Display apparatuses included in, for example, electronic devices for XR (Extended Reality or Cross Reality) such as VR (virtual reality) or AR (augmented reality), mobile phones (e.g., smartphones), tablet information terminals, and laptop PCs (personal computers) have been improved in various aspects in recent years. For example, display apparatuses have been developed aiming for a higher screen resolution, higher color reproducibility (NTSC ratio), a smaller driver circuit, lower power consumption, and the like.

Furthermore, for example, a circuit for reducing variations in the characteristics of a driving transistor included in a pixel has been under development in order to improve the display quality of a display apparatus. In particular, Patent Document 1 discloses the invention of a pixel circuit that includes a circuit for correcting the threshold voltage of a driving transistor.

Another example is a technique of using a transistor including an oxide semiconductor in a semiconductor thin film, as a switching element included in a pixel circuit of a display apparatus.

A silicon-based semiconductor material is widely known as a material for a semiconductor thin film applicable to a transistor. Other than the silicon-based semiconductor material, an oxide semiconductor has attracted attention. Examples of oxide semiconductors include not only single-component metal oxides, such as indium oxide and zinc oxide, but also multi-component metal oxides. Among the multi-component metal oxides, in particular, an In—Ga—Zn oxide (hereinafter also referred to as IGZO) has been actively researched.

A transistor that includes IGZO as an active layer has an extremely low off-state current (see Non-Patent Document 1), and LSI (Large Scale Integration) and a display apparatus that utilize the characteristics have been reported (see Non-Patent Documents 2 and 3). Patent Document 2 discloses the invention in which a transistor including IGZO in an active layer is used in a pixel circuit of a display apparatus.

### REFERENCE

### Patent Documents

[Patent Document 1] Japanese Published Patent Application No. 2017-10000
[Patent Document 2] Japanese Published Patent Application No. 2010-156963

### Non-Patent Document

[Non-Patent Document 1] K. Kato et al., “Japanese Journal of Applied Physics”, 2012, volume 51, p. 021201-1-021201-7
[Non-Patent Document 2] S. Matsuda et al., “2015 Symposium on VLSI Technology Digest of Technical Papers”, 2015, p. T216-T217
[Non-Patent Document 3] S. Amano et al., “SID Symposium Digest of Technical Papers”, 2010, volume 41, issue 1, p. 626-629

### SUMMARY OF THE INVENTION

### Problems to be Solved by the Invention

In general, by driving a driver circuit such as a source driver circuit or a gate driver circuit provided in a display apparatus, an image can be displayed on a display portion of the display apparatus. The driver circuit is provided with a shift register to transmit a predetermined signal to each row or each column.

The shift register where retention circuits are continuously connected is configured to transmit a signal input to a retention circuit to an adjacent retention circuit sequentially. When an operation malfunction occurs in one of the plurality of retention circuits, a defect such as missing or distortion may appear in a waveform of an output signal from the retention circuit. When a defect appears in the waveform of the signal output from the retention circuit, the signal is input to the retention circuits in the next and subsequent stages, and the effect spreads throughout the entire shift register. Thus, the defect such as missing or distortion may appear also in the waveform of a signal output from the shift register.

In particular, when noise is input to a retention node that retains data of a signal as a potential in a retention circuit included in a shift register, a defect appears in a waveform of a signal output from the retention circuit in some cases. Thus, a signal including a defect such as missing or distortion tends to be transmitted to the retention circuits in the subsequent stages in the shift register.

One object of one embodiment of the present invention is to provide a semiconductor device that operates stably. Another object of one embodiment of the present invention is to provide a semiconductor device with high driving speed. Another object of one embodiment of the present invention is to provide a highly reliable semiconductor device. Another object of one embodiment of the present invention is to provide a display apparatus including the semiconductor device. Another object of one embodiment of the present invention is to provide an electronic device including the above display apparatus. Another object of one embodiment of the present invention is to provide a novel semiconductor device, a novel display apparatus, or a novel electronic device.

Note that the objects of one embodiment of the present invention are not limited to the objects described above. The objects described above do not preclude the existence of other objects. Note that the other objects are objects that are not described in this section and are described below. The objects that are not described in this section can be derived from the description of the specification, the drawings, and the like and can be extracted as appropriate from the description by those skilled in the art. Note that one embodiment of the present invention achieves at least one of the objects listed above and the other objects. Note that one embodiment of the present invention does not necessarily achieve all of the above objects and the other objects.

### Means for Solving the Problems

A cause of the above-described defect that appears in a signal output from the retention circuit of the shift register is probably an unintentional change in the potential of the retention node that retains data of a signal in the retention circuit during the operation of the shift register. Thus, in one embodiment of the present invention, the retention circuit is configured to prevent the unintentional change in the potential of the retention node during the operation of the shift register.

Examples of a semiconductor device (a retention circuit), a display apparatus, and an electronic device for solving the above problems are described below.

(1) One embodiment of the present invention is a semiconductor device including a first transistor, a second transistor, a third transistor, a fourth transistor, a fifth transistor, a sixth transistor, a seventh transistor, an eighth transistor, a first capacitor, and a second capacitor. One of a source and a drain of the third transistor is electrically connected to one of a source and a drain of the second transistor, one of a source and a drain of the seventh transistor, and one of a source and a drain of the eighth transistor. The other of the source and the drain of the third transistor is electrically connected to a gate of the first transistor and a first terminal of the first capacitor. One of a source and a drain of the first transistor is electrically connected to a gate of the second transistor, one of a source and a drain of the fourth transistor, and a second terminal of the first capacitor. A gate of the fourth transistor is electrically connected to one of a source and a drain of the fifth transistor, one of a source and a drain of the sixth transistor, a gate of the eighth transistor, and a first terminal of the second capacitor. A gate of the seventh transistor is electrically connected to a gate of the sixth transistor.

(2) Another embodiment of the present invention is a semiconductor device, which is different from the above (1), including a first transistor, a second transistor, a third transistor, a fourth transistor, a fifth transistor, a sixth transistor, a seventh transistor, an eighth transistor, a first capacitor, and a second capacitor. One of a source and a drain of the third transistor is electrically connected to one of a source and a drain of the second transistor, one of a source and a drain of the seventh transistor, and one of a source and a drain of the eighth transistor. The other of the source and the drain of the third transistor is electrically connected to a gate of the first transistor and a first terminal of the first capacitor. One of a source and a drain of the first transistor is electrically connected to a gate of the second transistor, the gate of the second transistor, one of a source and a drain of the fourth transistor, and a second terminal of the first capacitor. A gate of the fourth transistor is electrically connected to one of a source and a drain of the fifth transistor, one of a source and a drain of the sixth transistor, a gate of the eighth transistor, and a first terminal of the second capacitor. A gate of the seventh transistor is electrically connected to a gate of the sixth transistor.

(3) Another embodiment of the present invention is a semiconductor device including a first transistor, a second transistor, a third transistor, a fourth transistor, a fifth transistor, a sixth transistor, a seventh transistor, an eighth transistor, a ninth transistor, a first capacitor, a second capacitor, and a third capacitor. One of a source and a drain of the third transistor is electrically connected to one of a source and a drain of the second transistor, one of a source and a drain of the fourth transistor, one of a source and a drain of the eighth transistor, and one of a source and a drain of the ninth transistor. The other of the source and the drain of the third transistor is electrically connected to a gate of the first transistor and a first terminal of the first capacitor. One of a source and a drain of the first transistor is electrically connected to one of a source and a drain of the fifth transistor, a second terminal of the first capacitor, and a first terminal of the second capacitor. A gate of the second transistor is electrically connected to the other of the source and the drain of the fourth transistor and a second terminal of the second capacitor. A gate of the fifth transistor is electrically connected to one of a source and a drain of the sixth transistor, one of a source and a drain of the seventh transistor, a gate of the ninth transistor, and a first terminal of the third capacitor. A gate of the ninth transistor is electrically connected to a gate of the seventh transistor.

(4) Another embodiment of the present invention is a semiconductor device, which is different from the above (1) and (2), including a first transistor, a second transistor, a third transistor, a fourth transistor, a fifth transistor, a sixth transistor, a seventh transistor, an eighth transistor, a first capacitor, and a second capacitor. One of a source and a drain of the third transistor is electrically connected to one of a source and a drain of the seventh transistor and one of a source and a drain of the eighth transistor. The other of the source and the drain of the third transistor is electrically connected to a gate of the first transistor, one of a source and a drain of the second transistor, and a first terminal of the first capacitor. One of a source and a drain of the first transistor is electrically connected to a gate of the second transistor, one of a source and a drain of the fourth transistor, and a second terminal of the first capacitor. A gate of the fourth transistor is electrically connected to one of a source and a drain of the fifth transistor, one of a source and a drain of the sixth transistor, a gate of the eighth transistor, and a first terminal of the second capacitor. A gate of the seventh transistor is electrically connected to a gate of the sixth transistor.

(5) Another embodiment of the present invention is a semiconductor device including a first transistor, a second transistor, a third transistor, and a first capacitor. One of a source and a drain of the third transistor is electrically connected to one of a source and a drain of the second transistor. The other of the source and the drain of the third transistor is electrically connected to a gate of the first transistor and a first terminal of the first capacitor. One of a source and a drain of the first transistor is electrically connected to a gate of the second transistor and a second terminal of the first capacitor.

(6) Another embodiment of the present invention is a semiconductor device, which is different from the above (5), including a first transistor, a second transistor, a third transistor, and a first capacitor. One of a source and a drain of the third transistor is electrically connected to one of a source and a drain of the second transistor. The other of the source and the drain of the third transistor is electrically connected to a gate of the first transistor and a first terminal of the first capacitor. One of a source and a drain of the first transistor is electrically connected to a gate of the second transistor, the other of the source and the drain of the second transistor, and a second terminal of the first capacitor.

(7) Another embodiment of the present invention is a semiconductor device including a first transistor, a second transistor, a third transistor, a buffer circuit, and a first capacitor. The buffer circuit includes an input terminal and an output terminal. One of a source and a drain of the third transistor is electrically connected to one of a source and a drain of the second transistor. The other of the source and the drain of the third transistor is electrically connected to a gate of the first transistor and a first terminal of the first capacitor. The input terminal of the buffer circuit is electrically connected to one of a source and a drain of the first transistor and a second terminal of the first capacitor. The output terminal of the buffer circuit is electrically connected to a gate of the second transistor.

(8) Another embodiment of the present invention is a semiconductor device including a first transistor, a second transistor, a third transistor, a fourth transistor, a first capacitor, and a second capacitor. One of a source and a drain of the third transistor is electrically connected to one of a source and a drain of the second transistor and one of a source and a drain of the fourth transistor. The other of the source and the drain of the third transistor is electrically connected to a gate of the first transistor and a first terminal of the first capacitor. One of a source and a drain of the first transistor is electrically connected to a gate of the second transistor, a second terminal of the first capacitor, and a first terminal of the second capacitor. A gate of the second transistor is electrically connected to the other of the source and the drain of the fourth transistor and a second terminal of the second capacitor.

(9) Another embodiment of the present invention is a semiconductor device, which is different from the above (5) and (6), including a first transistor, a second transistor, a third transistor, and a first capacitor. One of a source and a drain of the third transistor is electrically connected to one of a source and a drain of the second transistor. The other of the source and the drain of the third transistor is electrically connected to a gate of the first transistor, a gate of the second transistor, and a first terminal of the first capacitor. One of a source and a drain of the first transistor is electrically connected to a second terminal of the first capacitor.

(10) Another embodiment of the present invention is a display apparatus including a driver circuit and a display device. In particular, the driver circuit includes the semiconductor device described in any one of the above (1) to (9). The driver circuit has a function of transmitting a signal for displaying an image to the display device.

(11) Another embodiment of the present invention is the display apparatus described in the above (10), in which the display device may include a light-emitting device or a liquid crystal display device.

(12) Another embodiment of the present invention is an electronic device including the display apparatus described in the above (11) and a housing.

### Effect of the Invention

The use of the structure of any of the above semiconductor devices for a retention circuit included in a shift register enables an output signal of a retention circuit to be fed back to a retention node side. When the retention node side receives the feedback of the output signal, a fixed potential from a power supply line or the like is supplied to the retention node, for example, so that the retention node is not brought into a floating state. This can suppress a change in the potential of the retention node, whereby the output signal of the retention circuit can be stable. Note that the fixed potential is preferably equal to a potential corresponding to data retained in the retention circuit.

One embodiment of the present invention can provide a semiconductor device that operates stably. Another embodiment of the present invention can provide a semiconductor device with high driving speed. Another embodiment of the present invention can provide a highly reliable semiconductor device. Another embodiment of the present invention can provide a display apparatus including the semiconductor device. Another embodiment of the present invention can provide an electronic device including the above display apparatus. Another embodiment of the present invention can provide a novel semiconductor device, a novel display apparatus, or a novel electronic device.

Note that the effects of one embodiment of the present invention are not limited to the effects described above. The effects described above do not preclude the existence of other effects. Note that the other effects are effects that are not described in this section and will be described below. The effects that are not described in this section can be derived from the description of the specification, the drawings, and the like and can be extracted as appropriate from the description by those skilled in the art. Note that one embodiment of the present invention has at least one of the effects listed above and the other effects. Accordingly, one embodiment of the present invention does not have the above effects in some cases.

### BRIEF DESCRIPTION OF THE DRAWINGS

FIG. 1A to FIG. 1C are circuit diagrams each illustrating an example of an amplifier circuit.

FIG. 2A to FIG. 2C are circuit diagrams each illustrating an example of an amplifier circuit.

FIG. 3A to FIG. 3C are circuit diagrams each illustrating an example of an amplifier circuit.

FIG. 4A to FIG. 4D are circuit diagrams each illustrating an example of an amplifier circuit.

FIG. 5 is a circuit diagram illustrating an example of an amplifier circuit.

FIG. 6A and FIG. 6B are circuit diagrams each illustrating an example of an amplifier circuit.

FIG. 7A and FIG. 7B are circuit diagrams each illustrating an example of an amplifier circuit.

FIG. 8A to FIG. 8C are circuit diagrams each illustrating an example of an amplifier circuit.

FIG. 9A to FIG. 9F are circuit diagrams each illustrating an example of an amplifier circuit.

FIG. 10A to FIG. 10C are circuit diagrams each illustrating an example of an amplifier circuit.

FIG. 11 is a layout diagram illustrating an example of an amplifier circuit.

FIG. 12 is a block diagram illustrating an example of a display apparatus.

FIG. 13A and FIG. 13B are block diagrams each illustrating an example of a driver circuit.

FIG. 14 is a circuit diagram illustrating an example of a circuit included in a driver circuit.

FIG. 15 is a timing chart showing an operation example of a circuit included in a driver circuit.

FIG. 16 is a circuit diagram illustrating an example of a circuit included in a driver circuit.

FIG. 17 is a circuit diagram illustrating an example of a circuit included in a driver circuit.

FIG. 18 is a circuit diagram illustrating an example of a circuit included in a driver circuit.

FIG. 19 is a circuit diagram illustrating an example of a circuit included in a driver circuit.

FIG. 20 is a block diagram illustrating an example of a driver circuit.

FIG. 21 is a timing chart showing an operation example of a driver circuit.

FIG. 22 is a circuit diagram illustrating an example of a circuit included in a driver circuit.

FIG. 23 is a circuit diagram illustrating an example of a circuit included in a driver circuit.

FIG. 24 is a circuit diagram illustrating an example of a circuit included in a driver circuit.

FIG. 25A and FIG. 25B are schematic perspective views each illustrating a structure example of a display apparatus.

FIG. 26 is a block diagram illustrating a structure example of a display apparatus.

FIG. 27 is a schematic cross-sectional view illustrating a structure example of a display apparatus.

FIG. 28A to FIG. 28C are schematic cross-sectional views each illustrating a structure example of a display apparatus.

FIG. 29 is a schematic cross-sectional view illustrating a structure example of a display apparatus.

FIG. 30A and FIG. 30B are schematic cross-sectional views illustrating a structure example of a transistor included in a semiconductor device.

FIG. 31 is a schematic cross-sectional view illustrating a structure example of a transistor included in a semiconductor device.

FIG. 32 is a schematic cross-sectional view illustrating a structure example of a display apparatus.

FIG. 33A to FIG. 33C are schematic plan views each illustrating a structure example of a transistor included in a semiconductor device, and FIG. 33D is a schematic cross-sectional view illustrating the structure example of a display apparatus.

FIG. 34A is a schematic plan view illustrating a structure example of a transistor included in a semiconductor device, and FIG. 34B is a schematic cross-sectional view illustrating the structure example of a display apparatus.

FIG. 35 is a schematic cross-sectional view illustrating a structure example of a display apparatus.

FIG. 36 is a schematic cross-sectional view illustrating a structure example of a display apparatus.

FIG. 37 is a schematic cross-sectional view illustrating a structure example of a display apparatus.

FIG. 38 is a schematic cross-sectional view illustrating a structure example of a display apparatus.

FIG. 39 is a schematic cross-sectional view illustrating a structure example of a display apparatus.

FIG. 40 is a schematic cross-sectional view illustrating a structure example of a display apparatus.

FIG. 41 is a schematic cross-sectional view illustrating a structure example of a display apparatus.

FIG. 42 is a schematic cross-sectional view illustrating a structure example of a display apparatus.

FIG. 43 is a schematic cross-sectional view illustrating a structure example of a display apparatus.

FIG. 44A to FIG. 44D are schematic cross-sectional views each illustrating a structure example of an LED package.

FIG. 45A and FIG. 45B are schematic plan views each illustrating a structure example of an LED package.

FIG. 46A to FIG. 46F are diagrams each illustrating a structure example of a light-emitting device.

FIG. 47A to FIG. 47C are diagrams each illustrating a structure example of a light-emitting device.

FIG. 48A is a circuit diagram illustrating a structure example of a pixel circuit included in a display apparatus, and FIG. 48B is a schematic perspective view illustrating the structure example of the pixel circuit included in the display apparatus.

FIG. 49A to FIG. 49G are schematic plan views each illustrating an example of a pixel.

FIG. 50A to FIG. 50F are schematic plan views each illustrating an example of a pixel.

FIG. 51A to FIG. 51H are schematic plan views each illustrating an example of a pixel.

FIG. 52A to FIG. 52D are schematic plan views each illustrating an example of a pixel.

FIG. 53A to FIG. 53G are schematic plan views each illustrating an example of a pixel.

FIG. 54A to FIG. 54I are perspective views each illustrating an example of an electronic device.

### MODE FOR CARRYING OUT THE INVENTION

In this specification and the like, a semiconductor device refers to a device that utilizes semiconductor characteristics, and means a circuit including a semiconductor element (e.g., a transistor, a diode, and a photodiode), or a device including the circuit. The semiconductor device also means all devices that can function by utilizing semiconductor characteristics. An example of a semiconductor device is an integrated circuit. Another example of a semiconductor device is a chip that includes an integrated circuit. Another example of a semiconductor device is an electronic component in which a chip is stored in a package. Moreover, a memory device, a display apparatus, a light-emitting apparatus, a lighting device, an electronic device, and the like themselves are semiconductor devices in some cases and include semiconductor devices in other cases.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relation, for example, a connection relation shown in drawings or texts, a connection relation other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow electrical connection between X and Y (e.g., a switch, a transistor, a capacitor, an inductor, a resistor, a diode, a display device, a light-emitting device, and a load) can be connected between X and Y. Note that a switch has a function of being controlled to be turned on or off. That is, the switch has a function of being in a conducting state (on state) or a non-conducting state (off state) to control whether current flows or not.

In the case where an element and a power supply line (e.g., a wiring supplying VDD (high power supply potential), VSS (low power supply potential), GND (the ground potential), or a desired potential) are both provided between X and Y, X and Y are not defined as being electrically connected. In the case where only a power supply line is provided between X and Y, there is no element between X and Y; therefore, X and Y are directly connected. Accordingly, in the case where only a power supply line is provided between X and Y, X and Y can be expressed as being “electrically connected”. However, in the case where an element and a power supply line are both provided between X and Y, X and Y are not defined as being electrically connected, although X and the power supply line are electrically connected (through the element) and Y and the power supply line are electrically connected. Note that in the case where a gate and a source of a transistor are provided between X and Y, X and Y are not defined as being electrically connected. Note that in the case where a gate and a drain of a transistor are provided between X and Y, X and Y are not defined as being electrically connected. That is, in the case where a drain and a source of a transistor are provided between X and Y, X and Y are defined as being electrically connected. Note that in the case where a capacitor is provided between X and Y, X and Y are defined as being electrically connected in some cases and not defined in other cases. For example, in the case where a capacitor is provided between X and Y in a structure of a digital circuit or a logic circuit, X and Y are not defined as being electrically connected in some cases. On the other hand, for example, in the case where a capacitor is provided between X and Y in a structure of an analog circuit, X and Y are defined as being electrically connected in some cases.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-analog converter circuit, an analog-digital converter circuit, or a gamma correction circuit); a potential level converter circuit (e.g., a power supply circuit such as a step-up circuit or a step-down circuit, or a level shifter circuit for changing the potential level of a signal); a voltage source; a current source; a switching circuit; an amplifier circuit (e.g., a circuit that can increase signal amplitude, the amount of a current, or the like, an operational amplifier, a differential amplifier circuit, a source follower circuit, or a buffer circuit); a signal generation circuit; a memory circuit; or a control circuit) can be connected between X and Y. For instance, even if another circuit is provided between X and Y, X and Y are regarded as being functionally connected when a signal output from X is transmitted to Y.

For example, an expression “X, Y, a source (sometimes called one of a first terminal and a second terminal) of a transistor, and a drain (sometimes called the other of the first terminal and the second terminal) of the transistor are electrically connected to each other, and X, the source of the transistor, the drain of the transistor, and Y are electrically connected to each other in this order” can be used. Alternatively, an expression “a source of a transistor is electrically connected to X; a drain of the transistor is electrically connected to Y; and X, the source of the transistor, the drain of the transistor, and Y are electrically connected to each other in this order” can be used. Alternatively, the expression “X is electrically connected to Y through a source and a drain of a transistor, and X, the source of the transistor, the drain of the transistor, and Y are provided in this connection order” can be used. When the connection order in a circuit structure is defined by an expression like the above examples, a source and a drain of a transistor can be distinguished from each other to specify the technical scope. Note that these expressions are non-limiting examples. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has both functions of a wiring and an electrode. Thus, electrical connection in this specification includes, in its category, such a case where one conductive film has functions of a plurality of components.

In this specification and the like, a “resistor” can be, for example, a circuit element having a resistance value higher than 0Ω or a wiring having a resistance value higher than 0Ω. Therefore, in this specification and the like, a “resistor” includes a wiring having a resistance value, a transistor in which a current flows between a source and a drain, a diode, and a coil. Thus, the term “resistor” can sometimes be replaced with the terms “resistance”, “load”, or “region having a resistance value”. Conversely, the terms “resistance”, “load”, or “region having a resistance value” can sometimes be replaced with the term “resistor”. The resistance value can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. For another example, the resistance value may be higher than or equal to 1Ω and lower than or equal to 1×10⁹Ω.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. The term “capacitor”, “parasitic capacitance”, or “gate capacitance” can be replaced with the term “capacitance” in some cases. Conversely, the term “capacitance” can be replaced with the term “capacitor”, “parasitic capacitance”, or “gate capacitance” in some cases. In addition, a “capacitor” (including a “capacitor” with three or more terminals) includes an insulator and a pair of conductors between which the insulator is interposed. Thus, the term “pair of conductors” of “capacitor” can be replaced with “pair of electrodes”, “pair of conductive regions”, “pair of regions”, or “pair of terminals”. In addition, the terms “one of a pair of terminals” and “the other of the pair of terminals” are referred to as a first terminal and a second terminal, respectively, in some cases. Note that the electrostatic capacitance value can be higher than or equal to 0.05 fF and lower than or equal to 10 pF, for example. For another example, the electrostatic capacitance value may be higher than or equal to 1 pF and lower than or equal to 10 μF.

In this specification and the like, a transistor includes three terminals called a gate, a source, and a drain. The gate is a control terminal for controlling the conduction state of the transistor. Two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Thus, the terms “source” and “drain” can sometimes be replaced with each other in this specification and the like. In this specification and the like, expressions “one of a source and a drain” (or a first electrode or a first terminal) and “the other of the source and the drain” (or a second electrode or a second terminal) are used in description of the connection relation of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, a third gate, and the like in this specification and the like.

In this specification and the like, for example, a transistor with a multi-gate structure having two or more gate electrodes can be used as the transistor. With the multi-gate structure, channel formation regions are connected in series; accordingly, a plurality of transistors are connected in series. Thus, with the multi-gate structure, the amount of an off-state current can be reduced, and the breakdown voltage of the transistor can be increased (the reliability can be improved). Alternatively, with the multi-gate structure, drain-source current does not change very much even if drain-source voltage changes at the time of an operation in a saturation region, so that a flat slope of voltage-current characteristics can be obtained. By utilizing the flat slope of the voltage-current characteristics, an ideal current source circuit or an active load having an extremely high resistance value can be obtained. Accordingly, a differential circuit, a current mirror circuit, and the like having excellent properties can be obtained.

The case where a single circuit element is illustrated in a circuit diagram may include a case where the circuit element includes a plurality of circuit elements. For example, the case where a single resistor is illustrated in a circuit diagram may include a case where two or more resistors are electrically connected to each other in series. For another example, the case where a single capacitor is illustrated in a circuit diagram may include a case where two or more capacitors are electrically connected to each other in parallel. For another example, the case where a single transistor is illustrated in a circuit diagram may include a case where two or more transistors are electrically connected to each other in series and their gates are electrically connected to each other. Similarly, for another example, the case where a single switch is illustrated in a circuit diagram may include a case where the switch includes two or more transistors which are electrically connected to each other in series or in parallel and whose gates are electrically connected to each other.

In this specification and the like, a node can be referred to as a terminal, a wiring, an electrode, a conductive layer, a conductor, or an impurity region depending on the circuit structure and the device structure. Furthermore, a terminal, a wiring, or the like can be referred to as a node.

In this specification and the like, a “voltage” and a “potential” can be replaced with each other as appropriate. A “voltage” refers to a potential difference from a reference potential, and when the reference potential is a ground potential, for example, a “voltage” can be replaced with a “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, the terms “high-level potential” and “low-level potential” do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

A “current” means a charge transfer phenomenon (electrical conduction); for example, the description “electrical conduction of positively charged particles occurs” can be rephrased as “electrical conduction of negatively charged particles occurs in the opposite direction”. Therefore, unless otherwise specified, a “current” in this specification and the like refers to a charge transfer phenomenon (electrical conduction) accompanying carrier movement. Examples of a carrier here include an electron, a hole, an anion, a cation, and a complex ion, and the type of carrier differs between current flow systems (e.g., a semiconductor, a metal, an electrolyte solution, and a vacuum). The “direction of a current” in a wiring or the like refers to the direction in which a carrier with positive charge moves, and the amount of the current is expressed as a positive value. In other words, the direction in which a carrier with negative charge moves is opposite to the direction of a current, and the amount of the current is expressed as a negative value. Thus, in the case where the polarity of a current (or the direction of a current) is not specified in this specification and the like, the description “a current flows from element A to element B” can be rephrased as “a current flows from element B to element A”. The description “a current is input to element A” can be rephrased as “a current is output from element A”.

Ordinal numbers such as “first”, “second”, and “third” in this specification and the like are used in order to avoid confusion among components. Thus, the terms do not limit the number of components. The terms do not limit the order of components, either. For example, a “first” component in one embodiment in this specification and the like can be referred to as a “second” component in other embodiments or the scope of claims. For another example, a “first” component in one embodiment in this specification and the like can be omitted in other embodiments or the scope of claims.

In this specification and the like, the terms for describing positioning, such as “over” and “under”, are sometimes used for convenience to describe the positional relation between components with reference to drawings. The positional relationship between components is changed as appropriate in accordance with the direction in which the components are described. Thus, the positional relation is not limited to the terms described in the specification and the like, and can be described with another term as appropriate depending on the situation. For example, the expression “an insulator located over (on) a top surface of a conductor” can be replaced with the expression “an insulator located under (on) a bottom surface of a conductor” when the direction of a drawing illustrating these components is rotated by 180°.

Furthermore, the terms “over” and “under” do not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B. Similarly, for example, the expression “electrode B above insulating layer A” does not necessarily mean that the electrode B is formed above and in direct contact with the insulating layer A, and does not exclude the case where another component is provided between the insulating layer A and the electrode B. Similarly, for example, the expression “electrode B under insulating layer A” does not necessarily mean that the electrode B is formed under and in direct contact with the insulating layer A, and does not exclude the case where another component is provided between the insulating layer A and the electrode B.

In this specification and the like, components arranged in a matrix and their positional relationship are sometimes described using terms such as “row” and “column”. The positional relationship between components is changed as appropriate in accordance with the direction in which the components are described. Thus, the positional relationship is not limited to the terms described in the specification and the like, and can be described with another term as appropriate depending on the situation. For example, the term “row direction” can be replaced with the term “column direction” when the direction of the diagram is rotated by 90°.

In this specification and the like, the terms “film” and “layer” can be interchanged with each other depending on the situation. For example, the term “conductive layer” can be replaced with the term “conductive film” in some cases. For another example, the term “insulating film” can be changed into the term “insulating layer” in some cases. Alternatively, the terms “film” and “layer” are not used and can be interchanged with another term depending on the case or the situation. For example, the term “conductive layer” or “conductive film” can be changed into the term “conductor” in some cases. Furthermore, for example, the term “insulating layer” or “insulating film” can be changed into the term “insulator” in some cases.

In this specification and the like, the terms “electrode”, “wiring”, “terminal”, and the like do not limit the functions of such components. For example, an “electrode” is used as part of a “wiring” in some cases, and vice versa. Furthermore, the term “electrode” or “wiring” also includes, for example, the case where a plurality of “electrodes” or “wirings” are formed in an integrated manner. For example, a “terminal” is used as part of a “wiring” or an “electrode” in some cases, and vice versa. Furthermore, the term “terminal” also includes the case where one or more selected from “electrodes”, “wirings”, and “terminals” are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, or “terminal” is sometimes replaced with the term “region” depending on the case.

In this specification and the like, the terms “wiring”, “signal line”, and “power supply line” can be interchanged with each other depending on the case or the situation. For example, the term “wiring” can be changed into the term “signal line” in some cases. For another example, the term “wiring” can be changed into the term “power supply line” or the like in some cases. Conversely, the term “signal line” or “power supply line” can be changed into the term “wiring” in some cases. The term “power supply line” can be changed into the term “signal line” in some cases. Similarly, the term “signal line” can be changed into the term “power supply line” in some cases. The term “potential” that is applied to a wiring can be changed into the term “signal” depending on the case or the situation. Conversely, the term “signal” can be changed into the term “potential” in some cases.

In this specification and the like, a timing chart is used in some cases to describe an operation method of a semiconductor device. In this specification and the like, the timing chart shows an ideal operation example and a period, a level of a signal (e.g., a potential or a current), and a timing described in the timing chart are not limited unless otherwise specified. In the timing chart described in this specification and the like, the level of a signal (e.g., a potential or a current) input to a wiring (including a node) and a timing can be changed depending on the situation. For example, even when two periods are shown to have an equal length, the two periods have different lengths in some cases. Furthermore, for example, even when one of two periods is shown long and the other is shown short, the two periods can have the equal length in some cases, or the one period has a short length and the other has a long length in other cases.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is included in a channel formation region of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS transistor is mentioned, the OS transistor can also be referred to as a transistor including a metal oxide or an oxide semiconductor.

In this specification and the like, a metal oxide containing nitrogen is also referred to as a metal oxide in some cases. Alternatively, a metal oxide containing nitrogen may be called a metal oxynitride.

In this specification and the like, an impurity in a semiconductor refers to, for example, an element other than a main component of a semiconductor layer. For example, an element with a concentration of lower than 0.1 atomic % is an impurity. When an impurity is contained, for example, one or more of an increase in the density of defect states in a semiconductor, a decrease in carrier mobility, and a decrease in crystallinity occur in some cases. In the case where the semiconductor is an oxide semiconductor, examples of an impurity that changes characteristics of the semiconductor include Group 1 elements, Group 2 elements, Group 13 elements, Group 14 elements, Group 15 elements, and transition metals other than the main components; specific examples are hydrogen (contained also in water), lithium, sodium, silicon, boron, phosphorus, carbon, and nitrogen.

In this specification and the like, a switch has a function of being in a conducting state (on state) or a non-conducting state (off state) to control whether current flows or not. Alternatively, a switch has a function of selecting and changing a current path. Thus, a switch may have two terminals or three or more terminals through which current flows, in addition to a control terminal. For example, an electrical switch or a mechanical switch can be used. That is, a switch can be any element capable of controlling current, and is not limited to a particular element.

Examples of an electrical switch include a transistor (e.g., a bipolar transistor and a MOS transistor), a diode (e.g., a PN diode, a PIN diode, a Schottky diode, a MIM (Metal Insulator Metal) diode, a MIS (Metal Insulator Semiconductor) diode, a diode-connected transistor, and the like), and a logic circuit in which such elements are combined. Note that in the case of using a transistor as a switch, a “conducting state” of the transistor refers to a state where a source electrode and a drain electrode of the transistor can be regarded as being electrically short-circuited or a state where a current can be made to flow between the source electrode and the drain electrode. Furthermore, a “non-conducting state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

An example of a mechanical switch is a switch formed using a MEMS (micro electro mechanical systems) technology. Such a switch includes an electrode that can be moved mechanically, and operates by controlling conduction and non-conduction with movement of the electrode.

In this specification and the like, a device fabricated using a metal mask or an FMM (fine metal mask, high-resolution metal mask) may be referred to as a device having an MM (metal mask) structure. In this specification and the like, a device fabricated without using a metal mask or an FMM may be referred to as a device having an MML (metal maskless) structure.

In this specification and the like, a structure where light-emitting layers in light-emitting devices of different colors (here, blue (B), green (G), and red (R)) are separately formed or separately patterned may be referred to as an SBS (Side By Side) structure. In this specification and the like, a light-emitting device capable of emitting white light may be referred to as a white-light-emitting device. Note that a combination of white-light-emitting devices with coloring layers (e.g., color filters) enables a full-color display apparatus.

Light-emitting devices can be classified roughly into a single structure and a tandem structure. A device having a single structure includes one light-emitting unit between a pair of electrodes, and the light-emitting unit preferably includes one or more light-emitting layers. When white light emission is obtained using two light-emitting layers, the two light-emitting layers are selected such that emission colors of the light-emitting layers are complementary colors. For example, when the emission color of a first light-emitting layer and the emission color of a second light-emitting layer have a relationship of complementary colors, a structure where the light-emitting device emits white light as a whole can be obtained. When white light emission is obtained using three or more light-emitting layers, a light-emitting device is configured to emit white light as a whole by combining emission colors of the three or more light-emitting layers.

A device having a tandem structure includes two or more light-emitting units between a pair of electrodes, and each light-emitting unit preferably includes one or more light-emitting layers. To obtain white light emission, the light-emitting device is configured to obtain white light emission by combining light from light-emitting layers of the plurality of light-emitting units. Note that a structure for obtaining white light emission is similar to the structure of the case of a single structure. In the device having a tandem structure, an intermediate layer such as a charge-generation layer is suitably provided between the plurality of light-emitting units.

When the above white-light-emitting device (having a single structure or a tandem structure) and the above light-emitting device having an SBS structure are compared to each other, the light-emitting device having an SBS structure can have lower power consumption than the white-light-emitting device. To reduce power consumption, the light-emitting device having an SBS structure is suitably used. Meanwhile, the white light-emitting device is suitable in terms of lower manufacturing cost or higher manufacturing yield because the manufacturing process of the white light-emitting device is simpler than that of the light-emitting device having an SBS structure.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

In this specification and the like, one embodiment of the present invention can be constituted by appropriately combining a structure described in an embodiment with any of the structures described in the other embodiments. In addition, in the case where a plurality of structure examples are described in one embodiment, the structure examples can be combined as appropriate.

Note that a content (or part of the content) described in one embodiment can be applied to, combined with, or replaced with at least one of another content (or part of the content) in the embodiment and a content (or part of the content) described in one or a plurality of different embodiments.

Note that in each embodiment, a content described in the embodiment is a content described using a variety of diagrams or a content described with text disclosed in the specification.

Note that by combining a diagram (or part thereof) described in one embodiment with at least one of another part of the diagram, a different diagram (or part thereof) described in the embodiment, and a diagram (or part thereof) described in one or a plurality of different embodiments, much more diagrams can be provided.

Embodiments described in this specification are described with reference to the drawings. Note that the embodiments can be implemented in many different modes, and it will be readily appreciated by those skilled in the art that modes and details can be changed in various ways without departing from the spirit and scope thereof. Thus, the present invention should not be interpreted as being limited to the description in the embodiments. Note that in the structures of the invention in the embodiments, the same portions or portions having similar functions are denoted by the same reference numerals in different drawings, and repeated description thereof is omitted in some cases. In perspective views and the like, illustration of some components may be omitted for clarity of the drawings.

In this specification and the like, when a plurality of components are denoted with the same reference numerals, and in particular need to be distinguished from each other, an identification sign such as “_1”, “[n]”, or “[m, n]” is sometimes added to the reference numerals. Components denoted with identification signs such as “_1”, “[n]”, and “[m, n]” in the drawings and the like are sometimes described without such identification signs in this specification and the like when the components do not need to be distinguished from each other.

In the drawings in this specification, the size, the layer thickness, or the region is exaggerated for clarity in some cases. Thus, the size, the layer thickness, or the region is not limited to the illustrated scale. The drawings are schematic views showing ideal examples, and embodiments of the present invention are not limited to shapes, values, or the like shown in the drawings. For example, variations in signal, voltage, or current due to noise or a difference in timing can be included.

### Embodiment 1

In this embodiment, an amplifier circuit that is a semiconductor device of one embodiment of the present invention will be described.

### <Structure Example 1 of Amplifier Circuit>

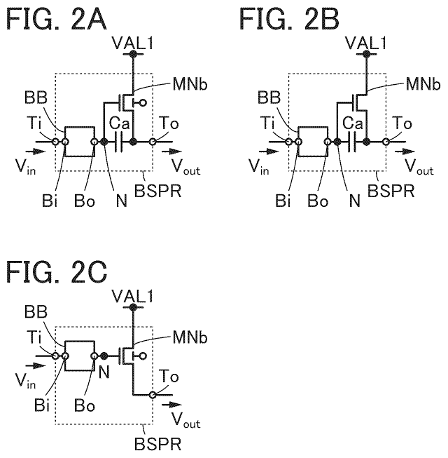

A circuit BSPR illustrated in FIG. 2A is an example of an amplifier circuit and includes a circuit BB, a transistor MNb, and a capacitor Ca. The circuit BSPR includes, for example, a terminal Ti functioning as an input terminal and a terminal To functioning as an output terminal. The circuit BB includes, for example, a terminal Bi functioning as an input terminal and a terminal Bo functioning as an output terminal.

An OS transistor is preferably used as the transistor MNb, for example. In particular, a metal oxide contained in a channel formation region of an OS transistor is preferably an In-M-Zn oxide containing indium, an element M, and zinc (the element M is one or more kinds selected from aluminum, gallium, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony), for example. Alternatively, as the transistor MNb, a transistor containing silicon in a channel formation region (hereinafter referred to as a Si transistor) may be used. As the silicon, single crystal silicon, amorphous silicon (referred to as hydrogenated amorphous silicon in some cases), microcrystalline silicon, or polycrystalline silicon can be used, for example. As a transistor other than an OS transistor and a Si transistor, for example, a transistor containing germanium (Ge) or the like in a channel formation region, a transistor containing a compound semiconductor such as zinc selenide (ZnSe), cadmium sulfide (CdS), gallium arsenide (GaAs), indium phosphide (InP), gallium nitride (GaN), or silicon germanium (SiGe) in a channel formation region, a transistor containing a carbon nanotube in a channel formation region, or a transistor containing an organic semiconductor in a channel formation region can be used.

The transistor MNb illustrated in FIG. 2A is an n-channel transistor having a multi-gate structure including gates over and under a channel; the transistor MNb includes a first gate and a second gate. Note that in this specification and the like, for convenience, the first gate is referred to as a gate (sometimes referred to as a front gate) and the second gate is referred to as a back gate so that they are distinguished from each other in some cases. In this specification and the like, the first gate and the second gate can be interchanged, and thus the term “gate” can be replaced with the term “back gate”. Similarly, the term “back gate” can be replaced with the term “gate”. As a specific example, a connection structure in which “a gate is electrically connected to a first wiring and a back gate is electrically connected to a second wiring” can be replaced with a connection structure in which “a back gate is electrically connected to a first wiring and a gate is electrically connected to a second wiring”.

In FIG. 2A, the back gate of the transistor MNb is illustrated. The connection of the back gate is not illustrated, and the destination to which the back gate is electrically connected can be determined at the design stage. For example, in a transistor including a back gate, a gate and the back gate may be electrically connected to each other to increase the on-state current of the transistor. In other words, for example, the gate and back gate of the transistor MNb may be electrically connected. Alternatively, for example, in a transistor including a back gate, a wiring for electrically connecting the back gate of the transistor to an external circuit or the like may be provided and a potential may be supplied to the back gate of the transistor with the external circuit or the like to change the threshold voltage of the transistor or to reduce the off-state current of the transistor.

Ideally, the transistor MNb is normally off and the threshold voltage of the transistor MNb is set to V_{th_MNb}. The threshold voltage V_{th_MNb} is set to satisfy V_{High}−V_{Low}>V_{th_MNb}. Note that V_{High} is a high-level potential and V_{Low} is a low-level potential.

Note that in this specification and the like, “normally off” means a state where a current does not flow through a transistor when a gate-source voltage is 0 V. Moreover, “normally off” of an OS transistor means that a current per micrometer of channel width flowing through a transistor when a gate-source voltage is 0 V is lower than or equal to 1×10⁻²⁰ A at room temperature, lower than or equal to 1×10⁻¹⁸ A at 85° C., or lower than or equal to 1×10⁻¹⁶ A at 125° C. Meanwhile, “normally on” means a state where a channel exists even when the gate-source voltage is 0 V, and a current flows through a transistor.

The semiconductor device of one embodiment of the present invention does not depend on the structure of a transistor included in the semiconductor device. For example, the transistor MNb in FIG. 2A may have a structure not including a back gate, that is, a single-gate structure (see FIG. 2B). It is also possible that some transistors include back gates and the other transistors do not include back gates.

Although the transistor MNb is an n-channel transistor in FIG. 2A, the transistor MNb may be a p-channel transistor.

Note that the description of the transistor applies to transistors described in other parts of the specification and transistors illustrated in the drawings other than FIG. 2A.

The terminal Bi of the circuit BB is electrically connected to the terminal Ti, and the terminal Bo of the circuit BB is electrically connected to a gate of the transistor MNb and a first terminal of the capacitor Ca. A first terminal of the transistor MNb is electrically connected to a wiring VAL1, and a second terminal of the transistor MNb is electrically connected to a second terminal of the capacitor Ca and the terminal To.

Note that in this embodiment, a portion where the terminal Bo of the circuit BB, the gate of the transistor MNb, and the first terminal of the capacitor Ca are electrically connected is referred to as a node N.

The circuit BB has a function of bringing the node N into a floating state, for example. Thus, the circuit BB can include a switching element, for example. The circuit BB also has a function of outputting, to the terminal Bo, a potential corresponding to the potential input to the terminal Bi. For example, the circuit BB can have a structure in which when the high-level potential V_{High} is supplied to the terminal Bi, a potential V_{Mid} is output to the terminal Bo. Note that V_{Mid} is a potential lower than the high-level potential V_{High} and higher than the low-level potential V_{Low}. In addition, V_{Mid} is a voltage satisfying V_{Mid}−V_{Low}>V_{th_MNb}.

The wiring VAL1 in FIG. 2A functions as a wiring supplying a fixed potential or a variable potential, for example. The fixed potential can be, for example, a high-level potential, a low-level potential, a ground potential, or a negative potential. An example of the variable potential is a pulse signal (also referred to as a pulse voltage in some cases). An example of the pulse signal is a clock signal.

In FIG. 2A, the potential of the terminal Ti is denoted by Vᵢₙ and the potential of the terminal To is denoted by Vₒᵤₜ.

Here, the potential of the node N of the circuit BSPR in FIG. 2A is assumed to be the potential V_{Mid}, which is lower than the high-level potential V_{High}. In this case, the node N is assumed not to be in a floating state. In addition, the low-level potential V_{Low} is assumed to be supplied to the first terminal of the transistor MNb from the wiring VAL1.

At this time, the gate-source voltage (the gate-first terminal voltage at this timing) of the transistor MNb is V_{Mid}−V_{Low}. Since V_{Mid}−V_{Low}>V_{th_MNb} is satisfied, the transistor MNb is turned on. Consequently, the wiring VAL1 outputs the low-level potential V_{Low} to the terminal To of the circuit BSPR through the transistor MNb, whereby Vₒᵤₜ=V_{Low}.

Next, the potential supplied to the first terminal of the transistor MNb from the wiring VAL1 is assumed to change from the low-level potential V_{Low} to the high-level potential V_{High}. In addition, the node N is assumed to be brought into a floating state by the circuit BB. At this time, the gate-source voltage (the gate-second terminal voltage at this timing) of the transistor MNb is V_{Mid}−V_{Low}, whereby the transistor MNb is turned on. Consequently, current flows from the wiring VAL1 to the terminal To of the circuit BSPR through the transistor MNb, which renders the potential of the terminal To higher than V_{Low}. Note that since the node N is in a floating state, the capacitive coupling with the capacitor Ca causes an increase in the potential of the node N from V_{Mid} in response to the increase in the potential of the terminal To. Accordingly, the gate-source voltage of the transistor MNb is retained by the capacitor Ca, whereby the potential of the terminal To increases to V_{High}. Ideally, the potential of the node N becomes V_{Mid}+V_{High}−V_{Low}.

As described above, in the circuit BSPR, when V_{Mid} lower than the high-level potential is input to the node N and the high-level potential V_{High} is supplied to the first terminal of the transistor MNb through the wiring VAL1, V_{High} is output as a potential from the terminal To. In this specification and the like, increasing the gate potential of a transistor with an increase in the potential of the first terminal or the second terminal of a transistor by utilizing capacitive coupling is referred to as a bootstrap.

In the circuit BSPR in FIG. 2A, when the high-level potential V_{High} is supplied to the first terminal of the transistor MNb by the wiring VAL1 and the high-level potential V_{High} is supplied to the node N, the potential of the node N increases to V_{Mid}+V_{High}−V_{Low} by bootstrap, and the potential output to the terminal To of the circuit BSPR becomes V_{High}.

Note that in the case where the gate capacitance between the gate of the transistor MNb and the channel formation region (sometimes including one or both of the first terminal and the second terminal depending on the situation) thereof is large, the circuit BSPR can have a structure in which the capacitor Ca is not provided as illustrated in FIG. 2C. In this case, the circuit area of the circuit BSPR can be reduced.

When the potential of the terminal Ti of the circuit BSPR is V_{High} and the terminal Ti is in a floating state (does not have electrical continuity with a wiring for supplying a potential), the potential of the terminal Ti may change depending on various factors. For example, in a transistor for retaining the potential of the terminal Ti, the potential of the terminal Ti changes when the off-state current flowing between the source and the drain or the leakage current flowing between the gate and the source or between the gate and the drain becomes large. The potential of the terminal Ti also changes when a noise signal is input to the terminal Ti. That is, the potential supplied to the terminal Bi of the circuit BB changes and thus the potential of the node N is also affected, which might make the potential output from the terminal To of the circuit BSPR unstable.

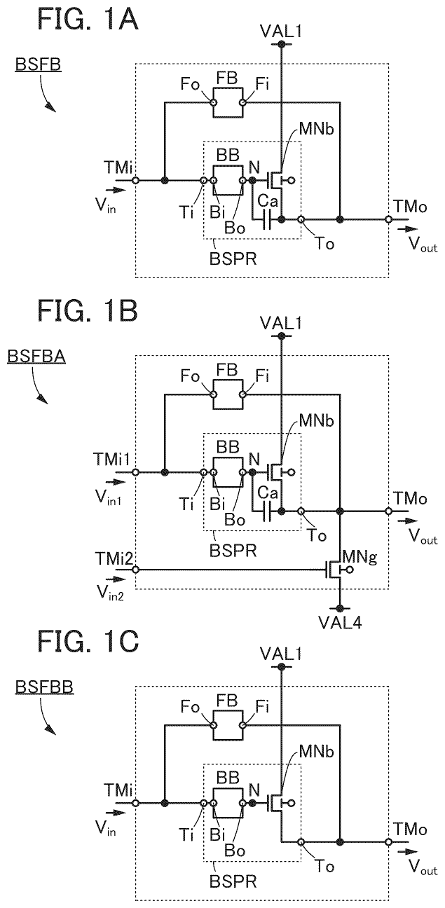

FIG. 1A illustrates an amplifier circuit, which is a semiconductor device of one embodiment of the present invention for solving the above problem. A circuit BSFB illustrated in FIG. 1A is a circuit including the circuit BSPR in FIG. 2A and a circuit FB.

The circuit FB includes a terminal Fi and a terminal Fo.

The terminal Ti of the circuit BSPR and the terminal Fo of the circuit FB are electrically connected to each other. The terminal To of the circuit BSPR and the terminal Fi of the circuit FB are electrically connected to each other. In FIG. 1A, the terminal Ti of the circuit BSPR and the terminal Fo of the circuit FB are shown as one terminal TMi, and the terminal To of the circuit BSPR and the terminal Fi of the circuit FB are shown as one terminal TMo.

The circuit FB has a function of obtaining a potential output from the terminal To of the circuit BSPR and supplying a fixed potential to the terminal Ti of the circuit BSPR, for example. That is, the circuit FB can be regarded as a circuit that supplies feedback to the circuit BSPR on the basis of the potential output from the terminal To of the circuit BSPR. Specifically, for example, the circuit FB may have a structure in which a fixed potential (e.g., the high-level potential V_{High}) is output to the terminal Fo when the high-level potential V_{High} is input to the terminal Fi.

When the circuit FB has the above structure and the high-level potential V_{High} is output from the terminal To of the circuit BSPR, for example, a fixed potential output from the terminal Fo of the circuit FB is supplied to the terminal Ti of the circuit BSPR. Thus, for example, even when the amount of an off-state current flowing between a source and a drain or the amount of a leakage current flowing between a gate and the source or between the gate and the drain becomes large in a transistor for retaining the potential of the terminal Ti (the terminal TMi), the potential of the terminal Ti (the terminal TMi) remains a fixed potential supplied from the circuit FB. In addition, when a noise signal is input to the terminal Ti (the terminal TMi), the potential of the terminal Ti (the terminal TMi) remains a fixed potential supplied from the circuit FB. Thus, the potential of the terminal To of the circuit BSPR does not change due to the above-described factors, whereby the potential of the node N is less likely to be affected. Accordingly, the potential output from the terminal To of the circuit BSPR becomes stable.

Note that the semiconductor device of one embodiment of the present invention is not limited to the circuit BSFB illustrated in FIG. 1A. The semiconductor device of one embodiment of the present invention may have a structure in which a transistor MNg is provided in the circuit BSFB in FIG. 1A as in a circuit BSFBA illustrated in FIG. 1B, for example.

As the transistor MNg, a transistor that can be used as the transistor MNb can be used, for example.

The circuit BSFBA in FIG. 1B includes a terminal TMi1 and a terminal TMi2 which function as input terminals and the terminal TMo which functions as an output terminal. Note that the terminal TMi1 corresponds to the terminal TMi illustrated in FIG. 1A. In FIG. 1B, the potential of the terminal TMi1 is denoted by Vᵢₙ₁ and the potential of the terminal TMi2 is denoted by Vᵢₙ₂.

A first terminal of the transistor MNg is electrically connected to the second terminal of the transistor MNb, the second terminal of the capacitor Ca, and the terminal TMo. A second terminal of the transistor MNg is electrically connected to a wiring VAL4. A gate of the transistor MNg is electrically connected to the terminal TMi2.

The wiring VAL4 functions as a wiring supplying a fixed potential, for example. An example of the fixed potential is a low-level potential. Other examples of the fixed potential include a ground potential and a negative potential. Depending on the circumstances, the wiring VAL4 may function as a wiring that supplies a variable potential.

The circuit BSFBA can output the low-level potential V_{Low} from the terminal TMo when the wiring VAL4 outputs the low-level potential V_{Low}, for example.

Here, an operation example of the circuit BSFBA in FIG. 1B is described. The high-level potential V_{High} is assumed to be input to the first terminal of the transistor MNb from the wiring VAL1, for example. In addition, the low-level potential V_{Low} is assumed to be supplied to the second terminal of the transistor MNg from the wiring VAL4.

For output of the high-level potential V_{High} from the terminal TMo of the circuit BSFBA, the low-level potential V_{Low} is first input to the terminal TMi2 to turn off the transistor MNg. Then, input of the high-level potential V_{High} to the terminal TMi1 allows the high-level potential V_{High} to be output from the terminal TMo. For the output operation of the high-level potential V_{High} from the terminal TMo, the operation example of the circuit BSFB in FIG. 1A can be referred to.

Then, for output of the low-level potential V_{Low} from the terminal TMo of the circuit BSFBA, the high-level potential V_{High} is input to the terminal TMi2 to turn on the transistor MNg. Thus, electrical continuity is established between the terminal TMo and the wiring VAL4, so that the electric charge accumulated in the terminal TMo flows to the wiring VAL4, which makes the potential of the terminal TMo become the low-level potential V_{Low}. At this time, the low-level potential V_{Low} is supplied to the terminal TMi1 so that the potential of the gate of the transistor MNb is set to the low-level potential V_{Low}, whereby the transistor MNb is turned off and electrical continuity is not established between the wiring VAL1 and the terminal TMo; hence, the potential of the terminal TMo can steeply drop to the low-level potential V_{Low}.

The semiconductor device of one embodiment of the present invention may have a structure in which the capacitor Ca is not provided in the circuit BSPR as in a circuit BSFBB illustrated in FIG. 1C, for example. Specifically, the circuit BSFBB in FIG. 1C has a structure in which the circuit BSPR in FIG. 1A is replaced with the circuit BSPR in FIG. 2C. As described with reference to FIG. 2C, in the case where the gate capacitance of the transistor MNb is large, the capacitor Ca is not necessarily provided in the circuit BSPR in FIG. 1A, and thus the circuit area of the circuit BSFB in FIG. 1A can be reduced.

### <<Structure Example 1 of Circuit FB>>

Next, a structure example of the circuit BSFB in FIG. 1A or the circuit BSFBA in FIG. 1B is described.

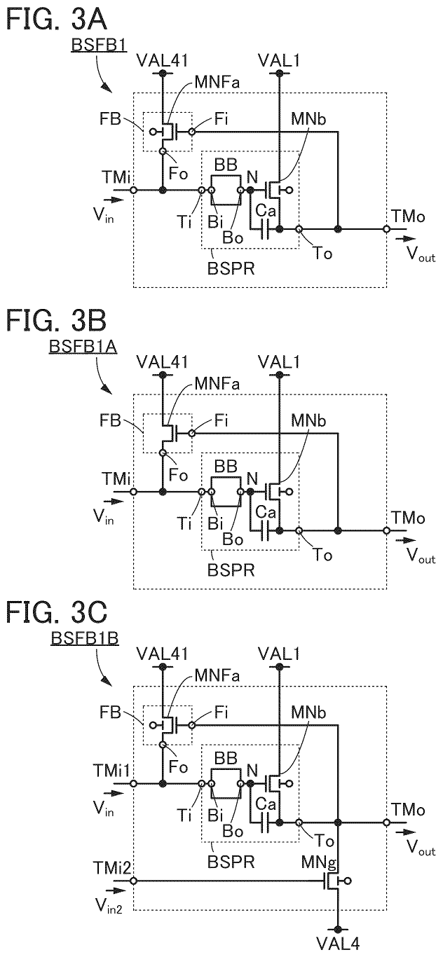

A circuit BSFB1 illustrated in FIG. 3A includes a transistor MNFa in the circuit FB. As the transistor MNFa, a transistor that can be used as the transistor MNb can be used, for example. Note that in FIG. 3A, for example, the transistor MNFa is an n-channel transistor with a multi-gate structure in which gates are provided above and below a channel.

A first terminal of the transistor MNFa is electrically connected to the terminal Fo, and a second terminal of the transistor MNFa is electrically connected to a wiring VAL41. A gate of the transistor MNFa is electrically connected to the terminal Fi.

The wiring VAL41 functions as a wiring supplying a fixed potential or a variable potential, for example, like the wiring VAL1. As a fixed potential, for example, a high-level potential, a low-level potential, a ground potential, or a negative potential can be given. As a variable potential, a pulse signal (also referred to as a pulse voltage in some cases) can be given.

The wiring VAL41 may be electrically connected to the wiring VAL1. In other words, the wiring VAL1 and the wiring VAL41 may be a single wiring.

Here, an operation example of the circuit BSFB1 in FIG. 3A is described.

For the operation of the circuit BSPR, the operation example of the circuit BSPR in FIG. 2A can be referred to. For example, when the high-level potential V_{High} is input to the terminal TMi of the circuit BSFB1 (i.e., when Vᵢₙ=V_{High}), the circuit BB outputs the potential V_{Mid} to the terminal Bo. Thus, V_{Mid} is supplied to the gate of the transistor MNb (the first terminal of the capacitor Ca). In addition, the low-level potential V_{Low} is assumed to be supplied to the first terminal of the transistor MNb from the wiring VAL1. The high-level potential V_{High} is assumed to be supplied to the second terminal of the transistor MNFa from the wiring VAL41.

At this time, the gate-source voltage (the gate-first terminal voltage at this timing) of the transistor MNb is V_{Mid}−V_{Low}, whereby the transistor MNb is turned on. Consequently, the wiring VAL1 outputs the low-level potential V_{Low} to the terminal To of the circuit BSPR through the transistor MNb, whereby Vₒᵤₜ=V_{Low}.

Thus, V_{Low}, which is the same as the potential of the terminal To, is input to the terminal Fi of the circuit FB. In this manner, the low-level potential V_{Low} is supplied to the gate of the transistor MNFa.

The transistor MNFa is normally off and the threshold voltage of the transistor MNFa is set to V_{th_MNFa}. The threshold voltage V_{th_MNFa} is set to satisfy V_{High}−V_{Low}>Vth MNFa.

Here, the gate-source voltage (here, the gate-first terminal voltage) of the transistor MNFa satisfies V_{Low}−V_{High}<V_{th_MNFa}; thus, the transistor MNFa is turned off.

Next, the potential supplied to the first terminal of the transistor MNb from the wiring VAL1 is assumed to change from the low-level potential V_{Low} to the high-level potential V_{High}. At this time, the gate-source voltage (the gate-second terminal voltage at this timing) of the transistor MNb is V_{Mid}−V_{Low}, whereby the transistor MNb is turned on. Consequently, current flows from the wiring VAL1 to the terminal To of the circuit BSPR through the transistor MNb, which renders the potential of the terminal To higher than V_{Low}. Note that since the node N is in a floating state, the capacitive coupling with the capacitor Ca causes an increase in the potential of the node N from V_{Mid} in response to the increase in the potential of the terminal To. Accordingly, the gate-source voltage of the transistor MNb is retained by the capacitor Ca, whereby the potential of the terminal To increases to V_{High}. Ideally, the potential of the node N is in the following points: V_{Mid}+V_{High}−V_{Low}.

At this time, V_{High}, which is the same as the potential of the terminal To, is input to the terminal Fi of the circuit FB. In this manner, the high-level potential V_{High} is supplied to the gate of the transistor MNFa.

Here, the gate-source voltage of the transistor MNFa (here, the gate-first terminal voltage) is V_{High}−V_{High}=0, for example. Since the transistor MNFa is normally off, the transistor MNFa is off.

In this state, when the potential of the terminal Ti of the circuit BSPR (the first terminal of the transistor MNFa) decreases from the high-level potential V_{High} and the gate-first terminal voltage of the transistor MNFa becomes higher than the threshold voltage, the transistor MNFa is turned on. At this time, electric charge from the wiring VAL41 is accumulated in the terminal Ti of the circuit BSPR, and the potential of the terminal Ti of the circuit BSPR increases. Specifically, the transistor MNFa is turned off when the gate-source voltage of the transistor MNFa becomes Vth MNFa; thus, the potential of the terminal Ti of the circuit BSPR (the first terminal of the transistor MNFa) is V_{High}−V_{th_MNFa}.

As described above, in the circuit BSFB1, when the high-level potential V_{High} is output from the terminal TMo and the potential of the terminal Ti of the circuit BSPR decreases, the circuit FB can supply the potential V_{High}−Vth MNFa to the terminal Ti. Thus, the potential of the terminal Ti is almost kept at V_{High}−V_{th_MNFa}, whereby the potential output from the terminal To of the circuit BSPR becomes stable.

Note that the semiconductor device of one embodiment of the present invention is not limited to the circuit BSFB1 illustrated in FIG. 3A. In the semiconductor device of one embodiment of the present invention, for example, the transistor MNFa may have a single gate structure as in a circuit BSFB1A illustrated in FIG. 3B. That is, the transistor MNFa may be a transistor without a back gate.

The semiconductor device of one embodiment of the present invention may have a structure in which the transistor MNg is provided in the circuit BSFB1 in FIG. 3A as in a circuit BSFB1B illustrated in FIG. 3C, for example. Specifically, the circuit BSFB1B in FIG. 3C has a structure in which the circuit FB illustrated in FIG. 3A is used as the circuit FB in the circuit BSFBA in FIG. 1B. Like the circuit BSFBA in FIG. 1B, the circuit BSFB1B is an amplifier circuit capable of outputting the high-level potential V_{High} or the low-level potential V_{Low} from the terminal TMo.

### <<Structure Example 2 of Circuit FB>>

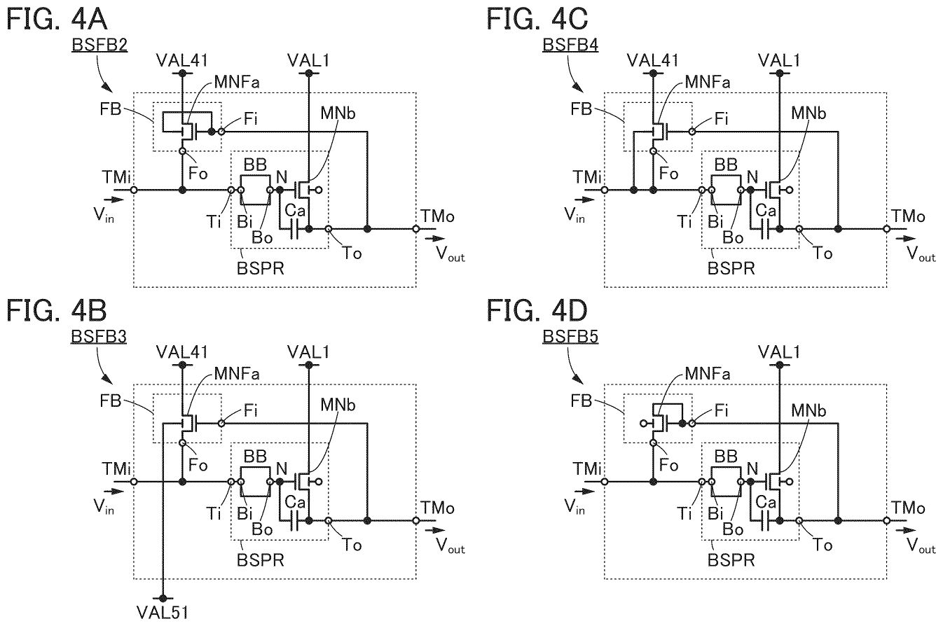

A circuit BSFB2 illustrated in FIG. 4A is a modification example of the circuit BSFB1 in FIG. 3A and is different from the circuit BSFB1 in that the back gate of the transistor MNFa is electrically connected to the gate of the transistor MNFa.

As described above, when the gate and the back gate of the transistor are electrically connected to each other, the on-state current of the transistor can be increased. That is, electrically connecting the gate and the back gate of the transistor MNFa in the circuit BSFB2 can increase the on-state current that flows when the transistor MNFa is on. Accordingly, the speed at which the potential of the terminal TMi is changed to a fixed potential (e.g., V_{High}−V_{th_MNFa}) output from the terminal Fo of the circuit FB can be increased.

A circuit BSFB3 illustrated in FIG. 4B is a modification example of the circuit BSFB1 in FIG. 3A and is different from the circuit BSFB1 in that the back gate of the transistor MNFa is electrically connected to a wiring VAL51.

Like the wiring VAL4, the wiring VAL51 functions as a wiring for supplying a fixed potential, for example. An example of the fixed potential is a low-level potential. Other examples of the fixed potential include a ground potential and a negative potential. Depending on the circumstances, the wiring VAL51 may function as a wiring that supplies a variable potential.

As described above, when a low-level potential output from the wiring VAL4 is input to the back gate of the transistor MNFa, for example, the threshold voltage of the transistor MNFa increases. Thus, the transistor MNFa can be normally off, whereby the off-state current flowing between the source and the drain of the transistor MNFa can be reduced.

A circuit BSFB4 illustrated in FIG. 4C is a modification example of the circuit BSFB1 in FIG. 3A and is different from the circuit BSFB1 in that the back gate of the transistor MNFa is electrically connected to the terminal TMi, the terminal Fo, and the terminal Ti.

In the transistor MNFa in the circuit BSFB4, when the low-level potential V_{Low} is input to the terminal TMi, the low-level potential V_{Low} is input to the back gate of the transistor MNFa, so that the threshold voltage of the transistor MNFa is increased. In the case where the low-level potential V_{Low} is output from the terminal TMo at this time, the low-level potential V_{Low} is input to the gate of the transistor MNFa; thus, the transistor MNFa is turned off, and the off-state current flowing between the source and the drain of the transistor MNFa at this time can be reduced.

In the transistor MNFa in the circuit BSFB4, when the high-level potential V_{High} is input to the terminal TMi, the high-level potential V_{High} is input to the back gate of the transistor MNFa, so that the threshold voltage of the transistor MNFa is decreased. At this time, in the case where the high-level potential V_{High} is output to the terminal TMo by the operation of the circuit BSPR, the high-level potential V_{High} is input to the gate of the transistor MNFa; thus, the transistor MNFa is turned on. The amount of the on-state current flowing between the source and the drain of the transistor MNFa at this time is increased because the high-level potential V_{High} is input to the back gate of the transistor MNFa. Accordingly, the speed at which the potential of the terminal TMi is changed to a fixed potential (e.g., V_{High}−V_{th_MNFa}) output from the terminal Fo of the circuit FB can be increased.

### <<Structure Example 3 of Circuit FB

A circuit BSFB5 illustrated in FIG. 4D is a modification example of the circuit BSFB1 in FIG. 3A and is different from the circuit BSFB1 in that the second terminal of the transistor MNFa is electrically connected not to the wiring VAL41 but to the gate of the transistor MNFa. That is, the transistor MNFa in the circuit BSFB5 is diode-connected.

In the case where the high-level potential V_{High} is input to the gate of the transistor MNFa (in the case where the high-level potential V_{High} is output from the terminal To of the circuit BSPR), the transistor MNFa is turned on when the potential of the first terminal of the transistor MNFa is lower than V_{High}−V_{th_MNFa}. At this time, a current output from the terminal To flows to the terminal TMi through the circuit FB and the source-drain of the transistor MNFa. When a current flows to the terminal TMi and the potential of the first terminal of the transistor MNFa becomes V_{High}−V_{th_MNFa}, the transistor MNFa is turned off.

Like the circuit BSFB, the circuit BSFB5 can supply a fixed potential to the terminal Ti of the circuit BSPR by feeding back the potential output from the terminal To of the circuit BSPR.

### <<Structure Example 4 of Circuit FB>>

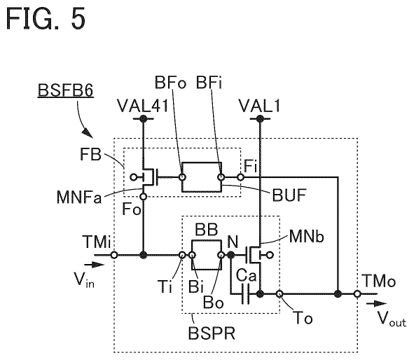

A circuit BSFB6 illustrated in FIG. 5 is a modification example of the circuit BSFB1 in FIG. 3A and is different from the circuit BSFB1 in that a circuit BUF is provided in the circuit FB. The circuit BSFB6 is different from the circuit BSFB1 also in that the terminal Fi of the circuit BSFB6 and the gate of the transistor MNFa are not directly electrically connected to each other, the terminal Fi of the circuit BSFB6 is directly electrically connected to a terminal BFi described later, and the gate of the transistor MNFa is directly electrically connected to a terminal BFo described later.

The circuit BUF includes the terminal BFi and the terminal BFo.

The circuit BUF has a function of amplifying a potential input to the terminal BFi and outputting the amplified potential to the terminal BFo, for example. In particular, here, the circuit BUF functions as a buffer circuit.

When the circuit BUF is used as a buffer circuit in the circuit BSFB6, a stable fixed potential can be supplied to the gate of the transistor MNFa even when the potential output from the terminal TMo is slightly changed by a noise signal or the like, for example.

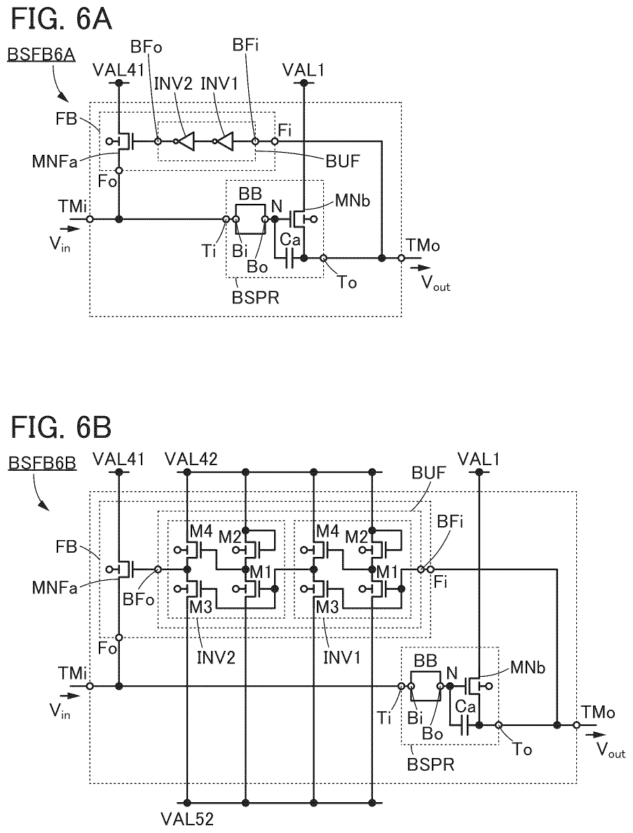

FIG. 6A illustrates a structure example of the circuit BUF of the circuit BSFB6 illustrated in FIG. 5. Note that FIG. 6A also illustrates the circuit BSPR, the terminal TMi, and the terminal TMo to illustrate the electrical connection structure.

In the circuit BSFB6A illustrated in FIG. 6A, the circuit BUF includes a logic circuit INV1 and a logic circuit INV2.

An input terminal of the logic circuit INV1 is electrically connected to the terminal BFi, an output terminal of the logic circuit INV1 is electrically connected to an input terminal of the logic circuit INV2, and an output terminal of the logic circuit INV2 is electrically connected to the terminal BFo.

Each of the logic circuit INV1 and the logic circuit INV2 has a function of generating an inverted signal of a signal input to the input terminal and outputting the inverted signal. As the logic circuit INV1 and the logic circuit INV2, for example, inverter circuits can be used. In addition to the inverter circuit, a NAND circuit, a NOR circuit, an XOR circuit, or a logic circuit including a combination thereof can be used, for example.

FIG. 6B illustrates a structure example of the logic circuit INV1 and the logic circuit INV2 included in the circuit BUF of the circuit BSFB6A illustrated in FIG. 6A.

In the circuit BSFB6B illustrated in FIG. 6B, each of the logic circuit INV1 and the logic circuit INV2 includes a transistor M1, a transistor M2, a transistor M3, and a transistor M4.

As each of the transistor M1 to the transistor M4, a transistor that can be used as the transistor MNb can be used, for example.

In the logic circuit INV1, each of a gate of the transistor M1 and a gate of the transistor M3 is electrically connected to the input terminal of the logic circuit INV1 (the terminal BFi of the circuit BUF). The first terminal of the transistor M1 is electrically connected to a first terminal of the transistor M2 and a gate of the transistor M4. A second terminal of the transistor M1 is electrically connected to a wiring VAL52. A second terminal of the transistor M2 is electrically connected to a gate of the transistor M2 and a wiring VAL42. A first terminal of the transistor M3 is electrically connected to a first terminal of the transistor M4 and an output terminal of the logic circuit INV1. A second terminal of the transistor M3 is electrically connected to the wiring VAL52. A second terminal of the transistor M4 is electrically connected to the wiring VAL42.

In the logic circuit INV2, each of the gate of the transistor M1 and the gate of the transistor M3 is electrically connected to the input terminal of the logic circuit INV2 (the output terminal of the logic circuit INV1). The first terminal of the transistor M1 is electrically connected to the first terminal of the transistor M2 and the gate of the transistor M4. The second terminal of the transistor M1 is electrically connected to the wiring VAL52. The second terminal of the transistor M2 is electrically connected to the gate of the transistor M2 and the wiring VAL42. The first terminal of the transistor M3 is electrically connected to the first terminal of the transistor M4 and the input terminal of the logic circuit INV2 (the terminal BFo of the logic circuit BUF). A second terminal of the transistor M3 is electrically connected to the wiring VAL52. A second terminal of the transistor M4 is electrically connected to the wiring VAL42.

The wiring VAL42 functions as a power supply line for supplying a high-level potential to each of the logic circuit INV1 and the logic circuit INV2, for example. Note that the wiring VAL42 may supply a low-level potential, a ground potential, or a negative potential instead of the high-level potential. Alternatively, the wiring VAL42 may supply a variable potential, instead of a fixed potential.

The wiring VAL52 functions as a power supply line for supplying a low-level potential to each of the logic circuit INV1 and the logic circuit INV2, for example. Note that the wiring VAL52 may supply a high-level potential, a ground potential, or a negative potential instead of the low-level potential. Alternatively, the wiring VAL52 may supply a variable potential, instead of a fixed potential.

Note that one wiring VAL42 is electrically connected to the second terminal of the transistor M2 and the second terminal of the transistor M4 which are included in each of the logic circuit INV1 and the logic circuit INV2; alternatively, different wirings may be electrically connected to the second terminal of the transistor M2 and the second terminal of the transistor M4 which are included in each of the logic circuit INV1 and the logic circuit INV2. Similarly, one wiring VAL52 is electrically connected to the second terminal of the transistor M1 and the second terminal of the transistor M3 which are included in each of the logic circuit INV1 and the logic circuit INV2; alternatively, different wirings may be electrically connected to the second terminal of the transistor M1 and the second terminal of the transistor M3 which are included in each of the logic circuit INV1 and the logic circuit INV2.

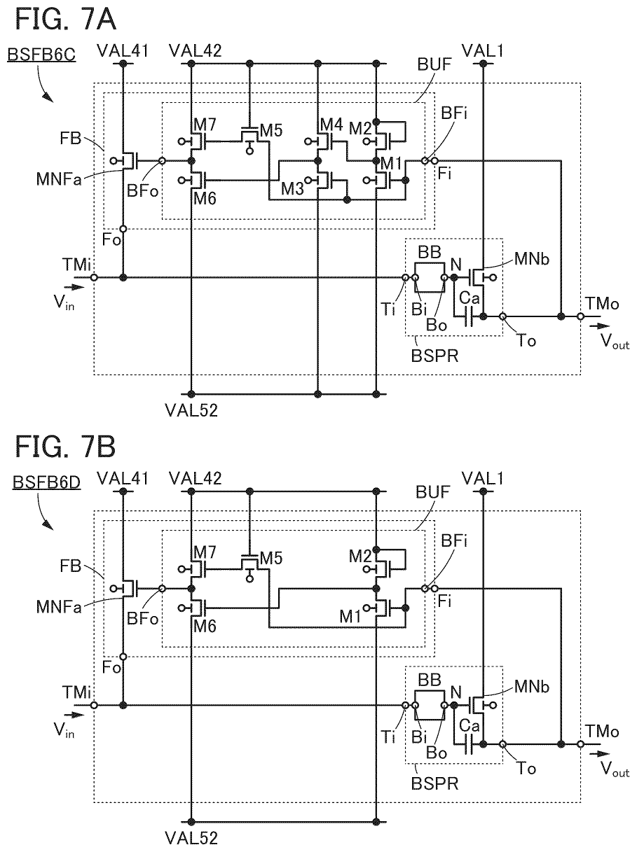

FIG. 7A illustrates a structure example of the circuit BUF of the circuit BSFB6 illustrated in FIG. 5. A circuit BSFB6C illustrated in FIG. 7A is a modification example of the circuit BSFB6B in FIG. 6B and is different from the circuit BSFB6B in the number of transistors included in the circuit BUF and the connection structure.

The circuit BUF of the circuit BSFB6C includes the transistor M1, the transistor M2, the transistor M3, the transistor M4, a transistor M5, a transistor M6, and a transistor M7.

As each of the transistor M1 to the transistor M7, a transistor that can be used as the transistor MNb can be used, for example.

In the circuit BUF of the circuit BSFB6C in FIG. 7A, each of the gate of the transistor M1, the gate of the transistor M3, and a first terminal of the transistor M5 is electrically connected to the terminal BFi of the circuit BUF (the terminal Fi of the circuit FB). The first terminal of the transistor M1 is electrically connected to the first terminal of the transistor M2 and the gate of the transistor M4. The second terminal of the transistor M1 is electrically connected to the wiring VAL52. The second terminal of the transistor M2 is electrically connected to the gate of the transistor M2 and the wiring VAL42. The first terminal of the transistor M3 is electrically connected to the first terminal of the transistor M4 and a gate of the transistor M6. The second terminal of the transistor M3 is electrically connected to the wiring VAL52. The second terminal of the transistor M4 is electrically connected to the wiring VAL42. A second terminal of the transistor M5 is electrically connected to a gate of the transistor M7, and a gate of the transistor M5 is electrically connected to the wiring VAL42. A first terminal of the transistor M6 is electrically connected to the first terminal of the transistor M2 and the terminal Bfo of the circuit BUF. A second terminal of the transistor M6 is electrically connected to the wiring VAL52. A second terminal of the transistor M7 is electrically connected to the wiring VAL42.

Note that one wiring VAL42 is electrically connected to the second terminal of the transistor M2, the second terminal of the transistor M4, the gate of the transistor M5, and a second terminal of the transistor M7; alternatively, different wirings may be electrically connected to the second terminal of the transistor M2, the second terminal of the transistor M4, the gate of the transistor M5, and the second terminal of the transistor M7. Similarly, one wiring VAL52 is electrically connected to the second terminal of the transistor M1, the second terminal of the transistor M3, and a second terminal of the transistor M6; alternatively, different wirings may be electrically connected to the second terminal of the transistor M1, the second terminal of the transistor M3, and the second terminal of the transistor M6.

FIG. 7B illustrates a structure example of the circuit BUF of the circuit BSFB6 illustrated in FIG. 5 which is different from the circuit BSFB6C in FIG. 7A. A circuit BSFB6D illustrated in FIG. 7B is a modification example of the circuit BSFB6C in FIG. 7A and is different from the circuit BSFB6C in the number of transistors included in the circuit BUF and the connection structure.

The circuit BUF of the circuit BSFB6D includes the transistor M1, the transistor M2, the transistor M5, the transistor M6, and the transistor M7, for example.

In the circuit BUF of the circuit BSFB6D in FIG. 7B, each of the gate of the transistor M1 and the first terminal of the transistor M5 is electrically connected to the terminal BFi of the circuit BUF (the terminal Fi of the circuit FB). The first terminal of the transistor M1 is electrically connected to the first terminal of the transistor M2 and the gate of the transistor M6. The second terminal of the transistor M1 is electrically connected to the wiring VAL52. The second terminal of the transistor M2 is electrically connected to the gate of the transistor M2 and the wiring VAL42. The second terminal of the transistor M5 is electrically connected to the gate of the transistor M7, and the gate of the transistor M5 is electrically connected to the wiring VAL42. The first terminal of the transistor M6 is electrically connected to a first terminal of the transistor M7 and the terminal Bfo of the circuit BUF. The second terminal of the transistor M6 is electrically connected to the wiring VAL52. The second terminal of the transistor M7 is electrically connected to the wiring VAL42.

When the circuit BUF of the circuit BSFB6 illustrated in FIG. 5 has the structure of the circuit BUF of any of the circuit BSFB6A in FIG. 6A (the circuit BSFB6B in FIG. 6B), the circuit BSFB6C in FIG. 7A, and the circuit BSFB6D in FIG. 7B, a stable fixed potential can be supplied to the gate of the transistor MNFa.

Note that the circuit BSFB6 may be a unipolar circuit using an n-channel transistor or a CMOS circuit also including a p-channel transistor, like the circuit BSFB6B in FIG. 6B, the circuit BSFB6C in FIG. 7A, or the circuit BSFB6D in FIG. 7B, in particular.

### <<Structure Example 5 of Circuit FB>>

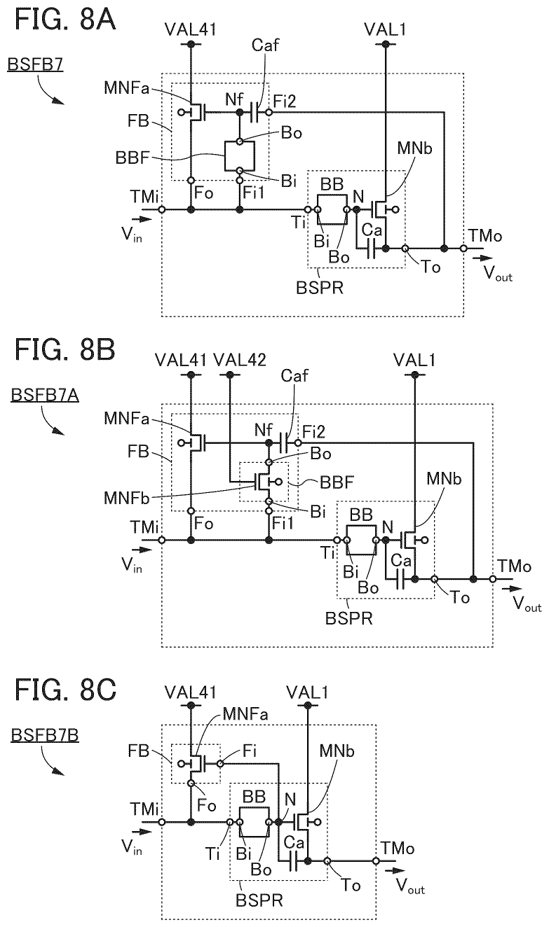

Like the circuit BSFB in FIG. 1A, a circuit BSFB7 illustrated in FIG. 8A is an amplifier circuit that performs feedback to the terminal Ti (the terminal TMi) in accordance with the potential output from the terminal To of the circuit BSPR. Note that the circuit FB of the circuit BSFB7 in FIG. 8A is different from the circuit BSFB in FIG. 1A in including a terminal Fi1 and a terminal Fi2 which function as input terminals.

In the circuit BSFB7 in FIG. 8A, the circuit FB includes the transistor MNFa, a capacitor Caf, and a circuit BBF. As described above, the circuit FB included in the circuit BSFB7 in FIG. 8A includes the terminal Fi1 and the terminal Fi2 which function as input terminals and the terminal Fo which functions as an output terminal. Note that the terminal Fi2 corresponds to the terminal Fi illustrated in FIG. 1A.

As the transistor MNFa, the transistor that can be used as the transistor MNb can be used.

The circuit BBF can be a circuit that can be used as the circuit BB included in the circuit BSPR illustrated in FIG. 2A. Thus, in the circuit BBF in FIG. 8A, the terminal Bi and the terminal Bo are illustrated as terminals, as in the circuit BB.

The terminal Fi1 is electrically connected to the terminal Bi of the circuit BBF. The terminal Fi1 is electrically connected to the terminal Ti of the circuit BSPR, the terminal TMi of the circuit BSFB7, and the terminal Fo of the circuit FB. The terminal Fi2 is electrically connected to a first terminal of the capacitor Caf. The terminal Fi2 is electrically connected to the terminal To of the circuit BSPR and the terminal TMo of the circuit BSFB7. A second terminal of the capacitor Caf is electrically connected to the terminal Bo of the circuit BBF and the gate of the transistor MNFa. The terminal Fo is electrically connected to the first terminal of the transistor MNFa, and the second terminal of the transistor MNFa is electrically connected to the wiring VAL41.

Note that in this embodiment, a portion where the terminal Bo of the circuit BBF, the gate of the transistor MNFa, and the second terminal of the capacitor Caf are electrically connected is referred to as a node Nf.

The circuit BBF has a function of bringing the node Nf into a floating state, for example. Thus, the circuit BBF can include a switching element, for example. The circuit BBF has a function of outputting, to the terminal Bo, a potential corresponding to the potential input to the terminal Bi. For example, the circuit BBF can have a structure in which when the high-level potential V_{High} is supplied to the terminal Bi, a potential V_{Mid_f} is output to the terminal Bo. Note that V_{Mid_f} is a potential lower than the high-level potential V_{High} and higher than the low-level potential V_{Low}.

For the wiring VAL41, the description of the wiring VAL41 with reference to the circuit BSFB1 in FIG. 3A can be referred to.

Here, an operation example of the circuit BSFB7 in FIG. 8A is described.

For the operation of the circuit BSPR, the operation example of the circuit BSPR in FIG. 2A can be referred to. For example, when the high-level potential V_{High} is input to the terminal TMi of the circuit BSFB7 (i.e., when Vᵢₙ=V_{High}), the circuit BB outputs the potential V_{Mid} to the terminal Bo. Thus, V_{Mid} is supplied to the gate of the transistor MNb (the first terminal of the capacitor Ca). At this time, the node N is assumed to be brought into a floating state by the circuit BB.

The low-level potential V_{Low} is assumed to be supplied to the first terminal of the transistor MNb from the wiring VAL1. At this time, the gate-source voltage (the gate-first terminal voltage at this timing) of the transistor MNb is V_{Mid}−V_{Low}, whereby the transistor MNb is turned on. Consequently, the wiring VAL1 outputs the low-level potential V_{Low} to the terminal To of the circuit BSPR through the transistor MNb, whereby Vₒᵤₜ=V_{Low}.

Thus, V_{Low}, which is the same as the potential of the terminal To, is input to the terminal Fi2 of the circuit FB. In this manner, the low-level potential V_{Low} is supplied to the first terminal of the capacitor Caf.

When the high-level potential V_{High} is input to the terminal TMi of the circuit BSFB7 (i.e., Vᵢₙ=V_{High}) in the circuit FB, the circuit BBF outputs the potential V_{Mid} f to the terminal Bo. Thus, the V_{Mid} f is supplied to the gate of the transistor MNFa (the second terminal of the capacitor Caf and the node Nf). Thus, the voltage retained in the capacitor Caf becomes V_{Mid} f-V_{Low} when the node Nf is regarded as a reference.

The transistor MNFa is normally off and the threshold voltage of the transistor MNFa is set to V_{th_MNFa}. The threshold voltage V_{th_MNFa} is set to satisfy V_{High}−V_{Low}>V_{th_MNFa}.

The high-level potential V_{High} is assumed to be supplied to the second terminal of the transistor MNFa from the wiring VAL41. At this time, the potentials of the first terminal and the second terminal of the transistor MNFa are V_{High} and the potential of the gate of the transistor MNFa is V_{Mid} f. At this time, the gate-source voltage (the gate-first terminal voltage at this timing) of the transistor MNFa is V_{Mid_f}−V_{High}. Since V_{Mid_f}−V_{High}<V_{th_MNFa} is satisfied, the transistor MNFa is turned off. At this time, the node Nf is assumed to be brought into a floating state by the circuit BBF.

Next, the potential supplied to the first terminal of the transistor MNb from the wiring VAL1 is assumed to change from the low-level potential V_{Low} to the high-level potential V_{High}. At this time, the gate-source voltage (the gate-second terminal voltage at this timing) of the transistor MNb is V_{Mid}−V_{Low}, whereby the transistor MNb is turned on. Consequently, current flows from the wiring VAL1 to the terminal To of the circuit BSPR through the transistor MNb, which renders the potential of the terminal To higher than V_{Low}. Note that since the node N is in a floating state, the capacitive coupling with the capacitor Ca causes an increase in the potential of the node N from V_{Mid} in response to the increase in the potential of the terminal To. Accordingly, the gate-source voltage of the transistor MNb is retained by the capacitor Ca, whereby the potential of the terminal To increases to V_{High}. Ideally, the potential of the node N is in the following points: V_{Mid}+V_{High}−V_{Low}.

At this time, V_{High}, which is the same as the potential of the terminal To, is input to the terminal Fi2 of the circuit FB. Thus, the potential of the first terminal of the capacitor Caf changes from the low-level potential V_{Low} to the high-level potential V_{High}. Since the node Nf is in a floating state, the capacitive coupling with the capacitor Caf causes an increase in the potential of the node Nf from V_{Mid} in response to the increase in the potential of the terminal Fi2. Here, the potential of the node Nf is V_{Mid_f}+V_{High}−V_{Low}.

In the above manner, the potential of the gate of the transistor MNFa becomes V_{Mid_f}+V_{High}−V_{Low}. Since each of the potentials of the first terminal and the second terminal of the transistor MNFa is V_{High}, the gate-source voltage of the transistor MNFa at this time becomes V_{Mid_f}−V_{Low}. When V_{Mid_f}−V_{Low}>V_{th_MNFa} is satisfied, the transistor MNFa is turned on. That is, electrical continuity is established between the terminal TMi of the circuit BSFB7 and the wiring VAL41.

As described above, the potential of the gate of the transistor MNFa is V_{Mid_f}+V_{High}−V_{Low}. Here, when the potential V_{Mid_f}+V_{High}−V_{Low} of the gate of the transistor MNFa is higher than V_{High}+V_{th_MNFa} (i.e., when V_{Mid_f}−V_{Low} is higher than Vth MNFa), a decrease in the threshold voltage V_{th_MNFa} of the transistor MNFa is not caused at the potential supplied from the wiring VAL41 to the terminal TMi of the circuit BSFB7 (the terminal Ti of the circuit BSPR) through the transistor MNFa. That is, the influence of the voltage drop in the transistor MNFa can be almost eliminated; thus, the potential of the terminal TMi of the circuit BSFB7 (the terminal Ti of the circuit BSPR) can be set to the high-level potential V_{High} supplied from the wiring VAL41.

Thus, for example, even when the amount of an off-state current flowing between a source and a drain or the amount of a leakage current flowing between a gate and the source or between the gate and the drain becomes large in a transistor for retaining the potential of the terminal Ti (the terminal TMi), the potential of the terminal Ti (the terminal TMi) remains a fixed potential (the high-level potential V_{High}) supplied from the circuit FB. In addition, when a noise signal is input to the terminal Ti (the terminal TMi), the potential of the terminal Ti (the terminal TMi) remains a fixed potential (the high-level potential V_{High}) supplied from the circuit FB. Thus, the potential of the terminal To of the circuit BSPR does not change due to the above-described factors, whereby the potential of the node N is less likely to be affected. Accordingly, the potential output from the terminal To of the circuit BSPR becomes stable.

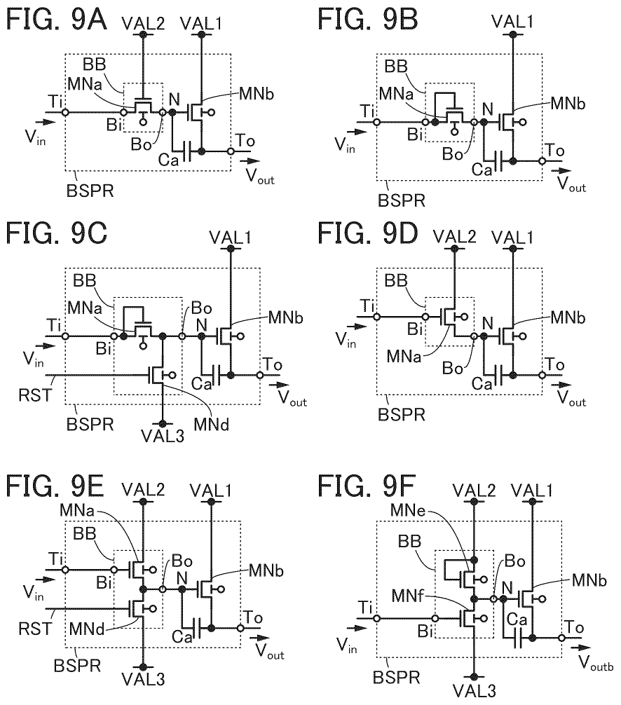

FIG. 8B illustrates a structure example in which the circuit BB in FIG. 9A described later is used as the circuit BBF in the circuit BSFB7 in FIG. 8A. The circuit BSFB7A in FIG. 8B includes a transistor MNFb in the circuit BBF.

A first terminal of the transistor MNFb is electrically connected to the terminal Bi of the circuit BBF, a second terminal of the transistor MNFb is electrically connected to the terminal Bo of the circuit BBF, and a gate of the transistor MNFb is electrically connected to the wiring VAL42.

For the wiring VAL42, the above description of the wiring VAL41 can be referred to.

The transistor MNFb is normally off and the threshold voltage of the transistor MNFb is set to Vth MNFb. The threshold voltage Vth MNFb is set to satisfy V_{High}−V_{Low}>V_{th_MNFb}.

Here, an operation example of the circuit FB in the circuit BSFB7A in FIG. 8B is described. First, in the circuit FB, the potential of the node Nf is the low-level potential V_{Low}. The high-level potential V_{High} is assumed to be supplied to the gate of the transistor MNFb from the wiring VAL42. At this time, since the gate-source voltage (the gate-second terminal voltage at this timing) of the transistor MNFb is V_{High}−V_{Low}, the transistor MNFb is turned on. Here, when the high-level potential V_{High} is input to the terminal TMi of the circuit BSFB7A (i.e., when Vᵢₙ=V_{High}), the potential of the second terminal of the transistor MNFb increases until the potential becomes the gate-source voltage at which the transistor MNFb is turned off. Specifically, when the potential of the second terminal of the transistor MNFb (the potential of the node Nf) reaches V_{High}−V_{th_MNFb}, the transistor MNFb is turned off. Note that V_{High}−V_{th_MNFb} corresponds to V_{Mid} f described above.

After that, the high-level potential V_{High} is assumed to be output from the terminal To by the circuit BSPR. Thus, the potential of the node Nf changes from V_{High}−V_{th_MNFb} to 2V_{High}−V_{th_MNFb}−V_{Low} owing to capacitive coupling with the capacitor Caf. That is, the potential of the gate of the transistor MNFa becomes 2V_{High}−V_{th_MNFb}−V_{Low} and the potential of each of the first terminal and the second terminal of the transistor MNFa is V_{High}; thus, the gate-source voltage of the transistor MNFa becomes V_{High}−V_{th_MNFb}−V_{Low}. When V_{High}−V_{th_MNFb}−V_{Low}>V_{th_MNFa} is satisfied, the transistor MNFa is turned on, and electrical continuity is established between the wiring VAL41 and the terminal Ti (the terminal TMi).

When the potential 2V_{High}−V_{th_MNFb}−V_{Low} of the gate of the transistor MNFa is higher than V_{High}+V_{th_MNFa} (i.e., when V_{High}−V_{Low}−V_{th_MNFb} is higher than V_{th_MNFa}), a decrease in the threshold voltage V_{th_MNFa} of the transistor MNFa is not caused at the potential supplied from the wiring VAL41 to the terminal TMi of the circuit BSFB7 (the terminal Ti of the circuit BSPR) through the transistor MNFa. That is, the influence of the voltage drop in the transistor MNFa can be almost eliminated; thus, the potential of the terminal TMi of the circuit BSFB7 (the terminal Ti of the circuit BSPR) can be set to the high-level potential V_{High} supplied from the wiring VAL41. Accordingly, the terminal Ti (the terminal TMi) is not in a floating state; thus, the potential of the terminal Ti (the terminal TMi) does not change due to a factor such as a leakage current or a noise signal.

Note that the semiconductor device of one embodiment of the present invention is not limited to the circuit BSFB7 illustrated in FIG. 8A and the circuit BSFB7A illustrated in FIG. 8B. The semiconductor device of one embodiment of the present invention may have a circuit structure obtained by replacing the circuit BSFB7 in FIG. 8A with the circuit BSFB7B illustrated in FIG. 8C, for example.

The circuit BSFB7B in FIG. 8C has a structure in which the capacitor Caf included in the circuit FB in the circuit BSFB7 in FIG. 8A is represented as the capacitor Ca included in the circuit BSPR and the circuit BBF included in the circuit FB in the circuit BSFB7 in FIG. 8A is represented as the circuit BB included in the circuit BSPR. Thus, the node Nf of the circuit FB is represented as the node N of the circuit BSPR.

In the circuit BSFB7B in FIG. 8C, an input terminal of the circuit FB is not the terminal Fi1 and the terminal Fi2 but the terminal Fi. In the circuit BSFB7B in FIG. 8C, the terminal Fi of the circuit FB is electrically connected to the terminal Bo of the circuit BB, the gate of the transistor MNb, and the first terminal of the capacitor Ca.

Note that the circuit BSFB7B in FIG. 8C also has a structure in which the terminal Fi of the circuit FB in the circuit BSFB1 in FIG. 3A is electrically connected not to the terminal To and the terminal TMo but to the terminal Bo of the circuit BB, the gate of the transistor MNb, and the first terminal of the capacitor Ca. That is, the circuit BSFB7B in FIG. 8C can be regarded as a modification example of the circuit BSFB1 in FIG. 3A.

For the operation of the circuit BSPR in the circuit BSFB7B in FIG. 8C, the operation example of the circuit BSPR in FIG. 2A can be referred to. Thus, the potential of the node N is set to V_{Mid} and the node N is brought into a floating state, and then the potential supplied from the wiring VAL1 to the first terminal of the transistor MNb is changed from the low-level potential V_{Low} to the high-level potential V_{High}, whereby the potential of the node N can be V_{Mid}+V_{High}−V_{Low} by bootstrap. Accordingly, V_{Mid}+V_{High}−V_{Low} is supplied to the gate of the transistor MNFa. Here, when the potential V_{Mid}+V_{High}−V_{Low} of the gate of the transistor MNFa is higher than V_{High}+Vth MNFa, a decrease in the threshold voltage V_{th_MNFa} of the transistor MNFa is not caused at the potential supplied from the wiring VAL41 to the terminal TMi of the circuit BSFB7 (the terminal Ti of the circuit BSPR) through the transistor MNFa. That is, as in the circuit BSFB7 in FIG. 8A, the influence of the voltage drop in the transistor MNFa can be almost eliminated; thus, the potential of the terminal TMi of the circuit BSFB7B (the terminal Ti of the circuit BSPR) can be set to the high-level potential V_{High} supplied from the wiring VAL41.

### <<Structure Example 1 of Circuit BB>>

Next, structure examples of the circuits BB included in the circuits BSPR in FIG. 1A and FIG. 1B are described. Note that the circuit BB described below can also be used as the circuit BBF included in the circuit FB in FIG. 8A.

The circuit BSPR illustrated in FIG. 9A includes a transistor MNa in the circuit BB. As the transistor MNa, a transistor that can be used as the transistor MNb can be used, for example.

A first terminal of the transistor MNa is electrically connected to the terminal Bi, and a second terminal of the transistor MNa is electrically connected to the terminal Bo. A gate of the transistor MNa is electrically connected to a wiring VAL2.

The wiring VAL2 functions as a wiring supplying a fixed potential or a variable potential, for example, like the wiring VAL1. As a fixed potential, for example, a high-level potential, a low-level potential, a ground potential, or a negative potential can be given. As a variable potential, a pulse signal can be given.

The wiring VAL2 may be electrically connected to the wiring VAL1. In other words, the wiring VAL1 and the wiring VAL2 may be a single wiring.

Here, an operation example of the circuit BSPR in FIG. 9A is described. The high-level potential V_{High} is assumed to be input to the input terminal Ti of the circuit BSPR, for example. That is, Vᵢₙ=V_{High}. In addition, the high-level potential V_{High} is assumed to be supplied to the gate of the transistor MNa from the wiring VAL2. The potential of the node N (the potential of the gate of the transistor MNb or the potential of the first terminal of the capacitor Ca) is the low-level potential V_{Low}.

The transistor MNa is normally off and the threshold voltage of the transistor MNa is set to V_{th_MNa}. The threshold voltage V_{th_MNa} is set to satisfy V_{High}−V_{Low}>V_{th_MNa}.

The gate-source voltage (the gate-second terminal voltage at this timing) of the transistor MNa is V_{High}−V_{Low}, whereby the transistor MNa is turned on. Consequently, electric charge is accumulated in the node N because of current flowing from the terminal Ti through the transistor MNa, so that the potential of the node N increases until the transistor MNa is turned off. Specifically, the transistor MNa is turned off when the gate-source voltage of the transistor MNa decreases to V_{th_MNa}; thus, the potential of the node N (the potential of the second terminal of the transistor MNa) at this time is V_{High}−V_{th_MNa}. Note that V_{High}−V_{th_MNa} corresponds to V_{Mid} described in FIG. 2A.

### <<Structure Example 2 of Circuit BB>>

The circuit BB of the circuit BSPR illustrated in FIG. 9B is a modification example of the circuit BB of the circuit BSPR in FIG. 9A and is different from the circuit BB of the circuit BSPR in FIG. 9A in that the gate of the transistor MNa is electrically connected not to the wiring VAL2 but to the first terminal of the transistor MNa.

In FIG. 9B, since the gate of the transistor MNa is electrically connected to the first terminal of the transistor MNa, the transistor MNa can be said to be diode-connected. Hence, for example, when the high-level potential V_{High} is input to the terminal Ti of the circuit BSPR, the potentials of the first terminal and the gate of the transistor MNa each become the high-level potential V_{High}; thus, the potential of the node N (the potential of the second terminal of the transistor MNa) becomes V_{High}−V_{th_MNa}.

When the potential V_{High}−V_{th_MNa} of the node N ((the potential of the second terminal of the transistor MNa) is to be decreased, that is, when the electric charge accumulated in the node N is to be released, the circuit BB of the circuit BSPR in FIG. 9B should be further modified.

The circuit BB of the circuit BSPR illustrated in FIG. 9C is a modification example of the circuit BB of the circuit BSPR in FIG. 9B and is different from the circuit BB of the circuit BSPR in FIG. 9B in that electric charge accumulated in the node N can be released.

In the circuit BSPR in FIG. 9C, the circuit BB includes a transistor MNd in addition to the transistor MNa.

As the transistor MNd, a transistor that can be used as the transistor MNa or the transistor MNb can be used, for example.

A first terminal of the transistor MNd is electrically connected to the second terminal of the transistor MNa and the terminal Bo, a second terminal of the transistor MNd is electrically connected to the wiring VAL3, and a gate of the transistor MNd is electrically connected to a wiring RST

Like the wiring VAL2 or the wiring VAL52, the wiring VAL3 functions as a wiring for supplying a fixed potential, for example. An example of the fixed potential is a low-level potential. Other examples of the fixed potential include a ground potential and a negative potential. Depending on the circumstances, the wiring VAL3 may function as a wiring that supplies a variable potential.

The wiring RST functions as a wiring that transmits a signal for selecting whether the electric charge accumulated in the node N is released or not, for example. Specifically, for example, when electric charge in the node N is not released, the wiring RST is supplied with the low-level potential V_{Low} as a signal to turn off the transistor MNd. For example, when the electric charge accumulated in the node N is released, the wiring RST is supplied with the high-level potential V_{High} as a signal to turn on the transistor MNd.

When the potential of the node N is to be increased (when the potential of the node Nis to be V_{High}−V_{th_MNa}), for example, the low-level potential V_{Low} is supplied to the wiring RST to turn off the transistor MNd and then the high-level potential V_{High} is supplied to the terminal Ti. When the potential of the node N is to be decreased (when the potential of the node N is to be V_{Low}), for example, the low-level potential V_{Low} is supplied to the terminal Ti to turn off the transistor MNa and then the high-level potential V_{High} is supplied to the wiring RST to turn on the transistor MNd. Here, when the potential supplied to the wiring VAL3 is the low-level potential V_{Low}, the electric charge in the node N flows to the wiring VAL3, whereby the potential of the node N becomes V_{Low}.

### <<Structure Example 3 of Circuit BB>>

The circuit BB of the circuit BSPR illustrated in FIG. 9D is a modification example of the circuit BB of the circuit BSPR in FIG. 9A and is different from the circuit BB of the circuit BSPR in FIG. 9A in that the gate of the transistor MNa is electrically connected not to the wiring VAL2 but to the terminal Bi and that the first terminal of the transistor MNa is electrically connected not to the terminal Bi but to the wiring VAL41.

An operation example of the circuit BSPR in FIG. 9D is described. The high-level potential V_{High} is assumed to be input to the input terminal Ti of the circuit BSPR, for example. In addition, the high-level potential V_{High} is supplied to the first terminal of the transistor MNa from the wiring VAL41. The potential of the node N is the low-level potential V_{Low}.

The gate-source voltage (the gate-second terminal voltage at this timing) of the transistor MNa is V_{High}−V_{Low}, whereby the transistor MNa is turned on. Consequently, electric charge is accumulated in the node N because of current flowing from the wiring VAL41 through the transistor MNa, so that the potential of the node N increases until the transistor MNa is turned off. Specifically, the transistor MNa is turned off when the gate-source voltage of the transistor MNa decreases to Vth MNa; thus, the potential of the node N (the potential of the second terminal of the transistor MNa) is V_{High}−V_{th_MNa}. Note that V_{High}−V_{th_MNa} corresponds to V_{Mid} described in FIG. 2A.

When the potential V_{High}−V_{th_MNa} of the node N (the potential of the second terminal of the transistor MNa) is to be decreased, that is, when the electric charge accumulated in the node N is to be released, the circuit BB of the circuit BSPR in FIG. 9D should be further modified.

The circuit BB of the circuit BSPR illustrated in FIG. 9E is a modification example of the circuit BB of the circuit BSPR in FIG. 9D and is different from the circuit BB of the circuit BSPR in FIG. 9D in that electric charge accumulated in the node N can be released.

In the circuit BSPR in FIG. 9E, the circuit BB includes a transistor MNd in addition to the transistor MNa.

The first terminal of the transistor MNd is electrically connected to the second terminal of the transistor MNa and the terminal Bo, the second terminal of the transistor MNd is electrically connected to the wiring VAL3, the gate of the transistor MNd is electrically connected the wiring RST.

For the transistor MNd, the wiring VAL3, and the wiring RST, the description of the transistor MNd, the wiring VAL3, and the wiring RST in the circuit BSPR in FIG. 9C can be referred to.

When the potential of the node N is to be increased (when the potential of the node Nis to be V_{High}−V_{th_MNa}), for example, the low-level potential V_{Low} is supplied to the wiring RST to turn off the transistor MNd and then the high-level potential V_{High} is supplied to the terminal Ti. When the potential of the node N is to be decreased (when the potential of the node N is to be V_{Low}), for example, the low-level potential V_{Low} is supplied to the terminal Ti to turn off the transistor MNa and then the high-level potential V_{High} is supplied to th wiring RST to turn on the transistor MNd. Here, when the potential supplied to the wiring VAL3 is the low-level potential V_{Low}, the electric charge in the node N flows to the wiring VAL3, whereby the potential of the node N becomes V_{Low}.

### <<Structure Example 4 of Circuit BB>>

A circuit BSPR illustrated in FIG. 9F includes an inverter circuit in the circuit BB. Specifically, the circuit BB includes a transistor MNe and a transistor MNf, and the transistors MNe and MNf form the inverter circuit.

As each of the transistor MNe and the transistor MNf, a transistor that can be used as the transistor MNb can be used, for example.

A first terminal of the transistor MNe is electrically connected to a gate of the transistor MNe and the wiring VAL41, and a second terminal of the transistor MNe is electrically connected to the terminal Bo and a first terminal of the transistor MNf. A second terminal of the transistor MNf is electrically connected to the wiring VAL3, and the gate of the transistor MNf is electrically connected to the terminal Bi.

For the wiring VAL2, the description of the wiring VAL2 of the circuit BSPR in FIG. 9A can be referred to. For the wiring VAL3, the description of the wiring VAL3 of the circuit BSPR in FIG. 9C can be referred to.

Note that in FIG. 9F, a potential output from the terminal To is not Vₒᵤₜ but V_{outb}.

An operation example of the circuit BSPR in FIG. 9F is described. The high-level potential V_{High} is assumed to be input to the first terminal of the transistor MNe from the wiring VAL41, for example. In addition, the low-level potential V_{Low} is assumed to be supplied to the second terminal of the transistor MNf from the wiring VAL3. The potential of the node N (the potential of the gate of the transistor MNb or the potential of the first terminal of the capacitor Ca) is set to the low-level potential V_{Low}.

The transistors MNe and MNf are normally-off transistors. The threshold voltage of the transistor MNe is Vth MNe, and V_{th_MNe} is the voltage in particular satisfying the formula: V_{High}−V_{Low}>V_{th_MNe}.

First, a case is considered in which the low-level potential V_{Low} is input to the terminal Ti. In this case, V_{Low} is input to the gate of the transistor MNf, so that the transistor MNf is turned off. The gate-source voltage (the gate-second terminal voltage at this timing) of the transistor MNe is V_{High}−V_{Low}, whereby the transistor MNe is turned on. Consequently, electric charge is accumulated in the node N because of current flowing from the wiring VAL2 through the transistor MNe, so that the potential of the node N increases until the transistor MNe is turned off. Specifically, the transistor MNe is turned off when the gate-source voltage of the transistor MNe decreases to V_{th_MNe}; thus, the potential of the node N (the potential of the second terminal of the transistor MNe) is V_{High}−V_{th_MNe}. Note that V_{High}−V_{th_MNe} corresponds to V_{Mid} described in FIG. 2.A.

Then, a case is considered in which the high-level potential V_{High} is input to the terminal Ti. In this case, V_{High} is input to the gate of the transistor MNf, so that the transistor MNf is turned on. Since the transistor MNf is in the on state, current flows from the node N to the wiring VAL3 through the transistor MNf, and electric charge is released, whereby the potential of the node N ideally becomes the low-level potential V_{Low} supplied through the wiring VAL3. Note that a reduction in the potential of the second terminal (node N) of the transistor MNe turns on the transistor MNe, so that the potential of the node N actually becomes higher than or equal to the low-level potential V_{Low} and lower than or equal to the high-level potential V_{High}.

### <Structure Example 2 of Amplifier Circuit>

Next, a structure example of an amplifier circuit that is different from the circuit BSFB in FIG. 1A is described.

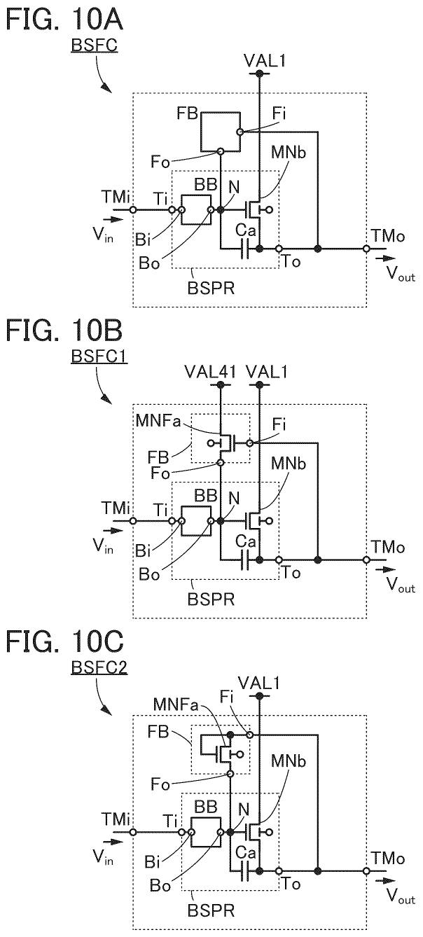

A circuit BSFC illustrated in FIG. 10A is a modification example of the circuit BSFB in FIG. 1A and is different from the circuit BSFB in FIG. 1A in that the terminal Fo of the circuit FB is electrically connected not to the terminal TMi (the terminal Bi of the circuit BB) but to the terminal Bo of the circuit BB, the gate of the transistor MNb, and the first terminal of the capacitor Ca.

As the circuit FB of the circuit BSFC illustrated in FIG. 10A, any of the circuits FB described above with reference to FIG. 3A, FIG. 3B, and FIG. 4A to FIG. 7B can be used, for example.

As an example, FIG. 10B illustrates a structure example in which the circuit FB of the circuit BSFB1 in FIG. 3A is used as the circuit FB of the circuit BSFC in FIG. 10A.

The circuit BSFC1 in FIG. 10B includes the circuit FB having the structure illustrated in FIG. 3A. Thus, in the circuit BSFC1 in FIG. 10B, the first terminal of the transistor MNFa is electrically connected to the terminal Bo of the circuit BB, the gate of the transistor MNb, and the first terminal of the capacitor Ca.

Next, an operation example of the circuit BSFC1 in FIG. 10B is described.

For the operation of the circuit BSPR, the operation example of the circuit BSPR in FIG. 2A can be referred to. For example, when the high-level potential V_{High} is input to the terminal TMi of the circuit BSFC1 (i.e., when Vᵢₙ=V_{High}), the circuit BB outputs the potential V_{Mid} to the terminal Bo. Thus, V_{Mid} is supplied to the gate of the transistor MNb (the first terminal of the capacitor Ca). In addition, the low-level potential V_{Low} is supplied to the first terminal of the transistor MNb from the wiring VAL1. The high-level potential V_{High} is supplied to the second terminal of the transistor MNFa from the wiring VAL41.

At this time, the gate-source voltage (the gate-first terminal voltage at this timing) of the transistor MNb is V_{Mid}−V_{Low}, whereby the transistor MNb is turned on. Consequently, the wiring VAL1 outputs the low-level potential V_{Low} to the terminal To of the circuit BSPR through the transistor MNb, whereby Vₒᵤₜ=V_{Low}.

At this time, V_{Low}, which is the same as the potential of the terminal To, is input to the terminal Fi of the circuit FB. In this manner, the low-level potential V_{Low} is supplied to the gate of the transistor MNFa.

The transistor MNFa is normally off and the threshold voltage of the transistor MNFa is set to V_{th_MNFa}. The threshold voltage V_{th_MNFa} is set to satisfy V_{High}−V_{Low}>V_{th_MNFa}.

Here, the gate-source voltage (here, the gate-first terminal voltage) of the transistor MNFa satisfies V_{Low}-V_{Mid}<Vth MNFa; thus, the transistor MNFa is turned off.

Next, the potential supplied to the first terminal of the transistor MNb from the wiring VAL1 is assumed to change from the low-level potential V_{Low} to the high-level potential V_{High}. In addition, the node N is assumed to be brought into a floating state by the circuit BB. At this time, the gate-source voltage (the gate-second terminal voltage at this timing) of the transistor MNb is V_{Mid}−V_{Low}, whereby the transistor MNb is turned on. Consequently, current flows from the wiring VAL1 to the terminal To of the circuit BSPR through the transistor MNb, which renders the potential of the terminal To higher than V_{Low}. Note that since the node N is in a floating state, the capacitive coupling with the capacitor Ca causes an increase in the potential of the node N from V_{Mid} in response to the increase in the potential of the terminal To. Accordingly, the gate-source voltage of the transistor MNb is retained by the capacitor Ca, whereby the potential of the terminal To increases to V_{High}. Ideally, the potential of the node N is in the following points: V_{Mid}+V_{High}−V_{Low}.

At this time, V_{High}, which is the same as the potential of the terminal To, is input to the terminal Fi of the circuit FB. In this manner, the high-level potential V_{High} is supplied to the gate of the transistor MNFa.

Here, the gate-source voltage of the transistor MNFa (here, the gate-second terminal voltage) is V_{High}−V_{High}=0, for example. Since the transistor MNFa is normally off, the transistor MNFa is off.

In this state, when the potential of the terminal Bo of the circuit BB (the first terminal of the transistor MNFa) decreases from V_{Mid}+V_{High}−V_{Low} and the gate-first terminal voltage of the transistor MNFa becomes higher than the threshold voltage, the transistor MNFa is turned on. At this time, electric charge from the wiring VAL41 is accumulated in the node N, and the potential of the terminal Ti of the circuit BSPR increases. Specifically, the transistor MNFa is turned off when the gate-source voltage of the transistor MNFa becomes Vth MNFa; thus, the potential of the node N (the potential of the first terminal of the transistor MNFa) is V_{High}−V_{th_MNFa}.

As described above, in the circuit BSFC1, when the high-level potential V_{High} is output from the terminal TMo and the potential of the terminal Bo of the circuit BB decreases, the circuit FB can supply the potential V_{High}−V_{th_MNFa} to the terminal Bo (the node N). After that, the bootstrap is performed again in the circuit BSPR, and the high-level potential V_{High} is output from the terminal To of the circuit BSPR. By the above operation, the potential output from the terminal To of the circuit BSPR is stabilized.

As another example, FIG. 10C illustrates a structure example in which the circuit FB of the circuit BSFB5 in FIG. 4D is used as the circuit FB of the circuit BSFC in FIG. 10A.

The circuit BSFC2 in FIG. 10C includes the circuit FB having the structure illustrated in FIG. 4D. Thus, in the circuit BSFC2 in FIG. 10C, the first terminal of the transistor MNFa is electrically connected to the terminal Bo of the circuit BB, the gate of the transistor MNb, and the first terminal of the capacitor Ca. The second terminal and the gate of the transistor MNFa are electrically connected to the terminal To of the circuit BSPR and the terminal TMo of the circuit BSFC2.

In the circuit BSFC2 in FIG. 10C, in the case where the high-level potential V_{High} is input to the gate of the transistor MNFa (in the case where the high-level potential V_{High} is output from the terminal To of the circuit BSPR), the transistor MNFa is turned on when the potential of the first terminal of the transistor MNFa is lower than or equal to V_{High}−V_{th_MNFa}. At this time, a current output from the terminal To flows to the terminal Bo (the node N) through the source-drain of the transistor MNFa. The potential of the first terminal of the transistor MNFa increases until the potential becomes V_{High}−V_{th_MNFa}. When the potential of the first terminal of the transistor MNFa reaches V_{High}−V_{th_MNFa}, the transistor MNFa is turned off. After that, the bootstrap is performed again in the circuit BSPR, and the high-level potential V_{High} is output from the terminal To of the circuit BSPR. By the above operation, the potential output from the terminal To of the circuit BSPR is stabilized.

As described above, with use of the circuit BSFC in FIG. 10A, the circuit BSFC1 in FIG. 10B, or the circuit BSFC2 in FIG. 10C, a potential output from the terminal To of the circuit BSPR can be fed back to supply a fixed potential to the terminal Bo of the circuit BB (the node N). As a result, a potential output from the terminal To of the circuit BSPR can be stabilized.

### <Layout Example of Amplifier Circuit>

Next, an example of a layout diagram (a schematic plan view) of the amplifier circuit described above is described.

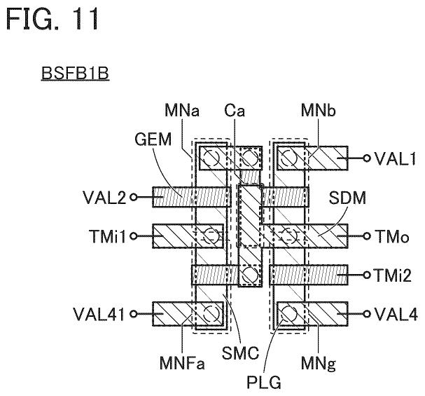

FIG. 11 is a layout diagram of the circuit BSFB1B illustrated in FIG. 3C. In particular, the circuit BB illustrated in FIG. 9A is used as the circuit BB included in the circuit BSFB1B in FIG. 3C. Note that although the back gates of the transistor MNFa, the transistor MNa, the transistor MNb, and the transistor MNg are not illustrated in the layout diagram of FIG. 11, the back gates may be provided in the layout diagram of FIG. 11.

In FIG. 11, the circuit BSFB1B includes a conductor GEM, a conductor SDM, a semiconductor SMC, and a conductor PLG. Note that an insulator included in the circuit BSFB1B is not illustrated in FIG. 11.

The semiconductor SMC is positioned below the conductor GEM, for example. The conductor GEM is positioned below the conductor SDM, for example. That is, in the circuit BSFB1B in FIG. 11, the semiconductor SMC, the conductor GEM, and the conductor SDM are formed in this order from the bottom.

Part of the conductor GEM functions as gates (sometimes referred to as first gates) of the transistor MNFa, the transistor MNa, the transistor MNb, and the transistor MNg, for example.

The semiconductor SMC, the conductor GEM, and the conductor SDM can be formed by a photolithography method, for example. Specifically, for example, in the case where the conductor GEM is formed, a conductive material to be the conductor GEM is formed by one or more selected from a sputtering method, a CVD (Chemical Vapor Deposition) method, a PLD (Pulsed Laser Deposition) method, and an ALD (Atomic Layer Deposition) method, and then a desired pattern is formed by a photolithography method. The semiconductor SMC and the conductor SDM can also be formed in a manner similar to the above.

An insulator may be provided between the semiconductor SMC and the conductor GEM. In particular, an insulator provided between the semiconductor SMC and the conductor GEM functions as a gate insulating film (sometimes referred to as a first gate insulating film or a front gate insulating film) in some cases. An insulator may also be provided between the conductor GEM and the conductor SDM.

The conductor PLG functioning as a wiring or a plug is provided between the semiconductor SMC and the conductor SDM. Similarly, the conductor PLG functioning as a wiring or a plug is also provided between the conductor GEM and the conductor SDM. The conductor PLG is formed, for example, in such a manner that an opening is formed in the insulator, and the opening is filled with a conductive material to be the conductor PLG. Note that after the formation of the conductor PLG, planarization may be performed by planarization treatment using a chemical mechanical polishing method or the like to align the levels of film surfaces of the conductor PLG and peripheral insulators.

Each of the transistor MNFa, the transistor MNa, the transistor MNb, and the transistor MNg illustrated in FIG. 11 includes part of the semiconductor SMC, part of the conductor GEM, part of the insulator, and part of the conductor PLG, for example.

The capacitor Ca illustrated in FIG. 11 includes part of the conductor SDM and part of the conductor GEM. Specifically, the capacitor Ca has a region where part of the conductor SDM and part of the conductor GEM overlap with each other. That is, in the capacitor Ca, the part of the conductor SDM functions as one of a pair of electrodes, and the part of the conductor GEM functions as the other of the pair of electrodes. Note that an insulator with high dielectric constant is preferably provided between the conductor SDM and the conductor GEM in the capacitor Ca.

Note that the layout of the display apparatus of one embodiment of the present invention is not limited to FIG. 11. The layout of the display apparatus of one embodiment of the present invention may be FIG. 11 on which some modification is performed as appropriate.

### <Application Example to Display Apparatus>

Next, a driver circuit including the above-described amplifier circuit and a display apparatus including the driver circuit are described.

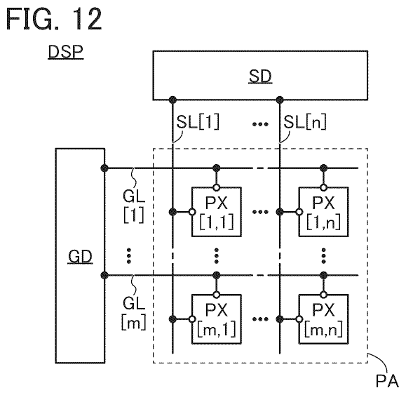

First, the display apparatus is described. FIG. 12 illustrates a configuration example of the display apparatus including the driver circuit including the amplifier circuit described above. As an example, a display apparatus DSP in FIG. 12 includes a driver circuit GD, a driver circuit SD, and a pixel array PA.

Note that in FIG. 12, the driver circuit GD, the driver circuit SD, the pixel array PA, a wiring GL[1], a wiring GL[m], a wiring SL[1], a wiring SL[n], a pixel circuit PX[1, 1], a pixel circuit PX[m, 1], a pixel circuit PX[1, n], and a pixel circuit PX[m, n] are selectively illustrated (m is an integer greater than or equal to 1 and n is an integer greater than or equal to 1).

The pixel array PA includes a plurality of pixel circuits PX, for example. The pixel circuits PX are arranged in a matrix of m rows and n columns in the pixel array PA.

Note that the symbol accompanying the reference characters of the pixel circuit PX in FIG. 12 represents an address in the pixel circuit. For example, the symbol in the reference characters of the pixel circuit PX[1, 1] means that the pixel circuit PX is placed in the first row and the first column in the pixel array PA. For another example, the symbol in the reference characters of the pixel circuit PX[m, 1] means that the pixel circuit PX is placed in the m-th row and the first column in the pixel array PA. For another example, the symbol in the reference characters of the pixel circuit PX[1, n] means that the pixel circuit PX is placed in the first row and the n-th column in the pixel array PA. For another example, the symbol in the reference characters of the pixel circuit PX[m, n] means that the pixel circuit PX is placed in the m-th row and the n-th column in the pixel array PA.

The pixel circuit PX placed in the i-th row and the j-th column (i is an integer greater than or equal to 1 and less than or equal to m, and j is an integer greater than or equal to 1 and less than or equal to n) in the pixel array PA is referred to as a pixel circuit PX[i, j] (not illustrated). The pixel circuit PX[i, j] is electrically connected to a wiring GL[i] (not illustrated), for example. The pixel circuit PX[i, j] is electrically connected to a wiring SL[j] (not illustrated), for example. The driver circuit GD is electrically connected to the wirings GL[1] to GL[m], for example. The driver circuit SD is electrically connected to the wirings SL[1] to SL[n], for example.

The wirings GL[1] to GL[m] are extended in the row direction in the pixel array PA, for example. Furthermore, the symbol [x] accompanying the reference characters of the wiring GL represents the number of the row in which the wiring is provided. For example, the reference of the wiring GL[1] represents a wiring provided in the first row in the pixel array PA. For another example, the reference of the wiring GL[m] represents a wiring provided in the m-th row in the pixel array PA.

The wirings SL[1] to SL[n] are extended in the column direction in the pixel array PA, for example. Furthermore, the symbol [y] accompanying the reference characters of the wiring SL represents the number of the column in which the wiring is provided. For example, the reference of the wiring SL[1] represents a wiring provided in the first column in the pixel array PA. For another example, the reference of the wiring SL[n] represents a wiring provided in the n-th column in the pixel array PA

For example, one or more selected from a liquid crystal display device, a light-emitting device including an organic EL material, a light-emitting device including an inorganic EL material, and a light-emitting device including a light-emitting diode (e.g., a micro LED) can be used in the pixel circuit PX. Note that in the description in this embodiment, the pixel circuit PX in the pixel array PA includes a light-emitting device including an organic EL material. The luminance of light emitted from a light-emitting device capable of high luminance light emission can be, for example, higher than or equal to 500 cd/m², preferably higher than or equal to 1000 cd/m² and lower than or equal to 10000 cd/m², further preferably higher than or equal to 2000 cd/m² and lower than or equal to 5000 cd/m².

The driver circuit GD has a function of selecting the pixel circuit PX to which image data is to be transmitted in the pixel array PA of the display apparatus DSP, for example. Accordingly, the driver circuit GD can be referred to as a gate driver circuit or the like.

The wiring GL, which electrically connects the driver circuit GD and the pixel circuit PX, functions as a wiring transmitting a selection signal. Note that the wiring GL may function as, for example, a wiring supplying a fixed potential, not a wiring transmitting a selection signal.

The driver circuit SD has a function of transmitting image data to the pixel circuit PX in the pixel array PA of the display apparatus DSP, for example. Accordingly, the driver circuit SD can be referred to as a source driver circuit or the like.

The wiring SL, which electrically connects the driver circuit SD and the pixel circuit PX, functions as a wiring transmitting image data as a signal. Note that the wiring SL may function as, for example, a wiring supplying a fixed potential, not a wiring transmitting image data.

Note that in the display apparatus DSP illustrated in FIG. 12, a wiring other than the wirings GL[1] to GL[m] and the wirings SL[1] to SL[n] may be provided. For example, a wiring supplying a fixed potential to the pixel circuit PX may be provided in the display apparatus DSP.

### <<Structure Example of Driver Circuit GD>>

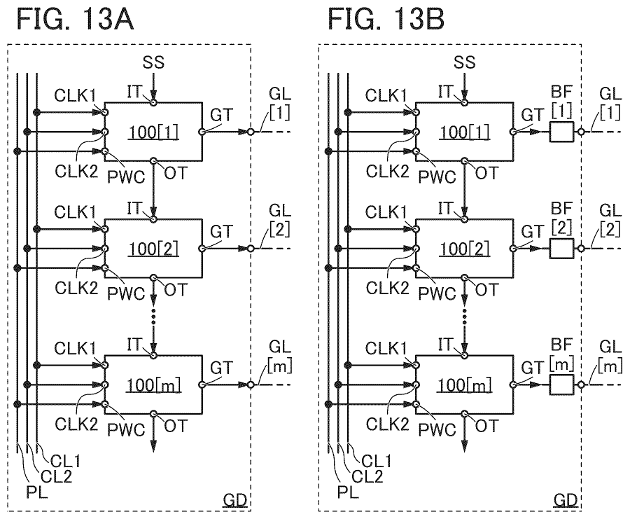

FIG. 13A illustrates a configuration example of the driver circuit GD of one embodiment of the present invention which can be used for the display apparatus DSP in FIG. 12. The driver circuit GD illustrated in FIG. 13A includes a circuit 100[1] to a circuit 100[m], for example.

Each of the circuits 100[1] to 100[m] includes, for example, a terminal IT, a terminal OT, a terminal CLK1, a terminal CLK2, a terminal PWC, and a terminal GT.

In each of the circuits 100[1] to 100[m], for example, the terminal CLK1 is electrically connected to a wiring CL1, the terminal CLK2 is electrically connected to a wiring CL2, and a terminal PWC is electrically connected to a wiring PL.

Each of the wirings CL1, CL2, and PL has, for example, a function of supplying a variable potential (referred to as a pulse voltage in some cases in this specification), such as a clock signal. Note that one or more of the wirings CL1, CL2, and PL may supply a fixed potential, not the variable potential.

The terminal OT of the circuit 100[k] (k is an integer greater than or equal to 1 and less than or equal to m−1) is electrically connected to the terminal IT of the circuit 100[k+1], for example.

The terminal GT of the circuit 100[i] is electrically connected to the wiring GL[i], for example.

Each of the circuits 100[1] to 100[m] has functions of, for example, retaining data input to the terminal IT and outputting the retained data to one or both of the terminals OT and GT.

For example, the circuit 100[i] has a function of outputting data retained in the circuit 100 [i] to the terminal OT when the high-level potential is input to the terminal CLK1. For another example, the circuit 100[i] has a function of outputting data retained in the circuit 100[i] to the terminal GT when the high-level potential is input to the terminal PWC. For another example, the circuit 100[i] has a function of resetting data retained in the circuit 100[i] when the high-level potential is input to the terminal CLK2. The circuit 100[i] is preferably configured to retain new data that is input to the terminal IT of the circuit 100[i] after the data retained in the circuit 100[i] is reset.

As described above, in the circuits 100[1] to 100[m], data is input to the terminal IT of the circuit 100[1] and then a variable potential is input to the terminal CLK1 and the terminal CLK2 at an appropriate timing, whereby the data can be transmitted to the circuit 100[2] and the subsequent circuits 100[m]. Furthermore, data is input to the terminal IT of the circuit 100[1] and then a variable potential is input to the terminal PWC at an appropriate timing, whereby data retained in the circuits 100[1] to 100[m] can be output from the terminals GT of the circuits 100[1] to 100[m]. Accordingly, the configuration of the circuits 100[1] to 100[m] can be referred to as a shift register in this specification and the like.

The above-described data can be, for example, a selection signal for selecting the pixel circuit PX to which image data is to be written in the pixel array PA. Note that in FIG. 13A, the selection signal is illustrated as a signal SS.

Note that although the circuit 100[m] in the driver circuit GD in FIG. 13A includes the terminal OT, the circuit 100[m] is not necessarily provided with the terminal OT because the circuits 100[1] to 100[m] form a shift register.

The configuration of the driver circuit GD applicable to the display apparatus DSP in FIG. 12 is not limited to the configuration in FIG. 13A. For example, the driver circuit GD illustrated in FIG. 13B may be employed as the driver circuit GD applicable to the display apparatus DSP in FIG. 12. The driver circuit GD in FIG. 13B is different from the driver circuit GD in FIG. 13A in including circuits BF [1] to BF [m].

In the driver circuit GD in FIG. 13B, input terminals of the circuits BF [1] to BF [m] are electrically connected to the respective terminals GT of the circuits 100[1] to 100[m], and output terminals of the circuits BF [1] to BF [m] are electrically connected to the wirings GL[1] to GL[m], respectively.

Each of the circuits BF [1] to BF [m] can include an amplifier circuit such as a buffer circuit, an inverter circuit, or a latch circuit, for example. Specifically, each of the circuits BF [1] to BF [m] can have a function of referring to and amplifying a potential of the terminal GT and outputting the amplified potential to the wiring GL.

Note that a wiring other than the wiring CL1, the wiring CL2, and the wiring PL may be provided in the driver circuits GD illustrated in FIG. 13A and FIG. 13B. For example, a wiring for supplying a fixed potential to drive the circuits 100[1] to 100[m] may be provided.

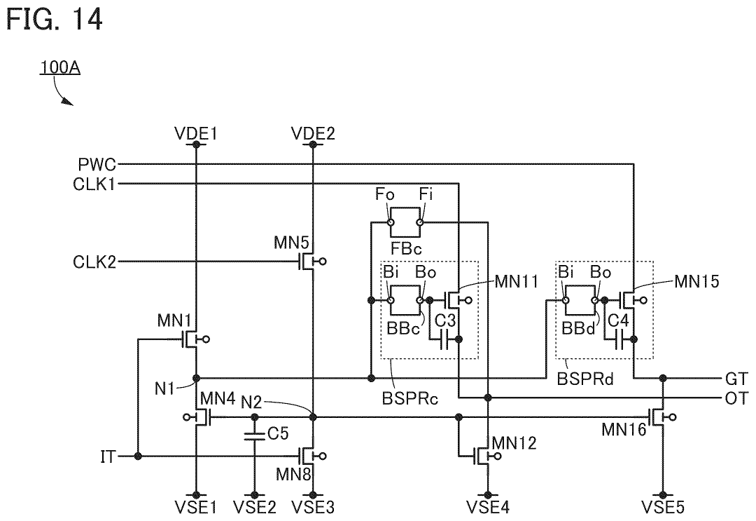

A circuit 100A in FIG. 14 can be employed for each of the circuits 100[1] to 100[m] included in the driver circuit GD illustrated in each of FIG. 13A and FIG. 13B.

The circuit 100A includes a circuit BSPRc, a circuit BSPRd, a circuit FBc, a transistor MN1, a transistor MN4, a transistor MN5, a transistor MN8, a transistor MN12, a transistor MN16, and a capacitor C5, for example. The circuit 100A further includes the terminal IT, the terminal PWC, the terminal CLK1, the terminal CLK2, the terminal GT, and the terminal OT, for example.

In the circuit 100A in FIG. 14, the circuit BSPR illustrated in FIG. 2A is used as each of the circuit BSPRc and the circuit BSPRd. The circuit BSPRc includes a transistor MN11, a capacitor C3, and a circuit BBc, and the circuit BSPRd includes a transistor MN15, a capacitor C4, and a circuit BBd.

For the transistor MN11 and the transistor MN15, the description of the transistor MNb included in the circuit BSPR in FIG. 2A can be referred to. For the capacitor C3 and the capacitor C4, the description of the capacitor Ca included in the circuit BSPR in FIG. 2A can be referred to. For the circuit BBc and the circuit BBd, the description of the circuit BB included in the circuit BSPR in FIG. 2A can be referred to.

A first gate of the transistor MN1 is electrically connected to a first gate of the transistor MN8 and the terminal IT, and a first terminal of the transistor MN1 is electrically connected to a wiring VDE1. A second terminal of the transistor MN1 is electrically connected to a first terminal of the transistor MN4, the terminal Bi of the circuit BBC, the terminal Fo of the circuit FBc, and the terminal Bi of the circuit BBd.

A first gate of the transistor MN5 is electrically connected to the terminal CLK2, and a first terminal of the transistor MN5 is electrically connected to a wiring VDE2. A second terminal of the transistor MN5 is electrically connected to a first gate of the transistor MN4, a first terminal of the capacitor C5, a first terminal of the transistor MN8, a first gate of the transistor MN12, and a first gate of the transistor MN16.

A first gate of the transistor MN11 is electrically connected to the terminal Bo of the circuit BBc and a first terminal of the capacitor C3, and a first terminal of the transistor MN11 is electrically connected to the terminal CLK1. A second terminal of the transistor MN11 is electrically connected to a second terminal of the capacitor C3, a first terminal of the transistor MN12, the terminal OT, and the terminal Fi of the circuit FBc.

A first gate of the transistor MN15 is electrically connected to the terminal Bo of the circuit BBd and a first terminal of the capacitor C4, and a first terminal of the transistor MN15 is electrically connected to the terminal PWC. A second terminal of the transistor MN15 is electrically connected to a second terminal of the capacitor C4, a first terminal of the transistor MN16, and the terminal GT.

A second terminal of the transistor MN4 is electrically connected to a wiring VSE1. A second terminal of the capacitor C5 is electrically connected to a wiring VSE2. A second terminal of the transistor MN8 is electrically connected to a wiring VSE3. A second terminal of the transistor MN12 is electrically connected to a wiring VSE4. A second terminal of the transistor MN16 is electrically connected to a wiring VSE5.

Note that in FIG. 14, a node N1 represents a point where the second terminal of the transistor MN1, the first terminal of the transistor MN4, the terminal Bi of the circuit BBc, the terminal Bi of the circuit BBd, and the terminal Fo of the circuit FBc are electrically connected. In addition, in FIG. 14, a node N2 represents a point where the second terminal of the transistor MN5, the first gate of the transistor MN4, the first terminal of the transistor MN8, the first gate of the transistor MN12, the first gate of the transistor MN16, and a first terminal of the capacitor C5 are electrically connected.

As described above, each of the circuit BSPRc and the circuit BSPRd corresponds to the circuit BSPR illustrated in FIG. 2A. The combination of the circuit BSPRc and the circuit FBc in FIG. 14 corresponds to the circuit BSFB illustrated in FIG. 1A.

Each of the wiring VDE1 and the wiring VDE2 functions as a wiring supplying a fixed potential, for example. The fixed potential can be a high-level potential, for example. Note that the wiring VDE1 and the wiring VDE2 may supply the same fixed potential or different fixed potentials. For example, in the case where the wiring VDE1 and the wiring VDE2 supply the same fixed potential, the wiring VDE1 and the wiring VDE2 may be a single wiring.

One or both of the wiring VDE1 and the wiring VDE2 may supply a variable potential, instead of a fixed potential.

Each of the wiring VSE1 to the wiring VSE5 functions as a wiring supplying a fixed potential, for example. The fixed voltage can be, for example, a low-level potential, the ground potential, or a negative potential. Note that the wiring VSE1 to the wiring VSE5 may supply the same fixed potential or different fixed potentials. Alternatively, two or more of the wiring VSE1 to the wiring VSE5 may supply the same fixed potential, and the other wiring(s) may supply a potential different from the fixed potential. Furthermore, the two or more of the wiring VSE1 to the wiring VSE5 which supply the same fixed potential may be a single wiring. For example, in the case where the wiring VSE1 and wiring VSE2 supply the same fixed potential, the wiring VSE1 and the wiring VSE2 may be a single wiring.

One or more of the wiring VSE1 to the wiring VSE5 may supply a variable potential, instead of a fixed potential.

By using a circuit in which the circuit BSPRc and the circuit FBc are parallel to each other as in the circuit 100A illustrated in FIG. 14, the potential of the output terminal of the circuit BSPRc (corresponding to the potential of the second terminal of the transistor MN11 or the potential of the second terminal of the capacitor C3) can be stabilized. That is, the potential of the terminal OT can be stabilized in the circuit 100A.

### <<Operation Example of Circuit 100A>>

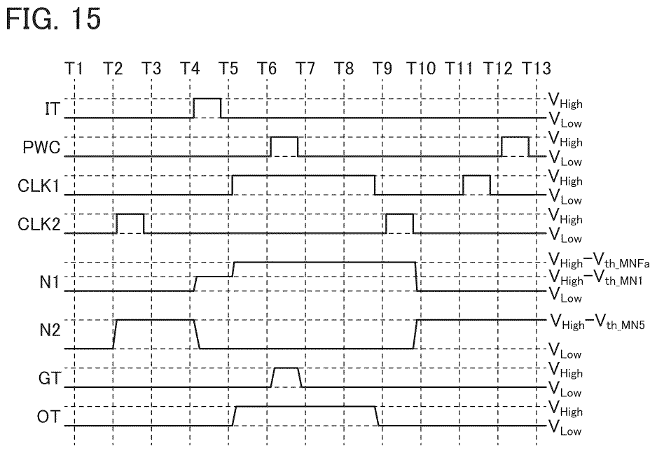

FIG. 15 is a timing chart showing an operation example of the circuit 100A. The timing chart in FIG. 15 shows, as an example, changes in potentials of the terminal IT, the terminal PWC, the terminal CLK1, the terminal CLK2, the node N1, the node N2, the terminal GT, and the terminal OT. In FIG. 15, high- and low-level potentials are expressed as V_{High} and V_{Low}, respectively.

To simply describe the operation of the circuit 100A, the lengths and the like of an input period and an output period of a signal shown in the timing chart in FIG. 15 are different from those in the actual circuit operation in some cases.

In this operation example, the fixed potentials supplied by the wiring VDE1 and the wiring VDE2 are the same high-level potential V_{High}. The fixed potentials supplied by the wiring VSE1 to the wiring VSE5 are the same low-level potential V_{Low}.

Preferably, the high-level potential V_{High} and the low-level potential V_{Low} are each set such that a difference between the high-level potential V_{High} and the low-level potential V_{Low} is preferably greater than the threshold voltage of each of the transistors described in FIG. 14.

[from Time T1 to Time T2]

In a period from Time T1 to Time T2, V_{Low} is supplied to the terminal IT, the low-level potential V_{Low} is supplied to the terminal PWC, the low-level potential V_{Low} is supplied to the terminal CLK1, and the low-level potential V_{Low} is supplied to the terminal CLK2. At the node N2, the low-level potential V_{Low} is retained as an example.

When the low-level potential V_{Low} is supplied to the terminal CLK2, the potential of the first gate of the transistor MN5 becomes the low-level potential V_{Low}. It is also assumed that the threshold voltage of the transistor MN5 is within an appropriate range. Consequently, the transistor MN5 is turned off.

The potential of the first gate of the transistor MN4 (the potential of the node N2) is the high-level potential V_{High}, and the second terminal of the transistor MN4 is supplied with the low-level potential V_{Low} from the wiring VSE1, whereby the transistor MN4 is turned on. Thus, electrical continuity is established between the node N1 and the wiring VSE1, so that the potential of the node N1 becomes the low-level potential V_{Low}.

It is assumed that when the low-level potential V_{Low} is supplied to the terminal IT, the potential of the first gate of the transistor MN1 is the low-level potential V_{Low}. It is also assumed that the threshold voltage of the transistor MN1 is within an appropriate range. Thus, the transistor MN1 is turned offe.

The potential of the first gate of the transistor MN12 (the potential of the node N2) is the low-level potential V_{Low} and the low-level potential V_{Low} is supplied from the wiring VSE4 to the second terminal of the transistor MN12, whereby the transistor MN12 is turned off.reby the transistor MN12 is turned off.

The potential of the first gate of the transistor MN16 (the potential of the node N2) is the low-level potential V_{Low} and the low-level potential V_{Low} is supplied from the wiring VSE5 to the second terminal of the transistor MN16, whereby the transistor MN16 is turned off.

The potential of the first gate of the transistor MN8 (the potential of the terminal IT) is the low-level potential V_{Low}, and the second terminal of the transistor MN8 is supplied with the low-level potential V_{Low} from the wiring VSE3, whereby the transistor MN8 is turned off.

Note that in the period from Time T1 to Time T2 in the timing chart in FIG. 15, each of the potentials of the terminal OT and the terminal GT is the low-level potential V_{Low}, for example. In the period from Time T1 to Time T2, each of the potentials of the terminal OT and the terminal GT may be the high-level potential V_{High}.

### [From Time T2 to Time T3]

In the period from Time T2 to Time T3, the high-level potential V_{High} is supplied to the terminal CLK2.

When the high-level potential V_{High} is supplied to the terminal CLK2, the potential of the gate of the transistor MN5 becomes the high-level potential V_{High}.

Here, the transistor MN5 is normally off and the threshold voltage of the transistor MN5 is set to Vth MN5. The threshold voltage V_{th_MN5} is set to satisfy V_{High}−V_{Low}>V_{th_MN5}.

When the potential of the second terminal of the transistor MN5 (the potential of the node N2) is the low-level potential V_{Low}, the transistor MN5 is turned on, and electric charge from the wiring VDE2 is accumulated in the second terminal of the transistor MN5 (the node N2). When electric charge is accumulated in the node N2 until the gate-source voltage (the gate-second terminal voltage at this timing) of the transistor MN5 becomes V_{High}−V_{th_MN5}, the transistor MN5 is turned off. Thus, the potential V_{High}−V_{th_MN5} is retained in the node N2.

Note that when the potential of the second terminal of the transistor MN5 (the potential of the node N2) is higher than the high-level potential V_{High}, the first terminal of the transistor MN5 serves as a source, and electric charge is released from the node N2 to the wiring VDE1. When the potential of the second terminal of the transistor MN5 (the potential of the node N2) becomes V_{High}−V_{th_MN5}, the transistor MN5 is turned off. Thus, the potential V_{High}−V_{th_MN5} is retained in the node N2 in a manner similar to the above.

In the period from Time T2 to Time T3, the terminal CLK2 is supplied with the high-level potential V_{High} and then supplied with the low-level potential V_{Low}. Thus, the potential of the first gate of the transistor MN5 is assumed to be the low-level potential V_{Low}.

By the above operation, in the circuit 100A, the high-level potential V_{High} is supplied to the terminal CLK2, whereby the potential of the node N2 can be refreshed to be the high-level potential V_{High}.

Since the potential of the node N2 is V_{High}−V_{th_MN5}, the potential of the first gate of the transistor MN12 (the potential of the node N2) is V_{High}−V_{th_MN5}. The low-level potential V_{Low} is supplied from the wiring VSE4 to the second terminal of the transistor MN12, and thus the transistor MN12 is on. Thus, electrical continuity is established between the terminal OT and the wiring VSE4, whereby the potential of the terminal OT becomes the low-level potential V_{Low}.

Since the potential of the node N2 is V_{High}−Vth MN5, the potential of the first gate of the transistor MN16 (the potential of the node N2) is V_{High}−Vth MN5. The low-level potential V_{Low} is supplied from the wiring VSE5 to the second terminal of the transistor MN16, and thus the transistor MN16 is on. Thus, electrical continuity is established between the terminal GT and the wiring VSE5, whereby the potential of the terminal GT becomes the low-level potential V_{Low}.

### [From Time T3 to Time T4]

In a period from Time T3 to Time T4, the low-level potential V_{Low} is supplied to the terminal IT, the low-level potential V_{Low} is supplied to the terminal PWC, V_{Low} is supplied to the terminal CLK1, and the low-level potential V_{Low} is supplied to the terminal CLK2. Potentials input to the terminal IT, the terminal PWC, the terminal CLK1, and the terminal CLK2 in the period from Time T3 to Time T4 are equal to those in the period from Time T1 to Time T2; therefore, for an operation example of the circuit 100A in the period from Time T3 to Time T4, the description of the operation example in the period from Time T1 to Time T2 is referred to.

### [From Time T4 to Time T5]

In a period from Time T4 to Time T5, the high-level potential V_{High} is supplied to the terminal IT.

The high-level potential V_{High} is supplied from the terminal IT to the first gate of the transistor MN8, and V_{Low} is supplied from the wiring VSE3 to the second terminal of the transistor MN8, whereby the transistor MN8 is turned on. Thus, electrical continuity is established between the node N2 and the wiring VSE3, so that the potential of the node N2 changes from the high-level potential V_{High} to the low-level potential V_{Low}.

In the above manner, the potential of the first gate of the transistor MN4 (the potential of the node N2) is the low-level potential V_{Low} and the low-level potential V_{Low} is supplied from the wiring VSE1 to the second terminal of the transistor MN4, whereby the transistor MN4 is turned off.

The potential of the first gate of the transistor MN12 (the potential of the node N2) is the low-level potential V_{Low} and the low-level potential V_{Low} is supplied from the wiring VSE4 to the second terminal of the transistor MN12, whereby the transistor MN12 is turned off.

The potential of the first gate of the transistor MN16 (the potential of the node N2) is the low-level potential V_{Low} and the low-level potential V_{Low} is supplied from the wiring VSE5 to the second terminal of the transistor MN16, whereby the transistor MN16 is turned off.

When the high-level potential V_{High} is supplied to the terminal IT, the potential of the gate of the transistor MN1 becomes the high-level potential V_{High}. Since the potential of the second terminal of the transistor MN1 (the potential of the node N1) is the low-level potential V_{Low}, the transistor MN1 is on. Thus, electric charge flowing from the wiring VDE1 is accumulated in the second terminal of the transistor MN1 (the node N1).

Here, the transistor MN1 is normally off and the threshold voltage of the transistor MN1 is set to V_{th_MN1}. The threshold voltage V_{th_MN1} is set to satisfy V_{High}−V_{Low}>V_{th_MN1}.

Accordingly, when electric charge is accumulated in the node N1 until the gate-source voltage (the gate-second terminal voltage at this timing) of the transistor MN1 becomes V_{High}-Vth MN1, the transistor MN1 is turned off. Thus, the potential V_{High}−V_{th_MN1} is retained in the node N1.

In the period from Time T4 to Time T5, the terminal IT is supplied with the high-level potential V_{High} and then supplied with the low-level potential V_{Low}. Thus, the potential of the first gate of the transistor MN1 is assumed to be the low-level potential V_{Low}.

V_{Low} is supplied from the terminal IT to the first gate of the transistor MN8, and the low-level potential V_{Low} is supplied from the wiring VSE3 to the second terminal of the transistor MN8, whereby the transistor MN8 is turned off. Thus, the low-level potential V_{Low} is retained in the node N2.

### [From Time T5 to Time T6]

In a period from Time T5 to Time T6, the high-level potential V_{High} is supplied to the terminal CLK1.

In a period from Time T4 to Time T5, the potential of the node N1 is the high-level potential V_{High}−Vth MN1. At this time, the high-level potential V_{High} is supplied to the terminal CLK1, whereby the potential of the second terminal (the terminal OT) of each of the transistor MN11 becomes the high-level potential V_{High} in accordance with the description of the circuit BSPR in FIG. 2A.

The high-level potential V_{High}, which is the potential of the second terminal (the terminal OT) of the transistor MN11, is supplied to the terminal Fi of the circuit FBc. When the circuit FBc is the circuit FB of the circuit BSFB1 in FIG. 3A, the circuit FBc outputs V_{High}−V_{th_MNFa} to the terminal Fo. That is, the potential of the node N1 becomes V_{High}−V_{th_MNFa}.

Note that although V_{High}−V_{th_MNFa} is shown as a potential higher than V_{High}−Vth MN1 in the timing chart of FIG. 15, V_{High}−V_{th_MNFa} may be a potential equal to V_{High}−Vth MN1 or a potential lower than V_{High}−V_{th_MN1}.

### [From Time T6 to Time T7]

In a period from Time T6 to Time T7, V_{High} is supplied to the terminal PWC.

In a period from Time T5 to Time T6, the potential of the node N1 is V_{High}−V_{th_MNFa}. At this time, the high-level potential V_{High} is supplied to the terminal PWC, whereby the potential of the second terminal (the terminal GT) of the transistor MN15 also becomes the high-level potential V_{High} in accordance with the description of the circuit BSPR in FIG. 2A.

In the period from Time T6 to Time T7, after the high-level potential V_{High} is supplied to the terminal PWC, the low-level potential V_{Low} is supplied to the terminal PWC. Thus, the potential of the second terminal (the terminal GT) of the transistor MN15 becomes the low-level potential V_{Low} as in the operation example in the period from Time T5 to Time T6.

### [From Time T8 to Time T9]

In a period from Time T8 to Time T9, the low-level potential V_{Low} is supplied to the terminal CLK1.

Thus, the potential of the second terminal (the terminal OT) of the transistor MN11 becomes the low-level potential V_{Low} as in the operation example in the period from Time T4 to Time T5.

The low-level potential V_{Low}, which is the potential of the second terminal (the terminal OT) of the transistor MN11, is supplied to the terminal Fi of the circuit FBc. When the circuit FBc is the circuit FB of the circuit BSFB1 in FIG. 3A, the transistor MNFa of the circuit FBc is turned off. When the transistor MNFa is turned off, the node N1 is brought into a floating state. In the case where the current leakage at the node N1 does not occur, the potential of the node N1 remains V_{High}−V_{th_MNFa}.

### [From Time T9 to Time T10]

In a period from Time T9 to Time T10, the high-level potential V_{High} is supplied to the terminal CLK2. At this time, operation of the circuit 100A in the period from Time T9 to Time T10 is the same as that in the period from Time T2 to Time T3.

For example, when the high-level potential V_{High} is supplied to the terminal CLK2, the potential of the second terminal of the transistor MN5 (the potential of the node N2) becomes the high-level potential V_{High}−V_{th_MN5}. Thus, the transistor MN4, the transistor MN12, and the transistor MN16 are turned on, and each of the potentials of the node N1, the terminal OT, and the terminal GT becomes V_{Low}.

### [After Time T10]

After Time T10, for example, a variable potential with the low-level potential V_{Low} is input to the terminal CLK2 to set the potential of the node N1 to V_{Low} and the potential of the node N2 to V_{High}−V_{th_MN5}, and after that, V_{High} is supplied to the terminal CLK1 or the terminal PWC without input of V_{High} to the terminal IT. A specific operation example is described below.

### [From Time T11 to Time T12]

In a period from Time T11 to Time T12, V_{High} is supplied to the terminal CLK1.

The potential of the first gate of the transistor MN11 is set to V_{Low}. The first terminal of the transistor MN11 is supplied with V_{High} from the terminal CLK1, and the potential of the second terminal of the transistor MN11 is V_{Low}. At this time, the potential of the second terminal of the transistor MN11 is lower than the potential of the first terminal thereof, so that the second terminal of the transistor MN11 serves as a source, and the transistor MN11 is turned off. Thus, electrical continuity is not established between the terminal CLK1 and the terminal OT.

The potential of the first gate of the transistor MN12 is V_{High}−Vth MN5, and the second terminal of the transistor MN12 is supplied with V_{Low} from the wiring VSE4, whereby the transistor MN12 is turned on. Thus, electrical continuity is established between the terminal OT and the wiring VSE4, so that the potential of the terminal OT becomes V_{Low}.

In the period from Time T11 to Time T12, after V_{High} is supplied to the terminal CLK1, V_{Low} is supplied to the terminal CLK1. The potential of the first gate of the transistor MN11 is V_{Low}, the first terminal of the transistor MN11 is supplied with V_{Low} from the terminal CLK1, and the potential of the second terminal of the transistor MN11 is V_{Low}; thus, the transistor MN11 is turned off when the threshold voltage of the transistor MN11 is in an appropriate range.

The low-level potential V_{Low}, which is the potential of the second terminal (the terminal OT) of the transistor MN11, is supplied to the terminal Fi of the circuit FBc. When the circuit FBc is the circuit FB of the circuit BSFB1 in FIG. 3A, the transistor MNFa of the circuit FBc is turned off. Thus, the potential of the node N1 does not change.

The transistor MN11 remains off even when the variable potential with V_{Low} is input to the terminal CLK2 to set the potential of the node N1 to V_{Low} and the potential of the node N2 to V_{High}−V_{th_MN5}, and then V_{High} is supplied to the terminal CLK1 without input of V_{High} to the terminal IT as described above. After that, even when V_{Low} is supplied to the terminal CLK1, the transistor MN11 remains off.

### [From Time T12 to Time T13]

In a period from Time T12 to Time T13, V_{High} is supplied to the terminal PWC.

The potential of the first gate of the transistor MN15 is V_{Low}, V_{High} is supplied from the terminal PWC to the first terminal of the transistor MN15, and the potential of the second terminal of the transistor MN15 is V_{Low}. At this time, the potential of the second terminal of the transistor MN15 is lower than the potential of the first terminal thereof, so that the second terminal of the transistor MN15 serves as a source and the transistor MN15 is turned off. Thus, electrical continuity is not established between the terminal PWC and the terminal GT.

The potential of the first gate of the transistor MN16 is V_{High}−V_{th_MN5}, and the second terminal of the transistor MN16 is supplied with V_{Low} from the wiring VSE5, whereby the transistor MN16 is turned on. Thus, electrical continuity is established between the terminal GT and the wiring VSE5, so that the potential of the terminal GT becomes V_{Low}.

In the period from Time T12 to Time T13, the terminal PWC is supplied with V_{High} and then supplied with V_{Low}. The potential of the first gate of the transistor MN15 is V_{Low}, the first terminal of the transistor MN15 is supplied with V_{Low} from the terminal PWC, and the potential of the second terminal of the transistor MN15 is V_{Low}, whereby the transistor MN15 is turned off.

The transistor MN15 remains off even when the variable potential with V_{Low} is input to the terminal CLK2 to set the potential of the node N1 to V_{Low} and the potential of the node N2 to V_{High}−V_{th_MN5}, and then V_{High} is supplied to the terminal PWC without input of V_{High} to the terminal IT as described above. After that, even when V_{Low} is supplied to the terminal PWC, the transistor MN15 remains off.

### <<Modification Example of Circuit 100A>>

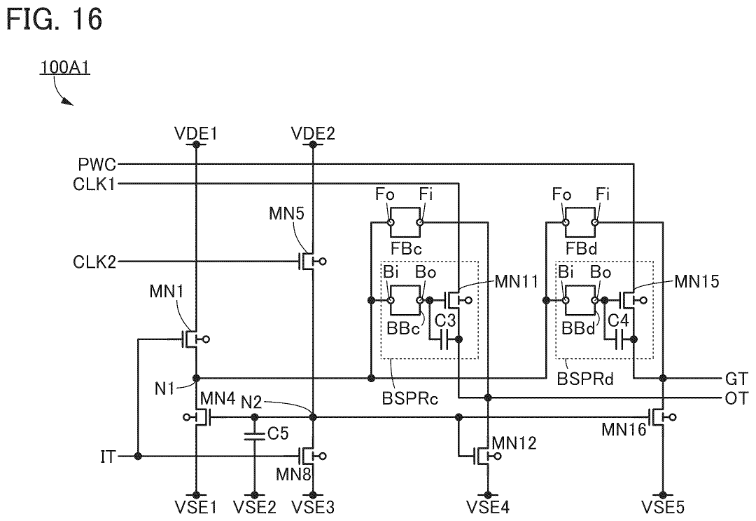

For example, a circuit 100A1 illustrated in FIG. 16 may be used as each of the circuit 100[1] to the circuit 100[m] of the driver circuit GD.

The circuit 100A1 is a modification example of the circuit 100A in FIG. 14 and has a structure in which a circuit FBd is electrically connected to the circuit BSPRd in parallel. Note that the circuit FBd is a circuit that can be used as the circuit FBc.

Specifically, the terminal Fo of the circuit FBd is electrically connected to the terminal Bi of the circuit BBd, the terminal Fo of the circuit FBc, the terminal Bi of the circuit BBc, the second terminal of the transistor MN1, and the first terminal of the transistor MN4. The terminal Fi of the circuit FBd is electrically connected to the second terminal of the transistor MN15, the first terminal of the transistor MN16, the second terminal of the capacitor C4, and the terminal GT.

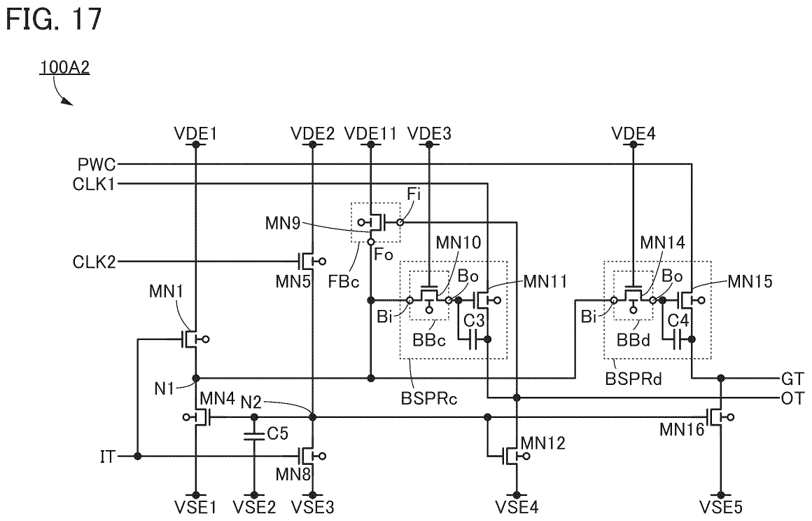

As each of the circuit 100[1] to the circuit 100[m] in the driver circuit GD, for example, a circuit 100A2 illustrated in FIG. 17 may be used.

The circuit 100A2 is a structure example in which the circuit BSPR in FIG. 9A is used as each of the circuit BSPRc and the circuit BSPRd, and the circuit FB in FIG. 3A is used as the circuit FBc. Thus, the circuit FBc includes the transistor MN9, the circuit BBc includes the transistor MN10, and the circuit BBd includes the transistor MN14.

A gate of the transistor MN9 is electrically connected to the terminal Fi of the circuit FBc, a first terminal of the transistor MN9 is electrically connected to a wiring VDE11, and a second terminal of the transistor MN9 is electrically connected to the terminal Fo of the circuit FBc. A gate of the transistor MN10 is electrically connected to a wiring VDE3, a first terminal of the transistor MN10 is electrically connected to the terminal Bi of the circuit BBc, and a second terminal of the transistor MN10 is electrically connected to the terminal Bo of the circuit BBc. A gate of the transistor MN14 is electrically connected to a wiring VDE4, a first terminal of the transistor MN14 is electrically connected to the terminal Bi of the circuit BBd, and a second terminal of the transistor MN14 is electrically connected to the terminal Bo of the circuit BBd.

For each of the wiring VDE11, the wiring VDE3, and the wiring VDE4, the description of the wiring VDE1 and the wiring VDE2 can be referred to. Note that the wiring VDE1 to the wiring VDE4 and the wiring VDE11 may supply the same fixed potential or different fixed potentials. Alternatively, two or more of the wiring VDE1 to the wiring VDE4 and the wiring VDE11 may supply the same fixed potential, and the other wiring(s) may supply a potential different from the fixed potential. Furthermore, the two or more of the wiring VDE1 to the wiring VDE4 and the wiring VDE11 which supply the same fixed potential may be a single wiring.

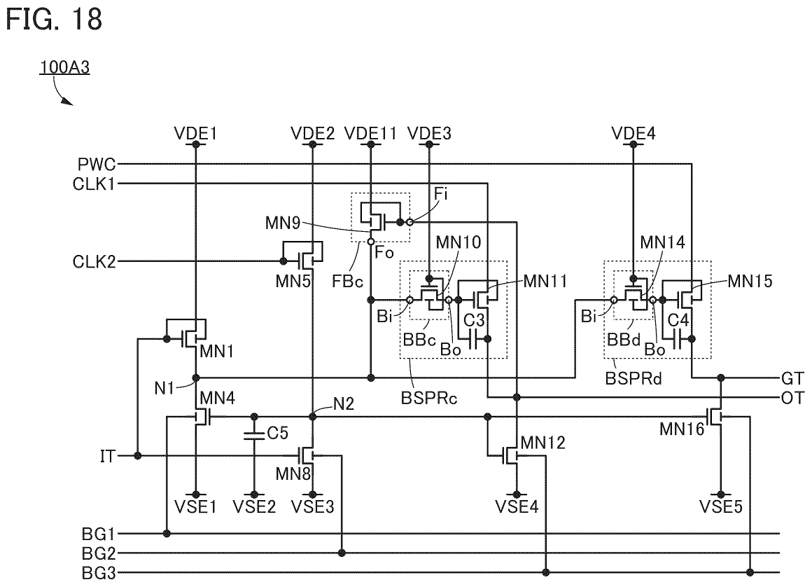

As each of the circuits 100[1] to 100[m] in the driver circuit GD, for example, a circuit 100A3 illustrated in FIG. 18 may be used.

The circuit 100A3 is a modification example of the circuit 100A2 in FIG. 17, in which portions to which the second gates of the transistor MN1, the transistor MN4, the transistor MN5, the transistor MN8 to the transistor MN12, and the transistor MN14 to the transistor MN16 are connected are defined clearly.

In each of the transistor MN1, the transistor MN5, the transistor MN9 to the transistor MN11, the transistor MN14, and the transistor MN15, the first gate is electrically connected to the second gate. A second gate of the transistor MN4 is electrically connected to the wiring BG1. A second gate of the transistor MN8 is electrically connected to the wiring BG2. The second gate of each of the transistors MN12 and MN16 is electrically connected to a wiring BG3.

Each of the wiring BG1 to the wiring BG3 functions as a wiring supplying a fixed potential, for example. The fixed voltage can be, for example, a low-level potential, the ground potential, or a negative potential. Note that the wiring BG1 to the wiring BG3 may supply the same fixed potential or different fixed potentials. In the case where two or more selected from the wiring BG1 to the wiring BG3 supply the same fixed potential, the two or more wirings may be a single wiring. One or more of the wiring BG1 to the wiring BG3 may supply a variable potential, not a fixed potential.

In the case where the wiring BG1 to the wiring BG3 are different from one another, different fixed potentials can be supplied to the second gates of the transistor MN4, the transistor MN8, the transistor MN12, and the transistor MN16. That is, the threshold voltage of the transistor MN4, the threshold voltage of the transistor MN8, and the threshold voltages of the transistor MN12 and the transistor MN16 can be controlled independently of one another.

With this configuration, for example, when a negative potential is supplied to the second gate of the transistor MN4 and the ground potential or a low-level potential (a potential higher than the negative potential) is supplied to the second gates of the transistors MN12 and MN16, the amounts of off-state currents of the transistors MN12 and MN16 can be larger than the amount of an off-state current of the transistor MN4. Accordingly, in the case where the circuit 100A3 in FIG. 18 is employed for each of the circuits 100[1] to 100[m] in the driver circuit GD in each of FIG. 13A and FIG. 13B, the driving speed of the driver circuit GD can be further increased.

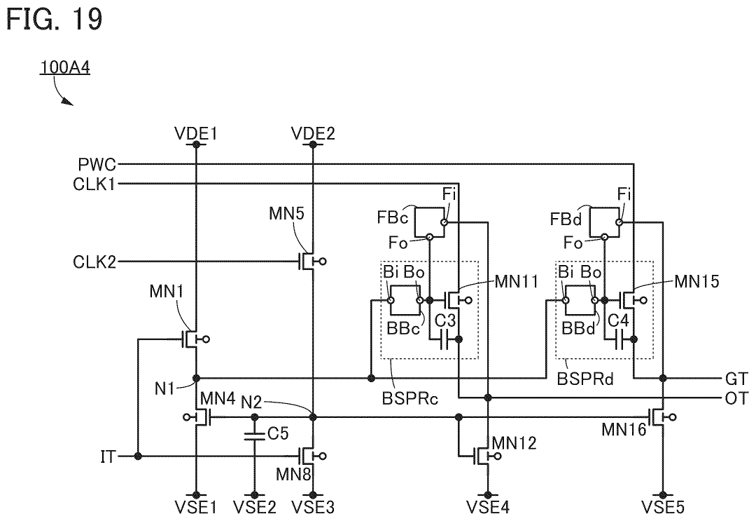

As each of the circuits 100[1] to 100[m] in the driver circuit GD, for example, a circuit 100A4 illustrated in FIG. 19 may be used.

The circuit 100A4 is a modification example of the circuit 100A1 in FIG. 16, in which the terminal Fo of the circuit FBc is electrically connected to the first terminal of the capacitor C3 of the circuit BSPRc and the terminal Fo of the circuit FBd is electrically connected to the first terminal of the capacitor C4 of the circuit BSPRd. Note that the combination of the circuit BSPRc and the circuit FBc and the combination of the circuit BSPRd and the circuit FBd each correspond to the circuit BSFC illustrated in FIG. 10A.

### <<Structure Example of Driver Circuit SD>>

Next, a structure example of the driver circuit SD is described.

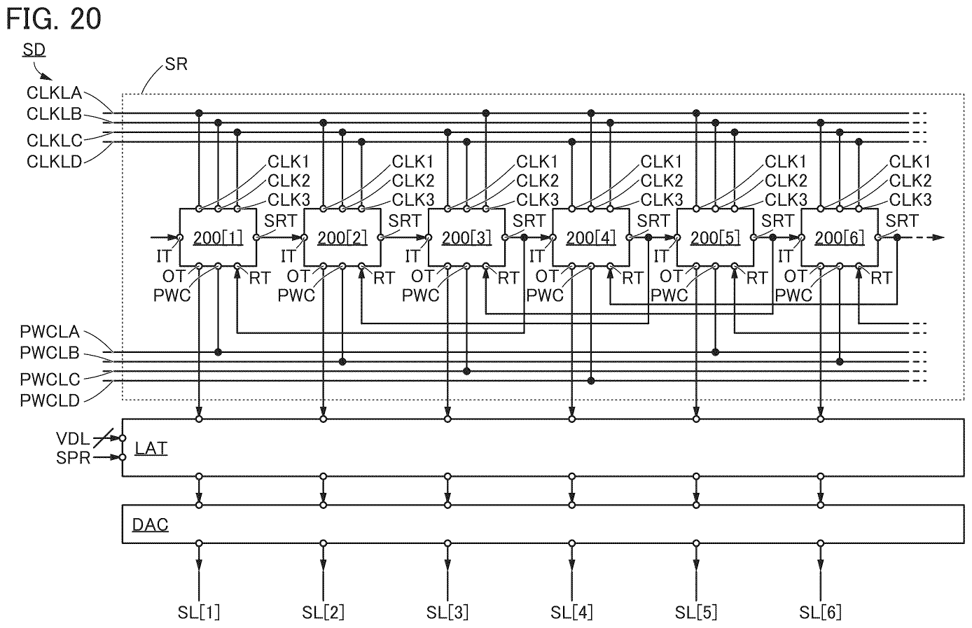

FIG. 20 illustrates a configuration example of the driver circuit SD of one embodiment of the present invention which can be used for the display apparatus DSP in FIG. 12. The driver circuit SD illustrated in FIG. 20 includes a circuit SR, a circuit LAT, and a circuit DAC, for example. Specifically, the circuit SR includes a circuit 200[1] to a circuit 200[n+2], for example. Note that the circuit 200[n+1] is a circuit for transmitting data from a terminal SRT of the circuit 200[n+1] to a terminal RT of a circuit 200[n-1], and the circuit 200[n+2] is a circuit for transmitting data from a terminal SRT of the circuit 200[n+2] to a terminal RT of a circuit 200[n]. FIG. 20 selectively illustrates the circuit 200[1] to a circuit 200[6].

Each of the circuit 200[1] to the circuit 200[n] includes, for example, the terminal IT, the terminal OT, the terminal CLK1, the terminal CLK2, a terminal CLK3, the terminal SRT, the terminal PWC, and the terminal RT.

In the circuit SR, a wiring CLKLA to a wiring CLKLD and a terminal PWCLA to a terminal PWCLD are extended.

In a circuit 200[4k−3], the terminal CLK1 is electrically connected to the wiring CLKLA, the terminal CLK2 is electrically connected to the wiring CLKLB, the terminal CLK3 is electrically connected to the wiring CLKLC, and the terminal PWC is electrically connected to the terminal PWCLA, where k is an integer greater than or equal to 1 and satisfies the formula: 1≤4k−3≤n). In a circuit 200[4k−2], the terminal CLK1 is electrically connected to the wiring

CLKLB, the terminal CLK2 is electrically connected to the wiring CLKLC, the terminal CLK3 is electrically connected to the wiring CLKLD, and the terminal PWC is electrically connected to the terminal PWCLB, where k is an integer greater than or equal to 1 and satisfies the formula: 2≤4k−2≤n). In a circuit 200[4k−1], the terminal CLK1 is electrically connected to the wiring CLKLC, the terminal CLK2 is electrically connected to the wiring CLKLD, the terminal CLK3 is electrically connected to the wiring CLKLA, and the terminal PWC is electrically connected to the terminal PWCLC, where k is an integer greater than or equal to 1 and satisfies the formula: 3≤4k−1≤n). In a circuit 200[4k], the terminal CLK1 is electrically connected to the wiring CLKLD, the terminal CLK2 is electrically connected to the wiring CLKLA, the terminal CLK3 is electrically connected to the wiring CLKLB, and the terminal PWC is electrically connected to the terminal PWCLD, where k is an integer greater than or equal to 1 and satisfies the formula: 4≤4k≤n).

A terminal SRT of the circuit 200[f] (j is an integer greater than or equal to 1 and less than or equal to n) is electrically connected to the terminal IT of the circuit 200[j+1]. The terminal RT of the circuit 200[j] is electrically connected to the terminal SRT of a circuit 200[j+2].

The terminals OT of the circuit 200[1] to the circuit 200[n] are electrically connected to the respective input terminals of the circuit LAT. The output terminals of the circuit LAT are electrically connected to the respective input terminals of the circuit DAC. The circuit LAT is electrically connected to a wiring VDL. The circuit LAT is electrically connected to a wiring SPR. The output terminals of the circuit DAC are electrically connected to the wiring SL[1] to the wiring SL[n]. FIG. 20 selectively illustrates the wiring SL[1] to the wiring SL[6].

Each of the circuits 200[1] to 200[n] has functions of, for example, retaining data input to the terminal IT and outputting the retained data to one or both of the terminal OT and the terminal SRT.

For example, the circuit 200[f] has a function of outputting data retained in the circuit 200[j] to the terminal SRT when the high-level potential is input to the terminal CLK1. For another example, the circuit 200[j] has a function of outputting data retained in the circuit 200[j] to the terminal OT when the high-level potential is input to the terminal PWC. For another example, the circuit 200[f] has a function of resetting data retained in the circuit 200[i] when a variable potential is input to the terminal CLK2 and the terminal CLK3 or the terminal RT or to the terminal CLK2, the terminal CLK3, and the terminal RT. The circuit 200[j] is preferably configured to retain new data that is input to the terminal IT of the circuit 200[f] after the data retained in the circuit 200[j] is reset.

Thus, the circuit SR illustrated in FIG. 20 functions as a shift register like the driver circuit GD illustrated in FIG. 13A and FIG. 13B.

The wiring VDL functions as a wiring that transmits a video signal for display in the pixel circuit PX included in the pixel array PA, for example. Note that in FIG. 20, the wiring VDL is illustrated as a wiring that transmits digital data.

The circuit LAT includes retention circuits of n columns, for example. The circuit LAT has a function of retaining a video signals, which are input to the wiring VDL, in retention circuits in response to the signals from the terminals OT of the circuits 200[1] to 200[n]. Specifically, for example, when the potential of the terminal OT in the circuit 200[j] is a high-level potential, the circuit LAT retains the video signal, which is input to the wiring VDL, in the retention circuit of the j-th column. For example, the circuit LAT has a function of collectively outputting the video signals, which are retained in the retention circuits of the n columns, to the output terminals of the circuit LAT when a high-level potential is input to the wiring SPR.

The circuit DAC has a function of converting a video signal which is digital data output from the output terminals of the circuit LAT into analog data (analog potential), for example. Note that the analog data (analog potential) is transmitted to the wiring SL in the column.

A wiring other than the wiring CLKLA to the wiring CLKLD and the wiring PWCLA to the wiring PWCLD may be provided in the driver circuit SD illustrated in FIG. 20. The configuration of the driver circuit SD illustrated in FIG. 20 is an example, and the number of wirings, electrical connections, and the like may be modified as appropriate.

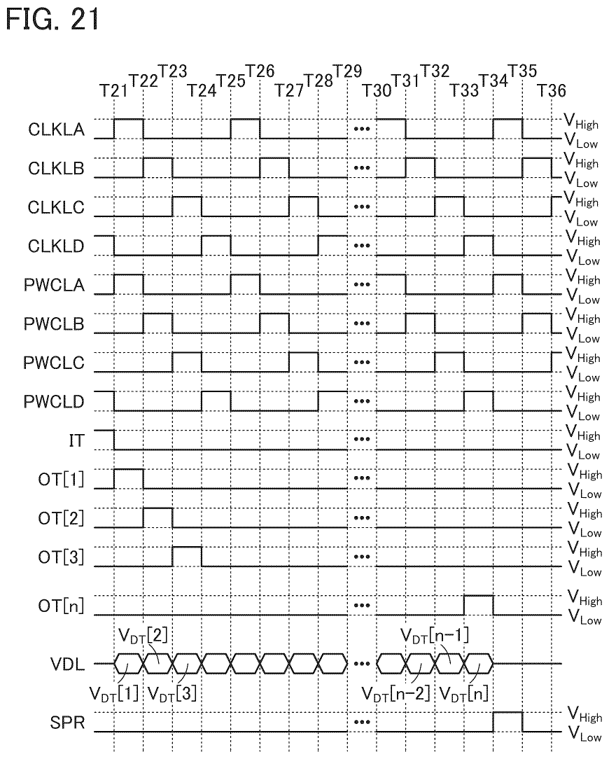

FIG. 21 is a timing chart showing an operation example of the driver circuit SD. FIG. 21 shows potential changes of the wiring CLKLA to the wiring CLKLD and the wiring PWCLA to the wiring PWCLD, the terminal IT, the terminal OT[1], the terminal OT[2], the terminal OT[3], the terminal OT[n], and the wiring SPR in the period from Time T21 to Time T36 and around the period. Note that a terminal OT[f] is the terminal OT included in the circuit 200[f]. In the example shown in FIG. 21, a video signal VDT [1] to a video signal VDT [n] are sequentially input to the wiring VDL.

In the period from Time T21 to Time T22, the high-level potential V_{High} is supplied to the wiring CLKLA and the wiring PWCLA. In the period from Time T22 to Time T23, the high-level potential V_{High} is supplied to the wiring CLKLB and the wiring PWCLB. In the period from Time T23 to Time T24, the high-level potential V_{High} is supplied to the wiring CLKLC and the wiring PWCLC. In the period from Time T24 to Time T25, the high-level potential V_{High} is supplied to the wiring CLKLD and the wiring PWCLD. In the period after Time T25, the high-level potential V_{High} is supplied to the wiring CLKLA to the wiring CLKLD and the wiring PWCLA to the wiring PWCLD as in the period from Time T21 to Time T25.

Since the high-level potential V_{High} is supplied to the wiring CLKLA to the wiring CLKLD and the wiring PWCLA to the wiring PWCLD at the above timings, the terminal OT[1] to the terminal OT[n] sequentially output the high-level potential V_{High} at predetermined timings when the high-level potential V_{High} is supplied to the terminal IT in the period before Time T21. For example, the terminal OT[1] outputs the high-level potential V_{High} in the period from Time T21 to Time T22, the terminal OT[2] outputs the high-level potential V_{High} in the period from Time T22 to Time T23, and the terminal OT[3] outputs the high-level potential V_{High} in the period from Time T23 to Time T24. For example, the terminal OT[n-2] outputs the high-level potential V_{High} in the period from Time T31 to Time T32, the terminal OT[n-1] outputs the high-level potential V_{High} in the period from Time T32 to Time T33, and the terminal OT[n] outputs the high-level potential V_{High} in the period from Time T33 to Time T34.

Note that the timing chart of FIG. 21 shows the case where n is a multiple of 4. In the case where n is not a multiple of 4 in the driver circuit SD, potentials supplied to the wiring CLKLA to the wiring CLKLD and the wiring PWCLA to the wiring PWCLD in the period from Time T30 to Time T34 are replaced as appropriate.

The circuit LAT retains the video signal VDT [1], which is input to the wiring VDL, in the retention circuit of the first column at the timing when the high-level potential V_{High} is output from the terminal OT[1]. The circuit LAT retains the video signal VDT [2], which is input to the wiring VDL, in the retention circuit of the second column at the timing when the high-level potential V_{High} is output from the terminal OT[2], and retains the video signal VDT [3], which is input to the wiring VDL, in the retention circuit of the third column at the timing when the high-level potential V_{High} is output from the terminal OT[3]. Similar operations are sequentially continued, and the circuit LAT retains the video signal VDT [n], which is input to the wiring VDL, in the retention circuit of the n-th column at the timing when the high-level potential V_{High} is output from the terminal OT[n].

When the potential of the wiring SPR changes to the high-level potential V_{High} in the period from Time T34 to Time T35, the circuit LAT outputs the video signal VDT [1] to the video signal VDT [n], which have been retained in the retention circuits of the n columns in the circuit LAT, to the circuit DAC through the output terminals of the circuit LAT.

The driver circuit SD is capable of transmitting the video signals to the pixel circuits in the pixel array PA by performing the above operation as an example in the timing chart in FIG. 21.

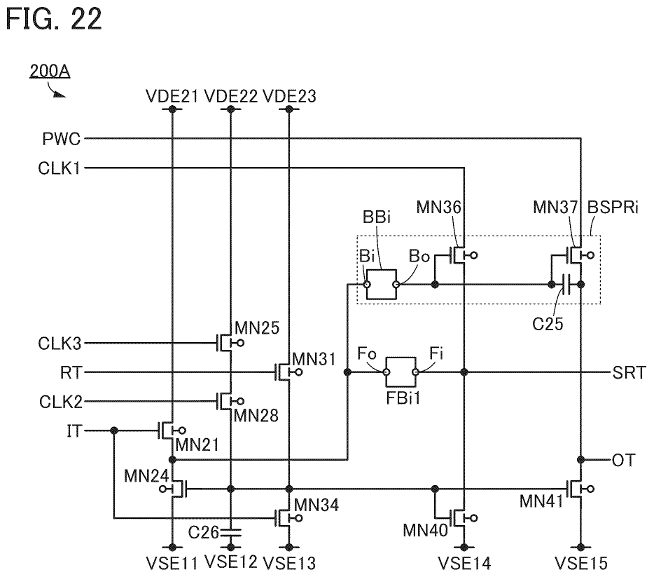

A circuit 200A in FIG. 22 has a circuit structure that can be used as the circuits 200[1] to 200[n] included in the driver circuit SD.

The circuit 200A includes a circuit BSPRi, a circuit FBi1, a transistor MN21, a transistor MN24, a transistor MN25, a transistor MN28, a transistor MN31, a transistor MN34, a transistor MN40, a transistor MN41, and a capacitor C26, for example. The circuit 200A further includes the terminal IT, the terminal PWC, the terminal CLK1, the terminal CLK2, the terminal CLK3, the terminal RT, the terminal SRT, and the terminal OT, for example.

In the circuit 200A in FIG. 22, the circuit BSPRi employs a circuit structure obtained by modifying the circuit BSPR illustrated in FIG. 2A. Specifically, the circuit BSPRi employs a circuit structure obtained by further adding one transistor to the circuit BSPR illustrated in FIG. 2A.

The circuit BSPRi includes a circuit BBi corresponding to the circuit BB of the circuit BSPR in FIG. 2A, a transistor MN37 corresponding to the transistor MNb of the circuit BSPR in FIG. 2A, a capacitor C25 corresponding to the capacitor Ca of the circuit BSPR in FIG. 2A, and a transistor MN36.

A first gate of the transistor MN21 is electrically connected to a first gate of the transistor MN34 and the terminal IT, and a first terminal of the transistor MN21 is electrically connected to a wiring VDE21. A second terminal of the transistor MN21 is electrically connected to a first terminal of the transistor MN24, the terminal Bi of the circuit BBi, and the terminal Fo of the circuit Fbi1.

A first gate of the transistor MN25 is electrically connected to the terminal CLK3, and a first terminal of the transistor MN25 is electrically connected to a wiring VDE22. A second terminal of the transistor MN25 is electrically connected to a first terminal of the transistor MN28. A first gate of the transistor MN28 is electrically connected to the terminal CLK2.

A first gate of the transistor MN31 is electrically connected to the terminal RT, and a first terminal of the transistor MN31 is electrically connected to a wiring VDE23. A second terminal of the transistor MN31 is electrically connected to a second terminal of the transistor MN28, a first gate of the transistor MN24, a first terminal of the capacitor C26, a first terminal of the transistor MN34, a first gate of the transistor MN40, and a first gate of the transistor MN41.

A first gate of the transistor MN36 is electrically connected to the terminal Bo of the circuit BBi, a first terminal of the capacitor C25, and a first gate of the transistor MN37, and a first terminal of the transistor MN36 is electrically connected to the terminal CLK1. A second terminal of the transistor MN36 is electrically connected to the terminal Fi of the circuit FBi1, a first terminal of the transistor MN40, and the terminal SRT. A first terminal of the transistor MN37 is electrically connected to the terminal PWC. A second terminal of the transistor MN37 is electrically connected to a second terminal of the capacitor C25, a first terminal of the transistor MN41, and the terminal OT.

A second terminal of the transistor MN24 is electrically connected to a wiring VSE11. A second terminal of the capacitor C26 is electrically connected to a wiring VSE12. A second terminal of the transistor MN34 is electrically connected to a wiring VSE13. A second terminal of the transistor MN40 is electrically connected to a wiring VSE14. A second terminal of the transistor MN41 is electrically connected to a wiring VSE15.

For the wiring VDE21 to the wiring VDE23, the description of the wiring VDE11, the wiring VDE3, and the wiring VDE4 can be referred to, for example.

For the wiring VSE11 to the wiring VSE15, the description of the wiring VSE1 to the wiring VSE5 can be referred to, for example.

In the circuit 200A, when the potential of the terminal SRT becomes the high-level potential V_{High}, electrical continuity is sometimes established between an electrical connection point of the second terminal of the transistor MN21, the first terminal of the transistor MN24, and the terminal Bi of the circuit BBi and a wiring supplying a fixed potential (e.g., the wiring VAL41 in FIG. 3A to FIG. 3C). Since electrical continuity is established between the wiring and the electrical connection point in such a manner, the potential of the electrical connection point can be kept constant even when electric charge accumulated at the electrical connection point changes unintentionally.

By using a circuit in which the circuit BBi and the transistor MN36 of the circuit BSPRi are parallel to the circuit FBi1 as in the circuit 200A illustrated in FIG. 22, the potential of the output terminal of the circuit BSPRi (the second terminal of the transistor MN36) can be stabilized. That is, the potential of the terminal SRT can be stabilized in the circuit 200A.

### <<Modification Example of Circuit 200A>>

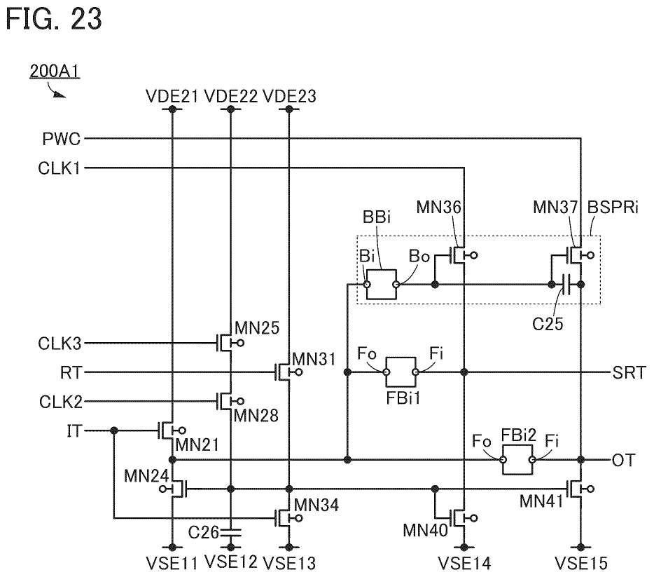

For example, a circuit 200A1 in FIG. 23 may be employed for each of the circuits 200[1] to 200[n] of the driver circuit SD.

The circuit 200A1 is a modification example of the circuit 200A in FIG. 22 and has a structure in which a circuit FBi2 is provided in the circuit 200A in FIG. 22. Note that the circuit structure of the circuit FBi2 can be a circuit structure applicable to the circuit FBi1.

Specifically, the terminal Fo of the circuit FBi2 is electrically connected to the terminal Fo of the circuit FBi1, the terminal Bi of the circuit BBi, the second terminal of the transistor MN21, and the first terminal of the transistor MN24. The terminal Fi of the circuit FBi2 is electrically connected to the second terminal of the transistor MN37, the first terminal of the transistor MN41, the second terminal of the capacitor C25, and the terminal OT.

In the circuit 200A1, when one or both of the potentials of the terminal SRT and the terminal OT become the high-level potential V_{High}, electrical continuity is sometimes established between an electrical connection point of the second terminal of the transistor MN21, the first terminal of the transistor MN24, and the terminal Bi of the circuit BBi and a wiring supplying a fixed potential (e.g., the wiring VAL41 in FIG. 3A to FIG. 3C). Since electrical continuity is established between the wiring and the electrical connection point, the potential of the electrical connection point can be kept constant even when electric charge accumulated at the electrical connection point changes unintentionally.

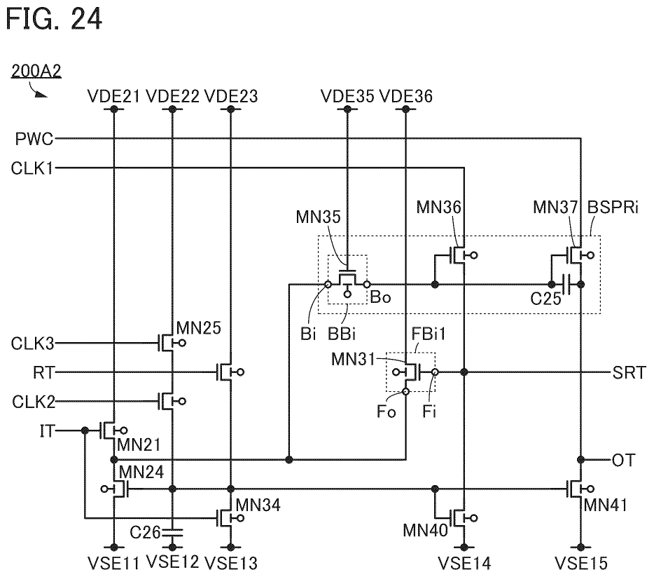

For example, a circuit 200A2 in FIG. 24 may be employed for each of the circuit 200[1] to the circuit 200[n] of the driver circuit SD.

The circuit 200A2 in FIG. 24 has a structure in which the circuit BB of the circuit BSPR in FIG. 9A and the circuit FB in FIG. 3A are respectively used as the circuit BBi and the circuit FBi1 in the circuit 200A in FIG. 22. Thus, the circuit BBi includes the transistor MN35, and the circuit FBi1 includes the transistor MN31.

A first terminal of the transistor MN35 is electrically connected to the terminal Bi of the circuit BBi, a second terminal of the transistor MN35 is electrically connected to the terminal Bo of the circuit BBi, and a gate of the transistor MN35 is electrically connected to a wiring VDE35. A first terminal of the transistor MN31 is electrically connected to a wiring VDE36, a second terminal of the transistor MN31 is electrically connected to the terminal Fo of the circuit FBi1, and a gate of the transistor MN31 is electrically connected to the terminal Fi of the circuit FBi1.

For the wiring VDE35 and the wiring VDE36, the description of the wiring VDE21 to the wiring VDE23 can be referred to, for example.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 2

In this embodiment, a structure example of a display apparatus of one embodiment of the present invention will be described.

### <Structure Example of Display Apparatus>

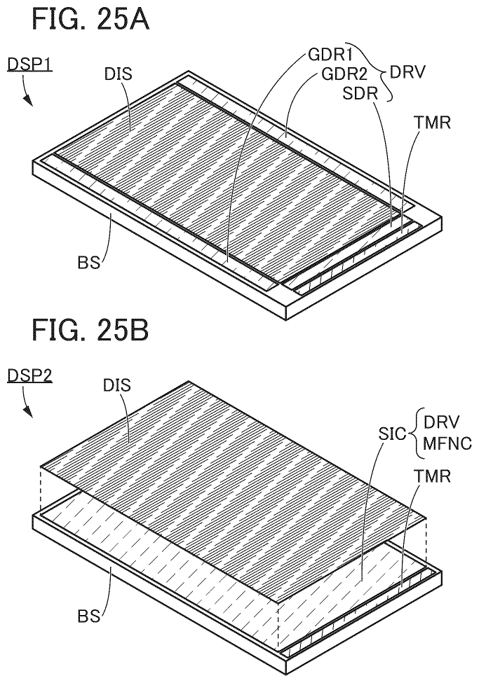

FIG. 25A is a schematic perspective view illustrating a display apparatus according to one embodiment of the present invention. A display apparatus DSP1 includes a display region DIS, a driver circuit region DRV, and a terminal region TMR, for example. The display apparatus DSP1 includes a substrate BS, and the display region DIS, the driver circuit region DRV, and the terminal region TMR are located over the substrate BS.

The driver circuit region DRV includes, for example, a driver circuit GDR1, a driver circuit GDR2, and a driver circuit SDR.

As the substrate BS, a semiconductor substrate (e.g., a single crystal substrate formed of silicon or germanium) can be used, for example. Besides such a semiconductor substrate, any of the following can be used as the substrate BS: a silicon on insulator (SOI) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, and paper or a base film including a fibrous material. Examples of the glass substrate include a barium borosilicate glass substrate, an aluminoborosilicate glass substrate, and a soda lime glass substrate. Examples of materials for the flexible substrate, the attachment film, or the base film include plastic typified by polyethylene terephthalate (PET), polyethylene naphthalate (PEN), polyethersulfone (PES), and polytetrafluoroethylene (PTFE). Another example is a synthetic resin such as an acrylic resin. Other examples are polypropylene, polyester, polyvinyl fluoride, and polyvinyl chloride. Other examples are polyamide, polyimide, aramid, an epoxy resin, an inorganic vapor-deposited film, and paper. Note that in the case where the manufacturing process of the display apparatus DSP1 involves heat treatment, a highly heat-resistant material is preferably used for the substrate BS.

For example, in the case where a semiconductor substrate including silicon as a material is used as the substrate BS, transistors included in the display region DIS and the driver circuit region DRV can be Si transistors and can be formed over the substrate BS.

For example, in the case where a glass substrate is used as the substrate BS, transistors included in the display region DIS and the driver circuit region DRV can be OS transistors and can be formed over the substrate BS.

One or more selected from the driver circuits GDR1, GDR2, and SDR included in the driver circuit region DRV may be mounted as an integrated circuit (IC) on the substrate BS by a chip on glass (COG) technique.

The driver circuits GDR1 and GDR2 each function as a driver circuit for displaying an image on the display region DIS, for example. Specifically, for example, the driver circuits GDR1 and GDR2 each function as a gate driver circuit for the display region DIS. For example, the driver circuit SDR functions as a source driver circuit for the display region DIS.

Thus, for example, the driver circuit GD in each of FIG. 13A or FIG. 13B described in the above embodiment can be employed for each of the driver circuits GDR1 and GDR2. For example, the driver circuit SD in FIG. 20 described in the above embodiment can be used as the driver circuit SDR.

The terminal region TMR includes a terminal for supplying an image signal and a power supply potential into the display apparatus DSP1 from the outside. A flexible printed circuit (FPC) may be electrically connected to the terminal region TMR. A chip may be provided as an IC over the FPC by a chip on film (COF) technique. The IC, for example, may include a driver circuit for displaying an image on the display region DIS.

The pixel region DIS includes, for example, a plurality of pixels. The plurality of pixels may be arranged in a matrix in the pixel region DIS.

Each of the plurality of pixels can express one color or a plurality of colors. In particular, the plurality of colors can be, for example, three colors of red, green, and blue. Alternatively, the plurality of colors may be two or more colors selected from, for example, red, green, blue, cyan, magenta, yellow, and white. Note that in the case where each of pixels expressing different colors is called a subpixel and white is expressed by a plurality of subpixels expressing different colors, the plurality of subpixels are collectively called a pixel in some cases.

In this specification and the like, a subpixel is referred to as a pixel for convenience. Note that the display apparatus of one embodiment of the present invention is not limited to the structure of the display apparatus DSP1 in FIG. 25A. For example, the display apparatus of one embodiment of the present invention may have the structure of the display apparatus DSP2 illustrated in FIG. 25B.

The display apparatus DSP2 in FIG. 25B includes the display region DIS, the circuit region SIC, and the terminal region TMR, for example. The display apparatus DSP2 further includes the substrate BS, like the display apparatus DSP1. The display apparatus DSP2 is different from the display apparatus DSP1 in that the circuit region SIC and the terminal region TMR are provided over the substrate BS and the display region DIS is provided over the circuit region SIC.

The circuit region SIC includes, for example, the driver circuit region DRV described above. The circuit region SIC may include any of a variety of functional circuits other than the driver circuit region DRV. In this embodiment, the functional circuit is included in a functional circuit region MFNC.

The functional circuit region MFNC may include a graphics processing unit (GPU), for example. In the case where the display apparatus DSP2 includes a touch panel, the functional circuit region MFNC may include a sensor controller for controlling a touch sensor included in the touch panel.

In the case where a light-emitting device containing an organic EL material is used as the display element of the display apparatus DSP2, a correction circuit may be included in the functional circuit region MFNC. The correction circuit has a function of appropriately adjusting the amount of current input to the light-emitting device containing an organic EL material. Since the emission luminance of the light-emitting device containing an organic EL material is proportional to the current, when the characteristics of a driving transistor electrically connected to the light-emitting device are not favorable, the luminance of light emitted from the light-emitting device might be lower than a desired luminance. For example, the correction circuit monitors the amount of current flowing through the light-emitting device and increases the amount of current when the amount of current is smaller than a desired amount, whereby the luminance of light emitted from the light-emitting device can be increased. By contrast, when the amount of current is larger than a desired amount, the amount of current flowing through the light-emitting device may be adjusted to be small.

In the case where a liquid crystal display device is used as the display element of the display apparatus DSP2, a gamma correction circuit may be included in the functional circuit region MFNC.

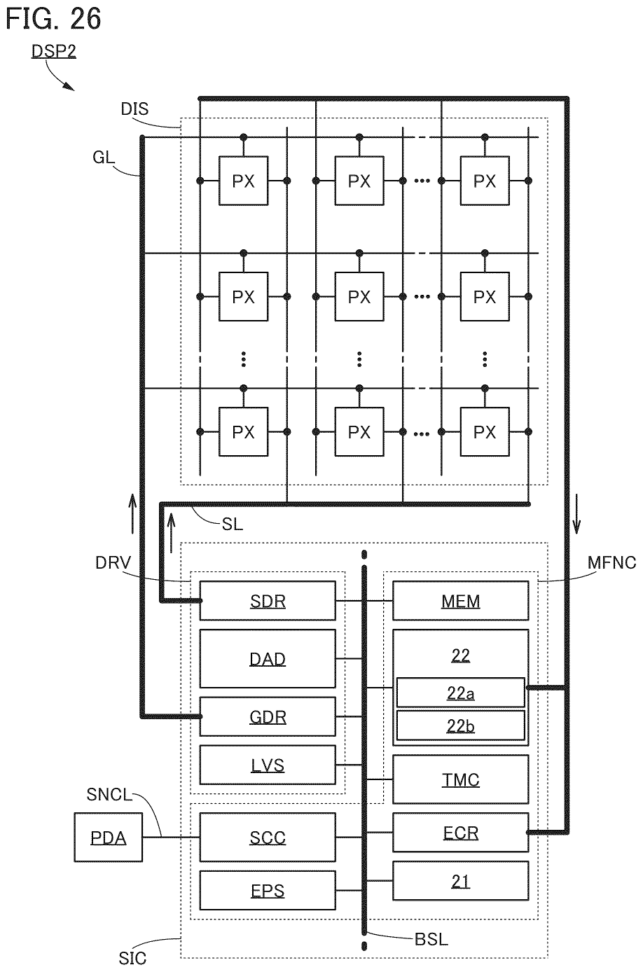

FIG. 26 is a block diagram illustrating a configuration example of the display apparatus DSP2 illustrated in FIG. 25B. The display apparatus DSP2 illustrated in FIG. 26 includes a display region DIS and a circuit region SIC, for example. A sensor PDA illustrated in FIG. 26 may be placed inside or outside the display apparatus DSP2.

The display apparatus DSP1 in FIG. 25A may be electrically connected to the functional circuit region MFNC located outside the display apparatus DSP1 through the terminal region TMR. The structure of the display apparatus DSP1 in this case can be regarded as similar to that of the display apparatus DSP2 illustrated in FIG. 26.

In FIG. 26, the thick solid lines denote a plurality of wirings or bus wirings.

In FIG. 26, the display region DIS includes a plurality of pixel circuits PX arranged in a matrix, for example. For example, one or more selected from a liquid crystal display device, a light-emitting device including an organic EL material, a light-emitting device including an inorganic EL material, and a light-emitting device including a light-emitting diode such as a micro LED can be used in the pixel circuit PX. Note that in the description in this embodiment, the pixel circuit PX in the display region DIS includes a light-emitting device including an organic EL material.

In FIG. 26, the circuit region SIC includes the driver circuit region DRV and the functional circuit region MFNC, as described above.

The driver circuit region DRV functions as a peripheral circuit for driving the display region DIS, for example. Specifically, the driver circuit region DRV includes, for example, the driver circuit SDR, the digital-analog converter circuit DAD, the driver circuit GDR, and a level shifter LVS. Note that the s driver circuit SDR corresponds to the driver circuit SD in FIG. 12, and the driver circuit GDR corresponds to the driver circuit GD in FIG. 12, for example.

The functional circuit region MFNC can be provided with, for example, a memory device storing image data to be displayed on the display region DIS, a decoder for decoding encoded image data, a GPU for processing image data, a power supply circuit, a correction circuit, and a CPU. In FIG. 26, the functional circuit region MFNC includes a memory device MEM, a GPU 22, a correction circuit ECR, a timing controller TMC, a CPU (NoffCPU (registered trademark)) 21, a sensor controller SCC, and a power supply circuit EPS, for example.

In the display apparatus DSP2 shown in FIG. 26, for example, a bus wiring BSL is electrically connected to each of the circuits included in the driver circuit region DRV and each of the circuits included in the functional circuit region MFNC.

The driver circuit SDR has a function of transmitting image data to the pixel circuit PX included in the display region DIS, for example. Thus, the driver circuit SDR is electrically connected to the pixel circuit PX through a wiring SL.

The digital-to-analog converter circuit DAD has a function of, for example, converting image data that has been digitally processed by the GPU or correction circuit described later, into analog data. The image data converted into analog data is transmitted to the display region DIS through the driver circuit SDR. Note that the digital-to-analog converter circuit DAD may be included in the driver circuit SDR, and the image data may be transmitted to the driver circuit SDR, the digital-to-analog converter circuit DAD, and the display region DIS in this order.

The driver circuit GDR has a function of selecting the pixel circuit PX to which image data is to be transmitted in the display region DIS, for example. Thus, the driver circuit GDR is electrically connected to the pixel circuit PX through a wiring GL.

The level shifter LVS has a function of converting the signals to be input to the driver circuit SDR, the digital-to-analog converter circuit DAD, the driver circuit GDR, and the like into signals having appropriate levels, for example.

The memory device MEM has a function of storing image data to be displayed on the display region DIS, for example. Note that the memory device MEM can be configured to store the image data as digital data or analog data.

In the case where the memory device MEM stores image data, the memory device MEM is preferably a nonvolatile memory. In this case, the memory device MEM can be a NAND memory or the like.

In the case where the memory device MEM stores temporary data generated in the GPU 22, the correction circuit ECR, the CPU 21, or the like, the memory device MEM is preferably a volatile memory. In that case, a static random access memory (SRAM), a dynamic random access memory (DRAM), or the like can be used as the memory device MEM.

The GPU 22 has a function of performing processing for plotting the image data read from the memory device MEM on the display region DIS, for example. Specifically, the GPU 22 is configured to perform pipeline processing in parallel and can thus perform high-speed processing of the image data to be displayed on the display region DIS. The GPU 22 can also function as a decoder for decoding an encoded image.

The functional circuit region MFNC may include a plurality of circuits that can increase the display quality of the display region DIS. As such circuits, for example, correction circuits (dimming or toning circuits) that detect and correct color irregularity of an image displayed on the display region DIS to optimize the image may be provided. In the case where the pixel in the display region DIS includes a light-emitting device including an organic EL material, the functional circuit region MFNC may be provided with a correction circuit. Note that because the description in this embodiment is made on the assumption that the pixel circuit PX in the display region DIS includes the light-emitting device including an organic EL material, the functional circuit region MFNC in this example is provided with the correction circuit ECR.

The above-described image correction may be performed using artificial intelligence in the following manner, for example. A current flowing in the display device included in the pixel (or a voltage applied to the display device) is monitored and acquired, an image displayed on the display region DIS is acquired with an image sensor or the like, the current (or voltage) and the image are used as input data in an arithmetic operation of the artificial intelligence (e.g., an artificial neural network), and the output result is used to determine whether the image should be corrected.

Such an arithmetic operation of artificial intelligence can be applied to not only image correction but also upconversion of image data. In this case, upconversion of low-screen resolution image data in accordance with the screen resolution of the display region DIS allows a high-display-quality image to be displayed on the display region DIS. The arithmetic operation of artificial intelligence can also be applied to downconversion of image data.

Note that the above-described arithmetic operation of artificial intelligence can be performed using the GPU 22 included in the functional circuit region MFNC. That is, the GPU 22 can be used to perform arithmetic operations for various kinds of correction (e.g., color irregularity correction or upconversion processing). The GPU 22 may include a circuit 22a that corrects color irregularity and a circuit 22b that performs upconversion processing.

Note that in this specification and the like, a GPU performing an arithmetic operation of the artificial intelligence is referred to as an AI accelerator. That is, the GPU included in the functional circuit region MFNC may be replaced with an AI accelerator in the description in this specification and the like.

The timing controller TMC has a function of changing the frame rate at which an image is displayed on the display region DIS. For example, the display apparatus DSP2 can be driven at a frame rate reduced by the timing controller TMC in the case where the display region DIS displays a still image; for another example, the display apparatus DSP2 can be driven at a frame rate increased by the timing controller TMC in the case where the display region DIS displays a moving image. In other words, the display apparatus DSP2 provided with the timing controller TMC can be driven at a frame rate that is changed depending on which of a still image and a moving image is displayed. Specifically, since the frame rate when the display region DIS displays a still image can be lowered, the power consumption of the display apparatus DSP2 can be reduced.

The CPU 21 has a function of, for example, performing general-purpose processing such as execution of an operating system, control of data, and execution of various arithmetic operations and programs. In the display apparatus DSP2, the CPU 21 has a function of, for example, giving an instruction for an operation for writing or reading image data to/from the memory device MEM, an operation for correcting image data, an operation for a later-described sensor, or the like. Furthermore, the CPU 21 may have a function of, for example, transmitting a control signal to at least one of the circuits included in the functional circuit region MFNC, such as the memory device, the GPU, the correction circuit, the timing controller, and a high frequency circuit.

The CPU 21 may include a circuit for temporarily backing up data (hereinafter referred to as a backup circuit). The backup circuit is preferably capable of retaining the data even after supply of a power supply voltage is stopped. For example, in the case where the display region DIS displays a still image, the CPU 21 can cease to work until an image different from the currently displayed still image is displayed. Accordingly, dynamic power consumption by the CPU 21 can be reduced in such a manner that the data under processing by the CPU 21 is backed up in the backup circuit and then supply of a power supply voltage to the CPU 21 is stopped to stop the CPU 21. In this specification and the like, a CPU including a backup circuit is referred to as a NoffCPU.

The sensor controller SCC has a function of, for example, controlling the sensor PDA. FIG. 26 shows a wiring SNCL as a wiring for electrically connecting the sensor PDA to the sensor controller SCC.

The sensor PDA is, for example, a touch sensor that can be provided above, below, or inside the display region DIS.

Alternatively, the sensor PDA may be an illuminance sensor, for example. Specifically, the illuminance sensor acquiring the intensity of the external light with which the display region DIS is irradiated makes it possible to change the brightness (luminance) of an image displayed on the display region DIS in accordance with the intensity of the external light. For example, under intense external light, the luminance of an image displayed on the display region DIS can be increased to enhance the viewability of the image. By contrast, under weak external light, the luminance of an image displayed on the display region DIS can be lowered to reduce the power consumption.

Alternatively, the sensor PDA can be an image sensor, for example. For example, an image or the like acquired with the image sensor can be displayed on the display region DIS.

The power supply circuit EPS has a function of, for example, generating voltages to be supplied to the circuits included in the driver circuit region DRV, the circuits included in the functional circuit region MFNC, the pixels included in the display region DIS, and the like. Note that the power supply circuit EPS may have a function of selecting a circuit to which a voltage is to be supplied. For example, the power supply circuit EPS stops supply of a voltage to the circuits included in the functional circuit region MFNC (e.g., the driver circuit SDR and the digital-analog converter circuit DAD) and the circuits included in the driver circuit region DRV (e.g., the CPU 21 and the GPU 22) during a period in which the display region DIS displays a still image, whereby the power consumption of the whole display apparatus DSP can be reduced.

### <Cross-Sectional Structure Example 1 of Display Apparatus>

Next, a cross-sectional structure example of the display apparatus DSP1 in FIG. 25A is described.

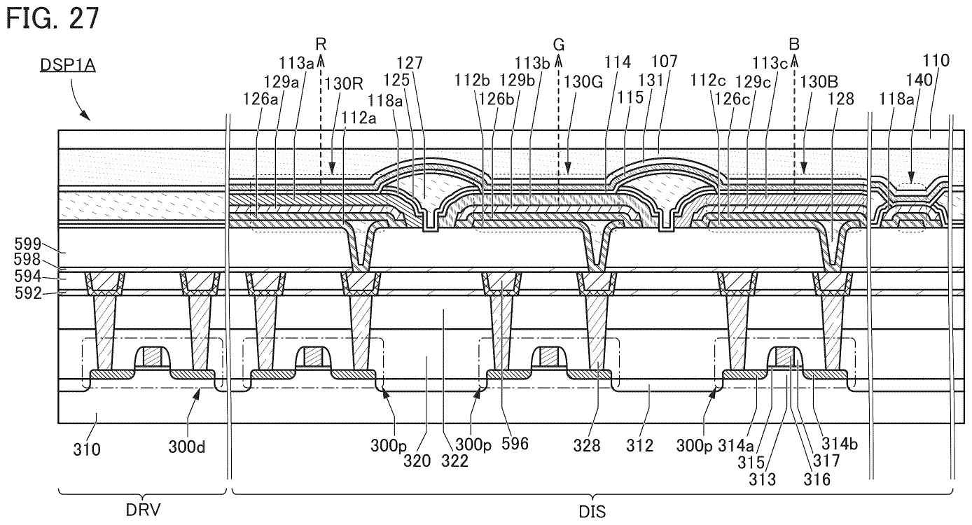

The display apparatus DSPIA in FIG. 27 is a cross-sectional structure example of the display apparatus DSP1 in FIG. 25A. The display apparatus DSPIA has a structure provided with a pixel circuit, a driver circuit, and the like over a substrate 310. In the display apparatus DSPIA in FIG. 27, the driver circuit region DRV and the display region DIS in FIG. 25A are illustrated.

The substrate 310 in FIG. 27 corresponds to the substrate BS in FIG. 25A. The diagonal size of the display apparatus DSPIA can be determined depending on the kind and the size of the substrate 310, for example. For example, in the case where a display apparatus with a diagonal size of greater than or equal to 30 inches, greater than or equal to 50 inches, greater than or equal to 70 inches, or greater than or equal to 100 inches is fabricated for a television device or an electronic device for digital signage application, a glass substrate may be used as the substrate 310. In the case where a display apparatus with a diagonal size of less than or equal to 10 inches, less than or equal to 5 inches, less than or equal to 1.5 inches, less than or equal to 1 inch, or less than or equal to 0.5 inches is fabricated for a device for XR or a wearable information terminal, a semiconductor substrate may be used as the substrate 310.

In the description of the display apparatus DSPIA in FIG. 27, the substrate 310 is a semiconductor substrate.

There is no particular limitation on the screen ratio (aspect ratio) of the display apparatus DSPIA. For example, the display apparatus DSPIA is compatible with a variety of screen ratios such as 1:1 (a square), 4:3, 16:9, 16:10, 21:9, and 32:9.

In the display apparatus DSPIA in FIG. 27, a transistor 300p and a transistor 300d are formed over the substrate 310. Note that in this specification and the like, the transistors 300p and 300d are collectively referred to as the transistor 300. Light-emitting devices 130 (a light-emitting device 130R, a light-emitting device 130G, and a light-emitting device 130B in FIG. 27) are provided above the transistors 300p and 300d.

The transistor 300p is included in the display region DIS and functions as, for example, a transistor included in the pixel circuit PX. The transistor 300d functions as a transistor included in the driver circuit region DRV. Thus, the transistor 300d can be, for example, a transistor included in any of the circuit 100[1] to the circuit 100[m] or the circuit 200[1] to the circuit 200[n+2] described in Embodiment 1. The light-emitting device 130 can be included in the pixel circuit PX.

The transistor 300 is provided on the substrate 310 and includes an element isolation layer 312, a conductor 316, an insulator 315, an insulator 317, a semiconductor region 313 that is part of the substrate 310, and a low-resistance region 314a and a low-resistance region 314b that function as a source region and a drain region. Thus, the transistor 300 is a Si transistor.

Although FIG. 27 illustrates a structure in which one of the source and the drain of the transistor 300 is electrically connected to a conductor 596 and a conductor 112 (a conductor 112a to a conductor 112c), which are described later, through a conductor 328 described later, the electrical connection in the display apparatus of one embodiment of the present invention is not limited thereto. The display apparatus of one embodiment of the present invention may have a structure in which, for example, a gate of the transistor 300 is electrically connected to the conductor 596 through the conductor 328.

The transistor 300 can be a fin type when, for example, the top surface of the semiconductor region 313 and the side surface thereof in the channel width direction are covered with the conductor 316 with the insulator 315 functioning as a gate insulator therebetween. The effective channel width can be increased in the fin-type transistor 300, so that the on-state characteristics of the transistor 300 can be improved. In addition, contribution of the electric field of the gate electrode can be increased, so that the off-state characteristics of the transistor 300 can be improved. The transistor 300 may have a planar structure instead of a fin-type structure.

Note that the transistor 300 may be either a p-channel transistor or an n-channel transistor. Alternatively, a plurality of the transistors 300 may be provided and both the p-channel transistor and the n-channel transistor may be used.

A region of the semiconductor region 313 where a channel is formed, a region in the vicinity thereof, and the low-resistance region 314a and the low-resistance region 314b that function as the source region and the drain region preferably contain a silicon-based semiconductor, specifically, preferably contain single crystal silicon. Alternatively, each of the regions may be formed using germanium, silicon germanium, gallium arsenide, aluminum gallium arsenide, or gallium nitride, for example. A structure using silicon whose effective mass is controlled by applying stress to the crystal lattice and changing the lattice spacing may be employed. Alternatively, the transistor 300 may be a HEMT (High Electron Mobility Transistor) using gallium arsenide and aluminum gallium arsenide, for example.

For the conductor 316 functioning as a gate electrode, a semiconductor material such as silicon containing an element that imparts n-type conductivity, such as arsenic or phosphorus, or an element that imparts p-type conductivity, such as boron or aluminum, can be used. Alternatively, for the conductor 316, a conductive material such as a metal material, an alloy material, or a metal oxide material can be used, for example.

Note that since the work function of a conductor depends on the material of the conductor, the threshold voltage of the transistor can be adjusted by selecting the material of the conductor. Specifically, it is preferable to use one or both of titanium nitride and tantalum nitride as the material of the conductor. Moreover, in order to ensure both conductivity and embeddability, it is preferable to use stacked layers of metal materials of one or both of tungsten and aluminum for the conductor, and it is particularly preferable to use tungsten in terms of heat resistance.

The element isolation layer 312 is provided to separate a plurality of transistors formed on the substrate 310 from each other. The element isolation layer can be formed by, for example, a LOCOS (Local Oxidation of Silicon) method, an STI (Shallow Trench Isolation) method, or a mesa isolation method.

Over the transistor 300 illustrated in FIG. 27, an insulator 320 and an insulator 322 are sequentially stacked from the substrate 310 side.

For the insulator 320 and the insulator 322, one or more selected from silicon oxide, silicon oxynitride, silicon nitride oxide, silicon nitride, aluminum oxide, aluminum oxynitride, aluminum nitride oxide, and aluminum nitride can be used, for example.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

The insulator 322 may have a function of a planarization film for eliminating a level difference caused by the transistor 300 or the like covered with the insulator 320 and the insulator 322. For example, the top surface of the insulator 322 may be planarized by planarization treatment using a chemical mechanical polishing (CMP) method to improve planarity.

An insulator 592 and an insulator 594 are sequentially stacked over the insulator 322.

For the insulator 592, it is preferable to use an insulating film having a barrier property (referred to as a barrier insulating film) which prevents diffusion of impurities such as water and hydrogen from the substrate 310 or the transistor 300 to a region above the insulator 592 (e.g., the region where the light-emitting device 130R, the light-emitting device 130G, the light-emitting device 130B, and the like are provided). Accordingly, for the insulator 592, it is preferable to use an insulating material that has a function of inhibiting diffusion of impurities such as a hydrogen atom, a hydrogen molecule, and a water molecule (through which the above impurities are less likely to pass). Furthermore, depending on the situation, for the insulator 592, it is preferable to use an insulating material that has a function of inhibiting diffusion of impurities such as a nitrogen atom, a nitrogen molecule, a nitrogen oxide molecule (e.g., N₂O, NO, and NO₂), and a copper atom (through which the above oxygen is less likely to pass). In addition, it is preferable that the insulator 592 have a function of inhibiting diffusion of oxygen (e.g., one or both of an oxygen atom and an oxygen molecule).

For the film having a barrier property against hydrogen, silicon nitride formed by a CVD method can be used, for example.

The amount of released hydrogen can be analyzed by thermal desorption spectrometry (TDS), for example. The amount of hydrogen released from the insulator 324 that is converted into hydrogen atoms per area of the insulator 324 is less than or equal to 10×10¹⁵ atoms/cm², preferably less than or equal to 5×10¹⁵ atoms/cm² in the TDS in a film-surface temperature range of 50° C. to 500° C., for example.

Note that the permittivity of the insulator 594 is preferably lower than that of the insulator 592. For example, the dielectric constant of the insulator 594 is preferably lower than 4, further preferably lower than 3. The dielectric constant of the insulator 594 is, for example, preferably 0.7 times or less, further preferably 0.6 times or less the dielectric constant of the insulator 592. When a material with a low permittivity is used for the insulator 594, the parasitic capacitance generated between wirings can be reduced.

In addition, the conductor 328 and the conductor 596 that are connected to the light-emitting devices and the like provided above the insulator 594 are embedded in the insulator 320, the insulator 322, the insulator 592, and the insulator 594. Note that the conductor 328, the conductor 596, and the like each have a function of a plug or a wiring. A plurality of conductors each having a function of a plug or a wiring are collectively denoted by the same reference numeral in some cases. Moreover, in this specification and the like, a wiring and a plug connected to the wiring may be a single component. That is, part of a conductor functions as a wiring in some cases and part of a conductor functions as a plug in other cases.

As a material of each of plugs and wirings (e.g., the conductor 328 and the conductor 596), a single layer or a stacked layer of one or more conductive materials selected from a metal material, an alloy material, a metal nitride material, and a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used for formation. The use of a low-resistance conductive material can reduce wiring resistance.

An insulator 598 and an insulator 599 are formed over the insulator 594 and the conductor 328.

Like the insulator 592, for example, the insulator 598 is preferably formed using an insulator having a barrier property against one or more selected from hydrogen, oxygen, and water. Like the insulator 594, the insulator 599 is preferably formed using an insulator having a relatively low dielectric constant to reduce parasitic capacitance generated between wirings. The insulator 599 has functions of an interlayer insulating film and a planarization film.

The light-emitting device 130 and a connection portion 140 are formed over the insulator 599.

The connection portion 140 is referred to as a cathode contact portion in some cases, and is electrically connected to cathode electrodes of the light-emitting device 130R, the light-emitting device 130G, and the light-emitting device 130B. The connection portion 140 in FIG. 27 includes one or more conductors selected from a conductor 112a to a conductor 112c to be described later, at least one of a conductor 126a to a conductor 126c to be described later, one or more conductors selected from a conductor 129a to a conductor 129c to be described later, a common layer 114 to be described later, and a common electrode 115 to be described later.

Note that the connection portion 140 may be provided to surround four sides of the display portion in the plan view, or may be provided in the display portion (e.g., between adjacent light-emitting devices 130).

The light-emitting device 130R includes the conductor 112a, the conductor 126a over the conductor 112a, and the conductor 129a over the conductor 126a. All of the conductor 112a, the conductor 126a, and the conductor 129a can be referred to as a pixel electrode, or one or two of them can be referred to as a pixel electrode. The light-emitting device 130G includes the conductor 112b, the conductor 126b over the conductor 112b, and the conductor 129b over the conductor 126b. As in the light-emitting device 130R, all of the conductor 112b, the conductor 126b, and the conductor 129b can be referred to as a pixel electrode, or one or two of them can be referred to as a pixel electrode. The light-emitting device 130B includes the conductor 112c, the conductor 126c over the conductor 112c, and the conductor 129c over the conductor 126c. As in the light-emitting device 130R and the light-emitting device 130G, all of the conductor 112c, the conductor 126c, and the conductor 129c can be referred to as a pixel electrode, or one or two of them can be referred to as a pixel electrode.

For the conductor 112a to the conductor 112c and the conductor 126a to the conductor 126c, a conductive layer functioning as a reflective electrode can be used, for example. For the conductive layer functioning as a reflective electrode, a conductor with high visible-light reflectance such as silver, aluminum, or an alloy film of silver (Ag), palladium (Pd), and copper (Cu)(an Ag—Pd—Cu (APC) film) can be used. The conductor 112a to the conductor 112c and the conductor 126a to the conductor 126c can each be a stacked-layer film in which a pair of titanium films sandwich aluminum (a film in which Ti, Al, and Ti are stacked in this order), or a stacked-layer film in which a pair of indium tin oxide films sandwich silver (a film in which ITO, Ag, and ITO are stacked in this order).

For example, a conductive layer functioning as a reflective electrode may be used for the conductor 112a to the conductor 112c, and a conductor with a high light-transmitting property may be used for the conductor 126a to the conductor 126c. Examples of the conductor with a high light-transmitting property include an alloy of silver and magnesium and indium tin oxide (sometimes referred to as ITO).

A conductive layer functioning as a transparent electrode can be used for the conductor 129a to the conductor 129c. For the conductive layer functioning as a transparent electrode, for example, the above-described conductor with a high light-transmitting property can be used.

A microcavity structure may be provided in the light-emitting device 130 to be described in detail later. The microcavity structure refers to a structure in which the distance between the bottom surface of the light-emitting layer and the top surface of a lower electrode is set to a thickness depending on a wavelength of color of light emitted from the light-emitting layer. In that case, a light-transmitting and light-reflective conductive material is preferably used for the conductor 129a to the conductor 129c serving as an upper electrode (a common electrode), and a light-reflective conductive material is preferably used for the conductor 112a to the conductor 112c and the conductor 126a to the conductor 126c which serve as lower electrodes (pixel electrodes).

The microcavity structure refers to a structure in which the optical distance between the lower electrode and the light-emitting layer is adjusted to be (2n−1)λ/4 (n is a natural number greater than or equal to 1, and 2 is a wavelength of emitted light to be amplified). Thus, light that is reflected back by the lower electrode (reflected light) considerably interferes with light that directly enters the upper electrode from the light-emitting layer (incident light). Accordingly, the phases of the reflected light and the incident light each having the wavelength λ can be aligned with each other, and the light emitted from the light-emitting layer can be further amplified. Meanwhile, in the case where the reflected light and the incident light each have a wavelength other than the wavelength 2, their phases are not aligned with each other, resulting in attenuation without resonation.

The conductor 112a is connected to the conductor 596 embedded in the insulator 594 through an opening formed in the insulator 599. The end portion of the conductor 112a is positioned on the outer side of the end portion of the conductor 126a. The end portion of the conductor 126a and the end portion of the conductor 129a are aligned or substantially aligned with each other.

Since the conductor 112b of the light-emitting device 130G and the conductor 112c of the light-emitting device 130B are similar to the conductor 112a of the light-emitting device 130R, detailed description of the conductors is omitted. Since the conductor 126b of the light-emitting device 130G and the conductor 126c of the light-emitting device 130B are similar to the conductor 126a of the light-emitting device 130R, detailed description of the conductors is omitted. Since the conductor 129b of the light-emitting device 130G and the conductor 129c of the light-emitting device 130B are similar to the conductor 129a of the light-emitting device 130R, detailed description of the conductors is omitted.

Depression portions are formed in the conductor 112a, the conductor 112b, and the conductor 112c to cover the openings provided in the insulator 599. A layer 128 is embedded in the depression portions.

The layer 128 has a function of filling the depression portions of the conductor 112a to the conductor 112c. The conductor 126a to the conductor 126c electrically connected to the conductor 112a to the conductor 112c, respectively, are provided over the conductor 112a to the conductor 112c and the layer 128. Thus, regions overlapping with the depression portions of the conductor 112a to the conductor 112c can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used for the layer 128. For the layer 128, an acrylic resin, a polyimide resin, an epoxy resin, a polyamide resin, a polyimide-amide resin, a siloxane resin, a benzocyclobutene-based resin, a phenol resin, or a precursor of any of these resins can be used, for example. A photosensitive resin can also be used for the layer 128. As the photosensitive resin, a positive material or a negative material is given.

When a photosensitive resin is used, the layer 128 can be formed through only light-exposure and development steps, reducing the influence of dry etching or wet etching on the surfaces of the conductor 112a, the conductor 112b, and the conductor 112c. When the layer 128 is formed using a negative photosensitive resin, the layer 128 can sometimes be formed using the same photomask (light-exposure mask) as the photomask used for forming the opening in the insulator 599.

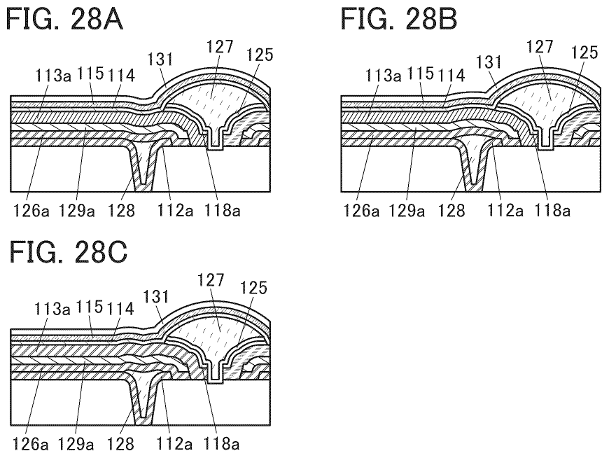

Although FIG. 27 illustrates an example where the top surface of the layer 128 includes a flat portion, the shape of the layer 128 is not particularly limited. As illustrated in FIG. 28A, the middle and the vicinity of the top surface of the layer 128 may be concave in the cross section. Alternatively, as illustrated in FIG. 28B, the middle and the vicinity of the layer 128 may be convex in the cross section. As illustrated in FIG. 28C, the middle and the vicinity of the layer 128 may be concave and convex in the cross section.

The light-emitting device 130R includes a first layer 113a, the common layer 114 over the first layer 113a, and the common electrode 115 over the common layer 114. The light-emitting device 130G includes a second layer 113b, the common layer 114 over the second layer 113b, and the common electrode 115 over the common layer 114. The light-emitting device 130B includes a third layer 113c, the common layer 114 over the third layer 113c, and the common electrode 115 over the common layer 114.

The first layer 113a is formed to cover the top surface and side surface of the conductor 126a and the top surface and side surface of the conductor 129a. Similarly, the second layer 113b is formed to cover the top surface and side surface of the conductor 126b and the top surface and side surface of the conductor 129b. Similarly, the third layer 113c is formed to cover the top surface and side surface of the conductor 126c and the top surface and side surface of the conductor 129c. Accordingly, regions provided with the conductor 126a, the conductor 126b, and the conductor 126c can be entirely used as the light-emitting regions of the light-emitting device 130R, the light-emitting device 130G, and the light-emitting device 130B, respectively, increasing the aperture ratio of the pixels.

In the light-emitting device 130R, the first layer 113a and the common layer 114 can be collectively referred to as an EL layer. Similarly, in the light-emitting device 130G, the second layer 113b and the common layer 114 can be collectively referred to as an EL layer. Similarly, in the light-emitting device 130B, the third layer 113c and the common layer 114 can be collectively referred to as an EL layer

There is no particular limitation on the structure of the light-emitting device in this embodiment, and the light-emitting device can have a single structure or a tandem structure.

The first layer 113a, the second layer 113b, and the third layer 113c each have an island shape after being processed by a photolithography method. At each of end portions of the first layer 113a, the second layer 113b, and the third layer 113c, an angle between the top surface and side surface is approximately 90°. By contrast, for example, an organic film formed using an FMM (Fine Metal Mask) tends to have a thickness that gradually decreases with decreasing distance to an end portion, and has the top surface forming a slope in an area extending greater than or equal to 1 μm and less than or equal to 10 μm from the end portion, for example; thus, such an organic film has a shape whose top surface and side surface cannot be easily distinguished from each other.

The top surface and side surface of each of the first layer 113a, the second layer 113b, and the third layer 113c are clearly distinguished from each other. Accordingly, as for the first layer 113a and the second layer 113b which are adjacent to each other, one of the side surfaces of the first layer 113a and one of the side surfaces of the second layer 113b face to each other. This applies to a combination of any two of the first layer 113a, the second layer 113b, and the third layer 113c.

The first layer 113a, the second layer 113b, and the third layer 113c each include at least a light-emitting layer. For example, a structure is preferable in which the first layer 113a includes a light-emitting layer that emits red light, the second layer 113b includes a light-emitting layer that emits green light, and the third layer 113c includes a light-emitting layer that emits blue light. Other than the above colors, cyan, magenta, yellow, or white can be employed for the light-emitting layers.

The first layer 113a, the second layer 113b, and the third layer 113c each preferably include a light-emitting layer and a carrier-transport layer (an electron-transport layer or a hole-transport layer) over the light-emitting layer. Since surfaces of the first layer 113a, the second layer 113b, and the third layer 113c may be exposed in the manufacturing process of the display apparatus, providing the carrier-transport layer over the light-emitting layers inhibits the light-emitting layers from being exposed on the outermost surface, so that damage to the light-emitting layers can be reduced. Accordingly, the reliability of the light-emitting devices can be improved. The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting device 130R, the light-emitting device 130G, and the light-emitting device 130B.

The common electrode 115 is shared by the light-emitting device 130R, the light-emitting device 130G, and the light-emitting device 130B. As illustrated in FIG. 27, the common electrode 115 shared by the plurality of light-emitting devices is electrically connected to a conductor included in the connection portion 140.

The insulator 125 preferably has a function of a barrier insulating layer against one or both of one of water and oxygen. Alternatively, the insulator 125 preferably has a function of inhibiting diffusion of one or both of water and oxygen. Alternatively, the insulator 125 preferably has a function of capturing or fixing (also referred to as gettering) one or both of water and oxygen. When the insulator 125 has a function of a barrier insulating layer or a gettering function, entry of impurities (typically, one or both of water and oxygen) that would diffuse into the light-emitting devices from the outside can be inhibited. With this structure, a highly reliable light-emitting device and a highly reliable display panel can be provided.

The insulator 125 preferably has a low impurity concentration. Accordingly, degradation of the EL layer, which is caused by entry of impurities into the EL layer from the insulator 125, can be inhibited. In addition, when the impurity concentration is reduced in the insulator 125, a barrier property against one or both of water and oxygen can be increased. For example, it is desirable that one or both of the hydrogen concentration and the carbon concentration in the insulator 125 be sufficiently low.

As the insulator 127, an insulating layer containing an organic material can be favorably used. As the organic material, a photosensitive organic resin is preferably used; for example, a photosensitive resin composition containing an acrylic resin may be used. The viscosity of the material of the insulator 127 is greater than or equal to 1 cP and less than or equal to 1500 cP, and is preferably greater than or equal to 1 cP and less than or equal to 12 cP. By setting the viscosity of the material of the insulator 127 in the above-described range, the insulator 127 having a tapered shape, which is to be described later, can be formed relatively easily. Note that in this specification and the like, an acrylic resin refers to not only a polymethacrylic acid ester or a methacrylic resin, but also all the acrylic polymer in a broad sense in some cases.

Note that in this specification and the like, a tapered shape indicates a shape in which at least part of a side surface of a structure is inclined to a substrate surface. For example, a tapered shape preferably includes a region where an angle formed between the inclined side surface and the substrate surface (such an angle is also referred to as a taper angle) is less than 90°.

Note that the organic material that can be used for the insulator 127 is not limited to the above as long as the insulator 127 has a tapered side surface as described later. For the insulator 127, an acrylic resin, a polyimide resin, an epoxy resin, an imide resin, a polyamide resin, a polyimide-amide resin, a silicone resin, a siloxane resin, a benzocyclobutene-based resin, a phenol resin, or precursors of these resins can be used in some cases, for example. Alternatively, an organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be employed for the insulator 127 in some cases. For the insulator 127, for example, a photoresist can be used as the photosensitive resin in some cases. Note that as the photosensitive resin, a positive material or a negative material can be used.

For the insulator 127, a material absorbing visible light may be used. When the insulator 127 absorbs light from the light-emitting device, leakage of light (stray light) from the light-emitting device to the adjacent light-emitting device through the insulator 127 can be inhibited. Thus, the display quality of the display panel can be improved. Since the display quality of the display panel can be improved without using a polarizing plate, the weight and thickness of the display panel can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two colors or three or more colors is particularly preferred, in which case the effect of blocking visible light can be enhanced. In particular, mixing color filter materials of three or more colors enables the formation of a black or nearly black resin layer.

For example, the insulator 127 can be formed by a wet deposition method such as spin coating, dipping, spray coating, ink-jetting, dispensing, screen printing, offset printing, doctor blade coating, slit coating, roll coating, curtain coating, or knife coating. Specifically, an organic insulating film that is to be the insulator 127 is preferably formed by spin coating.

The insulator 127 is formed at a temperature lower than the heat resistance temperature of the EL layer. The typical substrate temperature in formation of the insulator 127 is lower than or equal to 200° C., preferably lower than or equal to 180° C., further preferably lower than or equal to 160° C., still further preferably lower than or equal to 150° C., yet still further preferably lower than or equal to 140° C.

The description is made below on the structure of the insulator 127 or the like using the structure of the insulator 127 between the light-emitting device 130R and the light-emitting device 130G as an example. Note that the same applies to the insulator 127 between the light-emitting device 130G and the light-emitting device 130B and the insulator 127 between the light-emitting device 130B and the light-emitting device 130R. The description made below sometimes using an end portion of the insulator 127 over the second layer 113b as an example applies to an end portion of the insulator 127 over the first layer 113a and an end portion of the insulator 127 over the third layer 113c.

In a cross-sectional view of the display apparatus, the side surface of the insulator 127 preferably has a tapered shape with the taper angle θ1. The taper angle θ1 is an angle formed by the side surface of the insulator 127 and the substrate surface. Note that the taper angle θ1 is not limited to the angle with the substrate surface, and may be an angle formed by the side surface of the insulator 127 and the top surface of the flat portion of the insulator 125 or the top surface of the flat portion of the second layer 113b. When the side surface of the insulator 127 has a tapered shape, the side surface of the insulator 125 and the side surface of the mask layer 118a also have a tapered shape in some cases.

The taper angle θ1 of the insulator 127 is less than 90°, preferably less than or equal to 60°, and further preferably less than or equal to 45°. Such a forward tapered shape of the end portion of the side surface of the insulator 127 can prevent disconnection, local thinning, or the like from occurring in the common layer 114 and the common electrode 115 which are provided over the end portion of the side surface of the insulator 127, leading to film formation with good coverage. The common layer 114 and the common electrode 115 can have improved in-plane uniformity in this manner, whereby the display apparatus can have improved display quality.

The top surface of the insulator 127 preferably has a convex shape in a cross-sectional view of the display apparatus. The top surface of the insulator 127 preferably has a convex shape that bulges gradually toward the center. The insulator 127 preferably has a shape such that the projecting portion at the center portion of the top surface is connected smoothly to the tapered portion of the end portion of the side surface. When the insulator 127 has such a shape, the common layer 114 and the common electrode 115 can be deposited with good coverage over the whole the insulator 127.

The insulator 127 is formed in a region between two EL layers (e.g., a region between the first layer 113a and the second layer 113b). At this time, part of the insulator 127 is placed at a position sandwiched between an end portion of the side surface of one of the EL layers (e.g., the first layer 113a) and an end portion of the side surface of the other of the EL layers (e.g., the second layer 113b).

One end portion of the insulator 127 preferably overlaps with the conductor 126a serving as a pixel electrode, and the other end portion of the insulator 127 preferably overlaps with the conductor 126b serving as a pixel electrode. With such a structure, the end portion of the insulator 127 can be formed over a substantially flat region of the first layer 113a (the second layer 113b). This makes it relatively easy to process the tapered shape of the insulator 127 as described above.

By providing the insulator 127 and the like in the above manner, a disconnected portion and a locally thinned portion can be prevented from being formed in the common layer 114 and the common electrode 115 from a substantially flat region in the first layer 113a to a substantially flat region in the second layer 113b. Thus, between the light-emitting devices, a connection defect caused by the disconnected portion and an increase in electric resistance caused by the locally thinned portion can be inhibited from occurring in the common layer 114 and the common electrode 115.

In the display apparatus of this embodiment, the distance between the light-emitting devices can be short. Specifically, the distance between the light-emitting devices, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus of this embodiment includes a region where a distance between two adjacent island-shaped EL layers is less than or equal to 1 μm, preferably less than or equal to 0.5 μm (500 nm), further preferably less than or equal to 100 nm. The distance between light-emitting devices is shortened in this manner, whereby a display apparatus with high resolution and a high aperture ratio can be provided.

The protective layer 131 is provided over the light-emitting device 130. The protective layer 131 is a film serving as a passivation film for protecting the light-emitting devices 130.

Provision of the protective layer 131 covering the light-emitting device can inhibit an impurity such as water and oxygen from entering the light-emitting device, and increase the reliability of the light-emitting device 130. For the protective layer 131, aluminum oxide, silicon nitride, or silicon nitride oxide can be used, for example.

The protective layer 131 and the substrate 110 are bonded to each other with an adhesive layer 107. A solid sealing structure, a hollow sealing structure, or the like can be employed to seal the light-emitting devices. In FIG. 27, a solid sealing structure is employed in which a space between the substrate 310 and the substrate 110 is filled with the adhesive layer 107. Alternatively, a hollow sealing structure in which the space is filled with an inert gas (e.g., nitrogen or argon) may be employed. Here, the adhesive layer 107 may be provided not to overlap with the light-emitting devices. The space may be filled with a resin other than the frame-shaped adhesive layer 107.

For the adhesive layer 107, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-liquid-mixture-type resin may be used. An adhesive sheet may be used.

The display apparatus DSPIA has a top-emission structure. Light from the light-emitting device is emitted toward the substrate 110 side. Thus, for the substrate 110, a material having a high visible-light-transmitting property is preferably used. For example, a substrate having a high visible-light-transmitting property may be selected as the substrate 110 among substrates usable as the substrate 310 and the substrate BS. The pixel electrode contains a material that reflects visible light, and a counter electrode (the common electrode 115) contains a material that transmits visible light.

Note that the display apparatus of one embodiment of the present invention may be not a top-emission display apparatus but a bottom-emission display apparatus where light from the light-emitting device is emitted to the substrate 310 side. In that case, a substrate having a high visible-light-transmitting property is selected as the substrate 310.

### <Cross-Sectional Structure Example 2 of Display Apparatus>

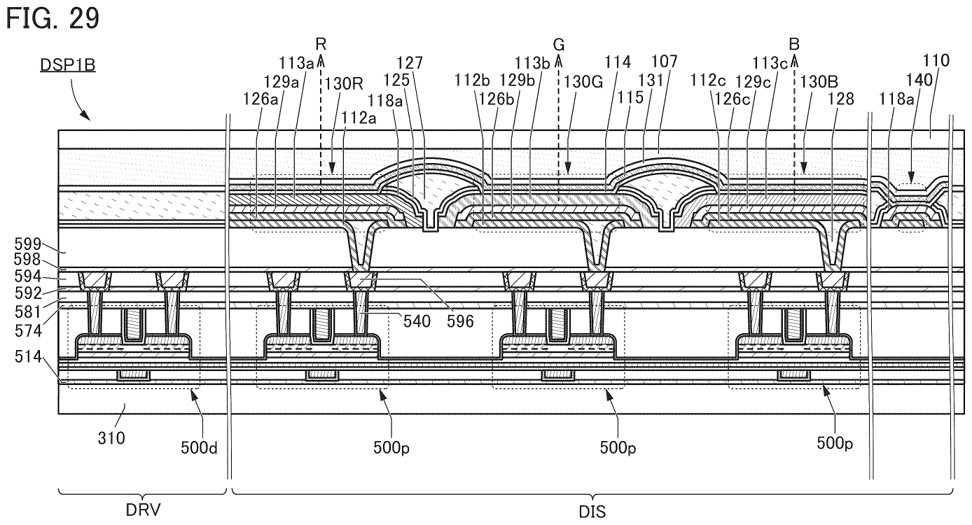

Next, a cross-sectional structure example of the display apparatus DSP1 in FIG. 25A which is different from the display apparatus DSP1A in FIG. 27 is described. A display apparatus DSP1B illustrated in FIG. 29 is a modification example of the display apparatus DSP1A and different from the display apparatus DSPIA in the structure of the transistor provided over the substrate 310.

A substrate that can be used as the substrate BS is preferably used as the substrate 310 in the display apparatus DSP1B in FIG. 29. In the description of the display apparatus DSP1B, the substrate 310 is a glass substrate.

In the display apparatus DSP1B in FIG. 29, a transistor 500p and a transistor 500d are formed over the substrate 310. Note that in this specification and the like, the transistors 500p and 500d are collectively referred to as the transistor 500. The transistor 500p in the display apparatus DSP1B corresponds to the transistor 300p in the display apparatus DSPIA, and the transistor 500d in the display apparatus DSP1B corresponds to the transistor 300d in the display apparatus DSP1A.

For the light-emitting devices 130 (the light-emitting devices 130R, 130G, and 130B in FIG. 29) above the transistors 500p and 500d, the description of the light-emitting devices 130 in FIG. 27 can be referred to.

An insulator 574 is formed over the transistor 500, and an insulator 581 is formed over the insulator 574. The insulator 574 and the insulator 581 include openings and the conductors 596 provided so as to be embedded in the openings. Note that the insulator 574 and the insulator 581 are described later. For the conductor 596, the description of the conductor 596 in FIG. 27 can be referred to.

The insulator 592 and the insulator 594 and the conductor 596 are formed over the insulator 581 and the conductor 540. For the insulator 592, the insulator 594, and the conductor 596, the description of the insulator 592 and the insulator 594 in FIG. 27 can be referred to.

### <<Structure Example of Transistor 500>>

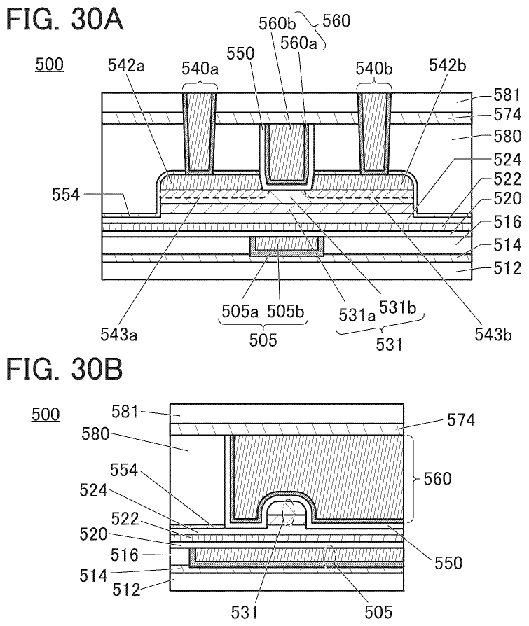

FIG. 30A is a schematic cross-sectional view in the channel length direction of the transistor 500 that can be included in the display apparatus DSP1B, and FIG. 30B is a schematic cross-sectional view in the channel width direction of the transistor 500. Note that in FIG. 30A and FIG. 30B, the transistor 500 is provided over not the substrate 310 but the insulator 512.

As illustrated in FIGS. 30A and 30B, the transistor 500 includes a metal oxide 531a, a metal oxide 531b, a conductor 505, a conductor 542a, a conductor 542b, an insulator 580, a conductor 560, an insulator 514, an insulator 516, an insulator 520, an insulator 522, an insulator 524, an insulator 550, an insulator 554, the insulator 574, an insulator 580, and the insulator 581, for example. Note that the transistor 500 does not necessarily include all the above components. For example, the transistor 500 may have a structure without the insulator 520.

The conductor 505 (a conductor 505a and a conductor 505b) and the insulator 516 are placed above a substrate (not illustrated). In particular, the conductor 505 is preferably provided to be embedded in the insulator 516. Specifically, the conductor 505a is preferably provided in contact with a bottom surface and a side wall of an opening provided in the insulator 516. The conductor 505b is preferably provided to be embedded in a depressed portion formed by the conductor 505a. In the transistor 500 in each of FIG. 30A and FIG. 30B, a top surface of the conductor 505b is substantially level with a top surfaces of the conductor 505a and the insulator 516.

The metal oxide 531 and the conductor 560 are located in a region overlapping with the conductor 505. The metal oxide 531b is provided over the metal oxide 531a. The conductor 542a and the conductor 542b are provided to be apart from each other over the metal oxide 531b. The insulator 580 is provided over the conductor 542a and the conductor 542b. Specifically, an opening is formed in the insulator 580 in a region between the conductor 542a and the conductor 542b. The conductor 560 is provided in the opening. The insulator 550 is provided between the conductor 560 and the metal oxide 531b, the conductor 542a, the conductor 542b, and the insulator 580. Here, as illustrated in FIG. 30A and FIG. 30B, a top surface of the conductor 560 is substantially level with top surfaces of the insulator 550 and the insulator 580. Note that in the following description, the conductor 505a and the conductor 505b are sometimes collectively referred to as a conductor 505. Note that in the following description, the metal oxides 531a and 531b are sometimes collectively referred to as a metal oxide 531. The conductor 542a and the conductor 542b are sometimes collectively referred to as a conductor 542.

As illustrated in FIG. 30A, a region 543a is sometimes formed as a low-resistance region at and near the interface between the metal oxide 531b and the conductor 542a. In addition, a region 543b is sometimes formed as a low-resistance region at and near the interface between the metal oxide 531b and the conductor 542b. In that case, the region 543a functions as one of a source region and a drain region, and the region 543b functions as the other of the source region and the drain region. A channel formation region is formed in a region between the region 543a and the region 543b.

When the conductor 542a (conductor 542b) is provided in contact with the metal oxide 531, the oxygen concentration of the region 543a (region 543b) sometimes decreases. In addition, a metal compound layer that contains the metal contained in the conductor 542a (conductor 542b) and the component of the metal oxide 531 is sometimes formed in the region 543a (region 543b). In such a case, the carrier concentration of the region 543a (region 543b) increases and the region 543a (region 543b) becomes a low-resistance region.

In the transistor 500 illustrated in FIG. 30A and FIG. 30B, side surfaces of the conductor 542a and the conductor 542b on the conductor 560 side are substantially perpendicular. Note that the transistor 500 illustrated in FIG. 30A and FIG. 30B is not limited thereto, and the angle formed between the side surfaces and the bottom surfaces of the conductor 542a and the conductor 542b may be greater than or equal to 10° and less than or equal to 80°, preferably greater than or equal to 30° and less than or equal to 60°. The side surfaces of the conductor 542a and the conductor 542b that face each other may have a plurality of surfaces.

In the transistor 500, two layers of the metal oxide 531a and the metal oxide 531b are stacked in and around the region where the channel is formed (hereinafter also referred to as channel formation region); however, the present invention is not limited thereto. For example, a single-layer structure of the metal oxide 531b or a stacked-layer structure of three or more layers may be employed. Alternatively, each of the metal oxide 531a and the metal oxide 531b may have a stacked-layer structure of two or more layers.

Here, the conductor 560 functions as a first gate electrode (sometimes referred to as a top gate electrode or a front gate electrode) of the transistor, and the conductor 542a and the conductor 542b each function as a source electrode or a drain electrode. As described above, the conductor 560 is formed to be embedded in the opening of the insulator 580 and the region between the conductor 542a and the conductor 542b. Here, the positions of the conductor 560, the conductor 542a, and the conductor 542b are selected in a self-aligned manner with respect to the opening of the insulator 580. In other words, in the transistor 500, the first gate electrode can be positioned between the source electrode and the drain electrode in a self-aligned manner. Thus, the conductor 560 can be formed without an alignment margin, resulting in a reduction in the area occupied by the transistor 500. Accordingly, the display apparatus can have higher resolution. In addition, the display apparatus can have a narrow bezel.

The conductor 505 sometimes functions as a second gate electrode (sometimes referred to as a bottom gate electrode or a back gate electrode). In that case, by changing a potential applied to the conductor 505 independently of a potential applied to the conductor 560, Vth of the transistor 500 can be controlled. In particular, by applying a negative potential to the conductor 505, the threshold voltage Vth of the transistor 500 can be increased and the off-state current can be reduced. Thus, a drain current at the time when a potential applied to the conductor 560 is 0 V can be lower in the case where a negative potential is applied to the conductor 505 than in the case where the negative potential is not applied to the conductor 505.

The conductor 505 is preferably provided to be larger than the channel formation region in the metal oxide 531. In particular, it is preferable that the conductor 505 extend as a wiring beyond an end portion of the metal oxide 531 that intersects with the channel width direction, as illustrated in FIG. 30B. In other words, the conductor 505 and the conductor 560 preferably overlap with each other with the insulator positioned therebetween, in a region outside the side surface of the metal oxide 531 in the channel width direction.

As illustrated in FIG. 30A, the conductor 560 preferably includes a conductor 560a provided inside the insulator 550 and a conductor 560b provided to be embedded inside the conductor 560a. Although the conductor 560 has a two-layer structure in FIG. 30A and FIG. 30B, the present invention is not limited to this. For example, the conductor 560 may have a single-layer structure or a stacked-layer structure of three or more layers.

As illustrated in FIG. 30A and FIG. 30B, the transistor 500 preferably includes the insulator 512 positioned over the substrate (not illustrated); the insulator 514 positioned over the insulator 512; the insulator 516 positioned over the insulator 514; a conductor 505 positioned to be embedded in the insulator 516; the insulator 520 positioned over the insulator 516 and the conductor 505; the insulator 522 positioned over the insulator 520; and the insulator 524 positioned over the insulator 522. The metal oxide 531a is preferably provided over the insulator 524.

As illustrated in FIG. 30A and FIG. 30B, the insulator 554 is preferably positioned between the insulator 524 and the insulator 580, between the metal oxide 531a and the insulator 580, between the metal oxide 531b and the insulator 580, between the conductor 542a and the insulator 580, and between the conductor 542b and the insulator 580. Here, as illustrated in FIG. 30A and FIG. 30B, the insulator 554 is preferably in contact with the side surface of the insulator 550, the top surface and side surface of the conductor 542a, the top surface and side surface of the conductor 542b, and the side surfaces and the top surfaces of the metal oxide 531a, the metal oxide 531b, and the insulator 524.

The insulator 574 and the insulator 581 functioning as interlayer films are preferably placed over the transistor 500. Here, the insulator 574 is preferably placed in contact with the top surfaces of the conductor 560, the insulator 550, and the insulator 580.

A conductor 540 (a conductor 540a and a conductor 540b) that is electrically connected to the transistor 500 and functions as a plug is preferably provided. Thus, the conductor 540 is provided in contact with the inner wall of an opening in the insulator 554, the insulator 580, the insulator 574, and the insulator 581. In particular, a structure may be employed in which a first conductor of the conductor 540 is provided in contact with the inner wall and a second conductor of the conductor 540 is provided on the side surface of the first conductor. Here, the top surface of the conductor 540 and the top surface of the insulator 581 can be substantially level with each other.

Specifically, for example, a first conductor of the conductor 540a is provided in contact with the inner wall of one of two openings in the insulator 581, the insulator 574, the insulator 580, and the insulator 554, and a second conductor of the conductor 540a is formed in contact with the side surface thereof. Note that the conductor 542a is located on part of the bottom portion of the opening, and the conductor 540a is in contact with the conductor 542a. Similarly, for example, a first conductor of the conductor 540b is provided in contact with the inner wall of the other of the two openings in the insulator 581, the insulator 574, the insulator 580, and the insulator 554, and a second conductor of the conductor 540b is formed in contact with the side surface thereof. Note that the conductor 542b is located on part of the bottom portion of the opening, and the conductor 540b is in contact with the conductor 542b.

Although the transistor 500 has a structure in which the first conductor of the conductor 540 and the second conductor of the conductor 540 are stacked, the present invention is not limited thereto. For example, the conductor 540 may have a single-layer structure or a stacked-layer structure of three or more layers. In the case where a component has a stacked-layer structure, layers may be distinguished by ordinal numbers given corresponding to the formation order.

As illustrated in FIG. 30B, the side surface of the metal oxide 531 is placed to be covered with the conductor 560 in a region where the metal oxide 531b does not overlap with the conductor 542, that is, the channel formation region of the metal oxide 531. Accordingly, electric fields of the conductor 560 functioning as the first gate electrode are likely to act on the side surface of the metal oxide 531. Consequently, the channel formation region of the metal oxide 531 can be electrically surrounded by the electric field of the conductor 560. Thus, the on-state current of the transistor 500 can be increased and the frequency characteristics can be improved.

### <<Materials for Transistor>>

Next, materials that can be used for the transistor 500 are described.

### [Metal Oxide (Oxide Semiconductor)]

In the transistor 500, a metal oxide functioning as an oxide semiconductor (hereinafter, also referred to as an oxide semiconductor) is preferably used as the metal oxide 531 including the channel formation region (the metal oxide 531a and the metal oxide 531b). For example, it is preferable to use a metal oxide having a band gap of 2 eV or more, preferably 2.5 eV or more as the metal oxide to be the channel formation region of the metal oxide 531.

The metal oxide preferably contains at least indium or zinc. In particular, indium and zinc are preferably contained. In addition to them, an element M is preferably contained. As the element M, one or more selected from aluminum, gallium, yttrium, tin, copper, vanadium, boron, titanium, iron, nickel, germanium, zirconium, molybdenum, lanthanum, cerium, neodymium, hafnium, tantalum, tungsten, magnesium, cobalt, and antimony can be used. In particular, the element M is preferably one or more of aluminum, gallium, yttrium, and tin. The element M further preferably contains one or both of gallium and tin.

As described above, the metal oxide 531 includes the metal oxide 531a and the metal oxide 531b over the metal oxide 531a. When the metal oxide 531a is provided under the metal oxide 531b, it is possible to inhibit diffusion of impurities into the metal oxide 531b from the components formed below the metal oxide 531a.

The metal oxide 531 preferably has a stacked-layer structure of a plurality of oxide layers that differ in the atomic ratio of metal atoms. For example, in the case where the metal oxide 531 contains at least indium (In) and the element M, the proportion of the number of atoms of the element M contained in the metal oxide 531a to the number of atoms of all elements that constitute the metal oxide 531a is preferably higher than the proportion of the number of atoms of the element M contained in the metal oxide 531b to the number of atoms of all elements that constitute the metal oxide 531b. In addition, the atomic ratio of the element M to In in the metal oxide 531a is preferably greater than the atomic ratio of the element M to In in the metal oxide 531b.

The energy of the conduction band minimum of the metal oxide 531a is preferably higher than the energy of the conduction band minimum of the metal oxide 531b. In other words, the electron affinity of the metal oxide 531a is preferably smaller than the electron affinity of the metal oxide 531b.

Here, the energy level of the conduction band minimum gently changes at junction portions between the metal oxide 531a and the metal oxide 531b. In other words, at junction portions between the metal oxide 531a and the metal oxide 531b, the energy level of the conduction band minimum continuously changes or the energy levels are continuously connected. This can be achieved by decreasing the density of defect states in a mixed layer formed at the interface between the metal oxide 531a and the metal oxide 531b.

Specifically, when the metal oxide 531a and the metal oxide 531b contain the same element (as a main component) in addition to oxygen, a mixed layer with a low density of defect states can be formed. For example, an In—Ga—Zn oxide (indium-gallium-zinc oxide), a Ga—Zn oxide, or gallium oxide can be used as the metal oxide 531a, in the case where the metal oxide 531b is an In—Ga—Zn oxide.

Specifically, as the metal oxide 531a, a metal oxide with In:Ga:Zn=1:3:4 [atomic ratio], 1:3:2 [atomic ratio], or 1:1:0.5 [atomic ratio] can be used. As the metal oxide 531b, a metal oxide with In:Ga:Zn=1:1:1 [atomic ratio], 4:2:3 [atomic ratio], or 3:1:2 [atomic ratio] can be used.

In this case, the metal oxide 531b serves as a main carrier path. When the metal oxide 531a has the above structure, the density of defect states at the interface between the metal oxide 531a and the metal oxide 531b can be made low. Thus, the influence of interface scattering on carrier conduction is small, and the transistor 500 can have a high on-state current and high frequency characteristics.

When the conductor 542 is provided in contact with the metal oxide 531, the oxygen concentration of the metal oxide 531 in the vicinity of the conductor 542 sometimes decreases. In addition, a metal compound layer that contains the metal contained in the conductor 542 and the component of the metal oxide 531 is sometimes formed in the metal oxide 531 in the vicinity of the conductor 542. In such cases, the carrier concentration of the region in the metal oxide 531 in the vicinity of the conductor 542 increases, and the region becomes a low-resistance region.

The metal oxide 531b in a region that does not overlap with the conductor 542 sometimes has a smaller thickness than the metal oxide 531b in a region that overlaps with the conductor 542. The thin region is formed when part of the top surface of the metal oxide 531b is removed at the time of forming the conductor 542a and the conductor 542b. When a conductive film to be the conductor 542 is formed, a low-resistance region is sometimes formed on the top surface of the metal oxide 531b in the vicinity of the interface with the conductive film. Removing the low-resistance region positioned between the conductor 542a and the conductor 542b on the top surface of the metal oxide 531b in the above manner can prevent formation of the channel in the region. [Conductor]

For the conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum. For another example, an alloy containing two or more selected from the above metal elements as components or an alloy combining two or more selected from the above metal elements is preferably used for the conductor. As the conductor, for example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, or an oxide containing lanthanum and nickel. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. As the conductor, a semiconductor having high electrical conductivity, typified by polycrystalline silicon containing an impurity element (e.g., phosphorus), or silicide (e.g., nickel silicide) may be used.

A plurality of conductors formed using any of the above materials may be stacked. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

For the conductor 505a which functions as the second gate electrode, it is preferable to use a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom. Alternatively, it is preferable to use a conductive material having a function of inhibiting diffusion of oxygen (e.g., one or both of an oxygen atom and an oxygen molecule).

When a conductive material having a function of inhibiting diffusion of hydrogen is used for the conductor 505a, impurities such as hydrogen contained in the conductor 505b can be inhibited from diffusing into the metal oxide 531 through the insulator 524. When a conductive material having a function of inhibiting diffusion of oxygen is used for the conductor 505a, the conductivity of the conductor 505b can be inhibited from being lowered because of oxidation. Examples of the conductive material having a function of inhibiting diffusion of oxygen include titanium, titanium nitride, tantalum, tantalum nitride, ruthenium, and ruthenium oxide. Thus, the conductor 505a is a single layer or stacked layers of the above conductive materials. For example, titanium nitride is used for the conductor 505a.

For the conductor 505b, a conductive material containing tungsten, copper, or aluminum as its main component is preferably used. For example, tungsten is used for the conductor 505b.

For the conductor 542 (the conductor 542a and the conductor 542b) functioning as a source electrode or a drain electrode, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum. For the conductor 542, an alloy containing two or more selected from the above metal elements as components or an alloy combining two or more selected from the above metal elements is preferably used for the conductor. For the conductor 542, for example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, or an oxide containing lanthanum and nickel. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen.

For the conductor 560a which functions as the first gate electrode, it is preferable to use a conductor having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom. Alternatively, it is preferable to use a conductive material having a function of inhibiting diffusion of oxygen (e.g., one or both of an oxygen atom and an oxygen molecule).

When the conductor 560a has a function of inhibiting diffusion of oxygen, it is possible to inhibit a reduction in conductivity of the conductor 560b due to oxidation caused by oxygen contained in the insulator 550. Examples of the conductive material having a function of inhibiting diffusion of oxygen include tantalum, tantalum nitride, titanium, titanium nitride, ruthenium, and ruthenium oxide. When the conductive material containing oxygen is provided as the conductor 560a, oxygen released from the conductive material is easily supplied to the channel formation region.

For the conductor 560b, a conductive material containing tungsten, copper, or aluminum as its main component is preferably used. Furthermore, the conductor 560 also functions as a wiring and thus is preferably a conductor having high conductivity. For example, a conductive material containing tungsten, copper, or aluminum as its main component can be used. Moreover, the conductor 560b may have a stacked-layer structure, for example, a stacked-layer structure of the above conductive material and titanium or titanium nitride.

Alternatively, for the conductor 560, indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used, for example. For the conductor, indium gallium zinc oxide containing nitrogen may be used, for example. With the use of such a material, hydrogen contained in the metal oxide where the channel is formed can be captured in some cases. Alternatively, hydrogen entering from an external insulator or the like can be captured in other cases.

Although the conductor 560 has a two-layer structure in FIG. 30A and FIG. 30B, the conductor 560 may have a single-layer structure or a stacked-layer structure of three or more layers.

For the conductor 540a and the conductor 540b which function as plugs, a conductive material containing tungsten, copper, or aluminum as its main component is preferably used. The conductor 540a and the conductor 540b may have a stacked-layer structure.

In the case where the conductor 540 has a stacked-layer structure, the aforementioned conductor having a function of inhibiting diffusion of impurities such as water and hydrogen is preferably used as the conductor in contact with the conductor 542, the insulator 554, the insulator 580, the insulator 574, and the insulator 581. For example, tantalum, tantalum nitride, titanium, titanium nitride, ruthenium, or ruthenium oxide is preferably used for the conductor. The conductive material having a function of inhibiting diffusion of impurities such as water and hydrogen can be used as a single-layer structure or a stacked-layer structure. The use of the conductive material can inhibit oxygen added to the insulator 580 from being absorbed by the conductor 540a and the conductor 540b. Moreover, impurities such as water or hydrogen can be inhibited from entering the metal oxide 531 through the conductor 540a and the conductor 540b from a layer above the insulator 581.

### [Insulator]

Examples of the insulator include an insulating oxide, an insulating nitride, an insulating oxynitride, an insulating nitride oxide, an insulating metal oxide, an insulating metal oxynitride, and an insulating metal nitride oxide.

The insulator 514 preferably functions as a barrier insulating film that inhibits the entry of impurities such as water and hydrogen to the transistor 500 from the substrate side. Accordingly, it is preferable to use, for the insulator 514, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the impurities are unlikely to pass). Alternatively, it is preferable to use an insulating material having a function of inhibiting diffusion of oxygen (e.g., one or both of an oxygen atom and an oxygen molecule) (an insulating material through which the oxygen is unlikely to pass).

An insulator having a function of inhibiting the passage of oxygen and impurities such as water and hydrogen can be formed to have a single layer or a stacked layer including an insulator containing one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum, for example. Specific examples of the insulator having a function of inhibiting the passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulator having a function of inhibiting the passage of oxygen and impurities such as water and hydrogen include oxides containing aluminum and hafnium (hafnium aluminate). Other examples of the insulator having a function of inhibiting the passage of oxygen and impurities such as water and hydrogen include metal nitrides such as aluminum nitride, aluminum titanium nitride, titanium nitride, silicon nitride oxide, and silicon nitride.

In particular, aluminum oxide or silicon nitride is preferably used for the insulator 514. Accordingly, it is possible to inhibit diffusion of impurities such as water and hydrogen to the transistor 500 side from the substrate side through the insulator 514. Alternatively, it is possible to inhibit diffusion of oxygen contained in the insulator 524 and the like to the substrate side through the insulator 514.

The insulator 520, the insulator 522, and the insulator 524 have a function of a second gate insulator.

Here, oxygen preferably has been released by heating from the second gate insulator in contact with the metal oxide 531. In this specification and the like, oxygen that is released by heating is referred to as excess oxygen in some cases. For example, silicon oxide or silicon oxynitride can be used as appropriate for the insulator 524 serving as the second gate insulator. When an insulator containing oxygen is provided in contact with the metal oxide 531, oxygen vacancies in the metal oxide 531 can be reduced, leading to improved reliability of the transistor 500.

Specifically, an oxide material that releases part of oxygen by heating is preferably used for the insulator 524. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³, still further preferably greater than or equal to 3.0×10²⁰ atoms/cm³ in TDS. Note that the temperature of the film surface in the TDS analysis is preferably within the range of 100° C. to 700° C. or 100° C. to 400° C.

Like the insulator 514, the insulator 522 preferably functions as a barrier insulating film that inhibits the entry of impurities such as water and hydrogen to the transistor 500 from the substrate side. For example, the insulator 522 preferably has a lower hydrogen permeability than the insulator 524.

Furthermore, it is preferable that the insulator 522 have a function of inhibiting diffusion of oxygen (e.g., one or both of an oxygen atom and an oxygen molecule) (it is preferable that the oxygen be less likely to pass through the insulator 522). For example, the insulator 522 preferably has a lower oxygen permeability than the insulator 524. The insulator 522 preferably has a function of inhibiting diffusion of oxygen and impurities such as water and hydrogen, in which case oxygen contained in the metal oxide 531 is less likely to diffuse to the substrate side. Moreover, the conductor 505 can be inhibited from reacting with oxygen contained in the insulator 524 and the metal oxide 531.

As the insulator 522, an insulator containing an oxide of one or both of aluminum and hafnium, which is an insulating material, is preferably used. Examples of the insulator containing an oxide of one or both of aluminum and hafnium include aluminum oxide, hafnium oxide, and an oxide containing aluminum and hafnium (hafnium aluminate). In the case where the insulator 522 is formed using such a material, the insulator 522 functions as a layer inhibiting release of oxygen from the metal oxide 531 and entry of impurities such as hydrogen into the metal oxide 531 from the periphery of the transistor 500.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. A stack of the insulator and silicon oxide, silicon oxynitride, or silicon nitride may be used.

The insulator 522 may be a single layer or a stacked layer using an insulator containing what is called a high-k material, such as aluminum oxide, hafnium oxide, tantalum oxide, zirconium oxide, lead zirconate titanate (PZT), strontium titanate (SrTiO₃), or (Ba,Sr)TiO₃ (BST). Alternatively, for the insulator 522, as an insulator having a high relative permittivity, an oxide containing aluminum and hafnium, an oxynitride containing aluminum and hafnium, an oxide containing silicon and hafnium, an oxynitride containing silicon and hafnium, or a nitride containing silicon and hafnium may be used. With further miniaturization and higher integration of a transistor, a problem such as generation of a leakage current may arise because of a thinned gate insulator. When a high-k material is used for the insulator functioning as a gate insulator, a gate potential at the time of the operation of the transistor can be reduced while the physical thickness is maintained.

It is preferable that the insulator 520 be thermally stable. For example, silicon oxide and silicon oxynitride are preferable because of their thermal stability. Furthermore, the combination of an insulator that is a high-k material and silicon oxide or silicon oxynitride enables the insulator 520 to have a stacked-layer structure that has thermal stability and high relative permittivity. The insulator 520 may be formed using any of the materials that can be used for the insulator 524.

Note that the insulator 520, the insulator 522, and the insulator 524 may each have a stacked-layer structure of two or more layers. In that case, the stacked layers are not necessarily formed of the same material and may be formed of different materials.

The permittivity of each of the insulator 512, the insulator 516, the insulator 580, and the insulator 581 functioning as an interlayer film is preferably lower than that of the insulator 514. When a material with a low permittivity is used for an interlayer film, the parasitic capacitance generated between wirings can be reduced. The concentration of impurities such as water and hydrogen in the insulator 516, the insulator 580, and the insulator 581 is preferably reduced.

For the insulator 512, the insulator 516, the insulator 580, and the insulator 581, for example, silicon oxide, silicon oxynitride, silicon nitride oxide, or silicon nitride can be used. For the insulator 512, the insulator 516, the insulator 580, and the insulator 581, for example, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. A resin can be used for the insulator 512, the insulator 516, the insulator 580, and the insulator 581. A material usable for the insulator 512, the insulator 516, the insulator 580, and the insulator 581 may be an appropriate combination of the above-described materials.

Like the insulator 514 and the insulator 522, the insulator 554 and the insulator 574 preferably have a function of inhibiting diffusion of impurities such as water and hydrogen (e.g., hydrogen atoms, hydrogen molecules, or both). In other words, each of the insulator 554 and the insulator 574 preferably functions as a barrier insulating film that inhibits the entry of the impurities into the transistor 500. Moreover, the insulator 554 and the insulator 574 preferably have a function of inhibiting diffusion of oxygen (e.g., one or both of an oxygen atom and an oxygen molecule). For example, the insulator 554 and the insulator 574 preferably have a lower oxygen permeability than the insulator 524, the insulator 550, and the insulator 580. In other words, the insulator 554 and the insulator 574 preferably have a function of inhibiting oxygen released from the metal oxide 531 from diffusing to the outside of the insulator 554 or in the upward direction above the insulator 580. Thus, for the insulator 554 and the insulator 574, a material that can be used for the insulator 514 or the insulator 524 can be used.

In this manner, the insulator 524, the metal oxide 531, the insulator 550, and the like are surrounded by the insulator 522, the insulator 554, and the insulator 574, whereby the entry of impurities such as water and hydrogen into the transistor 500 from the outside can be inhibited. Furthermore, outward diffusion of oxygen from the inside of the transistor 500 can be inhibited.

The insulator 550 functions as a first gate insulator. The insulator 550 is preferably positioned in contact with the top surface of the metal oxide 531b. For the insulator 550, silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable.

As in the insulator 524, the concentration of impurities such as water and hydrogen in the insulator 550 is preferably reduced. The thickness of the insulator 550 is preferably greater than or equal to 1 nm and less than or equal to 20 nm.

Note that an insulator may be provided between the insulator 580 and the insulator 550, between the insulator 554 and the insulator 550, between the conductor 542 and the insulator 550, and between the metal oxide 531b and the insulator 550. For example, aluminum oxide or hafnium oxide is preferably used for the insulator. Providing the insulator can inhibit release of oxygen from the metal oxide 531b, excessive supply of oxygen to the metal oxide 531b, and oxidation of the conductor 542.

A metal oxide may be provided between the insulator 550 and the conductor 560. The metal oxide preferably inhibits diffusion of oxygen from the insulator 550 to the conductor 560. Accordingly, oxidation of the conductor 560 due to oxygen in the insulator 550 can be inhibited.

The metal oxide has a function of part of the gate insulator in some cases. Therefore, when silicon oxide or silicon oxynitride is used for the insulator 550, a metal oxide that is a high-k material with a high relative permittivity is preferably used as the metal oxide. When the gate insulator has a stacked-layer structure of the insulator 550 and the metal oxide, the stacked-layer structure can be thermally stable and have a high relative permittivity. Accordingly, a gate potential applied during the operation of the transistor can be reduced while the physical thickness of the gate insulator is maintained. In addition, the equivalent oxide thickness (EOT) of the insulator functioning as the gate insulator can be reduced.

Specifically, as the oxide, a metal oxide containing one kind or two or more kinds selected from hafnium, aluminum, gallium, yttrium, zirconium, tungsten, titanium, tantalum, nickel, germanium, and magnesium can be used, for example. It is particularly preferable to use, as the oxide, any of aluminum oxide, hafnium oxide, and an oxide containing aluminum and hafnium (hafnium aluminate), which are insulators each contain an oxide of one or both of aluminum and hafnium.

A barrier insulating film that inhibits diffusion of impurities such as water, hydrogen, and oxygen may be provided between the conductor 540 and the insulator 580, between the conductor 540 and the insulator 574, and between the conductor 540 and the insulator 581. Thus, impurities such as water and hydrogen in the insulator 580 can be inhibited from entering the metal oxide 531 through the conductor 540a and the conductor 540b. Furthermore, oxygen contained in the insulator 580 can be inhibited from being absorbed by the conductor 540a and the conductor 540b.

Although not illustrated, a conductor functioning as a wiring may be placed in contact with the top surface of the conductor 540a and the top surface of the conductor 540b. For the conductor functioning as a wiring, a conductive material containing tungsten, copper, or aluminum as its main component is preferably used. Furthermore, the conductor may have a stacked-layer structure and may be a stack of titanium or titanium nitride and the above conductive material, for example. The conductor may be formed to be embedded in an opening provided in an insulator.

### <<Modification Example of Transistor 500>>

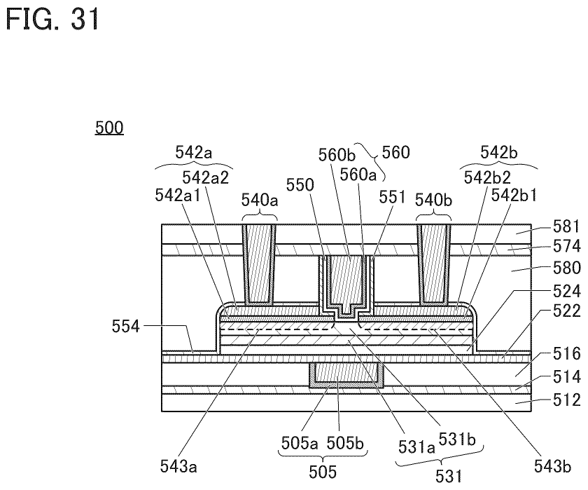

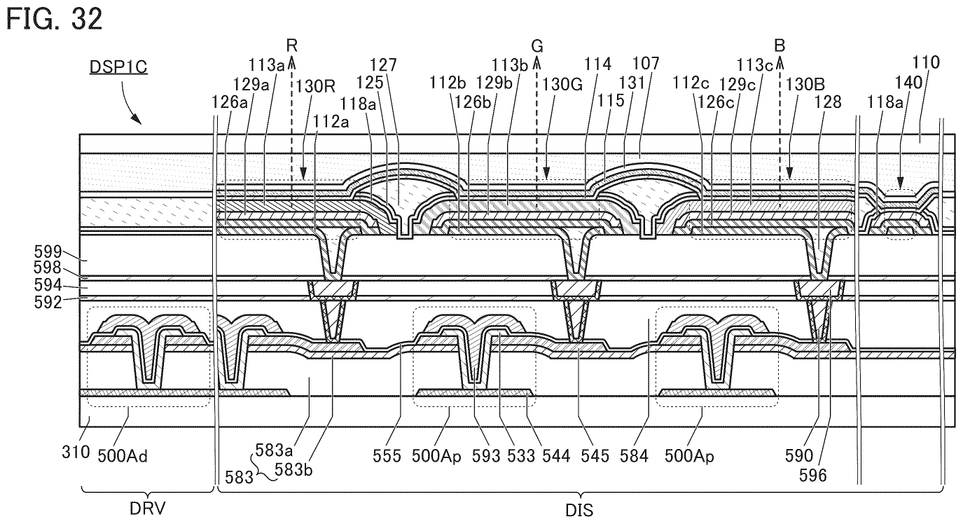

Note that the structure of the transistor included in the semiconductor device of one embodiment of the present invention is not limited to that of the transistor 500 illustrated in FIG. 30A and FIG. 30B. For example, the transistor 500 in FIG. 31 may be used as the transistor for the semiconductor device of one embodiment of the present invention. The transistor 500 in FIG. 32 is a modification example of the transistor 500 in FIG. 30A and FIG. 30B and different from the transistor 500 in FIG. 30A and FIG. 30B in that an insulator 551 is provided and the conductor 542a (a conductor 542al and a conductor 542a2) and the conductor 542b (a conductor 542b1 and a conductor 542b2) have a stacked-layer structure.

The conductor 542a has a stacked-layer structure of the conductor 542al and the conductor 542a2 over the conductor 542al, and the conductor 542b has a stacked-layer structure of the conductor 542b1 and the conductor 542b2 over the conductor 542b1. The conductor 542al and the conductor 542b1 which are in contact with the metal oxide 531b are preferably conductors that are less likely to be oxidized, such as a metal nitride. Thus, excessive oxidation of the conductor 542a and the conductor 542b due to oxygen included in the metal oxide 531b can be prevented. Moreover, the conductor 542a2 and the conductor 542b2 are preferably conductors having higher conductivity than the conductor 542al and the conductor 542b1, such as a metal layer. Thus, the conductor 542a and the conductor 542b can function as wirings or electrodes having high conductivity. In this manner, a semiconductor device in which the conductor 542a and the conductor 542b that function as wirings or electrodes are provided in contact with the top surface of the metal oxide 531 functioning as an active layer can be provided.

As the conductor 542al and the conductor 542b1, a metal nitride is preferably used; for example, a nitride including tantalum, a nitride including titanium, a nitride including molybdenum, a nitride including tungsten, a nitride including tantalum and aluminum, or a nitride including titanium and aluminum is preferably used. In one embodiment of the present invention, a nitride including tantalum is particularly preferable. As another example, ruthenium, ruthenium oxide, ruthenium nitride, an oxide including strontium and ruthenium, or an oxide including lanthanum and nickel may be used. These materials are preferable because they are each a conductive material that is less likely to be oxidized or a material that maintains the conductivity even after absorbing oxygen.

The conductor 542a2 and the conductor 542b2 preferably have higher conductivity than the conductor 542al and the conductor 542b1. For example, the thicknesses of the conductor 542a2 and the conductor 542b2 are preferably larger than the thicknesses of the conductor 542al and the conductor 542b1. For the conductor 542a2 and the conductor 542b2, a conductor that can be used for the conductor 560b can be used. The above structure can reduce the resistance of the conductor 542a2 and the conductor 542b2.

For example, tantalum nitride or titanium nitride can be used for the conductor 542al and the conductor 542b1, and tungsten can be used for the conductor 542a2 and the conductor 542b2.

As illustrated in FIG. 31, in a cross-sectional view of the transistor 500 in the channel length direction, the distance between the conductor 542al and the conductor 542b1 is smaller than the distance between the conductor 542a2 and the conductor 542b2. With such a structure, the distance between the source and the drain can be shortened, and the channel length can be accordingly shortened. Thus, the frequency characteristics of the transistor 500 can be improved. In this manner, miniaturization of the semiconductor device enables the semiconductor device to have a higher operating speed.

The insulator 551 is preferably an insulator that is less likely to be oxidized, such as a nitride. The insulator 551 is formed in contact with a side surface of the conductor 542a2 and a side surface of the conductor 542b2 and has a function of protecting the conductor 542a2 and the conductor 542b2. The insulator 551 is exposed to an oxidized atmosphere, and thus is preferably an inorganic insulator that is less likely to be oxidized. Since the insulator 551 is in contact with the conductor 542a2 and the conductor 542b2, the insulator 551 is preferably an inorganic insulator that is less likely to oxidize the conductor 542a2 and the conductor 542b2. Therefore, for the insulator 551, an insulating material having a barrier property against oxygen is preferably used. For example, silicon nitride can be used for the insulator 551.

In the transistor 500 in FIG. 31, with a first mask, an opening is formed in the insulator 554, the insulator 580, the insulator 574, and the insulator 581 to form the conductor 542a2 and the conductor 542b2. The insulator 551 is formed in contact with a side wall of the opening. After that, the conductor 542al and the conductor 542b1 are formed with a second mask, whereby the transistor 500 is formed. Here, the opening overlaps with a region between the conductor 542a2 and the conductor 542b2. The conductor 542al and the conductor 542b1 are formed to partly extend in the opening. Thus, in the opening, the insulator 551 is in contact with the top surface of the conductor 542al, the top surface of the conductor 542b1, a side surface of the conductor 542a2, and a side surface of the conductor 542b2. The insulator 550 is in contact with the top surface of the metal oxide 531 in a region between the conductor 542al and the conductor 542b1.

Heat treatment in an atmosphere containing oxygen is preferably performed after the formation of the conductor 542al and the conductor 542b1 and before the deposition of the insulator 550. Thus, oxygen can be supplied to the metal oxide 531a and the metal oxide 531b to reduce oxygen vacancies. Furthermore, since the insulator 551 is formed in contact with the side surface of the conductor 542a2 and the side surface of the conductor 542b2, excessive oxidation of the conductor 542a2 and the conductor 542b2 can be prevented. Accordingly, the transistor can have favorable electrical characteristics and higher reliability. In addition, variations in electrical characteristics of transistors formed over the same substrate can be reduced.

In the transistor 500, the insulator 524 may be formed into an island shape, as illustrated in FIG. 31. Here, the insulator 524 may be formed such that its side end portion is substantially aligned with a side end portion of the oxide 531.

In the transistor 500, the insulator 522 may be in contact with the insulator 516 and the conductor 505, as illustrated in FIG. 31. In other words, the insulator 520 illustrated in FIG. 30A and FIG. 30B may be omitted.

### <Cross-Sectional Structure Example 3 of Display Apparatus>

Next, a cross-sectional structure example of the display apparatus DSP1 in FIG. 25A which is different from the display apparatus DSPIA in FIG. 27 and the display apparatus DSP1B in FIG. 29 is described. A display apparatus DSPIC illustrated in FIG. 32 is a modification example of the display apparatus DSP1A and different from the display apparatus DSP1A and the display apparatus DSP1B in the structure of the transistor provided over the substrate 310.

A substrate that can be used as the substrate BS is preferably used as the substrate 310 in the display apparatus DSPIC in FIG. 32. In the description of the display apparatus DSPIC, the substrate 310 is a glass substrate.

In the display apparatus DSPIC in FIG. 32, a transistor 500Ap and a transistor 500Ad are formed over the substrate 310. Note that in this specification and the like, the transistors 500Ap and 500Ad are collectively referred to as a transistor 500A. The transistor 500Ap in the display apparatus DSPIC corresponds to the transistor 500p in the display apparatus DSP1B, and the transistor 500Ad in the display apparatus DSPIC corresponds to the transistor 500d in the display apparatus DSP1B.

For the light-emitting devices 130 (the light-emitting devices 130R, 130G, and 130B in FIG. 32) above the transistors 500Ap and 500Ad, the description of the light-emitting devices 130 in FIG. 27 can be referred to.

Over the transistor 500A, an insulator 584, the insulator 592, the insulator 594, and the conductor 596 are formed. For the insulator 584 in FIG. 32, the description of the insulator 594 in FIG. 27 can be referred to. For the insulator 592, the insulator 594, and the conductor 596 in FIG. 32, the description of the insulator 592 and the insulator 594 in FIG. 27 can be referred to.

An opening overlapping with part of the conductor 545 is provided in the insulator 584, and a conductor 590 is embedded in the opening. The conductor 590 functions as a wiring or a plug and can be formed using the material that can be used for the conductor 596, for example.

### <<Structure Example of Transistor 500A>>

In the transistor 500A, the channel length direction is not substantially parallel to the substrate 310 but along the side surface of the opening provided in the insulator.

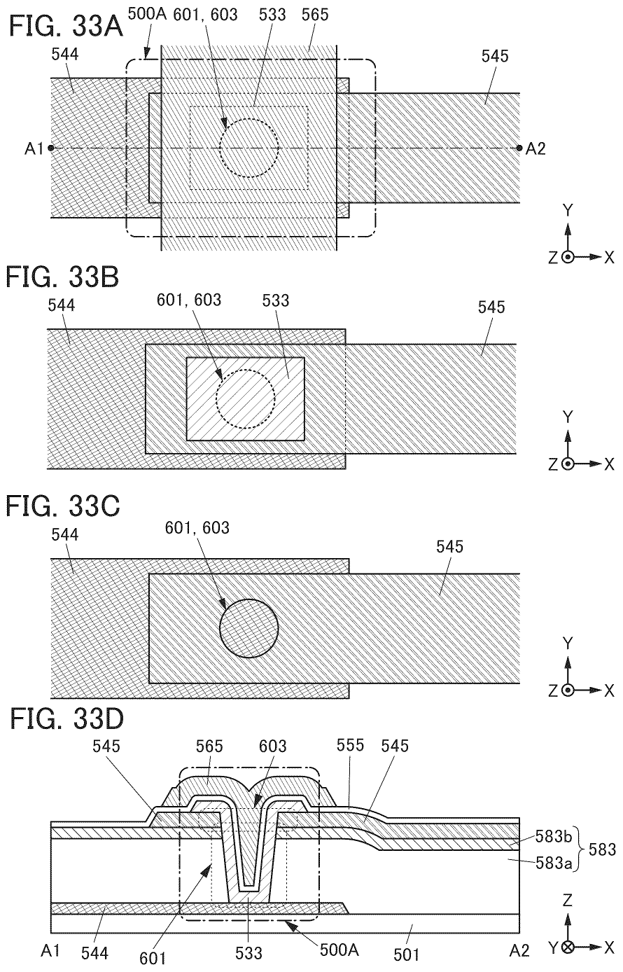

FIG. 33A is a schematic plan view illustrating a structure example of the transistor 500A that can be included in the display apparatus DSPIC described in the above and the vicinity of the transistor 500A. FIG. 33D is a schematic cross-sectional view along the dashed-dotted line A1-A2 in FIG. 33A. Note that in FIG. 33A, some components of the transistor 500A, such as an insulator, are not illustrated. Also in the other schematic plan views of the transistors described below, some components such as an insulator are not illustrated.

The transistor 500A is provided over the insulator 501, for example. The transistor 500A includes a conductor 544, the conductor 545, a metal oxide 533, an insulator 555, and a conductor 565. In the example in FIG. 33A, the conductor 545 extends in the direction parallel to the conductor 544 and the direction perpendicular to the conductor 565.

For the insulator 501, for example, the material that can be used for any of the insulator 514, the insulator 516, the insulator 522, the insulator 524, the insulator 550, the insulator 554, the insulator 574, the insulator 580, and the insulator 581 included in the transistor 500 can be used. For the insulator 555, for example, the material that can be used for the insulator 550 included in the transistor 500 can be used.

For the conductor 544 and the conductor 545, for example, the material that can be used for the conductor 542 included in the transistor 500 can be used. For the conductor 565, for example, the material that can be used for the conductor 560 included in the transistor 500 can be used.

For the metal oxide 533, for example, the material that can be used for the metal oxide 531 included in the transistor 500 can be used.

In FIG. 33A and FIG. 33D, the direction in which the conductor 545 extends is referred to as the X direction. The direction perpendicular to the X direction and parallel to the top surface of the insulator 501, for example, is referred to as the Y direction, and the direction perpendicular to the top surface of the insulator 501 is referred to as the Z direction. The definition of the X direction, the Y direction, and the Z direction applies to the following drawings in some cases and does not apply in other drawings. The X direction, the Y direction, and the Z direction can be perpendicular to each other. In the description of a schematic plan view in this specification and the like, the X direction may be referred to as the right side or the left side and the Y direction may be referred to as the upper side or the lower side. The right side may be rephrased as the X direction, the left side may be referred to as the −X direction, the upper side may be referred to as the Y direction, and the lower side may be referred to as the −Y direction in some cases.

The conductor 544 functions as one of the source electrode and the drain electrode of the transistor 500A. The conductor 545 functions as the other of the source electrode and the drain electrode of the transistor 500A. The insulator 555 functions as a gate insulating layer of the transistor 500A. The conductor 565 functions as the gate electrode of the transistor 500A.

In the metal oxide 533 between the source electrode and the drain electrode, the whole region overlapping with the gate electrode with the gate insulating layer therebetween functions as the channel formation region. In the metal oxide 533, a region in contact with the source electrode functions as a source region, and a region in contact with the drain electrode functions as a drain region.

The conductor 544 is provided over the insulator 501, the insulator 583 is provided over the insulator 501 and the conductor 544, and the conductor 545 is provided over the insulator 583. The insulator 583 can have a function of an interlayer insulating layer. The interlayer insulating layer here can be an interlayer film for separation of the source electrode and the drain electrode of the transistor 500A. The insulator 584 functions as an interlayer film for providing a circuit element or a wiring above the transistor 500A.

For the insulator 583, for example, the material that can be used for any of the insulator 514, the insulator 516, the insulator 522, the insulator 524, the insulator 550, the insulator 554, the insulator 574, the insulator 580, and the insulator 581 included in the transistor 500 can be used.

Specifically, an oxide or an oxynitride is preferably used as the insulator 583a, for example. The insulator 583a is preferably formed using a film from which oxygen is released by heating. As the insulator 583a, silicon oxide or silicon oxynitride can be suitably used, for example. Oxygen release from the insulator 583a enables oxygen supply from the insulator 583a to the metal oxide 533. When oxygen is supplied from the insulator 583a to the metal oxide 533, in particular, the channel formation region of the metal oxide 533, oxygen vacancies in the metal oxide 533 and hydrogen that enters the oxygen vacancies can be reduced. Consequently, the transistor 500A with favorable electrical characteristics and high reliability can be obtained.

Specifically, silicon nitride, silicon nitride oxide, or aluminum oxide can be suitably used for the insulator 583b, for example. The insulator 583b preferably includes a region containing more nitrogen than the insulator 583a, for example. A material containing more nitrogen than the insulator 583a can be used for the insulator 583b. A nitride or a nitride oxide is preferably used for the insulator 583b. For example, silicon nitride or silicon nitride oxide can be suitably used for the insulator 583b. When silicon nitride or silicon nitride oxide is used for the insulator 583b, the insulator 583b can serve as a blocking layer that inhibits release of oxygen from the insulator 583a. When silicon nitride or silicon nitride oxide is used for the insulator 583b, the insulator 583b can serve as a blocking layer that inhibits diffusion of hydrogen into the metal oxide 533 through the insulator 583.

The insulator 583 includes an opening 601 reaching the conductor 544. The conductor 545 includes an opening 603 reaching the opening 601. That is, the opening 603 includes a region overlapping with the opening 601.

FIG. 33A illustrates, as the components of the transistor 500A, the conductor 544, the conductor 545, the metal oxide 533, the conductor 565, the opening 601 and the opening 603. FIG. 33B illustrates a structure example in which the conductor 565 is omitted from the components illustrated in FIG. 33A. In other words, FIG. 33B illustrates the conductor 544, the conductor 545, the metal oxide 533, the opening 601, and the opening 603. FIG. 33C illustrates a structure example in which the metal oxide 533 is further omitted from the components illustrated in FIG. 33B. In other words, FIG. 33C illustrates the conductor 544, the conductor 545, the opening 601, and the opening 603.

As illustrated in FIG. 33C and FIG. 33D, the conductor 545 includes the opening 603 in a region overlapping with the conductor 544. As illustrated in FIG. 33C, the conductor 545 can be formed to entirely surround the periphery of the opening 601 in a plan view. It is preferable that the conductor 545 not be provided in the opening 601. In other words, it is preferable that the conductor 545 be not in contact with the side surface of the insulator 583 on the opening 601 side.

FIG. 33A to FIG. 33C illustrate an example in which each of the opening 601 and the opening 603 is circular in a plan view. In the case where the planar shapes of the opening 601 and the opening 603 are circular, the processing accuracy of forming each of the opening 601 and the opening 603 is increased, forming the opening 601 and the opening 603 having minute sizes.

Note that in this specification and the like, a circular shape is not limited to a perfect circular shape. For example, the planar shapes of the opening 601 and the opening 603 may be elliptical or a shape including a curve. Alternatively, a polygonal shape may be employed.

FIG. 33D illustrates an example in which the end portion of the conductor 545 on the opening 603 side is aligned with or substantially aligned with the end portion of the insulator 583 on the opening 601 side. In other words, the planar shape of the opening 603 is the same or substantially the same as the planar shape of the opening 601. Note that in this specification and the like, the end portion of the conductor 545 on the opening 603 side refers to the end portion of the bottom surface of the conductor 545 on the opening 603 side. The bottom surface of the conductor 545 refers to the surface on the insulator 583 side. The end portion of the insulator 583 on the opening 601 side refers to the end portion of the top surface of the insulator 583 on the opening 601 side. The top surface of the insulator 583 refers to the surface on the conductor 545 side. The planar shape of the opening 603 refers to the planar shape of the end portion of the bottom surface of the conductor 545 on the opening 603 side. The planar shape of the opening 601 refers to the planar shape of the end portion of the top surface of the insulator 583 on the opening 601 side.

In the case where end portions are aligned or substantially aligned with each other, the end portions can also be said to match or substantially match. In the case where end portions match or substantially match and the case where planar shapes are the same or substantially the same, it can be said that outlines of stacked layers at least partly overlap with each other in a plan view. For example, the case of processing the upper layer and the lower layer with use of the same mask pattern or mask patterns that are partly the same is included. Note that, in some cases, the outlines do not completely overlap with each other and the upper layer is positioned inward from the lower layer or the upper layer is positioned outward from the lower layer; such cases are also represented by the expression “end portions substantially match” or the expression “planar shapes are substantially the same”.

The opening 601 can be formed using a resist mask used for the formation of the opening 603, for example. Specifically, after the conductor 544 is formed over the insulator 501, the insulator 583 over the insulator 501 and the conductor 544, a conductive film to be the conductor 545 over the insulator 583, and the resist mask over the conductive film are formed. Then, the opening 603 is formed in the conductive film using the resist mask and then the opening 601 is formed in the insulator 583 using the resist mask, whereby the end portion of the opening 601 and the end portion of the opening 603 can be aligned or substantially aligned with each other. With such a structure, the process can be simplified.

The metal oxide 533 is provided to include a region positioned inside the opening 601 and the opening 603 to cover the opening 601 and the opening 603. The metal oxide 533 has a shape along the top surface and the side surface of the conductor 545, the side surface of the insulator 583, and the top surface of the conductor 544. The metal oxide 533 includes, for example, a region in contact with the top surface and the side surface of the conductor 545, the side surface of the insulator 583, and the top surface of the conductor 544.

The metal oxide 533 preferably covers the end portion of the conductor 545 on the opening 603 side. For example, FIG. 33D illustrates a structure in which the end portion of the metal oxide 533 is positioned over the conductor 545. The end portion of the metal oxide 533 can also be said to be in contact with the top surface of the conductor 545.

Although the metal oxide 533 has a single-layer structure in FIG. 33D, for example, one embodiment of the present invention is not limited thereto. The metal oxide 533 may have a stacked-layer structure of two or more layers.

The insulator 555 functioning as the gate insulating layer of the transistor 500A is provided to cover the opening 601 and the opening 603 and include a region positioned in the opening 601 and the opening 603. The insulator 555 is provided over the metal oxide 533, over the conductor 545, and over the insulator 583. The insulator 555 can include a region in contact with the top surface and the side surface of the metal oxide 533, the top surface and the side surface of the conductor 545, and the top surface of the insulator 583. The insulator 555 has a shape along the top surface of the insulator 583, the top surface and the side surface of the conductor 545, and the top surface and the side surface of the metal oxide 533.

The conductor 565 functioning as the gate electrode of the transistor 500A can be provided over the insulator 555 and can include a region in contact with the top surface of the insulator 555. The conductor 565 includes a region overlapping with the metal oxide 533 with the insulator 555 therebetween. The conductor 565 has a shape along the shape of the top surface of the insulator 555.

For example, as illustrated in FIG. 33D, the conductor 565 includes a region overlapping with the metal oxide 533 with the insulator 555 therebetween in the opening 601 and the opening 603. In the example illustrated in FIG. 33D, the conductor 565 includes a region overlapping with the conductor 544 and the conductor 545 with the insulator 555 and the metal oxide 533 therebetween. In the example illustrated in FIG. 33D, the conductor 565 includes a region overlapping with the conductor 544 and the conductor 545 with the insulator 555 therebetween but without the metal oxide 533 therebetween. The conductor 565 covers the entire metal oxide 533. With such a structure, a gate electric field can be applied to the entire metal oxide 533, which allows the transistor 500A to have better electrical characteristics, for example, the on-state current of the transistor can be increased.

The transistor 500A is what is called a top-gate transistor including a gate electrode above the metal oxide 533. Furthermore, since the bottom surface of the metal oxide 533 includes a region in contact with the source electrode and the drain electrode, the transistor 500A can be referred to as a TGBC (Top Gate Bottom Contact) transistor.

The transistor 500A can be used as, for example, one or both of the transistor included in the pixel circuit PX and the transistor included in the driver circuit region DRV. The transistor 500A may be used as, for example, the transistor included in the driver circuit region DRV or the functional circuit region MFNC, such as the transistor included in the driver circuit SDR, the transistor included in the driver circuit GDR, or the transistor included in the power supply circuit EPS.

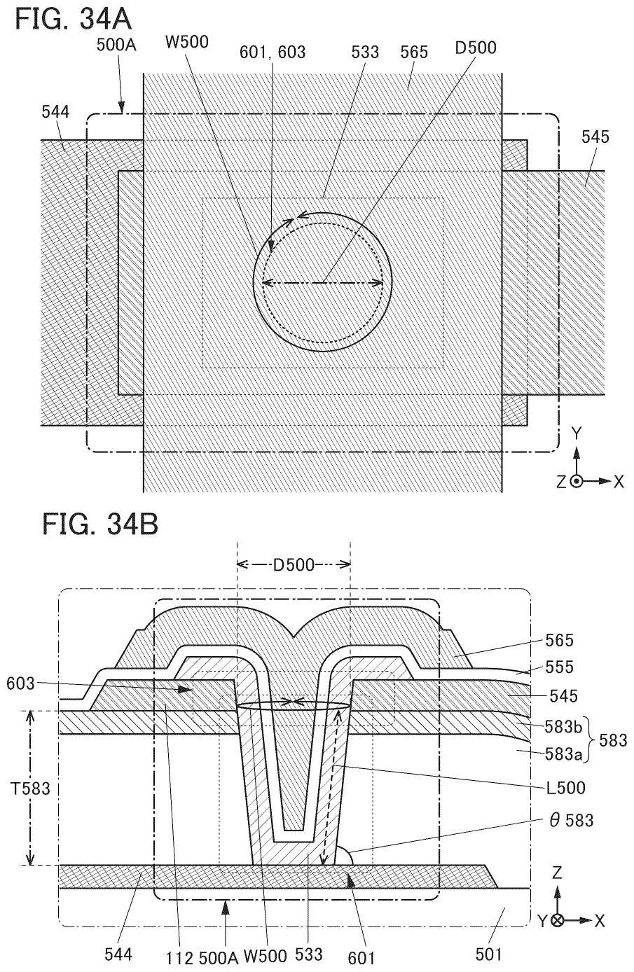

Here, the channel length and channel width of the transistor 500A are described with reference to FIG. 34A and FIG. 34B. FIG. 34A is an enlarged view of the schematic plan view of FIG. 33A illustrating the structure example of the transistor 500A and the vicinity thereof. FIG. 34B is an enlarged view of the schematic cross-sectional view of FIG. 33D illustrating the structure example of the transistor 500A and the vicinity thereof.

In the metal oxide 533, a region in contact with the conductor 544 functions as one of the source region and the drain region, a region in contact with the conductor 545 functions as the other of the source region and the drain region, and a region between the source region and the drain region functions as the channel formation region.

The channel length of the transistor 500A is a distance between the source region and the drain region. In FIG. 34B, a channel length L500 of the transistor 500A is indicated by a dashed double-headed arrow. In the cross-sectional view, the channel length L500 is a distance between the end portion of the region where the metal oxide 533 is in contact with the conductor 544 and the end portion of the region where the metal oxide 533 is in contact with the conductor 545.

Here, the channel length L500 of the transistor 500A corresponds to the length of the side surface of the insulator 583 on the opening 601 side when seen from the XZ plane. In other words, the channel length L500 is determined depending on a thickness T583 of the insulator 583 and an angle θ583 formed by the side surface of the insulator 583 on the opening 601 side and the formation surface of the insulator 583 (here, the top surface of the conductor 544), and is not affected by the performance of a light-exposure apparatus used for manufacturing the transistor. Thus, the channel length L500 can be a value smaller than that of the resolution limit of the light-exposure apparatus, which enables the transistor to have a minute size. For example, the channel length L500 is preferably larger than or equal to 0.010 μm and smaller than 3.0 μm, further preferably larger than or equal to 0.050 μm and smaller than 3.0 μm, still further preferably larger than or equal to 0.10 μm and smaller than 3.0 μm, yet still further preferably larger than or equal to 0.15 μm and smaller than 3.0 μm, yet still further preferably larger than or equal to 0.20 μm and smaller than 3.0 μm, yet still further preferably larger than or equal to 0.20 μm and smaller than 2.5 μm, yet still further preferably larger than or equal to 0.20 μm and smaller than 2.0 μm, yet still further preferably larger than or equal to 0.20 μm and smaller than 1.5 μm, yet still further preferably larger than or equal to 0.30 μm and smaller than 1.5 μm, yet still further preferably larger than or equal to 0.30 μm and smaller than or equal to 1.2 μm, yet still further preferably larger than or equal to 0.40 μm and smaller than or equal to 1.2 μm, yet still further preferably larger than or equal to 0.40 μm and smaller than or equal to 1.0 μm, yet still further preferably larger than or equal to 0.50 μm and smaller than or equal to 1.0 μm. In FIG. 34B, the thickness T583 of the insulator 583 is indicated by a dashed-dotted double-headed arrow.

When the transistor 500A is used as the transistor included in the pixel circuit PX in the display region DIS, the transistor included in the pixel circuit PX can be miniaturized, and the pixel circuit PX can be miniaturized. Thus, the display apparatus DSPIC can have high resolution. Furthermore, a reduction in the channel length L500 can increase the on-state current of the transistor 500A. Thus, with the use of the transistor 500A as the transistor included in the pixel circuit PX in the display apparatus DSPIC, the display apparatus DSPIC can be driven at high speed.

The channel length L500 can be controlled by adjustment of the thickness T583 of the insulator 583 and the angle θ583.

The thickness T583 of the insulator 583 is preferably greater than or equal to 0.010 μm and less than 3.0 μm, further preferably greater than or equal to 0.050 μm and less than 3.0 μm, further preferably greater than or equal to 0.10 μm and less than 3.0 μm, still further preferably greater than or equal to 0.15 μm and less than 3.0 μm, yet still further preferably greater than or equal to 0.20 μm and less than 3.0 μm, yet still further preferably greater than or equal to 0.20 μm and less than 2.5 μm, yet still further preferably greater than or equal to 0.20 μm and less than 2.0 μm, yet still further preferably greater than or equal to 0.20 μm and less than 1.5 μm, yet still further preferably greater than or equal to 0.30 μm and less than 1.5 μm, yet still further preferably greater than or equal to 0.30 μm and less than or equal to 1.2 μm, yet still further preferably greater than or equal to 0.40 μm and less than or equal to 1.2 μm, yet still further preferably greater than or equal to 0.40 μm and less than or equal to 1.0 μm, yet still further preferably greater than or equal to 0.50 μm and less than or equal to 1.0 μm.

The side surface of the insulator 583 on the opening 601 side preferably has a tapered shape. The angle θ583 formed by the side surface of the insulator 583 on the opening 601 side and the formation surface of the insulator 583 (here, the top surface of the conductor 544) is preferably less than 90°. By reducing the angle θ583, the coverage with a layer provided over the insulator 583 (e.g., the metal oxide 533) can be improved. However, reducing the angle θ583 might reduce the contact area between the metal oxide 533 and the conductor 544 to increase the contact resistance between the metal oxide 533 and the conductor 544. The angle θ583 is preferably greater than or equal to 45° and less than 90°, further preferably greater than or equal to 50° and less than 90°, further preferably greater than or equal to 55° and less than 90°, further preferably greater than or equal to 60° and less than 90°, further preferably greater than or equal to 60° and less than or equal to 85°, still further preferably greater than or equal to 65° and less than or equal to 85°, yet further preferably greater than or equal to 65° and less than or equal to 80°, yet still further preferably greater than or equal to 70° and less than or equal to 80°. When the angle θ583 is within the above range, the coverage with the layer formed over the conductor 544 and the insulator 583 (e.g., the metal oxide 533) can be improved, which can inhibit defects such as step disconnection or a void from being generated in the layer. In addition, the contact resistance between the metal oxide 533 and the conductor 544 can be reduced.

In this specification and the like, step disconnection refers to a phenomenon in which a layer, a film, or an electrode is split because of the shape of the formation surface (e.g., a step).

Although FIG. 34B illustrates the structure in which the side surface of the insulator 583 on the opening 601 side is linear in the cross-sectional view, one embodiment of the present invention is not limited thereto. In the cross-sectional view, the side surface of the insulator 583 on the opening 601 side may be curved, or the side surface may include both a linear region and a curved region.

The channel width of the transistor 500A is a width of the source region or a width of the drain region in the direction orthogonal to the channel length direction. In other words, the channel width is the width of the region where the metal oxide 533 is in contact with the conductor 544 or the width of the region where the metal oxide 533 is in contact with the conductor 545 in the direction orthogonal to the channel length direction. Here, the channel width of the transistor 500A is described as the width of the region where the metal oxide 533 and the conductor 545 are in contact with each other in the direction orthogonal to the channel length direction. In FIG. 34A and FIG. 34B, a channel width W500 of the transistor 500A is indicated by a solid double-headed arrow. In the plan view, the channel width W500 is the length of the end portion of the bottom surface of the conductor 545 on the opening 603 side.

The channel width W500 is determined by the planar shape of the opening 603. In FIG. 34A and FIG. 34B, the width D500 of the opening 603 is indicated by a dashed-two dotted double-headed arrow. In the plan view, the width D500 refers to the short side of the smallest rectangle that is circumscribed around the opening 603. In the case where the opening 603 is formed by a photolithography method, the width D500 of the opening 603 is larger than or equal to the resolution limit of a light-exposure apparatus. For example, the width D500 is preferably larger than or equal to 0.20 μm and smaller than 5.0 μm, further preferably larger than or equal to 0.20 μm and smaller than 4.5 μm, still further preferably larger than or equal to 0.20 μm and smaller than 4.0 μm, yet still further preferably larger than or equal to 0.20 μm and smaller than 3.5 μm, yet still further preferably larger than or equal to 0.20 μm and smaller than 3.0 μm, yet still further preferably larger than or equal to 0.20 μm and smaller than 2.5 μm, yet still further preferably larger than or equal to 0.20 μm and smaller than 2.0 μm, yet still further preferably larger than or equal to 0.20 μm and smaller than 1.5 μm, yet still further preferably larger than or equal to 0.30 μm and smaller than 1.5 μm, yet still further preferably larger than or equal to 0.30 μm and smaller than or equal to 1.2 μm, yet still further preferably larger than or equal to 0.40 μm and smaller than or equal to 1.2 μm, yet still further preferably larger than or equal to 0.40 μm and smaller than or equal to 1.0 μm, yet still further preferably larger than or equal to 0.50 μm and smaller than or equal to 1.0 μm. Note that when the planar shape of the opening 603 is circular, the width D500 corresponds to the diameter of the opening 603, and the channel width W500 can be equal to the length of the periphery of the opening 603 in a plan view and calculated to be “D500×π”.

Since the size of the transistor 500A is small, by using the transistor 500A for a display apparatus, a display apparatus with high resolution can be provided. Since the amount of the on-state current of the transistor 500A is large, by using the transistor 500A for a display apparatus, a display apparatus with high luminance can be provided. Since the operation speed of the transistor 500A is high, by using the transistor 500A for a display apparatus, a display apparatus with high driving speed can be provided. Since the electrical characteristics of the transistor 500A are stable, by using the transistor 500A for a display apparatus, a display apparatus with high reliability can be provided. Since the amount of the off-state current of the transistor 500A is small, by using the transistor 500A for a display apparatus, a display apparatus with low power consumption can be provided.

### <Cross-Sectional Structure Example 4 of Display Apparatus>

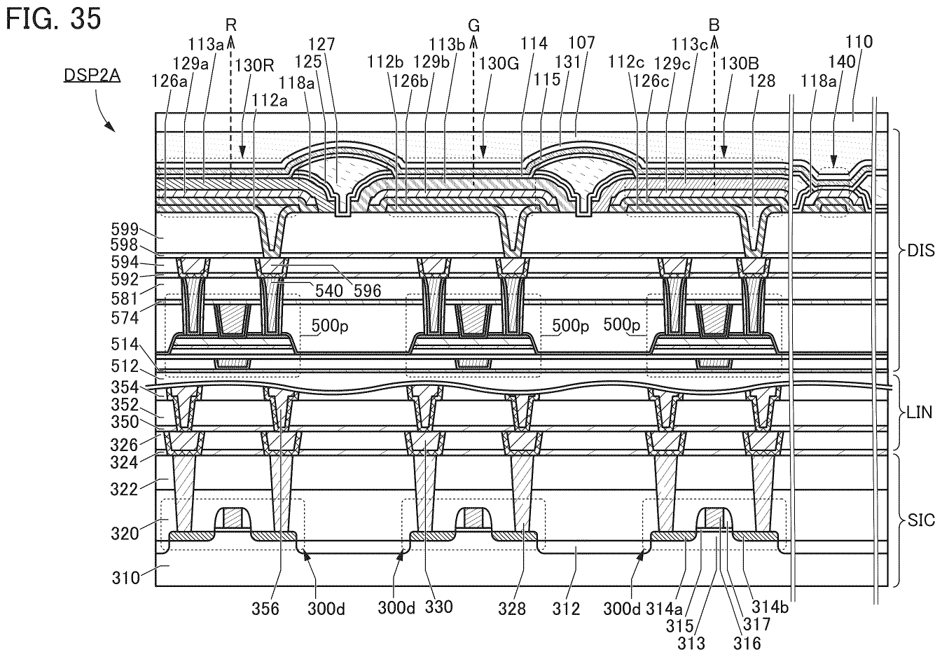

A display apparatus DSP2A in FIG. 35 is a cross-sectional structure example of the display apparatus DSP2 in FIG. 25B. The display apparatus DSP2A includes a pixel circuit and a driver circuit over the substrate 310, for example. Note that in FIG. 35 of the display apparatus DSP2A, not only the circuit region SIC and the display region DIS illustrated in FIG. 25B but also a wiring region LIN are illustrated.

The circuit region SIC includes the substrate 310, for example, and the transistor 300d is formed over the substrate 310. The wiring region LIN is provided above the transistor 300d, and the wiring region LIN includes a wiring that electrically connects the transistor 300d, the transistor 500p, the light-emitting device 130R, the light-emitting device 130G, and the light-emitting device 130B. The display region DIS is provided above the wiring region LIN, and the display region DIS includes, for example, the transistor 500p and the light-emitting device 130 (the light-emitting device 130R, the light-emitting device 130G, and the light-emitting device 130B in FIG. 35).

That is, the transistor 300d can be a transistor included in the circuit region SIC. The transistor 500p can be a transistor included in the pixel circuit PX. The light-emitting device 130 can be a light-emitting device included in the pixel circuit PX.

For the light-emitting devices 130 (the light-emitting device 130R, the light-emitting device 130G, and the light-emitting device 130B in FIG. 35) positioned above the transistor 500p, the description of the light-emitting devices 130 in FIG. 27 can be referred to.

As the substrate 310, a substrate that can be used as the substrate BS can be used, for example. In this embodiment, the substrate 310 is a semiconductor substrate containing silicon as a material. Therefore, a transistor included in the circuit region SIC can be a Si transistor.

For the screen ratio (aspect ratio) of the display apparatus DSP2A, the description of the screen ratio of the display apparatus DSP1 can be referred to. For the diagonal size of the display apparatus DSP2A, the description of the diagonal size of the display apparatus DSP1 can be referred to.

For the transistor 300d, the description of the transistor 300 of the display apparatus DSP1A in FIG. 27 can be referred to.

In the display apparatus DSP2A, the wiring region LIN is provided over the transistor 300d. The wiring region LIN includes, for example, the insulator 324, an insulator 326, a conductor 330, an insulator 350, an insulator 352, an insulator 354, and a conductor 356.

Over the insulator 322 and the conductor 328, the insulator 324 and the insulator 326 are stacked in this order. An opening is formed in the insulator 324 and the insulator 326 in a region overlapping with the conductor 328. In addition, the conductor 330 is embedded in the opening.

The insulator 350, the insulator 352, and the insulator 354 are stacked sequentially over the insulator 326 and the conductor 330. An opening is formed in the insulator 350, the insulator 352, and the insulator 354 in a region overlapping with the conductor 330. The conductor 356 is embedded in the opening.

The conductor 330 and the conductor 356 have a function of a plug or a wiring that is connected to the transistor 300d. Note that the conductor 330 and the conductor 356 can be provided using a material similar to that for the conductor 328 or the conductor 596.

Note that like the insulator 592, for example, the insulator 324 and the insulator 350 are preferably formed using an insulator having a barrier property against one or more selected from hydrogen, oxygen, and water. Like the insulator 594, each of the insulator 326, the insulator 352, and the insulator 354 is preferably formed using an insulator having a relatively low dielectric constant to reduce parasitic capacitance generated between wirings. Each of the insulator 326, the insulator 352, and the insulator 354 has a function of an interlayer insulating film and a planarization film. Furthermore, each of the insulator 326, the insulator 352, and the insulator 354 preferably includes a conductor having a barrier property against one or more selected from hydrogen, oxygen, and water.

For the conductor having a barrier property against hydrogen, tantalum nitride is preferably used, for example. The use of a stack including tantalum nitride and tungsten that has high conductivity can inhibit diffusion of hydrogen from the transistor 300 while the conductivity of a wiring is kept. In that case, a tantalum nitride layer having a barrier property against hydrogen is preferably in contact with the insulator 350 having a barrier property against hydrogen.

The insulator 512 is provided over the insulator 354 and the insulator 356. The insulator 514 is provided over the insulator 512, and the transistor 500p is provided over the insulator 514. An insulator 574 is formed over the transistor 500, and an insulator 581 is formed over the insulator 574.

For the transistor 500p, an insulator in the vicinity of the transistor 500p, and the like, the description of the transistor 500 of the display apparatus DSP1B in FIG. 29 can be referred to.

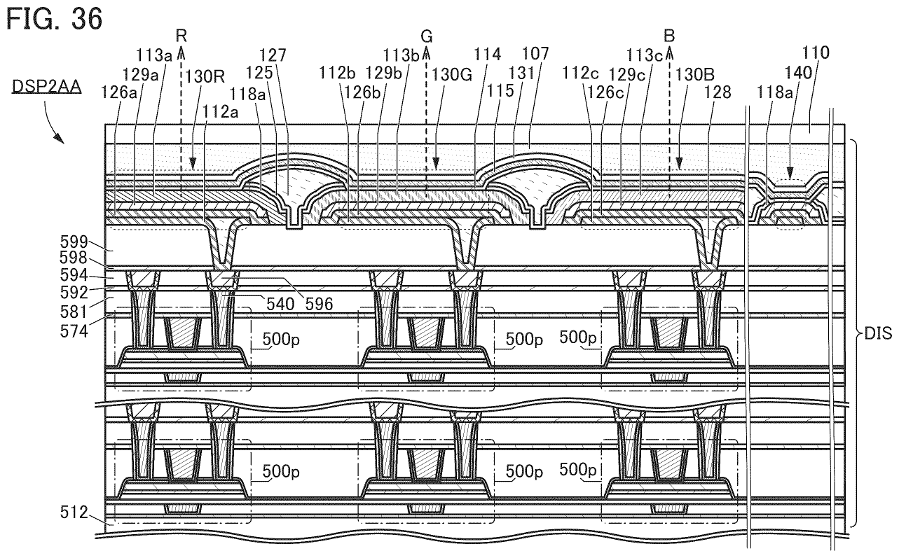

Although the display region DIS of the display apparatus DSP2A in FIG. 35 has a structure in which the transistor 500p is included in one layer, the display apparatus of one embodiment of the present invention may have a structure in which a plurality of layers are provided in the display region DIS and the transistor 500p is included in each of the plurality of layers as in a display apparatus DSP2AA illustrated in FIG. 36.

Note that although the display region DIS in the display apparatus DSP2AA in FIG. 36 is selectively illustrated, the wiring region LIN and the circuit region SIC are provided below the display region DIS.

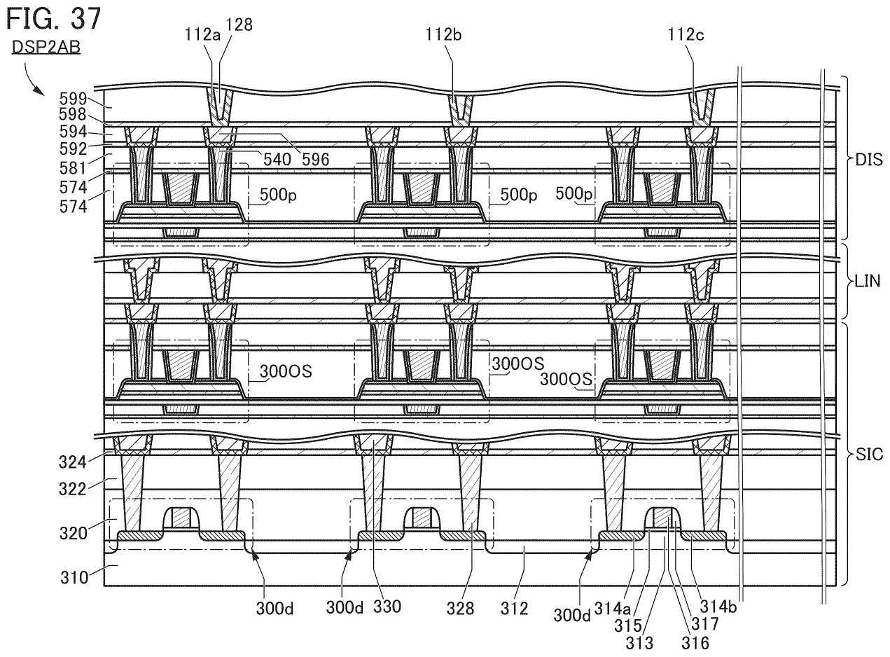

Note that although the display region DIS of the display apparatus DSP2A in FIG. 35 has a structure in which the transistor 300d is included in one layer in the circuit region SIC, the display apparatus of one embodiment of the present invention may have a structure in which one or more layers each including a transistor 300OS with a structure similar to that of the transistor 500p are provided above the transistor 300d in the circuit region SIC, as in a display apparatus DSP2AB illustrated in FIG. 37.

In particular, when the transistor 300OS is an n-channel transistor and the transistor 300d is a p-channel transistor, the circuit included in the circuit region SIC can be a CMOS circuit. When the transistor 300OS is an OS transistor and the transistor 300d is a Si transistor, a circuit included in the circuit region SIC is referred to as an LTPO in some cases.

Note that although part of the display region DIS, the wiring region LIN, and the circuit region SIC in the display apparatus DSP2AB in FIG. 37 are selectively illustrated, the light-emitting device 130 is provided above the transistor 500p in the display region DIS.

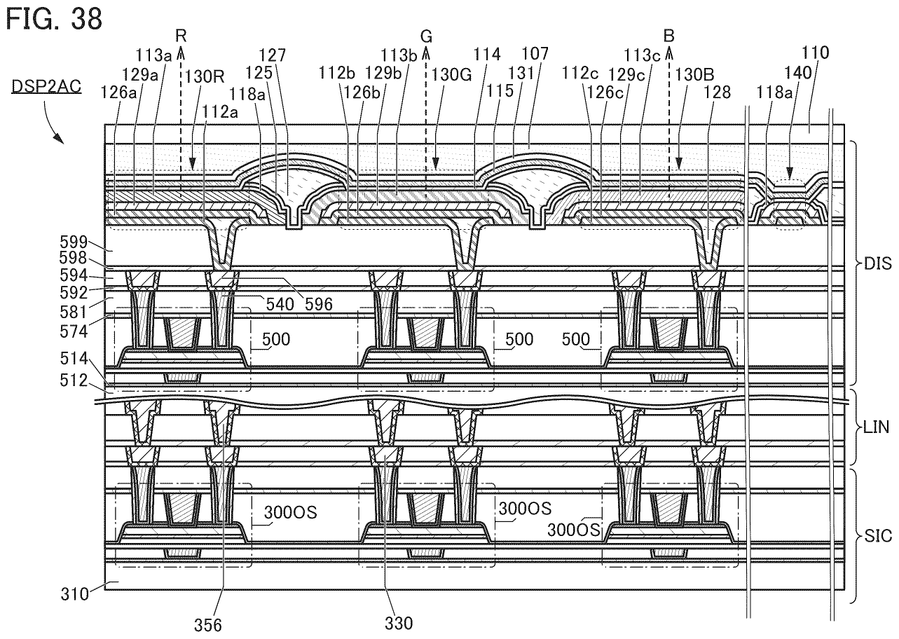

The structure of the transistor 300d in the display apparatus DSP2A in FIG. 35 may be similar to that of the transistor 500p included in the display region DIS. A display apparatus DSP2AC illustrated in FIG. 38 is a modification example of the display apparatus DSP2A in FIG. 35 and has a structure in which the transistor 300d has a structure similar to that of the transistor 500p included in the display region DIS.

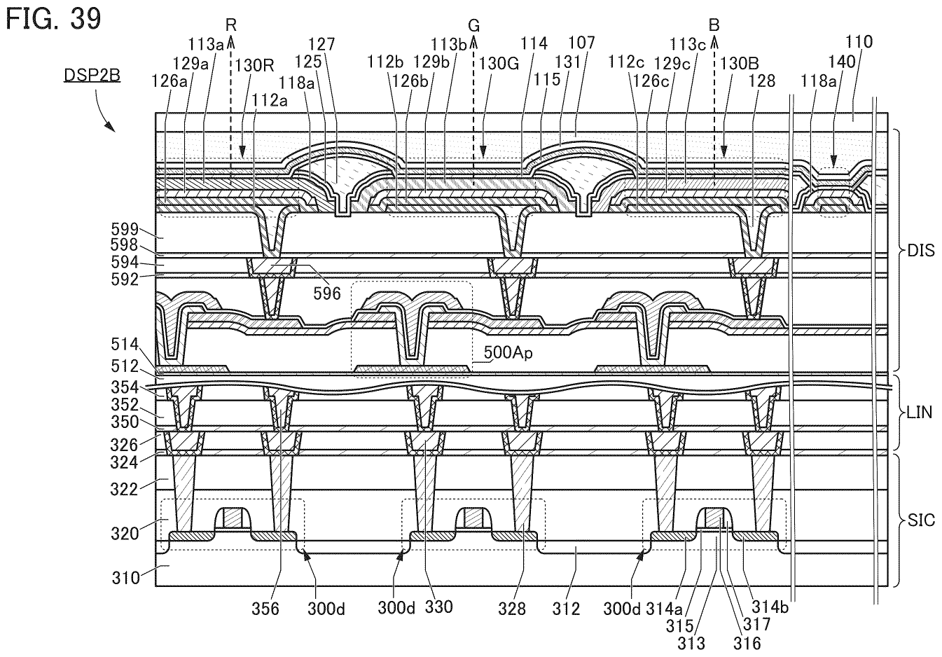

The structure of the transistor 500p in the display apparatus DSP2A in FIG. 35 may be the structure of the transistor 500A in the display apparatus DSPIC in FIG. 32. A display apparatus DSP2B illustrated in FIG. 39 is a modification example of the display apparatus DSP2A in FIG. 35 and has a structure in which the transistor 500p has the structure of the transistor 500A in the display apparatus DSPIC in FIG. 32.

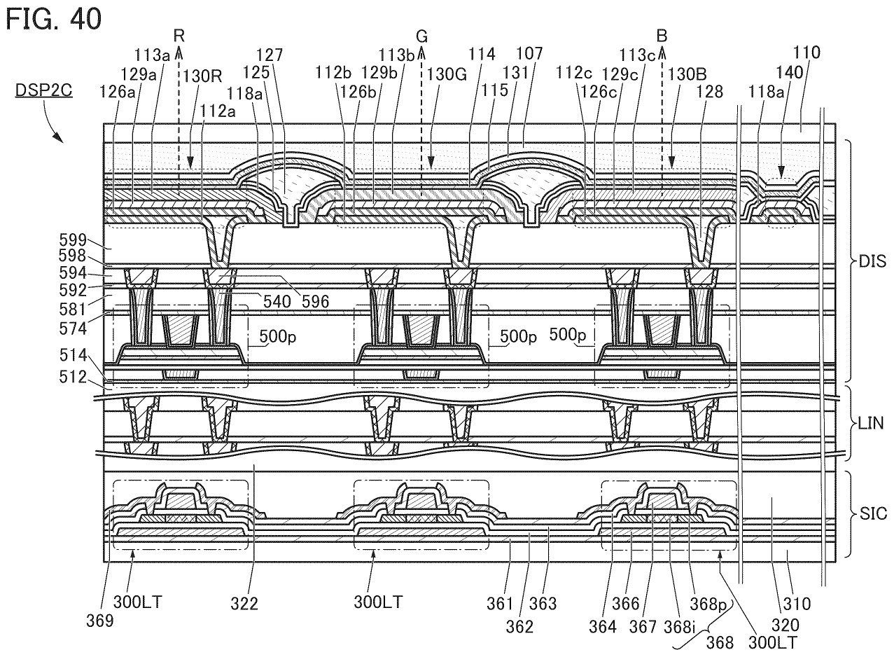

The transistor 300d in the display apparatus DSP2A in FIG. 35 may be a transistor containing low-temperature polysilicon in its channel formation region (hereinafter referred to as an LTPS transistor), for example. A display apparatus DSP2C illustrated in FIG. 40 is a modification example of the display apparatus DSP2A in FIG. 35 and has a structure in which a transistor 300LT, which is an LTPS transistor, is used instead of the transistor 300d

The transistor 300LT is provided over the substrate 310. The transistor 300LT includes an insulator 361, an insulator 362, an insulator 363, an insulator 364, a conductor 366, a conductor 367, a low-resistance region 368p, a semiconductor region 368i, and a conductor 369. Here, a plurality of layers obtained by processing the same conductive film are shown with the same hatching pattern. In this specification and the like, the low-resistance region 368p and the semiconductor region 368i are collectively referred to as a semiconductor layer 368. In particular, when, for example, low-temperature polysilicon is used as a semiconductor material contained in the semiconductor layer 368, the transistor 300LT can be an LTPS transistor. The LTPS transistor has high field-effect mobility and excellent frequency characteristics.

In FIG. 40, the conductor 367 functions as a first gate (sometimes referred to as one of a gate and a back gate) of the transistor 300LT. The conductor 366 functions as a second gate (sometimes referred to as the other of the gate and the back gate) of the transistor 300LT. One of the pair of low-resistance regions 368p in the semiconductor layer 368 functions as one of a source and a drain of the transistor 300LT, and the other of the pair of low-resistance regions 368p in the semiconductor layer 368 functions as the other of the source and the drain of the transistor 300LT. The insulator 363 functions as a first gate insulating film in the transistor 300LT, and the insulator 362 functions as a second gate insulating film in the transistor 300LT.

In FIG. 40, the insulator 361 is formed over the substrate 310. The conductor 366 is formed in a region over the insulator 361. The insulator 362 is formed to cover the insulator 361 and the conductor 366. The semiconductor layer 368 is formed in a region overlapping with the conductor 366 and the insulator 362 and being over the insulator 362. The insulator 363 is formed to cover the insulator 362 and the semiconductor layer 368. The conductor 367 is formed in a region overlapping with the conductor 366, the insulator 362, the semiconductor layer 368, and the insulator 363 and being over the insulator 363. The insulator 364 is formed to cover the insulator 363 and the conductor 367. An opening portion is formed in the insulator 363 and the insulator 364 in regions overlapping with the low-resistance region 368p, and the conductor 369 is formed over the insulator 364 to fill the opening portion.

For each of the insulator 361, the insulator 362, the insulator 363, and the insulator 364, one or more selected from silicon oxide, silicon oxynitride, silicon nitride oxide, silicon nitride, aluminum oxide, aluminum oxynitride, aluminum nitride oxide, or aluminum nitride may be used.

In particular, a barrier insulating film that inhibits diffusion of impurities (e.g., a metal ion, a metal atom, an oxygen atom, an oxygen molecule, a hydrogen atom, a hydrogen molecule, and a water molecule) from a region below the insulator 361 (e.g., the substrate 310) is preferably used as the insulator 361.

The low-resistance region 368p is a region containing an impurity element. For example, in the case where the transistor 300LT is an n-channel transistor, phosphorus or arsenic is added to the low-resistance region 368p. In contrast, in the case where the transistor 300LT is a p-channel transistor, boron or aluminum is added to the low-resistance region 368p. In addition, in order to control the threshold voltage of the transistor 300, the above-described impurity may be added to the semiconductor region 368i.

Note that the transistor 300LT may be either a p-channel transistor or an n-channel transistor. Alternatively, a plurality of the transistors 300LT may be provided in the circuit region SIC and both the p-channel transistor and the n-channel transistor may be used.

For the conductor 366 and the conductor 367, a metal such as aluminum, titanium, chromium, nickel, copper, yttrium, zirconium, molybdenum, silver, tantalum, or tungsten can be used, for example. Alternatively, for each of the conductor 366 and the conductor 367, an alloy containing two or more selected from the above metals as its main components can be used. Alternatively, for the conductor 366 and the conductor 367, a light-transmitting conductive material such as indium oxide, indium tin oxide (ITO), indium oxide containing tungsten, indium zinc oxide containing tungsten, indium oxide containing titanium, ITO containing titanium, indium zinc oxide, zinc oxide (ZnO), ZnO containing gallium, or indium tin oxide containing silicon can be used. Alternatively, for the conductor 366 and the conductor 367, silicide (e.g., nickel silicide) or a semiconductor (e.g., polycrystalline silicon or an oxide semiconductor) whose resistance is lowered by, for example, containing an impurity element may be used. Alternatively, for the conductor 366 and the conductor 367, a film containing graphene can be used. The film containing graphene can be formed, for example, by reducing a film containing graphene oxide. Alternatively, a conductive paste (e.g., a conductive paste containing silver, carbon, or copper) or a conductive polymer (e.g., polythiophene) may be used for forming the conductor 366 and the conductor 367. A conductive paste is preferable because it is inexpensive. A conductive polymer is preferable because it is easily applied. Alternatively, the conductor 366, the conductor 367, or both can have a single-layer structure containing any of the above materials or a structure (a stacked structure) in which two or more selected from the above materials overlap each other.

The conductor 369 functions as a wiring electrically connected to the low-resistance region 368p of the transistor 300LT. That is, the conductor 369 functions as a source or a drain of the transistor 300LT. Note that for the conductor 369, any of the materials usable for the conductor 366 and the conductor 367 can be used.

Note that the structure of the display apparatus of one embodiment of the present invention is not limited to the structures of the display apparatus DSP2A in FIG. 35, the display apparatus DSP2AA in FIG. 36, the display apparatus DSP2AB in FIG. 37, the display apparatus DSP2AC in FIG. 38, the display apparatus DSP2B in FIG. 39, and the display apparatus DSP2C in FIG. 40. The structure of the display apparatus of one embodiment of the present invention may be the structure of the display apparatus which is modified as appropriate.

For example, the display apparatus of one embodiment of the present invention may have a structure in which a plurality of substrates are bonded to each other. Specifically, for example, a structure may be employed in which a first substrate provided with the display region DIS is bonded over a second substrate provided with the circuit region SIC by Cu-to-Cu (copper-to-copper) direct bonding technique or the like (not illustrated).

### <Cross-Sectional Structure Example 5 of Display Apparatus>

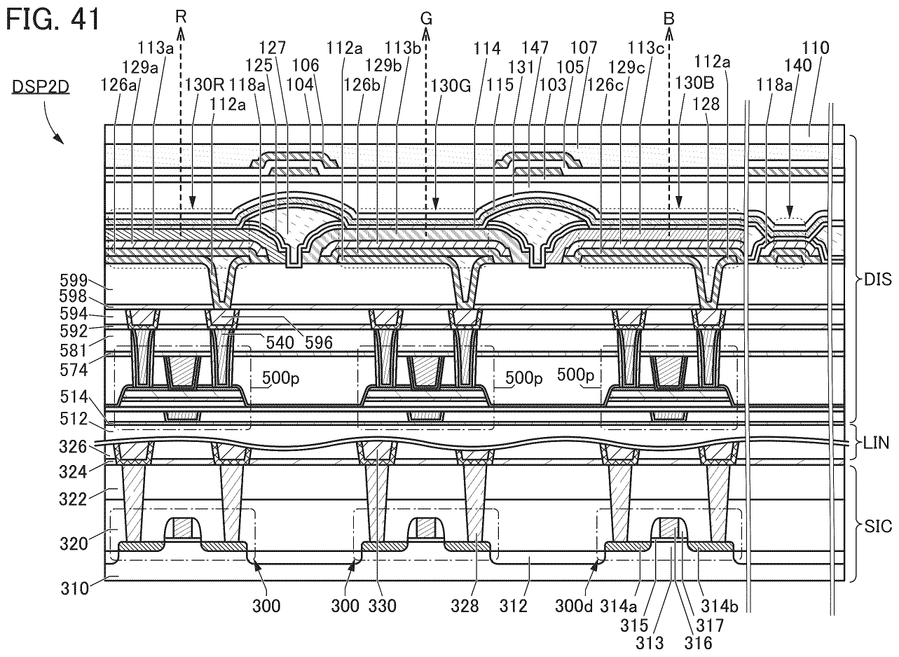

The display apparatus DSP2A illustrated in FIG. 35 may be provided with a panel having a touch sensor function (sometimes referred to as a touch panel), for example. In a display apparatus DSP2D illustrated in FIG. 41, a resin layer 147, an insulator 103, a conductor 104, an insulator 105, and a conductor 106 are formed in this order over the protective layer 131, for example.

The resin layer 147 preferably contains an organic insulating material. Examples of the organic insulating material include an acrylic resin, a polyimide resin, an epoxy resin, a polyamide resin, a polyimide-amide resin, a siloxane resin, a benzocyclobutene-based resin, a phenol resin, and precursors of these resins.

The insulator 103 preferably contains an inorganic insulating material. Examples of the inorganic insulating material include oxide and nitride such as silicon oxide, silicon oxynitride, silicon nitride oxide, silicon nitride, aluminum oxide, aluminum oxynitride, and hafnium oxide.

The conductor 104 and the conductor 106 function as electrodes of a touch sensor. In the case of using a mutual capacitive touch sensor, a pulse potential may be supplied to one of the conductor 104 and the conductor 106, and an analog-digital (A-D) converter circuit or a sensing circuit such as a sense amplifier may be electrically connected to the other of the conductor 104 and the conductor 106, for example. In that case, electrostatic capacitance is formed between the conductor 104 and the conductor 106. When a finger or the like approaches the conductor 104 and the conductor 106, the electrostatic capacitance changes (specifically, the electrostatic capacitance is reduced). This change in the electrostatic capacitance appears, when a pulse potential is supplied to one of the conductor 104 and the conductor 106, as a change in the amplitude of a signal that occurs in the other of the conductor 104 and the conductor 106. Accordingly, the touch and approach of the finger or the like can be sensed.

For the insulator 105, an inorganic insulating film or an organic insulating film can be used, for example. Specifically, for the insulator 105, a resin such as an acrylic resin or an epoxy resin can be used, for example. Alternatively, for the insulator 105, an inorganic insulating material such as silicon oxide, silicon oxynitride, silicon nitride oxide, silicon nitride, or aluminum oxide can be used, for example. Note that the insulator 105 may have either a single-layer structure or a stacked-layer structure.

Note that although FIG. 41 illustrates the structure in which the electrode of the touch sensor is provided above the light-emitting device 130, the touch sensor may be provided in the same layer as the light-emitting device 130 (not illustrated). For example, when formed concurrently with the light-emitting device 130, the touch sensor can be provided in the same layer as the light-emitting device 130.

### <Cross-Sectional Structure Example 6 of Display Apparatus>

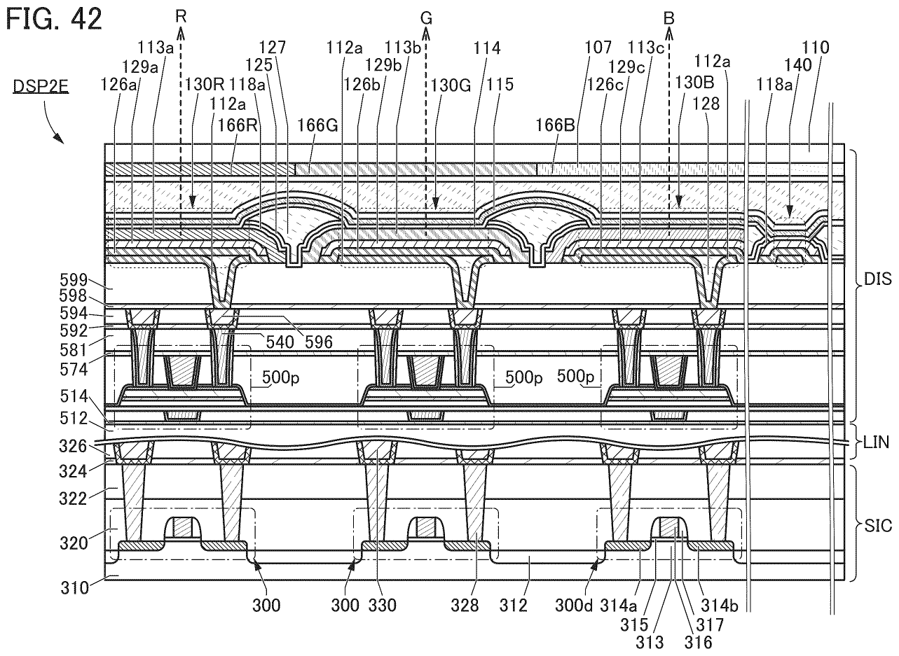

The display apparatus DSP2A in FIG. 35 may include, for example, a coloring layer (a color filter) or the like. A display apparatus DSP2E illustrated in FIG. 42 includes a coloring layer 166R, a coloring layer 166G, and a coloring layer 166B between the adhesive layer 107 and the substrate 110, for example. Note that the coloring layer 166R, the coloring layer 166G, and the coloring layer 166B can be formed on the substrate 110, for example. In the case where the light-emitting device 130R includes a light-emitting layer that emits red (R) light, the light-emitting device 130G includes a light-emitting layer that emits green (G) light, and the light-emitting device 130B includes a light-emitting layer that emits blue (B) light, the coloring layer 166R is a red coloring layer, the coloring layer 166G is a green coloring layer, and the coloring layer 166B is a blue coloring layer.

Note that a black matrix (not illustrated) may be provided between the coloring layer 166R and the coloring layer 166G, between the coloring layer 166G and the coloring layer 166B, and between the coloring layer 166G and the coloring layer 166B. Providing a black matrix in the display apparatus DSP2E can prevent light emitted from the light-emitting device from entering the color layer included in the adjacent pixel. This can enhance the display contrast, improving the display quality of the display apparatus DSP2E.

### <Cross-Sectional Structure Example 7 of Display Apparatus>

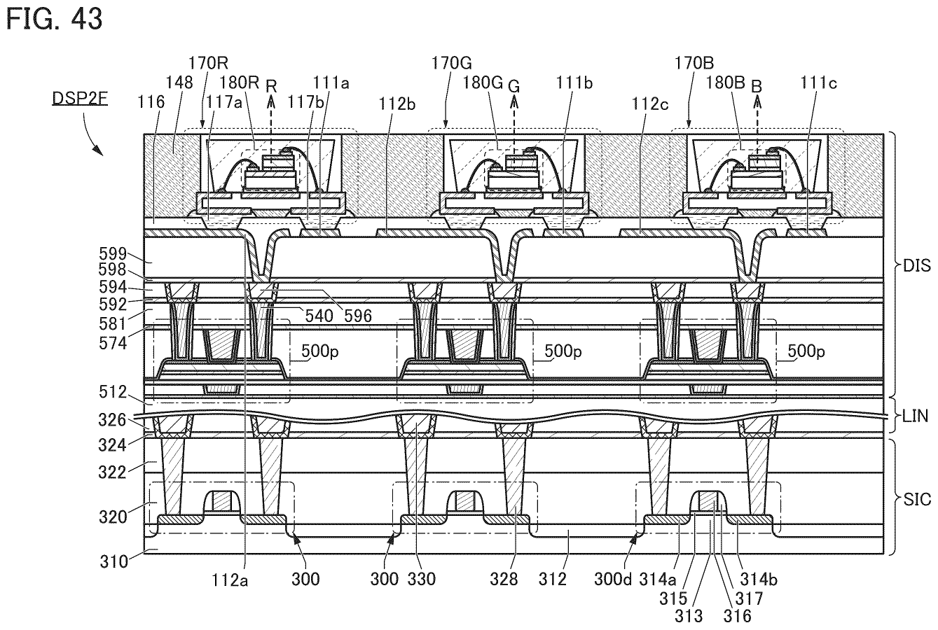

The display apparatus DSP2A in FIG. 35 may include not a light-emitting device including an organic EL element but a light-emitting device including an LED (also including a micro LED), for example. In the display apparatus DSP2F illustrated in FIG. 43, a packaged LED chip is mounted on the display apparatus. Specifically, in the display apparatus DSP2F illustrated in FIG. 43, an LED package 170R, an LED package 170G, and an LED package 170B are provided as light-emitting devices in the display region DIS.

In the display apparatus DSP2F in FIG. 43, a conductor 111a to a conductor 111c and the conductor 112a to the conductor 112c are provided over the insulator 599, for example. A protective layer 116 is provided over the conductor 111a to the conductor 111c, the conductor 112a to the conductor 112c, and the insulator 599. The protective layer 116 is formed to fill an opening portion of the insulator 599 whose bottom portion is regarded as the conductor 596. In particular, the protective layer 116 is preferably provided to cover end portions of the conductor 111a to the conductor 111c and the conductor 112a to the conductor 112c.

For example, a resin such as an acrylic resin, a polyimide resin, an epoxy resin, or a silicone resin is suitably used for the protective layer 116. Providing the protective layer 116 can inhibit a conductor 117a and a conductor 117b to be described later from being in contact with each other, that is, from being short-circuited. Note that depending on circumstances, the protective layer 116 is not necessarily provided over the insulator 599, the conductor 111a to the conductor 111c, and the conductor 112a to the conductor 112c.

Opening portions are formed in the protective layer 116 in regions partly overlapping with the conductor 111a to the conductor 111c and regions partly overlapping with the conductor 112a to the conductor 112c. The conductor 117a and the conductor 117b are provided over the protective layer 116. Specifically, the conductor 117a is provided to fill the opening portions of the protective layer 116 in the regions partly overlapping with the conductor 112a to the conductor 112c, and the conductor 117b is provided to fill the opening portions of the protective layer 116 in the regions partly overlapping with the conductor 111a to the conductor 111c.

For example, a conductive paste including a material such as silver, carbon, or copper or a bump including a material such as gold or solder can be suitably used for the conductor 117a and the conductor 117b. For each of the conductor 112a to the conductor 112c (the conductor 111a to the conductor 111c) and an electrode 172 (an electrode 173) to be described later, which are electrically connected to the conductor 117a (the conductor 117b), a conductive material having low contact resistance with the conductor 117a (the conductor 117b) is preferably used. For example, in the case where a silver paste is used for the conductor 117a (the conductor 117b), aluminum, titanium, or copper is used as the conductive material usable for the conductor 112a to the conductor 112c (the conductor 111a to the conductor 111c) and the electrode 172 (the electrode 173) to be described later, whereby the contact resistance with the conductor 117a (the conductor 117b) can be low. As another conductive material, for example, an alloy of silver, palladium, and copper (Ag—Pd—Cu (APC)) can also reduce the contact resistance with the conductor 117a (the conductor 117b).

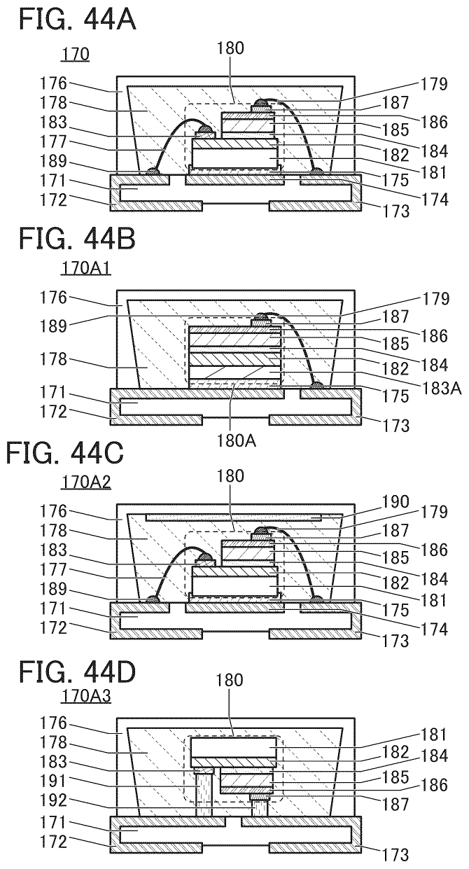

The LED package 170R, the LED package 170G, and the LED package 170B are provided over the conductor 117a and the conductor 117b. Note that FIG. 44A illustrates specific structure examples of the LED package 170R, the LED package 170G, and the LED package 170B included in the display apparatus DSP2F in FIG. 43.

The LED package 170 in FIG. 44A includes a substrate 171, the electrode 172, the electrode 173, a heat sink 174, an adhesive layer 175, a case 176, a wire 177, a wire 179, a sealing layer 178, a ball 189, and an LED chip 180.

In this specification and the like, an LED chip is a light-emitting diode in which an electrode serving as a cathode, an electrode serving as an anode, a p-type semiconductor, an n-type semiconductor, and a light-emitting layer are provided over a substrate. Note that in this specification and the like, the term “LED chip” can be replaced with the term “light-emitting diode” in the description in some cases.

Specifically, in this specification and the like, a light-emitting diode whose LED chip area is less than or equal to 10000 μm² is referred to as a micro light-emitting diode, a light-emitting diode whose LED chip area is greater than 10000 μm² and less than or equal to 1 mm² is referred to as a mini light-emitting diode, and a light-emitting diode whose LED chip area is greater than 1 mm² is referred to as a macro light-emitting diode in some cases. Note that the area of an LED chip here can be, for example, the area of the upper surface or the bottom surface of a substrate 181 in FIG. 44C and FIG. 44D described later and FIG. 44A. Alternatively, the area of an LED chip can be, for example, the area of the upper surface or the bottom surface of an electrode 183A in FIG. 44B described later.

For example, a light-emitting diode whose LED chip area is less than or equal to 100 μm² can be referred to as a micro light-emitting diode (micro LED chip). As a light-emitting diode usable for an LED package with an area of 1 mm², a micro LED chip or a mini LED chip can be used in some cases, for example.

Any of a micro light-emitting diode, a mini light-emitting diode, and a macro light-emitting diode can be used for the LED package of the display apparatus of one embodiment of the present invention. In particular, the display apparatus of one embodiment of the present invention preferably includes a micro light-emitting diode or a mini light-emitting diode, and more preferably includes a micro light-emitting diode.

In particular, the area of a LED chip of the light-emitting diode is preferably less than or equal to 1 mm², further preferably less than or equal to 10000 μm², still further preferably less than or equal to 3000 μm², even further preferably less than or equal to 700 μm².

The area of a light-emitting region of the light-emitting diode is preferably less than or equal to 1 mm², further preferably less than or equal to 10000 μm², still further preferably less than or equal to 3000 μm², even further preferably less than or equal to 700 μm². Here, the area of the light-emitting region of the light-emitting diode is the area of the top surface or the bottom surface of a light-emitting layer 184 in FIG. 44B to FIG. 44D described later and FIG. 44A.

In this embodiment, in particular, an example where a micro light-emitting diode is used as a light-emitting diode is described. A micro light-emitting diode having a double heterojunction is described in this embodiment. Note that there is no particular limitation on the light-emitting diode, and for example, a micro light-emitting diode having a quantum well junction or a nanocolumn light-emitting diode may be used.

The LED chip 180 includes the substrate 181, a semiconductor layer 182, an electrode 183, the light-emitting layer 184, a semiconductor layer 185, an electrode 186, and an electrode 187.

As the substrate 171, a glass epoxy resin substrate, a polyimide substrate, a ceramic substrate, an alumina substrate, or an aluminum nitride substrate can be used, for example.

The electrode 172 and the electrode 173 are formed on the top surface, the side surfaces, and the bottom surface of the substrate 171. Specifically, the electrode 172 formed on the top surface, the side surface, and the bottom surface of the substrate 171 functions as one wiring. Similarly, the electrode 173 formed on the top surface, the side surface, and the bottom surface of the substrate 171 functions as another wiring. Note that electrical continuity is not established between the electrode 172 and the electrode 173.

The substrate 171 is provided with a heat sink 174. The heat sink 174 has a function of releasing heat generated in the LED chip 180, for example.

Note that the electrode 172, the electrode 173, and the heat sink 174 can be formed with the same material. For example, for each of the electrode 172, the electrode 173, and the heat sink 174, one element selected from nickel, copper, silver, platinum, and gold, or an alloy material containing any of the elements at 50% or higher can be used.

The electrode 172, the electrode 173, and the heat sink 174 can be formed in the same step.

The LED chip 180 is attached above the substrate 171 with the adhesive layer 175. Specifically, the substrate 181 of the LED chip 180 is provided to overlap with the heat sink 174 on the substrate 171, with the adhesive layer 175 positioned therebetween. There is no particular limitation on a material of the adhesive layer 175. For example, the use of an adhesive with conductivity as a material of the adhesive layer 175 can increase the heat dissipation property of the LED chip 180.

The substrate 181 can be a single crystal substrate such as a sapphire substrate, a silicon carbide substrate, a silicon substrate, or a gallium nitride substrate, for exa

In the LED chip 180, the semiconductor layer 182 is formed over the substrate 181. The electrode 183 is formed over part of the semiconductor layer 182, and the light-emitting layer 184 is formed over other part of the semiconductor layer 182. The semiconductor layer 185 is formed over the light-emitting layer 184, the electrode 186 is formed over the semiconductor layer 185, and the electrode 187 is formed over part of the electrode 186.

In the LED chip 180, the light-emitting layer 184 is sandwiched between the semiconductor layer 182 and the semiconductor layer 185. In the light-emitting layer 184, electrons and holes are combined to emit light. One of the semiconductor layer 182 and the semiconductor layer 185 is an n-type semiconductor layer, and the other of the semiconductor layer 182 and the semiconductor layer 185 is a p-type semiconductor layer. An n-type semiconductor layer, an i-type semiconductor layer, or a p-type semiconductor layer can be used as the light-emitting layer 184. That is, a semiconductor layer can be used as each of the semiconductor layer 182, the light-emitting layer 184, and the semiconductor layer 185. Note that the semiconductor layer 182, the light-emitting layer 184, and the semiconductor layer 185 are collectively referred to as an LED layer or a light-emitting diode in some cases.

The LED layer is formed to emit light such as red light, yellow light, green light, blue light, or ultraviolet light. There is no particular limitation on the structure of the LED layer; a homostructure, a heterostructure, a double-heterostructure, or the like having a PN junction or a PIN junction may be used or a MIS (Metal Insulator Semiconductor) junction may be used. The LED layer may have a superlattice structure, a single quantum well structure, or a multi quantum well (MQW) structure. Alternatively, a nanocolumn may be used in the LED layer.

A compound containing a Group 13 element and a Group 15 element can be used for the LED layer, for example. Examples of the Group 13 element include aluminum, gallium, and indium. Examples of the Group 15 element include nitrogen, phosphorus, arsenic, and antimony. For the LED layer, for example, a compound of gallium and phosphorus, a compound of gallium and arsenic, a compound of gallium, aluminum, and arsenic, a compound of aluminum, gallium, indium, and phosphorus, gallium nitride (GaN), a compound of indium and gallium nitride, or a compound of selenium and zinc can be used.

For example, gallium nitride can be used for an LED layer that emits light in the ultraviolet wavelength range to the blue wavelength range. A compound of indium and gallium nitride can be used for an LED layer that emits light in the ultraviolet wavelength range to the green wavelength range. A compound of aluminum, gallium, indium, and phosphorus or a compound of gallium and arsenic can be used for an LED layer that emits light in the green wavelength range to the red wavelength range. A compound of gallium and arsenic can be used for an LED layer that emits light in the infrared wavelength range.

In the display apparatus DSP2F in FIG. 43, a light-emitting diode included in an LED chip of each of the LED package 170R, the LED package 170G, and the LED package 170B has a stacked-layer structure of a pair of semiconductor layers and a light-emitting layer between the pair of semiconductor layers, and emits red light, green light, or blue light. Thus, the colors of light emitted from the light-emitting diodes of the LED chips can be freely determined separately in the LED package 170R, the LED package 170G, and the LED package 170B.

The colors of light emitted from the light-emitting diodes included in the LED chips 180 of the LED packages 170 can be cyan, magenta, yellow, and white in addition to red, green, and blue.

The electrode 183 is electrically connected to the electrode 172 through the wire 177. That is, the electrode 183 functions as a pixel electrode of the light-emitting diode. The electrode 187 is electrically connected to the electrode 173 through the wire 179. That is, the electrode 187 functions as a common electrode of the light-emitting diode.

A wire bonding method can be used as a method of bonding the electrode 183 and the wire 177, a method of bonding the electrode 172 and the wire 177, a method of bonding the electrode 187 and the wire 179, and a method of bonding the electrode 173 and the wire 179, for example. A thermocompression bonding method and an ultrasonic bonding method are kinds of the wire bonding method. In a step of bonding the wire 177 and the wire 179 by the wire bonding method, the ball 189 made of the same material as the wire 179 is formed over the electrode 172, the electrode 173, the electrode 183, and the electrode 187.

For example, a material usable for the conductor 111a to the conductor 111c or the conductor 112a to the conductor 112c is preferably used for each of the electrode 183, the electrode 186, and the electrode 187. In particular, since the light-emitting layer 184 of the LED chip 180 emits light to the upside of the LED package 170, the electrode 186 is preferably a light-transmitting conductor among the materials usable for each of the conductor 111a to the conductor 111c and the conductor 112a to the conductor 112c. For the same reason, the electrode 187 is preferably a light-transmitting conductive material among the materials usable for each of the conductor 111a to the conductor 111c and the conductor 112a to the conductor 112c.

As the wire 177 and the wire 179, a thin metal wire of gold, an alloy containing gold, copper, or an alloy containing copper can be used, for example.

A resin can be used as the material of the case 176. The case 176 does not necessarily cover the top surface of the LED chip 180 as long as the case 176 covers the side surface of the sealing layer 178. That is, for example, the sealing layer 178 may be exposed from the top surface of the LED chip 180. The inner side surface of the case 176, specifically, the periphery of the LED chip 180 (peripheries of the substrate 181, the semiconductor layer 182, the electrode 183, the light-emitting layer 184, the semiconductor layer 185, the electrode 186, and the electrode 187) is preferably provided with a reflector made of ceramics or the like. Part of light emitted by the light-emitting layer 184 of the LED chip 180 is reflected by the reflector, so that a larger amount of light can be extracted from the LED package 170.

The inside of the case 176 is filled with the sealing layer 178. For the sealing layer 178, a resin having a property of transmitting visible light is preferably used. Specifically, for the sealing layer 178, for example, an ultraviolet curable resin such as an epoxy resin or a silicone resin or a visible light curable resin can be used.

A variety of optical members can be provided on surfaces of a resin layer 148, the LED package 170R, the LED package 170G, and the LED package 170B, for example, in the display apparatus DSP2F. Examples of the optical members include a polarizing plate, a retardation plate, a light diffusion layer (e.g., a diffusion film), an anti-reflective layer, and a light-condensing film. The surfaces of the resin layer 148, the LED package 170R, the LED package 170G, and the LED package 170B, for example, in the display apparatus DSP2F may be provided with a surface protective layer such as an antistatic film suppressing the attachment of a foreign substance, a water repellent film suppressing the attachment of stain, a hard coat film suppressing generation of a scratch in use, or an impact absorption layer. For example, it is preferable to provide, as the surface protective layer, a glass layer or a silica layer (SiOₓ layer) because the surface contamination or damage can be inhibited from being generated. For the surface protective layer, DLC (diamond-like carbon), aluminum oxide (AlOₓ), a polyester-based material, a polycarbonate-based material, or the like may be used. For the surface protective layer, a material having a high transmitting property with respect to visible light is preferably used. For the surface protective layer, a material with high hardness is preferably used.

Next, a structure example of an LED package which can be used as the LED package 170R, the LED package 170G, and the LED package 170B of the display apparatus DSP2F and is different from the LED package 170 in FIG. 44A is described.

An LED package 170A1 illustrated in FIG. 44B is different from the LED package 170 in FIG. 44A in that an LED chip 180A is provided over the substrate 171. Note that a pixel electrode of the LED chip 180A is bonded not with the wire 177 but with the adhesive layer 175.

The LED package 170A1 in FIG. 44B includes the substrate 171, the electrode 172, the electrode 173, the adhesive layer 175, the case 176, the wire 177, the wire 179, the sealing layer 178, the ball 189, and the LED chip 180A.

In the LED package 170A1 in FIG. 44B, the LED chip 180A includes the electrode 183A and a light-emitting diode provided over the electrode 183A. The light-emitting diode includes the semiconductor layer 182, the light-emitting layer 184, the semiconductor layer 185, the electrode 186, and the electrode 187.

As the electrode 183A, a conductive substrate can be used, for example. As a kind of the conductive substrate, a metal substrate is given, for example.

The semiconductor layer 182, the light-emitting layer 184, the semiconductor layer 185, the electrode 186, and the electrode 187 are formed in this order over the electrode 183A. For the semiconductor layer 182, the light-emitting layer 184, the semiconductor layer 185, the electrode 186, and the electrode 187, description of the LED package 170 in FIG. 44A is referred to.

In the LED package 170A1 in FIG. 44B, the electrode 172 and the electrode 173 are formed on the top surface, the side surfaces, and the bottom surface of the substrate 171. In particular, the electrode 172 is also provided in a region of the substrate 171 where the LED chip 180A is provided. The electrode 172 formed on the top surface, the side surface, and the bottom surface of the substrate 171 functions as one wiring. Similarly, the electrode 173 formed on the top surface, the side surface, and the bottom surface of the substrate 171 functions as another wiring. Note that electrical continuity is not established between the electrode 172 and the electrode 173.

The LED chip 180A is attached above the substrate 171 with the adhesive layer 175. Specifically, the electrode 183A of the LED chip 180A is provided to overlap with a region of the electrode 172 provided on the substrate 171, with the adhesive layer 175 positioned therebetween. Note that the adhesive layer 175 is an adhesive having conductivity.

As described above, in the case where the LED chip 180A in which the light-emitting diode is formed over the conductive substrate is employed, the pixel electrode of the LED chip 180A and the electrode 172 of the substrate 171 are attached not with the wire 177 but with the adhesive layer 175, whereby an LED package 170A2 can be formed.

Next, a structure example of an LED package which can be used as the LED package 170R, the LED package 170G, and the LED package 170B of the display apparatus DSP2F and is different from the LED package 170 in FIG. 44A and the LED package 170A1 in FIG. 44B is described.

The LED package 170A2 illustrated in FIG. 44C is different from the LED package in FIG. 44A in that a color conversion layer 190 is provided inside the case 176.

Note that although a structure in which the color conversion layer 190 is provided above the sealing layer 178 is illustrated in FIG. 44C, the position of the color conversion layer 190 is not limited thereto. For example, the color conversion layer 190 may be separated inside the sealing layer 178.

As the color conversion layer 190, a phosphor or a quantum dot (QD) is preferably used. In particular, a quantum dot has an emission spectrum with a narrow peak, so that emission with high color purity can be obtained. The use of a quantum dot for the color conversion layer 190 can improve the display quality of the display apparatus DSP2F.

The color conversion layer 190 has a function of converting light emitted by the light-emitting layer 184 included in the LED chip 180 of the LED package 170A2 into light of another color.

For example, as the color conversion layer 190, a color conversion layer converting blue light into green light or a conversion layer converting blue light into red light can be used. For example, in the case where a blue light-emitting diode is provided in a red subpixel, blue light emitted by the blue light-emitting diode passes through the color conversion layer 190, thereby being converted into red light and emitted to the upside of the case 176, that is, the outside of the display apparatus DSP2F. For example, in the case where a blue light-emitting diode is provided in a green subpixel, blue light emitted by the blue light-emitting diode passes through the color conversion layer 190, thereby being converted into green light and emitted to the upside of the case 176, that is, the outside of the display apparatus DSP2F.

The color conversion layer 190 can be formed by a droplet discharge method (e.g., an ink-jet method), a coating method, an imprinting method, a variety of printing methods (screen printing or offset printing), or the like. Alternatively, for the color conversion layer 190, a color conversion film such as a quantum dot film can be used.

As the phosphor, an organic resin layer having a surface on which a phosphor is printed or which is coated with a phosphor or an organic resin layer mixed with a phosphor can be used.

There is no limitation on a material of quantum dots, and examples include a Group 14 element, a Group 15 element, a Group 16 element, a compound of a plurality of Group 14 elements, a compound of an element belonging to any of Group 4 to Group 14 and a Group 16 element, a compound of a Group 2 element and a Group 16 element, a compound of a Group 13 element and a Group 15 element, a compound of a Group 13 element and a Group 17 element, a compound of a Group 14 element and a Group 15 element, a compound of a Group 11 element and a Group 17 element, iron oxides, titanium oxides, spinel chalcogenides, and semiconductor clusters.

Specific examples include cadmium selenide; cadmium sulfide; cadmium telluride; zinc selenide; zinc oxide; zinc sulfide; zinc telluride; mercury sulfide; mercury selenide; mercury telluride; indium arsenide; indium phosphide; gallium arsenide; gallium phosphide; indium nitride; gallium nitride; indium antimonide; gallium antimonide; aluminum phosphide; aluminum arsenide; aluminum antimonide; lead selenide; lead telluride; lead sulfide; indium selenide; indium telluride; indium sulfide; gallium selenide; arsenic sulfide; arsenic selenide; arsenic telluride; antimony sulfide; antimony selenide; antimony telluride; bismuth sulfide; bismuth selenide; bismuth telluride; silicon; silicon carbide; germanium; tin; selenium; tellurium; boron; carbon; phosphorus; boron nitride; boron phosphide; boron arsenide; aluminum nitride; aluminum sulfide; barium sulfide; barium selenide; barium telluride; calcium sulfide; calcium selenide; calcium telluride; beryllium sulfide; beryllium selenide; beryllium telluride; magnesium sulfide; magnesium selenide; germanium sulfide; germanium selenide; germanium telluride; tin sulfide; tin selenide; tin telluride; lead oxide; copper fluoride; copper chloride; copper bromide; copper iodide; copper oxide; copper selenide; nickel oxide; cobalt oxide; cobalt sulfide; iron oxide; iron sulfide; manganese oxide; molybdenum sulfide; vanadium oxide; tungsten oxide; tantalum oxide; titanium oxide; zirconium oxide; silicon nitride; germanium nitride; aluminum oxide; barium titanate; a compound of selenium, zinc, and cadmium; a compound of indium, arsenic, and phosphorus; a compound of cadmium, selenium, and sulfur; a compound of cadmium, selenium, and tellurium; a compound of indium, gallium, and arsenic; a compound of indium, gallium, and selenium; a compound of indium, selenium, and sulfur; a compound of copper, indium, and sulfur; and combinations thereof. What is called an alloyed quantum dot, whose composition is represented by a given ratio, may be used.

Examples of the quantum dot include a core-type quantum dot, a core-shell quantum dot, and a core-multishell quantum dot. Quantum dots have a high proportion of surface atoms and thus have high reactivity and easily cohere together. For this reason, it is preferable that a protective agent be attached to, or a protective group be provided at the surfaces of quantum dots. The attachment of the protective agent or the provision of the protective group can prevent cohesion and increase solubility in a solvent. It can also reduce reactivity and improve electrical stability.

Since band gaps of quantum dots are increased as their size (diameter) is decreased, the size is adjusted as appropriate so that light with a desired wavelength can be obtained. Light emission from the quantum dots is shifted to a blue color side, i.e., a high energy side, as the crystal size is decreased; thus, emission wavelengths of the quantum dots can be adjusted over a wavelength range in the spectrum of an ultraviolet region, a visible light region, and an infrared region by changing the size of quantum dots. The size (diameter) of quantum dots is, for example, greater than or equal to 0.5 nm and less than or equal to 20 nm, preferably greater than or equal to 1 nm and less than or equal to 10 nm. The emission spectra are narrowed as the size distribution of quantum dots gets smaller, and thus light can be obtained with high color purity. The shape of quantum dots is not particularly limited and may be a spherical shape, a rod shape, a circular shape, or other shapes. A quantum rod, which is a rod-shaped quantum dot, has a function of emitting directional light.

Alternatively, a stacked-layer structure of the color conversion layer 190 and a coloring layer may be provided inside or above the LED package 170A2. Thus, light that has been converted by the color conversion layer 190 passes through the coloring layer, whereby the color purity of light can be increased. A coloring layer of the same color as light emitted by the light-emitting layer 184 may be provided in a position overlapping with the LED chip 180 (the substrate 181, the semiconductor layer 182, the electrode 183, the light-emitting layer 184, the semiconductor layer 185, the electrode 186, and the electrode 187). Providing a coloring layer of the same color can increase the color purity of light emitted by the light-emitting layer 184. Furthermore, in the case where a coloring layer is not provided in the LED package 170A2, the manufacturing process can be simplified.

The coloring layer is a colored layer that transmits light in a specific wavelength range. For example, a color filter for transmitting light in a red, green, blue, or yellow wavelength range can be used. Examples of a material that can be used for the coloring layer include a metal material, a resin material, and a resin material containing a pigment or dye.

As described above, the color conversion layer provided above the LED chip 180 enables the LED package 170A2 to emit light with a high color purity.

Next, a structure example of an LED package which can be used as the LED package 170R, the LED package 170G, and the LED package 170B of the display apparatus DSP2F and is different from the LED package 170 in FIG. 44A, the LED package 170A1 in FIG. 44B, and the LED package 170A2 in FIG. 44C is described.

An LED package 170A3 illustrated in FIG. 44D is different from the LED package 170 in FIG. 44A in that the substrate 181 of the LED chip 180 provided over the substrate 171 is positioned in an upper portion, and the electrode 183 and the electrode 187 are positioned in a lower portion.

With this structure, light emitted by the light-emitting layer 184 is emitted to the upside of the LED package 170A3; thus, the substrate 181 preferably has a light-transmitting property.

In the LED package 170A3 in FIG. 44D, since the electrode 183 and the electrode 187 in the LED chip 180 face the substrate 171 side, bonding between the electrode 183 and the electrode 172 and bonding between the electrode 187 and the electrode 173 are performed not by a wire but by a conductor serving as a bump. Specifically, the electrode 183 and the electrode 172 are bonded by a conductor 191, and the electrode 187 and the electrode 173 are bonded by a conductor 192.

For the conductor 191 and the conductor 192, a material usable for the conductor 117a or the conductor 117b can be used.

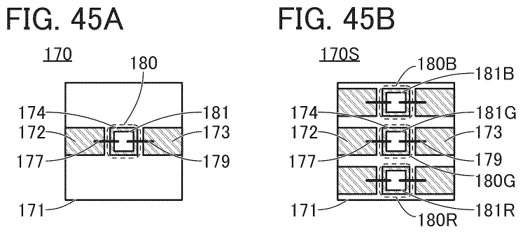

Next, the number of LED chips 180 that can be provided in the LED package 170 is described. FIG. 45A is an example of a schematic plan view of the LED package 170 in FIG. 44A. FIG. 45A illustrates the substrate 181 which is a component of the LED chip 180. Although the LED package 170 including one LED chip 180 over the substrate 171 is described above as an example as illustrated in FIG. 45A, one embodiment of the present invention is not limited to this structure. For example, the LED package 170 may include not one LED chip but a plurality of LED chips over the substrate 171.

FIG. 45B illustrates a structure of an LED package 170S in which three LED chips 180R, 180G, and 180B are provided over the substrate 171. FIG. 45B illustrates a substrate 181R which is a component of the LED chip 180R, a substrate 181G which is a component of the LED chip 180G, and a substrate 181B which is a component of the LED chip 180B. Light-emitting layers of light-emitting diodes included in the LED chip 180R, the LED chip 180G, and the LED chip 180B provided in the LED package 170S may emit light of different colors. For example, the substrate 181R is provided with a light-emitting diode emitting red light, the substrate 181G is provided with a light-emitting diode emitting green light, and the substrate 181B is provided with a light-emitting diode emitting blue light, whereby the LED package 170S can emit light of three colors, red, green, and blue.

The light-emitting diodes (the LED chip 180R, the LED chip 180G, and the LED chip 180B) in the LED package 170, the LED package 170A1, the LED package 170A2, and the LED package 170S, which are described above, may be driven by transistors with the same structure, or may be driven by transistors with different structures. For example, in the display apparatus DSP2F in FIG. 43, a transistor that drives the LED chip 180R included in the LED package 170R, a transistor that drives the LED chip 180G included in the LED package 170G, and a transistor that drives the LED chip 180B included in the LED package 170B may be different from one another in one or more selected from a transistor size, a channel length, a channel width, and a structure. Specifically, depending on the amount of current required for light emission with desired luminance, one or both of the channel length and the channel width of the transistor may be changed for each color.

In the display apparatus DSP2F in FIG. 43, the top surface of the protective layer 116, the top surface and side surface of the conductor 117a, the top surface and side surface of the conductor 117b, and the side surfaces of the LED package 170R, the LED package 170G, and the LED package 170B may be covered with the resin layer 148. Use of a black resin for the resin layer 148 can enhance the display contrast of the display apparatus DSP2F. One or more selected from the top surface of the resin layer 148 and the top surfaces of the LED package 170R, the LED package 170G, and the LED package 170B may be provided with a surface protective layer, an impact absorption layer, or both. Since each of the LED package 170R, the LED package 170G, and the LED package 170B has a structure in which light is emitted upward, a layer provided on each of the top surfaces of the LED package 170R, the LED package 170G, and the LED package 170B preferably has a visible-light-transmitting property.

All the conductor 112a to the conductor 112c, the conductor 117a, and the electrode 172 in the LED package 170R, the LED package 170G, and the LED package 170B are referred to as pixel electrodes in some cases. Furthermore, parts of the conductor 112a to the conductor 112c, the conductor 117a, and the electrode 172 are referred to as pixel electrodes in some cases.

Note that the structure of the display apparatus of one embodiment of the present invention is not limited to the structure of the display apparatus DSP2F illustrated in FIG. 43.

The display apparatus of one embodiment of the present invention may have the structure of the display apparatus DSP2F illustrated in FIG. 43 which is modified as appropriate.

For example, the display apparatus of one embodiment of the present invention may have not a structure in which a plurality of LED packages 170 are mounted above the substrate 310 but a structure in which a substrate provided with a plurality of light-emitting diodes are attached above the substrate 310 (not illustrated).

Although the display apparatus DSP2F illustrated in FIG. 43 is provided with the LED packages exhibiting a plurality of colors, the whole display portion may be formed of LED packages exhibiting a single color, for example.

When one of the above structure examples is applied to a display apparatus, the display apparatus having high screen resolution and high definition can be achieved in some cases. Specifically, for example, a display apparatus with a screen resolution of HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320) can be achieved in some cases. Furthermore, specifically, for example, a display apparatus with a definition of greater than or equal to 100 ppi, greater than or equal to 300 ppi, greater than or equal to 500 ppi, greater than or equal to 1000 ppi, greater than or equal to 2000 ppi, greater than or equal to 3000 ppi, greater than or equal to 5000 ppi, or greater than or equal to 6000 ppi can be achieved in some cases.

### <Structure Example of Light-Emitting Device>

Next, a structure example of a light-emitting device that can be used as the light-emitting device 130 of the above-described display apparatus is described.

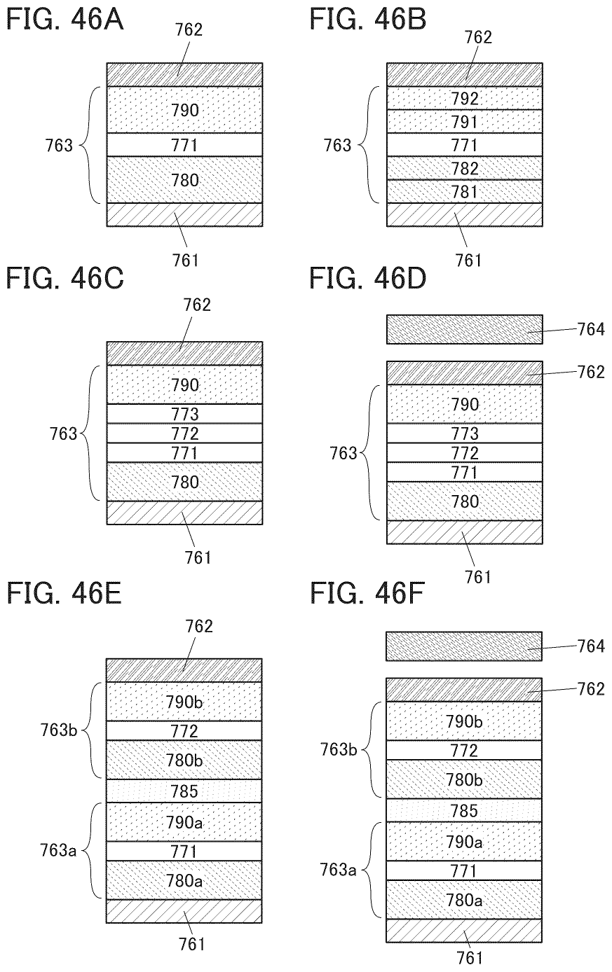

As illustrated in FIG. 46A, the light-emitting device includes an EL layer 763 between a pair of electrodes (a lower electrode 761 and an upper electrode 762). The EL layer 763 can be a layer including a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance with a high hole-injection property (a hole-injection layer), a layer containing a substance with a high hole-transport property (a hole-transport layer), and a layer containing a substance with a high electron-blocking property (an electron-blocking layer). Furthermore, the layer 790 includes one or more of a layer containing a substance with a high electron-injection property (an electron-injection layer), a layer containing a substance with a high electron-transport property (an electron-transport layer), and a layer containing a substance with a high hole-blocking property (a hole-blocking layer). In the case where the lower electrode 761 is a cathode and the upper electrode 762 is an anode, the above structures of the layer 780 and the layer 790 are replaced with each other.

The structure including the layer 780, the light-emitting layer 771, and the layer 790, which is provided between a pair of electrodes, can function as a single light-emitting unit, and the structure in FIG. 46A is referred to as a single structure in this specification.

FIG. 46B is a modification example of the EL layer 763 included in the light-emitting device illustrated in FIG. 46A. Specifically, the light-emitting device illustrated in FIG. 46B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected to the light-emitting layer 771, and the efficiency of the recombination of carriers in the light-emitting layer 771 can be increased.

Note that structures in which a plurality of light-emitting layers (the light-emitting layer 771, a light-emitting layer 772, and a light-emitting layer 773) are provided between the layer 780 and the layer 790 as illustrated in FIG. 46C and FIG. 46D are variations of the single structure. Although FIG. 46C and FIG. 46D illustrate the examples where three light-emitting layers are included, the light-emitting device having a single structure may include two or four or more light-emitting layers. In addition, the light-emitting device having a single structure may include a buffer layer between two light-emitting layers.

A structure in which a plurality of light-emitting units (a light-emitting unit 763a and a light-emitting unit 763b) are connected in series with a charge-generation layer 785 (also referred to as an intermediate layer) therebetween as illustrated in FIG. 46E and FIG. 46F is referred to as a tandem structure in this specification. Note that the tandem structure may be referred to as a stack structure. The tandem structure enables a light-emitting device capable of high-luminance light emission. Furthermore, the tandem structure reduces the amount of current needed for obtaining the same luminance as compared with a single structure, and thus can improve the reliability.

Note that FIG. 46D and FIG. 46F illustrate examples where the display apparatus includes a layer 764 overlapping with the light-emitting device. FIG. 46D illustrates an example where the layer 764 overlaps with the light-emitting device illustrated in FIG. 46C, and FIG. 46F illustrates an example where the layer 764 overlaps with the light-emitting device illustrated in FIG. 46E.

One or both of a color conversion layer and a color filter (coloring layer) can be used as the layer 764.

In FIG. 46C and FIG. 46D, light-emitting substances that emit light of the same color, or moreover, the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In a subpixel that emits red light and a subpixel that emits green light, by providing a color conversion layer as the layer 764 illustrated in FIG. 46D, blue light emitted from the light-emitting device can be converted into light with a longer wavelength, and red light or green light can be extracted.

Alternatively, light-emitting substances that emit light of different colors may be used for the light-emitting layer 771, the light-emitting layer 772, and the light-emitting layer 773. In particular, the light-emitting device preferably enables white light emission by combining light emitted by the light-emitting layer 771, the light-emitting layer 772, and the light-emitting layer 773. The light-emitting device having a single structure preferably includes a light-emitting layer containing a light-emitting substance that emits blue light and a light-emitting layer containing a light-emitting substance that emits visible light with a longer wavelength than blue light, for example.

In the case where the light-emitting device having a single structure includes three light-emitting layers, for example, a light-emitting layer containing a light-emitting substance that emits red (R) light, a light-emitting layer containing a light-emitting substance that emits green (G) light, and a light-emitting layer containing a light-emitting substance that emits blue (B) light are preferably included. The stacking order of the light-emitting layers can be, for example, a red (R) light-emitting layer, a green (G) light-emitting layer, and a blue (B) light-emitting layer from the anode side, or a red (R) light-emitting layer, a blue (B) light-emitting layer, and a green (G) light-emitting layer from the anode side. At this time, a buffer layer may be provided between a red (R) light-emitting layer and a green (G) light-emitting layer or between a red (R) light-emitting layer and a blue (B) light-emitting layer.

For example, in the case where the light-emitting device having a single structure includes two light-emitting layers, the light-emitting device preferably includes a light-emitting layer containing a light-emitting substance that emits blue (B) light and a light-emitting layer containing a light-emitting substance that emits yellow (Y) light. Such a structure may be referred to as a BY single structure.

A color filter may be provided as the layer 764 illustrated in FIG. 46D. When white light passes through the color filter, light of a desired color can be obtained.

The light-emitting device that emits white light preferably contains two or more kinds of light-emitting substances. To obtain white light emission, two light-emitting substances may be selected such that the emission colors of the two light-emitting substances are complementary colors. For example, when an emission color of a first light-emitting layer and an emission color of a second light-emitting layer are complementary colors, the light-emitting device can be configured to emit white light as a whole. To obtain white light emission by using three or more light-emitting layers, the light-emitting device is configured to emit white light as a whole by combining emission colors of the three or more light-emitting layers.

In FIG. 46E and FIG. 46F, light-emitting substances that emit light of the same color, or moreover, the same light-emitting substance may be used for the light-emitting layer 771 and the light-emitting layer 772.

For example, in light-emitting devices included in subpixels emitting light of different colors, a light-emitting substance that emits blue light may be used for each of the light-emitting layer 771 and the light-emitting layer 772. In a subpixel that emits blue light, blue light emitted from the light-emitting device can be extracted. In the subpixel that emits red light and the subpixel that emits green light, by providing a color conversion layer as the layer 764 illustrated in FIG. 46F, blue light emitted from the light-emitting device can be converted into light with a longer wavelength, and red light or green light can be extracted.

In the case where the light-emitting device having the structure illustrated in FIG. 46E or FIG. 46F is used for the subpixels emitting different colors, the subpixels may use different light-emitting substances. Specifically, in the light-emitting device included in the subpixel emitting red light, a light-emitting substance that emits red light may be used for each of the light-emitting layer 771 and the light-emitting layer 772. Similarly, in the light-emitting device included in the subpixel emitting green light, a light-emitting substance that emits green light may be used for each of the light-emitting layer 771 and the light-emitting layer 772. In the light-emitting device included in the subpixel emitting blue light, a light-emitting substance that emits blue light may be used for each of the light-emitting layer 771 and the light-emitting layer 772. A display apparatus having such a structure can be regarded as employing a light-emitting device with the tandem structure and the SBS structure. Thus, advantages of both the tandem structure and the SBS structure can be achieved. Accordingly, a light-emitting device being capable of high-luminance light emission and having high reliability can be obtained.

In FIG. 46E and FIG. 46F, light-emitting substances that emit light of different colors may be used for the light-emitting layer 771 and the light-emitting layer 772. White light emission can be obtained when the light-emitting layer 771 and the light-emitting layer 772 emit light of complementary colors. A color filter may be provided as the layer 764 illustrated in FIG. 46F. When white light passes through the color filter, light of a desired color can be obtained.

Although FIG. 46E and FIG. 46F illustrate examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

In addition, although FIG. 46E and FIG. 46F each illustrate the light-emitting device including two light-emitting units as an example, one embodiment of the present invention is not limited thereto. The light-emitting device may include three or more light-emitting units.

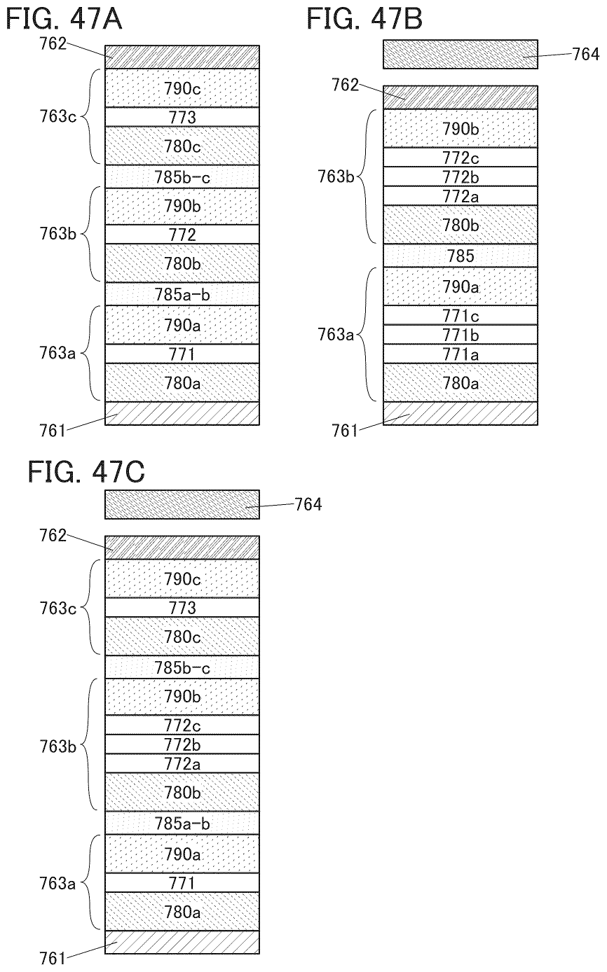

Specifically, structures of the light-emitting device illustrated in FIG. 47A to FIG. 47C can be given.

FIG. 47A illustrates a structure including three light-emitting units. Note that a structure including two light-emitting units and a structure including three light-emitting units may be referred to as a two-unit tandem structure and a three-unit tandem structure, respectively.

As illustrated in FIG. 47A, a plurality of light-emitting units (the light-emitting unit 763a, the light-emitting unit 763b, and a light-emitting unit 763c) are connected in series through charge-generation layers (a charge-generation layer 785a-b and a charge-generation layer 785b-c). Specifically, in the light-emitting device illustrated in FIG. 46A, the light-emitting unit 763a, the charge-generation layer 785a-b, the light-emitting unit 763b, the charge-generation layer 785b-c, and the light-emitting unit 763c are stacked in this order. The light-emitting unit 763a includes a layer 780a, the light-emitting layer 771, and a layer 790a. The light-emitting unit 763b includes a layer 780b, the light-emitting layer 772, and a layer 790b. The light-emitting unit 763c includes a layer 780c, the light-emitting layer 773, and a layer 790c.

For the charge-generation layer 785a-b and the charge-generation layer 785b-c, the above description of the charge-generation layer 785 can be referred to.

In the structure illustrated in FIG. 47A, the light-emitting layer 771, the light-emitting layer 772, and the light-emitting layer 773 preferably contain light-emitting substances that emit light of the same color. Specifically, the light-emitting layer 771, the light-emitting layer 772, and the light-emitting layer 773 can each contain a light-emitting substance that emits red (R) light (what is called an R\R\R three-unit tandem structure); the light-emitting layer 771, the light-emitting layer 772, and the light-emitting layer 773 can each contain a light-emitting substance that emits green (G) light (what is called a G\G\G three-unit tandem structure); or the light-emitting layer 771, the light-emitting layer 772, and the light-emitting layer 773 can each contain a light-emitting substance that emits blue (B) light (what is called a B\B\B three-unit tandem structure).

Note that the structure containing the light-emitting substances that emit light of the same color is not limited to the above structure. For example, a light-emitting device having a tandem structure may be employed in which light-emitting units each including a plurality of light-emitting substances are stacked as illustrated in FIG. 47B. FIG. 47B illustrates a structure in which a plurality of light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In the structure illustrated in FIG. 47B, white (W) light can be obtained by combining colors of light emitted by the light-emitting layer 771a, the light-emitting layer 771b, and the light-emitting layer 771c. In addition, white (W) light can be obtained by combining colors of light emitted by the light-emitting layer 772a, the light-emitting layer 772b, and the light-emitting layer 772c. That is, the structure illustrated in FIG. 47C is a two-unit tandem structure of WWW. Note that there is no particular limitation on the stacking order of the light-emitting substances of the light-emitting layer 771a, the light-emitting layer 771b, and the light-emitting layer 771c. The practitioner can select the optimal stacking order as appropriate. Although not illustrated, the structure may be a three-unit tandem structure of W\W\W or a tandem structure with four or more units.

In the case of using a light-emitting device having a tandem structure, the following structure can be given: a BY two-unit tandem structure including a light-emitting unit that emits yellow (Y) light and a light-emitting unit that emits blue (B) light; an RG\B two-unit tandem structure including a light-emitting unit that emits red (R) light and green (G) light and a light-emitting unit that emits blue (B) light; a B\Y\B three-unit tandem structure including a light-emitting unit that emits blue (B) light, a light-emitting unit that emits yellow (Y) light, and a light-emitting unit that emits blue (B) light in this order; a BYG\B three-unit tandem structure including a light-emitting unit that emits blue (B) light, a light-emitting unit that emits yellowish-green (YG) light, and a light-emitting unit that emits blue (B) light in this order; and a B\GIB three-unit tandem structure including a light-emitting unit that emits blue (B) light, a light-emitting unit that emits green (G) light, and a light-emitting unit that emits blue (B) light in this order.

As illustrated in FIG. 47C, a light-emitting unit including one light-emitting substance and a light-emitting unit including a plurality of light-emitting substances may be used in combination.

Specifically, in the structure illustrated in FIG. 47C, a plurality of light-emitting units (the light-emitting unit 763a, the light-emitting unit 763b, and the light-emitting unit 763c) are connected in series through the charge-generation layers (the charge-generation layer 785a-b and the charge-generation layer 785b-c). The light-emitting unit 763a includes the layer 780a, the light-emitting layer 771, and the layer 790a. The light-emitting unit 763b includes a layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 47C, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellowish-green (YG) light, and the light-emitting unit 763c is a light-emitting unit that emits blue (B) light can be employed.

Examples of the number of stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of light-emitting layers stacked in the light-emitting unit X and the order of colors from the anode side include a two-layer structure of R and Y, a two-layer structure of R and G, a two-layer structure of G and R, a three-layer structure of G, R, and G, and a three-layer structure of R, G, and R. Another layer may be provided between two light-emitting layers.

Also in FIG. 46C and FIG. 46D, the layer 780 and the layer 790 may each independently have a stacked-layer structure of two or more layers as illustrated in FIG. 46B.

In FIG. 46E and FIG. 46F, the light-emitting unit 763a includes the layer 780a, the light-emitting layer 771, and the layer 790a, and the light-emitting unit 763b includes the layer 780b, the light-emitting layer 772, and the layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are replaced with each other, and the structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of fabricating a light-emitting device having a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

Next, materials that can be used for the light-emitting device are described.

A conductive film transmitting visible light is used as the electrode through which light is extracted, which is either the lower electrode 761 or the upper electrode 762. A conductive film reflecting visible light is preferably used as the electrode through which light is not extracted. In the case where a display apparatus includes a light-emitting device emitting infrared light, it is preferable that a conductive film transmitting visible light and infrared light be used as the electrode through which light is extracted, and a conductive film reflecting visible light and infrared light be used as the electrode through which light is not extracted.

A conductive film transmitting visible light may be used as the electrode through which light is not extracted. In that case, the electrode is preferably placed between a reflective layer and the EL layer 763. In other words, light emitted from the EL layer 763 may be reflected by the reflective layer to be extracted from the display apparatus.

As a material that forms the pair of electrodes of the light-emitting device, a metal, an alloy, an electrically conductive compound, a mixture thereof, or the like can be used as appropriate. Specific examples of the material include metals such as aluminum, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Examples of the material include indium tin oxide (In—Sn oxide, also referred to as ITO), In—Si—Sn oxide (also referred to as ITSO), indium zinc oxide (In—Zn oxide), and In—W—Zn oxide. Another example of the material is an alloy containing aluminum (an aluminum alloy). An example of the alloy containing aluminum is an alloy (Al—Ni—La) of aluminum (Al), nickel (Ni), and lanthanum (La). Another example of the material is an alloy (Ag—Pd—Cu, also referred to as APC) of silver, palladium, and copper. Other example of the material include elements belonging to Group 1 or Group 2 of the periodic table, which are not exemplified above (e.g., lithium, cesium, calcium, and strontium), rare earth metals such as europium and ytterbium, an alloy containing any of these metals in appropriate combination, and graphene.

The light-emitting device preferably employs a microcavity structure. Therefore, one of the pair of electrodes of the light-emitting device preferably includes an electrode having properties of transmitting and reflecting visible light (a transflective electrode), and the other preferably includes an electrode having a property of reflecting visible light (a reflective electrode). When the light-emitting device has a microcavity structure, light obtained from the light-emitting layer can be resonated between the electrodes, whereby light emitted from the light-emitting device can be intensified.

The transflective electrode is preferably formed with, for example, a conductor having properties of transmitting and reflecting visible light. Alternatively, for example, the transflective electrode may have a stacked-layer structure of a conductive layer that can be used as a reflective electrode and a conductive layer that can be used as an electrode having a property of transmitting visible light (also referred to as a transparent electrode).

The transparent electrode has a light transmittance higher than or equal to 40%. For example, an electrode having a visible light (light with a wavelength longer than or equal to 400 nm and shorter than 750 nm) transmittance higher than or equal to 40% is preferably used as the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity less than or equal to 1×10⁻² Ωcm.

The light-emitting device includes at least the light-emitting layer. The light-emitting device may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, or a substance with a bipolar property (a substance with a high electron-transport property and a high hole-transport property). For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may be included. Each layer included in the light-emitting device can be formed by any of the following methods: an evaporation method (including a vacuum evaporation method), a transfer method, a printing method, an ink-jet method, and a coating method.

The light-emitting layer contains one or more kinds of light-emitting substances. As the light-emitting substance, for example, a substance exhibiting an emission color of blue, violet, bluish violet, green, yellowish green, yellow, orange, or red is used as appropriate. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material and an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material having a high hole-transport property which can be used for the hole-transport layer and will be described later. As the electron-transport material, it is possible to use a material having a high electron-transport property which can be used for the electron-transport layer and will be described later. Alternatively, as one or more kinds of organic compounds, a bipolar material or a TADF material may be used.

The light-emitting layer preferably contains a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination is selected to form an exciplex that exhibits light emission whose wavelength overlaps with the wavelength of the lowest-energy-side absorption band of the light-emitting substance, energy can be transferred smoothly and light emission can be obtained efficiently. With this structure, high efficiency, low-voltage driving, and a long lifetime of the light-emitting device can be achieved at the same time.

The hole-injection layer is a layer injecting holes from the anode to the hole-transport layer, and is a layer containing a material with a high hole-injection property. Examples of a material with a high hole-injection property include an aromatic amine compound and a composite material containing a hole-transport material and an acceptor material (electron-accepting material).

As the hole-transport material, it is possible to use a material having a high hole-transport property which can be used for the hole-transport layer and will be described later.

As the acceptor material, an oxide of a metal belonging to Group 4 to Group 8 of the periodic table can be used, for example. Specific examples of the oxide of the metal include molybdenum oxide, vanadium oxide, niobium oxide, tantalum oxide, chromium oxide, tungsten oxide, manganese oxide, and rhenium oxide. Among these, molybdenum oxide is particularly preferable since it is stable in the air, has a low hygroscopic property, and is easy to handle. An organic acceptor material containing fluorine can be used. An organic acceptor material such as a quinodimethane derivative, a chloranil derivative, or a hexaazatriphenylene derivative can be used.

As the material having a high hole-injection property, a material that contains a hole-transport material and the above-described oxide of a metal belonging to any of Group 4 to Group 8 of the periodic table (typically, molybdenum oxide) may be used, for example.

The hole-transport layer is a layer transporting holes injected from the anode by the hole-injection layer, to the light-emitting layer. The hole-transport layer is a layer containing a hole-transport material. As the hole-transport material, a substance having a hole mobility higher than or equal to 1×10⁶ cm²/Vs is preferable. Note that other substances can also be used as long as the substances have a hole-transport property higher than an electron-transport property. As the hole-transport material, a material with a high hole-transport property, such as a T-electron rich heteroaromatic compound (e.g., a carbazole derivative, a thiophene derivative, or a furan derivative) or an aromatic amine (a compound having an aromatic amine skeleton), is preferable.

The electron-blocking layer is provided in contact with the light-emitting layer. The electron-blocking layer has a hole-transport property and contains a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer transporting electrons injected from the cathode by the electron-injection layer, to the light-emitting layer. The electron-transport layer is a layer containing an electron-transport material. As the electron-transport material, a substance having an electron mobility higher than or equal to 1×10⁻⁶ cm²/Vs is preferable. Note that other substances can also be used as long as the substances have an electron-transport property higher than a hole-transport property. As the electron-transport material, any of the following materials with a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a x-electron deficient heteroaromatic compound such as a nitrogen-containing heteroaromatic compound.

The hole-blocking layer is provided in contact with the light-emitting layer. The hole-blocking layer has an electron-transport property and contains a material capable of blocking holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer injecting electrons from the cathode to the electron-transport layer, and is a layer containing a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The difference between the lowest unoccupied molecular orbital (LUMO) level of the material with a high electron-injection property and the work function value of the material used for the cathode is preferably small (specifically, smaller than or equal to 0.5 eV).

For the electron-injection layer, for example, an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato) lithium (abbreviation: Liq), 2-(2-pyridyl) phenolatolithium (abbreviation: LiPP), 2-(2-pyridyl)-3-pyridinolatolithium (abbreviation: LiPPy), 4-phenyl-2-(2-pyridyl) phenolatolithium (abbreviation: LiPPP), lithium oxide (LiOₓ), or cesium carbonate can be used. The electron-injection layer may have a stacked-layer structure of two or more layers. The stacked-layer structure can be, for example, a structure in which lithium fluoride is used for the first layer and ytterbium is used for the second layer.

The electron-injection layer may contain an electron-transport material. For example, a compound having an unshared electron pair and an electron deficient heteroaromatic ring can be used as the electron-transport material. Specifically, a compound having one or more selected from a pyridine ring, a diazine ring (e.g., a pyrimidine ring, a pyrazine ring, or a pyridazine ring), and a triazine ring can be used.

Note that the LUMO level of the organic compound having an unshared electron pair is preferably higher than or equal to −3.6 eV and lower than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino [2,3-a: 2′, 3′-c] phenazine (abbreviation: HATNA), or 2,4,6-tris[3′-(pyridin-3-yl)biphenyl-3-yl]-1,3,5-triazine (abbreviation: TmPPPyTz) can be used for the organic compound having an unshared electron pair. Note that NBPhen has a higher glass transition temperature (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the hole-injection layer.

The charge-generation layer preferably includes a layer containing a material having a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material that can be used for the electron-injection layer can be suitably used for the electron-injection buffer layer.

The charge-generation layer preferably includes a layer containing a material having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from each other in some cases on the basis of the cross-sectional shapes, the characteristics, or the like.

Note that the charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between two light-emitting units can inhibit an increase in driving voltage.

### <Structure Example of Pixel Circuit>

Here, structure examples of a pixel circuit that can be included in the display region DIS are described.

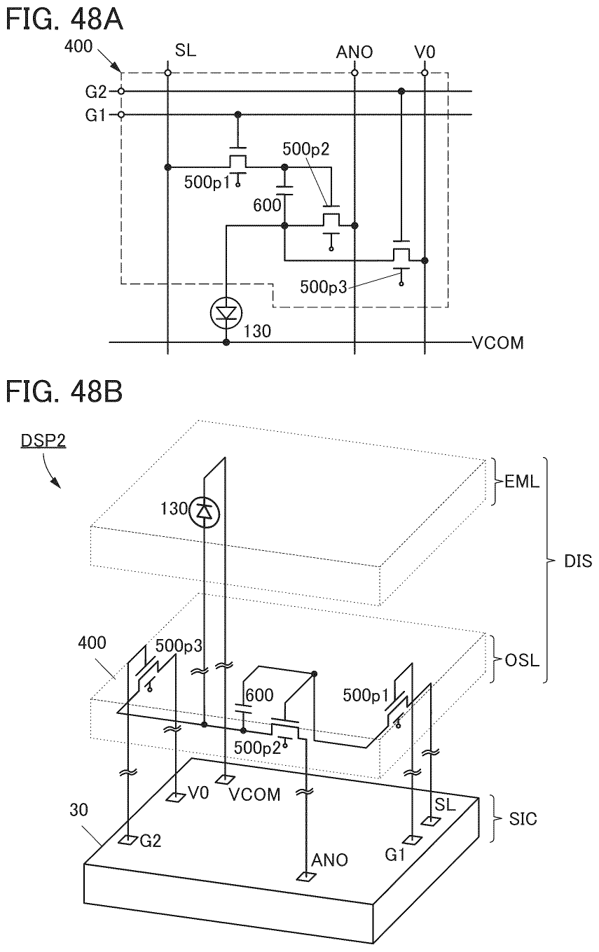

FIG. 48A and FIG. 48B illustrate a structure example of a pixel circuit that can be provided in the display region DIS and the light-emitting device 130 connected to the pixel circuit. FIG. 48A is a diagram illustrating connection of circuit elements included in a pixel circuit 400 included in the display region DIS, and FIG. 48B is a diagram schematically illustrating the vertical relation of the circuit region SIC including a driver circuit 30, a layer OSL including a plurality of transistors of the pixel circuit, and a layer EML including the light-emitting device 130. Note that the display region DIS of the display apparatus DSP2 illustrated in FIG. 48B includes the layer OSL and the layer EML, for example. A transistor 500p1, a transistor 500p2, and a transistor 500p3 included in the layer OSL illustrated in FIG. 48B correspond to the transistor 500p in FIG. 35 to FIG. 37 and FIG. 40 and the transistor 500Ap in FIG. 39, for example. The light-emitting device 130 included in the layer EML illustrated in FIG. 48B corresponds to the light-emitting device 130R, the light-emitting device 130G, or the light-emitting device 130B in FIG. 35, FIG. 36, FIG. 39, and FIG. 40, for example.

The pixel circuit 400 illustrated as an example in FIG. 48A and FIG. 48B includes the transistor 500p1, the transistor 500p2, the transistor 500p3, and a capacitor 600. The transistor 500p1, the transistor 500p2, and the transistor 500p3 can be, for example, transistors usable as the transistor 500 or the transistor 500A described above as examples. That is, the transistor 500p1, the transistor 500p2, and the transistor 500p3 can be OS transistors. Alternatively, the transistor 500p1, the transistor 500p2, and the transistor 500p3 can be, for example, Si transistors. In particular, in the case where the transistor 500p1, the transistor 500p2, and the transistor 500p3 are OS transistors, each of the transistor 500p1, the transistor 500p2, and the transistor 500p3 preferably includes a back gate electrode, in which case the structure in which the back gate electrode is supplied with the same signals as those supplied to the gate or the structure in which the back gate electrode is supplied with signals different from those supplied to the gate can be used. Although each of the transistor 500p1, the transistor 500p2, and the transistor 500p3 illustrated in FIG. 48A and FIG. 48B includes a back gate electrode, each of the transistor 500p1, the transistor 500p2, and the transistor 500p3 does not necessarily include a back gate electrode.

One or more selected from the transistor 500p1 to the transistor 500p3 may be OS transistors and the others may be Si transistors. In particular, in this specification and the like, a circuit including an OS transistor and a Si transistor is referred to as LTPO in some cases.

The transistor 500p2 includes a gate electrode electrically connected to the transistor 500p1, a first electrode electrically connected to the light-emitting device 130, and a second electrode electrically connected to a wiring ANO. The wiring ANO is a wiring for supplying a potential for supplying current to the light-emitting device 130.

The transistor 500p1 includes a first terminal electrically connected to the gate electrode of the transistor 500p2, a second terminal electrically connected to the wiring SL functioning as a source line, and the gate electrode having a function of controlling switching of the on state and the off state on the basis of the potential of a wiring G1 functioning as a gate line.

The transistor 500p3 includes a first terminal electrically connected to a wiring VO, a second terminal electrically connected to the light-emitting device 130, and the gate electrode having a function of controlling switching of the on state and the off state on the basis of the potential of a wiring G2 functioning as a gate line. The wiring VO is a wiring for supplying a reference potential and a wiring for outputting a current flowing through the pixel circuit 400 to the driver circuit 30.

The capacitor 600 includes a conductive film electrically connected to the gate electrode of the transistor 500p2 and a conductive film electrically connected to a second electrode of the transistor 500p3.

The light-emitting device 130 includes a first electrode electrically connected to the first electrode of the transistor 500p2 and a second electrode electrically connected to a wiring VCOM. The wiring VCOM is a wiring for supplying a potential for supplying current to the light-emitting device 130.

Accordingly, the intensity of light emitted from the light-emitting device 130 can be controlled in accordance with an image signal supplied to the gate electrode of the transistor 500p2. Furthermore, variations in the gate-source voltage of the transistor 500p2 can be inhibited by the reference potential of the wiring VO supplied through the transistor 500p3.

A current value that can be used for setting pixel parameters can be output from the wiring VO. Specifically, the wiring VO can function as a monitor line for outputting a current flowing through the transistor 500p2 or a current flowing through the light-emitting device 130 to the outside. A current output to the wiring VO is converted into a voltage by, for example, a source follower circuit and output to the outside. Alternatively, for example, a current output to the wiring VO can be converted into a digital signal by an A-D converter or the like and output to the AI accelerator included in the functional circuit region MFNC, which is described in the above embodiment.

Note that in the structure illustrated as an example in FIG. 48B, the wirings electrically connecting the pixel circuit 400 and the driver circuit 30 can be shortened, so that wiring resistance of the wirings can be reduced. Thus, data writing can be performed at high speed, leading to high-speed driving of the display apparatus DSP2. Therefore, even when the number of pixel circuits 400 included in the display apparatus DSP2 is large, a sufficiently long frame period can be ensured and thus the pixel density of the display apparatus DSP2 can be increased. In addition, the increased pixel density of the display apparatus DSP2 can increase the resolution of an image displayed by the display apparatus DSP2. For example, the pixel density of the display apparatus DSP2 can be greater than or equal to 500 ppi, preferably greater than or equal to 1000 ppi, further preferably greater than or equal to 3000 ppi, still further preferably greater than or equal to 5000 ppi, still further preferably greater than or equal to 6000 ppi. Thus, the display apparatus DSP2 can be, for example, a display apparatus for AR or VR and can be suitably used in an electronic device with a short distance between a display portion and the user, such as a head-mounted display.

### <Pixel Layout>

Here, a pixel layout is described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and pentile arrangement.

Examples of the top surface shape of the subpixel include polygons such as a triangle, a tetragon (including a rectangle and a square), and a pentagon; polygons with rounded corners; an ellipse; and a circle. Here, the top surface shape of the subpixel corresponds to the top surface shape of a light-emitting region of the light-emitting device.

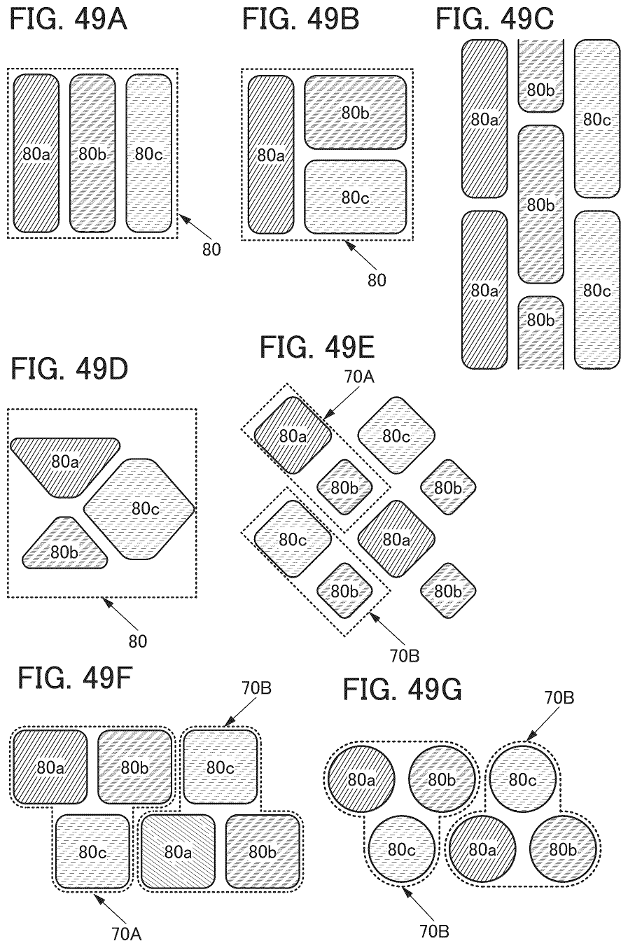

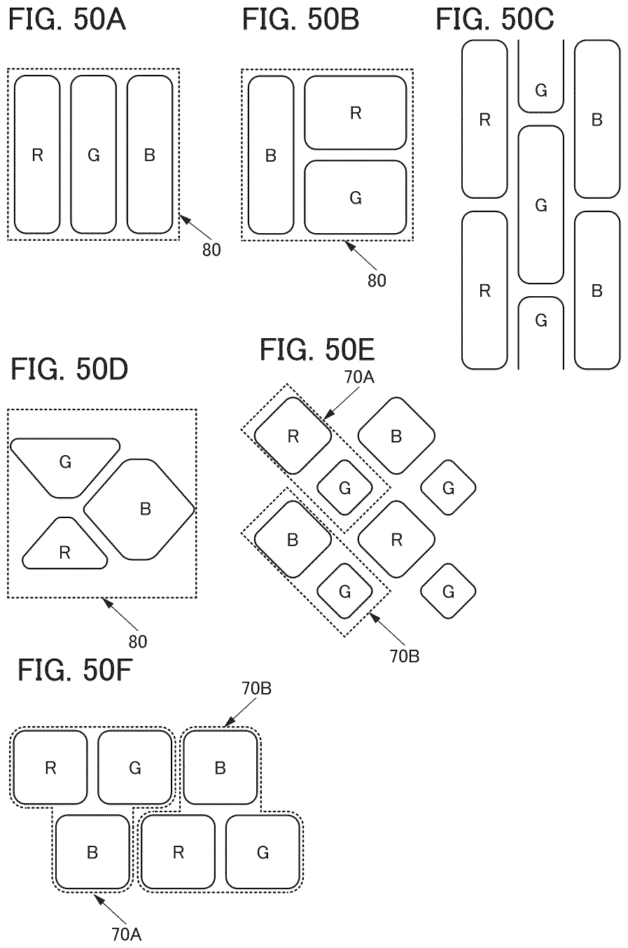

A pixel 80 illustrated in FIG. 49A employs stripe arrangement. The pixel 80 illustrated in FIG. 49A is composed of three subpixels: a subpixel 80a, a subpixel 80b, and a subpixel 80c. For example, as illustrated in FIG. 50A, the subpixel 80a may be a red subpixel R, the subpixel 80b may be a green subpixel G, and the subpixel 80c may be a blue subpixel B.

The pixel 80 illustrated in FIG. 49B employs S-stripe arrangement. The pixel 80 illustrated in FIG. 49B is composed of three subpixels: the subpixel 80a, the subpixel 80b, and the subpixel 80c. For example, as illustrated in FIG. 50B, the subpixel 80a may be the blue subpixel B, the subpixel 80b may be the red subpixel R, and the subpixel 80c may be the green subpixel G.

FIG. 49C illustrates an example where subpixels of different colors are arranged in a zigzag manner. Specifically, the positions of the top sides of two subpixels arranged in the column direction (e.g., the subpixel 80a and the subpixel 80b or the subpixel 80b and the subpixel 80c) are not aligned in the plan view. For example, as illustrated in FIG. 50C, the subpixel 80a may be the red subpixel R, the subpixel 80b may be the green subpixel G, and the subpixel 80c may be the blue subpixel B.

The pixel 80 illustrated in FIG. 49D includes the subpixel 80a whose top surface has a rough trapezoidal shape with rounded corners, the subpixel 80b whose top surface has a rough triangle shape with rounded corners, and the subpixel 80c whose top surface has a rough tetragonal or rough hexagonal shape with rounded corners. The subpixel 80a has a larger light-emitting area than the subpixel 80b. In this manner, the shapes and sizes of the subpixels can be determined independently. For example, the size of a subpixel including a light-emitting device with higher reliability can be smaller. For example, as illustrated in FIG. 50D, the subpixel 80a may be the green subpixel G, the subpixel 80b may be the red subpixel R, and the subpixel 80c may be the blue subpixel B.

A pixel 70A and a pixel 70B illustrated in FIG. 49E employ pentile arrangement. FIG. 49E illustrates an example where the pixels 70A including the subpixel 80a and the subpixel 80b and the pixels 70B including the subpixel 80b and the subpixel 80c are alternately arranged. For example, as illustrated in FIG. 50E, the subpixel 80a may be the red subpixel R, the subpixel 80b may be the green subpixel G, and the subpixel 80c may be the blue subpixel B.

The pixel 70A and the pixel 70B illustrated in FIG. 49F and FIG. 49G employ delta arrangement. The pixel 70A includes two subpixels (the subpixel 80a and the subpixel 80b) in the upper row (first row) and one subpixel (the subpixel 80c) in the lower row (second row). The pixel 70B includes one subpixel (the subpixel 80c) in the upper row (first row) and two subpixels (the subpixel 80a and the subpixel 80b) in the lower row (second row). For example, as illustrated in FIG. 50F, the subpixel 80a may be the red subpixel R, the subpixel 80b may be the green subpixel G, and the subpixel 80c may be the blue subpixel B.

FIG. 49F illustrates an example in which each subpixel has a rough tetragonal top surface shape with rounded corners, and FIG. 49G illustrates an example in which each subpixel has a circular top surface shape.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel has a polygonal shape with rounded corners, an elliptical shape, or a circular shape in some cases.

Furthermore, in the method for manufacturing the display apparatus of one embodiment of the present invention, the EL layer is processed into an island shape with the use of a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape by processing. As a result, the top surface of the EL layer may have a polygonal shape with rounded corners, an elliptical shape, or a circular shape. For example, when a resist mask with a square top surface is intended to be formed, a resist mask with a circular top surface may be formed, and the top surface of the EL layer may be circular.

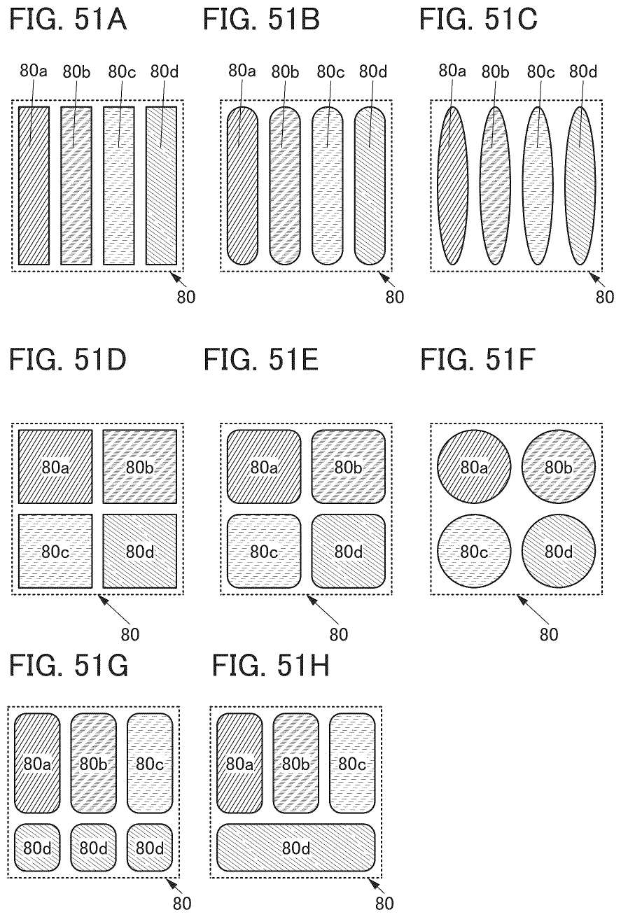

To obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern. The pixels 80 illustrated in FIG. 51A to FIG. 51C employ stripe arrangement.

FIG. 51A illustrates an example where each subpixel has a rectangular top surface shape, FIG. 51B illustrates an example where each subpixel has a top surface shape formed by combining two half circles and a rectangle, and FIG. 51C illustrates an example where each subpixel has an elliptical top surface shape.

The pixels 80 illustrated in FIG. 51D to FIG. 51F employ matrix arrangement.

FIG. 51D illustrates an example where each subpixel has a square top surface shape, FIG. 51E illustrates an example where each subpixel has a substantially square top surface shape with rounded corners, and FIG. 51F illustrates an example where each subpixel has a circular top surface shape.

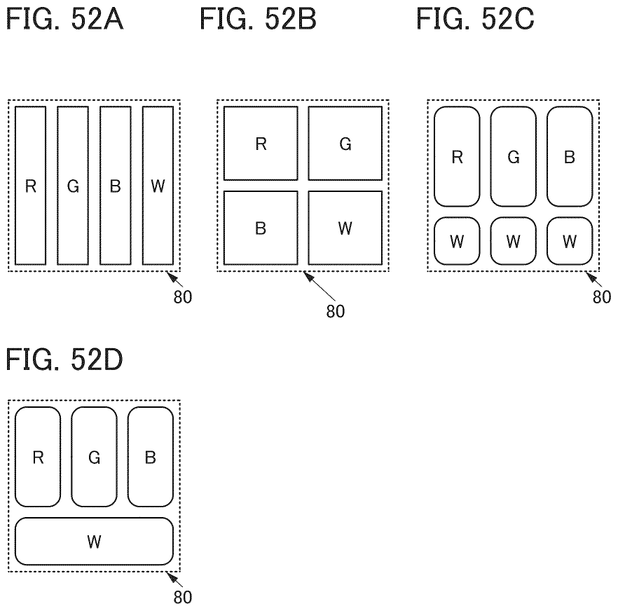

The pixels 80 illustrated in FIG. 51A to FIG. 51F are each composed of four subpixels: the subpixel 80a, the subpixel 80b, the subpixel 80c, and a subpixel 80d. The subpixel 80a, the subpixel 80b, the subpixel 80c, and the subpixel 80d emit light of different colors. For example, the subpixel 80a, the subpixel 80b, the subpixel 80c, and the subpixel 80d can be red, green, blue, and white subpixels, respectively. For example, the subpixel 80a, the subpixel 80b, the subpixel 80c, and the subpixel 80d can be red, green, blue, and white subpixels, respectively, as illustrated in FIG. 52A and FIG. 52B. Alternatively, the subpixel 80a, the subpixel 80b, the subpixel 80c, and the subpixel 80d can be red, green, blue, and infrared-light subpixels, respectively.

The subpixel 80d includes a light-emitting device. The light-emitting device includes, for example, a pixel electrode, an EL layer, and a common electrode. Note that for the pixel electrode, a material similar to those of the conductor 112a to the conductor 112c or the conductor 126a to the conductor 126c is used. For the EL layer, a material similar to that of the first layer 113a, the second layer 113b, or the third layer 113c is used, for example.

FIG. 51G illustrates an example where one pixel 80 is composed of two rows and three columns. The pixel 80 includes three subpixels (the subpixel 80a, the subpixel 80b, and the subpixel 80c) in the upper row (first row) and three subpixels 80d in the lower row (second row). In other words, the pixel 80 includes the subpixel 80a and the subpixel 80d in the left column (first column), the subpixel 80b and another subpixel 80d in the center column (second column), and the subpixel 80c and another subpixel 80d in the right column (third column). Matching the positions of the subpixels in the upper row and the lower row as illustrated in FIG. 51G enables dust and the like that would be produced in the manufacturing process to be removed efficiently. Thus, a display apparatus with high display quality can be provided.

FIG. 51H illustrates an example where one pixel 80 is composed of two rows and three columns. The pixel 80 includes three subpixels (the subpixel 80a, the subpixel 80b, and the subpixel 80c) in the upper row (first row) and one subpixel (the subpixel 80d) in the lower row (second row). In other words, the pixel 80 includes the subpixel 80a in the left column (first column), the subpixel 80b in the center column (second column), the subpixel 80c in the right column (third column), and the subpixel 80d across these three columns.

In the pixel 80 illustrated in each of FIG. 51G and FIG. 51H, for example, the subpixel 80a can be the red subpixel R, the subpixel 80b can be the green subpixel G, the subpixel 80c can be the blue subpixel B, and the subpixel 80d can be a white subpixel W, as illustrated in FIG. 52C and FIG. 52D.

Next, examples of a pixel layout applicable to the display apparatus DSP2F in FIG. 43 is described. That is, the pixel layout of the display apparatus DSP2F can be regarded as a plan view of the LED chip 180 of the display apparatus DSP2F illustrated in FIG. 43.

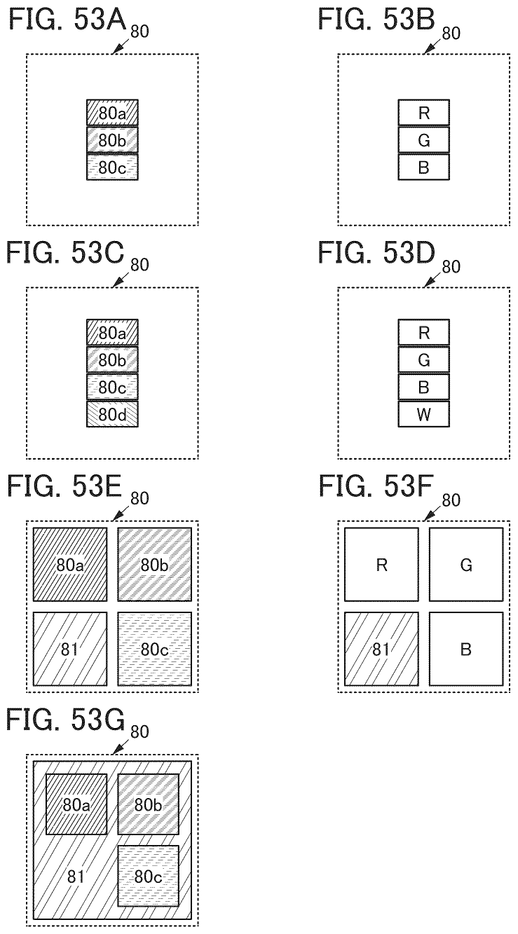

In the pixel 80 illustrated in FIG. 53A, subpixels each have a rectangular top surface and are arranged such that long sides of the subpixels are adjacent to one another. Note that the subpixels may be arranged to be in contact with each other or may be arranged not to be in contact with each other.

The pixel 80 illustrated in FIG. 53A includes three subpixels: the subpixel 80a, the subpixel 80b, and the subpixel 80c. As an example, the subpixel 80a, the subpixel 80b, and the subpixel 80c emit light of different colors. The different colors here can be, for example, red (R), green (G), and blue (B). Thus, the subpixel 80a, the subpixel 80b, and the subpixel 80c can be subpixels for red (R), green (G), and blue (B), respectively, as illustrated in FIG. 53B. Note that in FIG. 53B, the colors of light emitted by the subpixel 80a, the subpixel 80b, and the subpixel 80c can be cyan (C), magenta (M), yellow (Y), or white (W) in addition to red (R), green (G), and blue (B).

The number of subpixels included in the pixel 80 illustrated in FIG. 53A is three, but the number of subpixels included in the pixel 80 illustrated in FIG. 53A may be one, two, or four or more. For example, as illustrated in FIG. 53C, the pixel 80 includes four subpixels: the subpixel 80a, the subpixel 80b, the subpixel 80c, and the subpixel 80d. The subpixel 80a, the subpixel 80b, and the subpixel 80c in the pixel 80 in FIG. 53C can be configured to emit light of different colors in a manner similar to that of the pixel 80 in FIG. 53A. The different colors here can be, for example, red (R), green (G), blue (B), and white (W). Accordingly, the subpixel 80a, the subpixel 80b, the subpixel 80c, and the subpixel 80d can be subpixels for red (R), green (G), blue (B), and white (W), respectively, as illustrated in FIG. 53D.

Note that in FIG. 53D, the colors of light emitted by the subpixel 80a, the subpixel 80b, the subpixel 80c, and the subpixel 80d can be cyan (C), magenta (M), or yellow (Y) in addition to red (R), green (G), blue (B), and white (W).

Although FIG. 53A and FIG. 53C illustrate examples where the subpixels in the pixel 80 are arranged such that the long sides are adjacent to one another as an example, the subpixels in the pixel 80 may be arranged such that the short sides are adjacent to one another.

FIG. 53E illustrates an example where each pixel has a square top surface and an electrode is formed.

The pixel 80 illustrated in FIG. 53E includes a conductor 81 serving as an electrode and three subpixels: the subpixel 80a, the subpixel 80b, and the subpixel 80c.

As an example, the subpixel 80a, the subpixel 80b, and the subpixel 80c emit light of different colors. The different colors here can be, for example, red (R), green (G), and blue (B). Thus, the subpixel 80a, the subpixel 80b, and the subpixel 80c can be subpixels for red (R), green (G), and blue (B), respectively, as illustrated in FIG. 53F.

Note that in FIG. 53F, the colors of light emitted by the subpixel 80a, the subpixel 80b, and the subpixel 80c can be cyan (C), magenta (M), yellow (Y), or white (W) in addition to red (R), green (G), and blue (B).

The conductor 81 has a function of a common electrode of light-emitting diodes provided in the subpixel 80a, the subpixel 80b, and the subpixel 80c, for example. In particular, the common electrode preferably functions as a cathode electrode of the light-emitting diode included in each of the subpixel 80a, the subpixel 80b, and the subpixel 80c.

The conductor 81 corresponds to the electrode 172 or the electrode 173 in the LED package 170 in FIG. 44A, for example. Thus, a material usable for the electrode 172 or the electrode 173 can be used as a material for the conductor 81, for example.

Note that the conductor 81 may be provided such that the subpixel 80a, the subpixel 80b, and the subpixel 80c are positioned above the conductor 81 as illustrated in FIG. 53G. That is, the subpixel 80a, the subpixel 80b, and the subpixel 80c are provided over the conductor 81. The conductor 81 of the pixel 80 in FIG. 53G corresponds the electrode 172 of the LED package 170A1 in FIG. 44B.

Although a conductor corresponding to the electrode 173 of the LED package 170A1 in FIG. 44B is not illustrated in the pixel 80 in FIG. 53G, the pixel 80 in FIG. 53G may include the conductor corresponding to the electrode 173.

The number of electrodes of the pixel 80 illustrated in FIG. 53E is one, but the number of electrodes of the pixel 80 illustrated in FIG. 53E may be two or more. For example, the number of electrodes of the pixel 80 may be determined in accordance with the number of subpixels. For example, in the case where an anode electrode and a cathode electrode are provided in each of three subpixels in the pixel 80 in FIG. 53E, the number of electrodes provided in the pixel 80 can be six. For another example, in the case where an anode electrode and a common electrode serving as a cathode electrode are provided in each of three subpixels in the pixel 80 in FIG. 53E, the number of electrodes provided in the pixel 80 can be four.

The top surface of the conductor 81 of the pixel 80 has a square shape in FIG. 53E, but the top surface of the conductor 81 may have a variety of shapes such as a rough trapezoid shape with rounded corners, a rough square shape with rounded corners, a rough hexagonal shape with rounded corners, a shape formed by combining a half circle and a rectangle, a circular shape, or an elliptical shape.

One of the plurality of subpixels included in the pixel 80 illustrated in each of FIG. 49A to FIG. 49G, FIG. 51A to FIG. 51H, FIG. 53A, and FIG. 53C may be replaced with the conductor 81.

Note that the insulators, the conductors, and the semiconductors disclosed in this specification and the like can be formed by a PVD (Physical Vapor Deposition) method or a CVD method. Examples of a PVD method include a sputtering method, a resistance heating evaporation method, an electron beam evaporation method, an MBE (Molecular Beam Epitxy) method, and a PLD method. Examples of the CVD method include a plasma CVD method and a thermal CVD method. In particular, examples of a thermal CVD method include a MOCVD (Metal Organic Chemical Vapor Deposition) method and an ALD method.

A thermal CVD method is a deposition method not using plasma, and thus has an advantage that no defect due to plasma damage is generated.

Deposition by a thermal CVD method may be performed in such a manner that a source gas and an oxidizer are supplied into a chamber at a time, the pressure in the chamber is set to an atmospheric pressure or a reduced pressure, and they are made to react with each other in the vicinity of the substrate or over the substrate to be deposited over the substrate.

Deposition by an ALD method may be performed in such a manner that pressure in a chamber is set to an atmospheric pressure or a reduced pressure, source gases for reaction are sequentially introduced into the chamber, and then the sequence of the gas introduction is repeated. For example, two or more kinds of source gases are sequentially supplied to the chamber by switching respective switching valves (also referred to as high-speed valves); in order to avoid mixing of the plurality of kinds of source gases, an inert gas (e.g., argon or nitrogen) or the like is introduced at the same time as or after introduction of a first source gas and then a second source gas is introduced. Note that in the case where the first source gas and the inert gas are introduced at a time, the inert gas serves as a carrier gas, and the inert gas may also be introduced at the same time as the introduction of the second source gas. Alternatively, the second source gas may be introduced after the first source gas is exhausted by vacuum evacuation instead of the introduction of the inert gas. The first source gas is adsorbed on the surface of the substrate to deposit a first thin layer; then the second source gas is introduced to react with the first thin layer; as a result, a second thin layer is stacked over the first thin layer, so that a thin film is formed. The sequence of the gas introduction is controlled and repeated a plurality of times until a desired thickness is obtained, so that a thin film with excellent step coverage can be formed. The thickness of the thin film can be adjusted by the number of repetition times of the sequence of the gas introduction; therefore, an ALD method makes it possible to accurately adjust the thickness and is thus suitable for manufacturing a minute FET.

A variety of films such as the metal film, the semiconductor film, and the inorganic insulating film disclosed in the above-described embodiments can be formed by a thermal CVD method such as an MOCVD method and an ALD method; for example, in the case of depositing an In—Ga—Zn—O film, trimethylindium (In(CH₃)₃), trimethylgallium (Ga(CH₃)₃), and dimethylzinc (Zn(CH₃)₂) are used. Without limitation to the above combination, triethylgallium (Ga(C₂H₅)₃) can also be used instead of trimethylgallium, and diethylzinc (Zn(C₂H₅)₂) can also be used instead of dimethylzinc.

For example, in the case where a hafnium oxide film is formed with a deposition apparatus using an ALD method, two kinds of gases, ozone (O₃) as an oxidizer and a source gas which is obtained by vaporizing liquid containing a solvent and a hafnium precursor compound (e.g., hafnium alkoxide and hafnium amide such as tetrakis(dimethylamide) hafnium (TDMAH, Hf[N(CH₃)₂]₄)), are used. Examples of another material include tetrakis(ethylmethylamide) hafnium.

For example, in the case where an aluminum oxide film is formed with a deposition apparatus using an ALD method, two kinds of gases, H₂O as an oxidizer and a source gas which is obtained by vaporizing liquid containing a solvent and an aluminum precursor compound (e.g., trimethylaluminum (TMA, Al(CH₃)₃)) are used. Examples of another material include tris(dimethylamide) aluminum, triisobutylaluminum, and aluminum tris(2,2,6,6-tetramethyl-3,5-heptanedionate).

For example, in the case where a silicon oxide film is formed by a deposition apparatus using an ALD method, hexachlorodisilane is adsorbed on a surface on which a film is to be formed, and radicals of an oxidizing gas (e.g., O₂ or dinitrogen monoxide) are supplied to react with the adsorbate.

For example, in the case where a tungsten film is deposited by a deposition apparatus using an ALD method, a WF₆ gas and a B₂H₆ gas are sequentially and repeatedly introduced to form an initial tungsten film, and then a WF₆ gas and an H₂ gas are sequentially and repeatedly introduced to form a tungsten film. Note that an SiH₄ gas may be used instead of a B₂H₆ gas.

In the case where an In—Ga—Zn—O film is deposited as an oxide semiconductor film with a deposition apparatus using an ALD method, a precursor (generally referred to as a metal precursor or the like in some cases) and an oxidizer (generally referred to as a reactant, a non-metal precursor, or the like in some cases) are sequentially and repetitively introduced. Specifically, for example, an In(CH₃)₃ gas as a precursor and an O₃ gas as an oxidizer are introduced to form an In—O layer; a Ga(CH₃)₃ gas as a precursor and an O₃ gas as an oxidizer are introduced to form a GaO layer; and then, a Zn(CH₃)₂ gas as a precursor and an O₃ gas as an oxidizer are introduced to form a ZnO layer. Note that the order of these layers is not limited to this example. A mixed oxide layer such as an In—Ga—O layer, an In—Zn—O layer, or a Ga—Zn—O layer may be formed with the use of these gases. Note that although an H₂O gas which is obtained by bubbling water with an inert gas (e.g., Argon) may be used instead of an O₃ gas, it is preferable to use an O₃ gas which does not contain H. Furthermore, instead of an In(CH₃)₃ gas, an In(C₂H₅)₃ gas may be used. Furthermore, instead of a Ga(CH₃)₃ gas, a Ga(C₂H₅)₃ gas may be used. Furthermore, instead of a Zn(CH₃)₂ gas, a Zn(C₂H₅)₂ gas may be used.

There is no particular limitation on the screen ratio (aspect ratio) of the display portion of the electronic device of one embodiment of the present invention. For example, the display portion is compatible with a variety of screen ratios such as 1:1 (a square), 4:3, 16:9, 16:10, 21:9, and 32:9.

There is no particular limitation on the shape of the display portion of the electronic device of one embodiment of the present invention. The display portion can have any of various shapes such as a rectangular shape, a polygonal shape (e.g., an octagonal shape), a circular shape, and an elliptical shape.

Note that this embodiment can be combined with any of the other embodiments described in this specification as appropriate. For example, the configurations, structures, methods, and the like described in this embodiment can be used in an appropriate combination with any of the configurations, structures, methods, and the like described in the other embodiments and the like.

### Embodiment 3

In this embodiment, electronic devices each including a display apparatus fabricated using one embodiment of the present invention will be described. Electronic devices described in this embodiment as examples are each provided with a display apparatus of one embodiment of the present invention in a display portion. Thus, the electronic devices achieve high definition.

One embodiment of the present invention includes the display apparatus and one or more selected from an antenna, a battery, a housing, a camera, a speaker, a microphone, a touch sensor, and an operation button.

The electronic device of one embodiment of the present invention may include a secondary battery. It is preferable that the secondary battery be capable of being charged by non-contact power transmission.

Examples of the secondary battery include a lithium ion secondary battery (such as a lithium polymer battery using a gel electrolyte (lithium ion polymer battery)), a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. With the antenna receiving a signal, the electronic device can display an image, information, or the like on a display portion. When the electronic device includes an antenna and a secondary battery, the antenna may be used for contactless power transmission.

The display portion of the electronic device of one embodiment of the present invention can display, for example, an image with full high definition, 4K2K, 8K4K, 16K8K, or higher resolution.

As examples of the electronic device, electronic devices having a relatively large screen, such as a television device, a laptop personal computer, a monitor device, digital signage, a pachinko machine, and a game machine are given. In addition, as the electronic device, such as a digital camera, a digital video camera, a digital photo frame, a mobile phone device, a portable game machine, a portable information terminal, and an audio reproducing device are given.

An electronic device to which one embodiment of the present invention is applied can be incorporated along an inner wall or an outer wall of a house or a building. The electronic device can be incorporated along a flat surface or a curved surface of an interior, an exterior, or the like of an automobile or the like.

### [Mobile Phone]

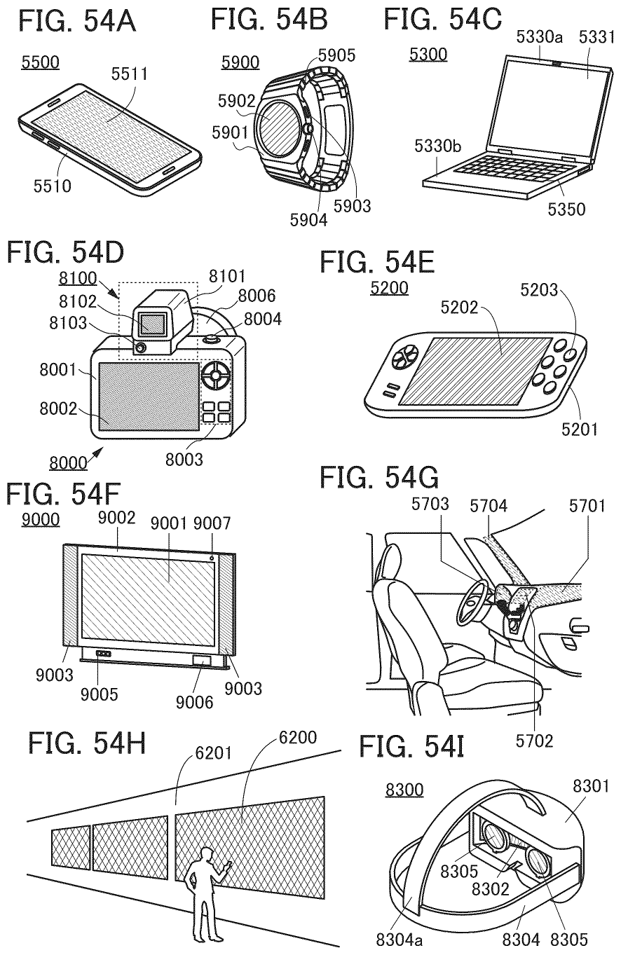

An information terminal 5500 illustrated in FIG. 54A is a mobile phone (a smartphone), which is a type of information terminal. The information terminal 5500 includes a housing 5510 and a display portion 5511. As input interfaces, a touch panel and a button are provided in the display portion 5511 and the housing 5510, respectively.

### [Wearable Terminal]

FIG. 54B is an external view of an information terminal 5900 as an example of a wearable terminal. The information terminal 5900 includes a housing 5901, a display portion 5902, an operation button 5903, a crown 5904, and a band 5905.

### [Information Terminal]

FIG. 54C illustrates a notebook information terminal 5300. The notebook information terminal 5300 in FIG. 54C includes, for example, a display portion 5331 in a housing 5330a and a keyboard portion 5350 in a housing 5330b.

Note that although FIG. 54A to FIG. 54C illustrate a smartphone, a wearable terminal, and a notebook information terminal as examples of electronic device, one embodiment of the present invention can also be applied to an information terminal other than a smartphone, a wearable terminal, and a notebook information terminal. Examples of the information terminals other than a smartphone, a wearable terminal, and a notebook information terminal include a personal digital assistant (PDA), a desktop information terminal, and a workstation.

### [Camera]

FIG. 54D is an external view of a camera 8000 to which a finder 8100 is attached. The camera 8000 includes a housing 8001, a display portion 8002, operation buttons 8003, and a shutter button 8004. Furthermore, a detachable lens 8006 is attached to the camera 8000. The finder 8100 includes a housing 8101, a display portion 8102, and a button 8103.

Note that the lens 8006 may be included in the housing of the camera 8000.

Images can be taken with the camera 8000 at the press of the shutter button 8004 or the touch of the display portion 8002 serving as a touch panel.

The housing 8001 includes a mount including an electrode, so that a stroboscope, for example, as well as the finder 8100 can be connected to the housing.

The housing 8101 is attached to the camera 8000 by a mount for engagement with the mount of the camera 8000. The finder 8100 can display an image received from the camera 8000 on the display portion 8102.

The button 8103 functions as a power supply button.

The display apparatus of one embodiment of the present invention can be used in the display portion 8002 of the camera 8000 and the display portion 8102 of the finder 8100. Note that a finder may be incorporated in the camera 8000.

### [Game Machine]

FIG. 54E is an external view of a portable game machine 5200 as an example of a game machine. The portable game machine 5200 includes a housing 5201, a display portion 5202, and a button 5203.

An image displayed on the portable game machine 5200 can be output with a display apparatus included in a television device, a personal computer display, a game display, or a head-mounted display.

The portable game machine 5200 can have low power consumption by including the display apparatus described in the above embodiment. Furthermore, heat generation from a circuit can be reduced owing to low power consumption; thus, the influence of heat generation on the circuit, the peripheral circuit, and the module can be reduced.

Although FIG. 54E illustrates the portable game machine as an example of a game machine, the electronic device of one embodiment of the present invention is not limited thereto. Examples of the electronic device of one embodiment of the present invention include a stationary game machine, an arcade game machine installed in an entertainment facility (e.g., a game center or an amusement park), and a throwing machine for batting practice installed in sports facilities.

### [Television Device]

FIG. 54F is a perspective view illustrating a television device. The television device 9000 includes a housing 9002, a display portion 9001, a speaker 9003, an operation key 9005 (including a power switch or an operation switch), a connection terminal 9006, a sensor 9007 (a sensor having a function of measuring or detecting force, displacement, position, speed, acceleration, angular velocity, rotational frequency, distance, light (including infrared rays), liquid, magnetism, temperature, chemical substance, sound, time, hardness, electric field, current, voltage, power, radiation, flow rate, humidity, gradient, oscillation, odor, or light (including visible light, invisible light such as infrared rays or ultraviolet rays)). The memory device of one embodiment of the present invention can be provided in the television device. The television device can include the display portion 9001 having a screen size of, for example, 50 inches or more, or 100 inches or more.

The television device 9000 to which the display apparatus described in the above embodiment is applied achieves low power consumption. Furthermore, heat generation from a circuit can be reduced owing to low power consumption; thus, the influence of heat generation on the circuit, the peripheral circuit, and the module can be reduced.

### [Moving Vehicle]

The display apparatus of one embodiment of the present invention can be used around a driver's seat in a car, which is a moving vehicle.

FIG. 54G illustrates a windshield and its vicinity inside a car. FIG. 54G shows a display panel 5701, a display panel 5702, and a display panel 5703 which are attached to a dashboard, and a display panel 5704 attached to a pillar.

The display panel 5701 to the display panel 5703 can provide various kinds of information by displaying navigation data, a speedometer, a tachometer, a mileage, a fuel meter, a gearshift state, air-conditioning settings, and the like. Items displayed on the display panel and their layout can be changed as appropriate to suit the user's preferences, resulting in more sophisticated design. The display panel 5701 to the display panel 5703 can also be used as lighting devices.

The display panel 5704 can compensate for the view obstructed by the pillar (blind areas) by showing an image taken by an imaging unit provided for the car body. That is, displaying an image taken by the imaging unit provided on the outside of the car body leads to elimination of blind areas and enhancement of safety. Moreover, showing an image to compensate for the area that a driver cannot see makes it possible for the driver to confirm safety more easily and comfortably. The display panel 5704 can also be used as a lighting device.

The display apparatus of one embodiment of the present invention can be used for the display panel 5701 to the display panel 5704, for example.

Although a car is described above as an example of a moving vehicle, moving vehicles are not limited to a car. Examples of the moving vehicles include a train, a monorail train, a ship, and a flying object (a helicopter, an unmanned aircraft (a drone), an airplane, and a rocket), and these moving vehicles can use the display apparatus of one embodiment of the present invention.

### [Digital Signage]

FIG. 54H illustrates an example of a digital signage that can be attached to a wall. FIG. 54H illustrates a state where a digital signage 6200 is attached to a wall 6201. The display apparatus of one embodiment of the present invention can be used in a display portion in the digital signage 6200, for example. An interface such as a touch panel may be provided in the digital signage 6200.

Note that an electronic device attachable to a wall is described above as an example of a digital signage, the kind of the digital signage is not limited thereto. Examples of the digital signage include a digital signage mounted on a pillar, a freestanding digital signage placed on the ground, and a digital signage mounted on a rooftop or a side wall of a building.

### [Head-Mounted Display]

FIG. 54I is an external view of an electronic device 8300 which is a head-mounted display for VR. The electronic device 8300 includes the housing 8301, a display portion 8302, a band-like fixing member 8304, a fixture member 8304a worn on a head, and a pair of lenses 8305.

Although not illustrated in FIG. 541, the electronic device 8300 may include an interface such as an operation button or a power button.

A user can see display on the display portion 8302 through the lenses 8305. The display portion 8302 is preferably curved because the user can feel high realistic sensation. Another image displayed in another region of the display portion 8302 is viewed through the lenses 8305, so that three-dimensional display using parallax can be performed. Note that the number of the display portions 8302 is not limited to one; two display portions 8302 may be provided for user's respective eyes.

As the display portion 8302, a display apparatus with high definition is preferably used, for example. With use of a display apparatus with extremely high definition for the display portion 8302, even when the display portion 8302 is enlarged by the lens 8305, a more realistic image can be displayed without user's visual recognition of pixels.

The head-mounted display, which is an electronic device of one embodiment of the present invention, may have a structure of an electronic device which is a glasses-type head-mounted display, instead of the electronic device 8300 in FIG. 541 which is a goggles-type head-mounted display. In particular, a glasses-type head-mounted display is suitable for an electronic device for AR.

Note that this embodiment can be combined with any of the other embodiments in this specification as appropriate. The configurations, structures, methods, and the like described in this embodiment can be used in an appropriate combination with any of the configurations, structures, methods, and the like described in the other embodiments and the like.

[Reference Numerals]

BSFB: circuit, BSFBA: circuit, BSFBB: circuit, BSFB1: circuit, BSFB1A: circuit, BSFB1B:
circuit, BSFB2: circuit, BSFB3: circuit, BSFB4: circuit, BSFB5: circuit, BSFB6: circuit, BSFB6A:
circuit, BSFB6B: circuit, BSFB6C: circuit, BSFB6D: circuit, BSFB7: circuit, BSFB7A: circuit,
BSFC: circuit, BSFC1: circuit, BSFC2: circuit, BSPR: circuit, BSPRc: circuit, BSPRd: circuit,
BSPRi: circuit, BB: circuit, BBd: circuit, BBc: circuit, BBi: circuit, BBF: circuit, FB: circuit, FBc:
circuit, FBd: circuit, FBi1: circuit, FBi2: circuit, BUF: circuit, BF[1]: circuit, BF[m]: circuit, GD:
driver circuit, SD: driver circuit, SR: circuit, LAT: circuit, DAC: circuit, MNa: transistor, MNb:
transistor, MNd: transistor, MNe: transistor, MNf: transistor, MNg: transistor, MNFa: transistor,
MNFb: transistor, M1: transistor, M2: transistor, M3: transistor, M4: transistor, M5: transistor,
M6: transistor, M7: transistor, MN1: transistor, MN4: transistor, MN5: transistor, MN8: transistor,
MN9: transistor, MN10: transistor, MN11: transistor, MN12: transistor, MN14: transistor, MN15:
transistor, MN16: transistor, MN21: transistor, MN24: transistor, MN25: transistor, MN28:
transistor, MN31: transistor, MN34: transistor, MN35: transistor, MN36: transistor, MN37:
transistor, MN40: transistor, MN41: transistor, Ca: capacitor, Caf: capacitor, C3: capacitor, C4:
capacitor, C5: capacitor, C25: capacitor, C26: capacitor, INV1: logic circuit, INV2: logic circuit,
TMi: terminal, TMi1: terminal, TMi2: terminal, TMo: terminal, Ti: terminal, To: terminal, Bi:
terminal, Bo: terminal, Fi: terminal, Fi1: terminal, Fi2: terminal, Fo: terminal, BFi: terminal, BFo:
terminal, IT: terminal, CLK1: terminal, CLK2: terminal, CLK3: terminal, PWC: terminal, RT:
terminal, GT: terminal, OT: terminal, SRT: terminal, N: node, Nf: node, N1: node, N2: node,
VAL1: wiring, VAL2: wiring, VAL3: wiring, VAL4: wiring, VAL41: wiring, VAL42: wiring,
VAL51: wiring, VAL52: wiring, VDE1: wiring, VDE2: wiring, VDE11: wiring, VDE21: wiring,
VDE22: wiring, VDE23: wiring, VDE35: wiring, VDE36: wiring, VSE1: wiring, VSE2: wiring,
VSE3: wiring, VSE4: wiring, VSE5: wiring, VSE11: wiring, VSE12: wiring, VSE13: wiring,
VSE14: wiring, VSE15: wiring, BG1: wiring, BG2: wiring, BG3: wiring, RST: wiring, CL1:
wiring, CL2: wiring, PL: wiring, CLKLA: wiring, CLKLB: wiring, CLKLC: wiring, CLKLD:
wiring, PWCLA: wiring, PWCLB: wiring, PWCLC: wiring, PWCLD: wiring, VDL: wiring, SPR:
wiring, GL: wiring, GL[1]: wiring, GL[2]: wiring, GL[m]: wiring, SL: wiring, SL[1]: wiring,
SL[2]: wiring, SL[3]: wiring, SL[4]: wiring, SL[5]: wiring, SL[6]: wiring, G1: wiring, G2: wiring,
ANO: wiring, V0: wiring, VCOM: wiring, SS: signal, SMC: semiconductor, SDM: conductor,
GEM: conductor, PLG: conductor, DSP: display apparatus, DSP1: display apparatus, DSP1A:
display apparatus, DSP1B: display apparatus, DSP1C: display apparatus, DSP2: display apparatus,
DSP2A: display apparatus, DSP2AA: display apparatus, DSP2AB: display apparatus, DSP2AC:
display apparatus, DSP2B: display apparatus, DSP2C: display apparatus, DSP2D: display
apparatus, DSP2E: display apparatus, DSP2F: display apparatus, DIS: display region, EML: layer,
OSL: layer, SIC: circuit region, DRV: driver circuit region, MFNC: functional circuit region,
GDR: driver circuit, GDR1: driver circuit, GDR2: driver circuit, SDR: driver circuit, PDA: sensor,
DAD: digital-analog converter circuit, LVS: level shifter, TMR: terminal region, BS: substrate,
SCC: sensor controller, EPS: power supply circuit, MEM: memory device, TMC: timing controller,
ECR: correction circuit, SNCL: wiring, BSL: bus wiring, 21: CPU, 22: GPU, 22a: circuit, 22b:
circuit, 30: driver circuit, 70A: pixel, 70B: pixel, 80: pixel, 80a: subpixel, 80b: subpixel, 80c:
subpixel, 80d: subpixel, 81: conductor, 100: circuit, 100[1]: circuit, 100[2]: circuit, 100[m]: circuit,
100A1: circuit, 100A2: circuit, 100A3: circuit, 100A4: circuit, 103: insulator, 104: conductor, 105:
insulator, 106: conductor, 107: adhesive layer, 110: substrate, 111a: conductor, 111b: conductor,
111c: conductor, 112a: conductor, 112b: conductor, 112c: conductor, 113a: first layer, 113b:
second layer, 113c: third layer, 114: common layer, 115: common electrode, 116: protective layer,
117a: conductor, 117b: conductor, 118a: mask layer, 125: insulator, 126a: conductor, 126b:
conductor, 126c: conductor, 127: insulator, 128: layer, 129a: conductor, 129b: conductor, 129c:
conductor, 130R: light-emitting device, 130G: light-emitting device, 130B: light-emitting device,
131: protective layer, 140: connection portion, 147: resin layer, 148: resin layer, 166R: coloring
layer, 166G: coloring layer, 166B: coloring layer, 170: LED package, 170R: LED package, 170G:
LED package, 170B: LED package, 170A1: LED package, 170A2: LED package, 170A3: LED
package, 170S: LED package, 171: substrate, 172: electrode, 173: electrode, 174: heat sink, 175:
adhesive layer, 176: case, 177: wire, 178: sealing layer, 179: wire, 180: LED chip, 180R: LED
chip, 180G: LED chip, 180B: LED chip, 180A: LED chip, 181: substrate, 181R: substrate, 181G:
substrate, 181B: substrate, 182: semiconductor layer, 183: electrode, 183A: electrode, 184: light-
emitting layer, 185: semiconductor layer, 186: electrode, 187: electrode, 189: ball, 191: conductor,
192: conductor, 200: circuit, 200[1]: circuit, 200[2]: circuit, 200[3]: circuit, 200[4]: circuit, 200[5]:
circuit, 200[6]: circuit, 200A: circuit, 200A1: circuit, 200A2: circuit, 300: transistor, 300p:
transistor, 300d: transistor, 300OS: transistor, 300LT: transistor, 310: substrate, 312: element
isolation layer, 313: semiconductor region, 314a: low-resistance region, 314b: low-resistance
region, 315: insulator, 316: conductor, 317: insulator, 320: insulator, 322: insulator, 324: insulator,
326: insulator, 328: conductor, 330: conductor, 350: insulator, 352: insulator, 354: insulator, 356:
conductor, 361: insulator, 362: insulator, 363: insulator, 364: insulator, 366: conductor, 367:
conductor, 368: semiconductor layer, 368p: low-resistance region, 368i: semiconductor region,
369: conductor, 400: pixel circuit, 500: transistor, 500d: transistor, 500p: transistor, 500p1:
transistor, 500p2: transistor, 500p3: transistor, 500A: transistor, 500Ap: transistor, 500Ad:
transistor, 501: insulator, 505: conductor, 505a: conductor, 505b: conductor, 512: insulator, 514:
insulator, 516: insulator, 520: insulator, 522: insulator, 524: insulator, 531: metal oxide, 531a:
metal oxide, 531b: metal oxide, 533: metal oxide, 540: conductor, 540a: conductor, 540b:
conductor, 542a: conductor, 542a1: conductor, 542a2: conductor, 542b: conductor, 542b1:
conductor, 542b2: conductor, 543a: region, 543b: region, 544: conductor, 545: conductor, 550:
insulator, 551: insulator, 554: insulator, 555: insulator, 560: conductor, 560a: conductor, 560b:
conductor, 565: conductor, 574: insulator, 580: insulator, 581: insulator, 583: insulator, 583a:
insulator, 583b: insulator, 584: insulator, 590: conductor, 592: insulator, 594: insulator, 596:
conductor, 598: insulator, 599: insulator, 600: capacitor, 601: opening, 603: opening, 761: lower
electrode, 762: upper electrode, 763: EL layer, 764: layer, 771: light-emitting layer, 771a: light-
emitting layer, 771b: light-emitting layer, 771c: light-emitting layer, 772: light-emitting layer,
772a: light-emitting layer, 772b: light-emitting layer, 772c: light-emitting layer, 773: light-
emitting layer, 780: layer, 780a: layer, 780b: layer, 780c: layer, 781: layer, 782: layer, 785: charge-
generation layer, 785a-b: charge-generation layer, 785b-c: charge-generation layer, 790: layer,
790a: layer, 790b: layer, 790c: layer, 791: layer, 792: layer, 5200: portable game machine, 5201:
housing, 5202: display portion, 5203: button, 5300: laptop information terminal, 5330a: housing,
5330b: housing, 5331: display portion, 5350: keyboard portion, 5500: information terminal, 5510:
housing, 5511: display portion, 5701: display panel, 5702: display panel, 5703: display panel,
5704: display panel, 5900: information terminal, 5901: housing, 5902: display portion, 5903:
operation button, 5904: crown, 5905: band, 6200: digital signage, 6201: wall, 8000: camera, 8001:
housing, 8002: display portion, 8003: operation button, 8004: shutter button, 8006: lens, 8100:
finder, 8101: housing, 8102: display portion, 8103: button, 8300: electronic device, 8301: housing,
8302: display portion, 8304: fixture member, 8304a: fixture member, 8305: lens, 9000: television
device, 9001: display portion, 9002: housing, 9003: speaker, 9005: operation key, 9006:
connection terminal, 9007: sensor

1-4. (canceled)

5. A semiconductor device comprising:
a first transistor;
a second transistor;
a third transistor; and
a first capacitor,
wherein one of a source and a drain of the first transistor is electrically connected to one of a source and a drain of the second transistor,
wherein the other of the source and the drain of the first transistor is electrically connected to a gate of the third transistor and a first terminal of the first capacitor, and
wherein one of a source and a drain of the third transistor is electrically connected to a gate of the second transistor and a second terminal of the first capacitor.

6. The semiconductor device according to claim 5,
wherein the gate of the second transistor is electrically connected to the other of the source and the drain of the second transistor.

7. The semiconductor device according to claim 5, further comprising a buffer circuit,
wherein the buffer circuit comprises an input terminal and an output terminal,
wherein the input terminal of the buffer circuit is electrically connected to the one of the source and the drain of the third transistor and the second terminal of the first capacitor, and
wherein the output terminal of the buffer circuit is electrically connected to the gate of the second transistor.

8. The semiconductor device according to claim 5, further comprising a fourth transistor and a second capacitor,
wherein the one of the source and the drain of the first transistor is electrically connected to one of a source and a drain of the fourth transistor,
wherein the one of the source and the drain of the third transistor is electrically connected to a first terminal of the second capacitor, and
wherein the gate of the second transistor is electrically connected to the other of the source and the drain of the fourth transistor and a second terminal of the second capacitor.

9. A semiconductor device comprising:
a first transistor;
a second transistor;
a third transistor; and
a first capacitor,
wherein one of a source and a drain of the first transistor is electrically connected to one of a source and a drain of the second transistor,
wherein the other of the source and the drain of the first transistor is electrically connected to a gate of the third transistor, a gate of the second transistor, and a first terminal of the first capacitor, and
wherein one of a source and a drain of the third transistor is electrically connected to a second terminal of the first capacitor.

10. A display apparatus comprising:
a driver circuit; and
a display device,
wherein the driver circuit comprises the semiconductor device according to claim 5, and
wherein the driver circuit is configured to transmit a signal for displaying an image to the display device.

11. The display apparatus according to claim 10,
wherein the display device comprises a light-emitting device or a liquid crystal display device.

12. An electronic device comprising:
the display apparatus according to claim 11; and
a housing.

13. A semiconductor device comprising:
a first transistor;
a second transistor;
a third transistor;
a fourth transistor;
a fifth transistor;
a sixth transistor;
a seventh transistor;
an eighth transistor;
a first capacitor; and
a second capacitor,
wherein one of a source and a drain of the first transistor is electrically connected to one of a source and a drain of the second transistor, one of a source and a drain of the seventh transistor, and one of a source and a drain of the eighth transistor,
wherein the other of the source and the drain of the first transistor is electrically connected to a gate of the third transistor and a first terminal of the first capacitor,
wherein one of a source and a drain of the third transistor is electrically connected to a gate of the second transistor, one of a source and a drain of the fourth transistor, and a second terminal of the first capacitor,
wherein a gate of the fourth transistor is electrically connected to one of a source and a drain of the fifth transistor, one of a source and a drain of the sixth transistor, a gate of the eighth transistor, and a first terminal of the second capacitor, and
wherein a gate of the seventh transistor is electrically connected to a gate of the sixth transistor.

14. The semiconductor device according to claim 13, wherein the gate of the second transistor is electrically connected to the other of the source and the drain of the second transistor.

15. The semiconductor device according to claim 13, further comprising a buffer circuit,
wherein the buffer circuit comprises an input terminal and an output terminal,
wherein the input terminal of the buffer circuit is electrically connected to the one of the source and the drain of the third transistor and the second terminal of the first capacitor, and
wherein the output terminal of the buffer circuit is electrically connected to the gate of the second transistor.

16. The semiconductor device according to claim 13, further comprising a tenth transistor and a third capacitor,
wherein the one of the source and the drain of the first transistor is electrically connected to one of a source and a drain of the tenth transistor,
wherein the one of the source and the drain of the third transistor is electrically connected to a first terminal of the third capacitor, and
wherein the gate of the second transistor is electrically connected to the other of the source and the drain of the tenth transistor and a second terminal of the third capacitor.

17. A display apparatus comprising:
a driver circuit; and
a display device,
wherein the driver circuit comprises the semiconductor device according to claim 13, and
wherein the driver circuit is configured to transmit a signal for displaying an image to the display device.

18. The display apparatus according to claim 17,
wherein the display device comprises a light-emitting device or a liquid crystal display device.

19. An electronic device comprising:
the display apparatus according to claim 18; and
a housing.
